(19) United States
(12) Patent Application Publication
(10) Pub. No.: US 2015/0303387 A1
(43) Pub. Date: Oct. 22, 2015

(54) Organic Electroluminescent Device

(71) Applicant: UDC Ireland Limited, Dublin (IE)

(72) Inventor: Yoshitaka Kitamura, Ashigarakami-gun (JP)

(21) Appl. No.: 14/754,975

(22) Filed: Jun. 30, 2015

Related U.S. Application Data
(63) Continuation of application No. 11/272,763, filed on Nov. 15, 2005.

(30) Foreign Application Priority Data
Nov. 17, 2004 (JP) 2004-333263

(51) Int. Cl. H01L 51/00; H01L 51/50

(52) U.S. Cl. CPC H01L 51/0091; H01L 51/508; H01L 51/5064; H01L 51/5004; H01L 51/0087; H01L 51/0089; H01L 51/0085; H01L 51/0084; H01L 51/0086; H01L 51/0088; H01L 51/0094; H01L 51/5012; H01L 2251/5376; H01L 51/5016; H01L 2251/5361

(57) ABSTRACT

A first aspect of the invention is an organic electroluminescent device that includes a plurality of organic compound layers between a pair of electrodes. The plurality of organic compound layers include a luminescent layer and two or more hole-transporting layers. The hole-transporting layers include a layer adjacent to the luminescent layer. The luminescent layer contains a host material and a luminescent material. The luminescent material is a metal complex containing a tri- or higher-dentate ligand. When the ionization potential of the luminescent layer is designated as Ip₀, the ionization potential of the hole-transporting layer adjacent to the luminescent layer among the hole-transporting layers is designated as Ip₁, and the ionization potential of the n-th hole-transporting layer from the luminescent layer among the hole-transporting layers is designated as Ipₙ, these values satisfy the relationship represented by the following formula (1). In formula (1) n is an integer of 2 or more.

Ip₀>Ip₁>Ip₂> . . . >Ipₙ₋₁>Ipₙ formula (1)

### CROSS-REFERENCE TO RELATED APPLICATION

This application claims priority under 35 USC 119 from Japanese Patent Application Nos. 2004-333263, the disclosures of which are incorporated by reference herein.

### BACKGROUND OF THE INVENTION

1. Field of the Invention

The invention relates to an organic electroluminescent device that emits light by converting electric energy to light and, in particular, to an organic electroluminescent device capable of driving at low-voltage and having high driving durability.

2. Description of the Related Art

Today, research and development on various display devices is being vigorously conducted. Among these, organic electroluminescent devices (organic EL devices) have attracted attention as promising display devices because light emission can be obtained with high luminance at low voltage.

Generally, organic electroluminescent devices have one or more organic compound layers containing at least a luminescent layer and a pair of electrodes holding the layer in between. When an electric field is applied between the electrodes, electrons are injected from the cathode and holes from the anode. The electrons and the holes recombine in the luminescent layer, generating excitons and emitting light.

However, organic electroluminescent devices have a problem of luminous efficiency lower than that of inorganic LED devices or fluorescent lamps. Thus, there is an urgent need for further improvement in luminous efficiency and luminance. In addition, it is preferable for organic luminescent devices to be reduced in power consumption so that they might also be used as a display part of portable devices. From this viewpoint, it is desirable to reduce the driving voltage as much as possible.

For example, to solve the above problems and to improve durability, Japanese Patent Application Laid-Open (JP-A) No. 6-314594, the disclosure of which is incorporated by reference herein, discloses that it is possible to produce an organic thin film EL device superior in durability by inserting several carrier injecting layers at the interface between anode and luminescent layer and/or the interface between cathode and luminescent layer. Japanese Patent Application National Publication (Laid-Open) No. 2004-514257, the disclosure of which is incorporated by reference herein, discloses a protective layer of organic material formed between a charged-particle conductive layer containing impurities and a luminescent layer.

As for the luminescent material, U.S. Pat. No. 6,653,654B1, for example, the disclosure of which is incorporated by reference herein, discloses a device in which a complex having a tetradentate ligand is used as a luminescent material.

### SUMMARY OF THE INVENTION

The invention provides an organic electroluminescent device capable of driving at low voltage and/or having higher driving durability.

After intensive studies, the inventor has found that it was possible to improve the driving durability by using a metal complex having a tri- or higher-dentate ligand as the luminescent material, forming a luminescent layer and a plurality of charge-transporting layers, and controlling the ionization potential and/or the electron affinity among the luminescent layer and the plurality of charge-transporting layers to satisfy a certain relationship, and thus completed the invention.

A first aspect of the invention provides an organic electroluminescent device comprising a plurality of organic compound layers between a pair of electrodes. The plurality of organic compound layers include a luminescent layer and two or more hole-transporting layers. The hole-transporting layers include a layer adjacent to the luminescent layer. The luminescent layer contains a host material and a luminescent material. The luminescent material is a metal complex containing a tri- or higher-dentate ligand. When the ionization potential of the luminescent layer is designated as Ip₀, the ionization potential of the hole-transporting layer adjacent to the luminescent layer among the hole-transporting layers is designated as Ip₁, and the ionization potential of an n-th hole-transporting layer from the luminescent layer among the hole-transporting layers is designated as Ipₙ, these values satisfy the relationship represented by the following formula (1).

Ip₀>Ip₁>Ip₂> . . . >Ipₙ₋₁>Ipₙ formula (1)

In formula (1), n is an integer of 2 or more.

A second aspect of the invention provides an organic electroluminescent device comprising a plurality of organic compound layers between a pair of electrodes. The plurality of organic compound layers include a luminescent layer and two or more electron-transporting layers. The electron-transporting layers include a layer adjacent to the luminescent layer. The luminescent layer contains a host material and a luminescent material. The luminescent material is a metal complex containing a tri- or higher-dentate ligand. When the electron affinity of the luminescent layer is designated as Ea₀, the electron affinity of the electron-transporting layer adjacent to the luminescent layer among the electron-transporting layers is designated as Eaₜ, and the electron affinity of an m-th electron-transporting layer from the luminescent layer among the electron-transporting layers is designated as Eaₘ, these values satisfy the relationship represented by the following formula (2).

Ea₀<Ea₁<Ea₂< . . . <Eaₘ₋₁<Eaₘ formula (2)

In formula (2), m is an integer of 2 or more.

A third aspect of the invention provides an organic electroluminescent device comprising a plurality of organic compound layers between a pair of electrodes. The plurality of organic compound layers include a luminescent layer, two or more hole-transporting layers, and two or more electron-transporting layers. The hole-transporting layers include a layer adjacent to the luminescent layer. The electron-transporting layers include a layer adjacent to the luminescent layer. The luminescent layer contains a host material and a luminescent material. The luminescent material is a metal complex containing a tri- or higher-dentate ligand. When the ionization potential of the luminescent layer is designated as Ip₀, the ionization potential of the hole-transporting layer adjacent to the luminescent layer among the hole-transporting layers is designated as Ip₁, the ionization potential of an n-th hole-transporting layer from the luminescent layer among the hole-transporting layers is designated as Ipₙ, the electron affinity of the luminescent layer is designated as Ea₀, the electron affinity of the electron-transporting layer adjacent to the luminescent layer among the electron-transporting layers is designated as Ea₁, and the electron affinity of an m-th electron-transporting layer from the luminescent layer among the electron-transporting layers is designated as Eaₘ, these values satisfy the relationship represented by the following formulae (1) and (2).

Ip₀>Ip₁>Ip₂> . . . >Ipₙ₋₁>Ipₙ formula (1)

In formula (1), n is an integer of 2 or more.

Ea₀<Ea₁<Ea₂< . . . <Eaₘ₋₁<Eaₘ formula (2)

In formula (2), m is an integer of 2 or more.

A fourth aspect of the invention provides an organic electroluminescent device comprising a plurality of organic compound layers between a pair of electrodes. The plurality of organic compound layers include a first luminescent layer, a second luminescent layer, two or more hole-transporting layers, and two or more electron-transporting layers. The hole-transporting layers include a layer adjacent to the first luminescent layer. The electron-transporting layers include a layer adjacent to the second luminescent layer. Each of the first and second luminescent layers contains a host material and a luminescent material. The host materials contained in the first and second luminescent layers differ from each other. Each of the luminescent materials contained in the first and second luminescent layers is a metal complex containing a tri- or higher-dentate ligand.

A fifth aspect of the invention provides an organic electroluminescent device comprising a plurality of organic compound layers between a pair of electrodes. The plurality of organic compound layers include a first luminescent layer, a second luminescent layer, two or more hole-transporting layers, and two or more electron-transporting layers. The hole-transporting layers include a layer adjacent to the first luminescent layer. The electron-transporting layers include a layer adjacent to the second luminescent layer. Each of the first and second luminescent layers contains a host material and a luminescent material. The host materials contained in the first and second luminescent layers differ from each other. Each of the luminescent materials contained in the first and second luminescent layers is a metal complex containing a tri- or higher-dentate ligand. When the ionization potential of the first luminescent layer is designated as Ip₀, the ionization potential of the hole-transporting layer adjacent to the first luminescent layer among the hole-transporting layers is designated as Ip₁, the ionization potential of an n-th hole-transporting layer from the first luminescent layer among the hole-transporting layers is designated as Ipₙ, the electron affinity of the second luminescent layer is designated as Ea₀, the electron affinity of the electron-transporting layer adjacent to the second luminescent layer among the electron-transporting layers is Ea₁, and the electron affinity of an m-th electron-transporting layer from the second luminescent layer among the electron-transporting layers is designated as Eaₘ, these values satisfy the relationship represented by the following formulae (1) and (2).

Ip₀>Ip₁>Ip₂> . . . >Ipₙ₋₁>Ipₙ formula (1)

In formula (1), n is an integer of 2 or more.

Ea₀<Ea₁<Ea₂< . . . <Eaₘ₋₁<Eaₘ formula (2)

In formula (2), m is an integer of 2 or more.

### DETAILED DESCRIPTION OF THE INVENTION

Hereinafter, the organic electroluminescent device according to the invention (hereinafter, also referred to as “organic EL device” or “luminescent device”) will be described in detail. The range of “A to B” in the present specification means a range including A and B as the lower and upper limit values.

A first aspect of the invention is an organic electroluminescent device including at least a plurality of organic compound layers between a pair of electrodes, wherein the plurality of organic layers includes a luminescent layer containing a luminescent material and a host material, and two or more hole-transporting layers. The hole-transporting layers include a layer adjacent to the luminescent layer. The luminescent layer contains a metal complex having a tri- or higher-dentate ligand as the luminescent material. When the ionization potential of the luminescent layer is designated as Ip₀, the ionization potential of the hole-transporting layer adjacent to the luminescent layer among the hole-transporting layers is designated as Ip₁, and the ionization potential of the n-th hole-transporting layer from the luminescent layer among the hole-transporting layers is designated as Ipₙ, these values satisfy the relationship represented by the following Formula (1).

Ip₀>Ip₁>Ip₂> . . . >Ipₙ₋₁>IPₙ Formula (1)

In formula (1), n is an integer of 2 or more.

In the configuration above, it is possible to obtain an organic electroluminescent device having high driving durability.

In the first aspect of the invention, it seems that the high driving durability is due to the acceleration of charge (hole) injection caused by using a metal complex having a tri- or higher-dentate ligand that is superior in stability (chemical stability, in particular, for example, resistance to decomposition), forming two or more hole-transporting layers including a layer adjacent to the luminescent layer, and controlling the relationship in ionization potential among the luminescent layer and the two or more hole-transporting layers.

A feature of the invention is that the layer adjacent to the luminescent layer has the greatest ionization potential among the two or more hole-transporting layers; and such a configuration seems to be effective in reducing the barrier of charge injection, reducing retention of charge at the interfaces between the layers and consequently degradation of the material, and improving the driving durability significantly, in combination with the effect of using a metal complex having a tri- or higher-dentate ligand.

The second aspect of the invention is an organic electroluminescent device having at least a plurality of organic compound layers between a pair of electrodes, wherein the plurality of organic compound layers include a luminescent layer containing a luminescent material and a host material, and two or more electron-transporting layers. The electron-transporting layers include a layer adjacent to the luminescent layer. The luminescent layer contains a metal complex having a tri- or higher-dentate ligand as the luminescent material. When the electron affinity of the luminescent layer is designated as Ea₀, the electron affinity of the electron-transporting layer adjacent to the luminescent layer is designated Ea₁, and the electron affinity of the m-th electron-transporting layer from the luminescent layer is designated as Eaₘ, these values satisfy the relationship represented by the following Formula (2).

Ea₀<Ea₁<Ea₂< . . . <Eaₘ₋₁<Eaₘ Formula (2)

In formula (2), m is an integer of 2 or more.

In the configuration above, it is possible to produce an organic electroluminescent device having high driving durability.

Although the mechanism of effect of the configuration is not completely clear, it seems that the high driving durability is due to the acceleration of charge (electron) injection caused by using the metal complex having a tri- or higher-dentate ligand that is superior in stability, and controlling the relationships in electron affinity of the luminescent layer and the two or more electron-transporting layers.

The third aspect of the invention is an organic electroluminescent device having at least a plurality of organic compound layers between a pair of electrodes, wherein the plurality of organic compound layers include a luminescent layer containing a luminescent material and a host material, two or more hole-transporting layers, and two or more electron-transporting layers. The hole-transporting layers include a layer adjacent to the luminescent layer, and the electron-transporting layers include a layer adjacent to the luminescent layer. The luminescent layer contains a metal complex having a tri- or higher-dentate ligand as the luminescent material. When the ionization potential of the luminescent layer is designated as Ip₀, the ionization potential of the hole-transporting layer adjacent to the luminescent layer among the hole-transporting layers is designated as Ip₁, the ionization potential of the n-th hole-transporting layer from the luminescent layer among the hole-transporting layers is designated as Ipₙ, the electron affinity of the luminescent layer is designated as Ea₀, the electron affinity of the electron-transporting layer adjacent to the luminescent layer among the electron-transporting layers is designated Ea₁, and the electron affinity of the m-th electron-transporting layer from the luminescent layer among the electron-transporting layers is designated as Eaₘ, these values satisfy the following Formulae (1) and Formula (2).

Ip₀>Ip₁>Ip₂> . . . >Ipₙ₋₁>Ipₙ Formula (1)

In formula (1), n is an integer of 2 or more.

Ea₀<Ea₁<Ea₂< . . . <Eaₘ₋₁<Eaₘ Formula (2)

In formula (2), m is an integer of 2 or more.

As in the third aspect, it is possible to obtain a further higher driving durability by forming two or more hole-transporting layers and electron-transporting layers adjacent to the luminescent layer and controlling the relationships in ionization potential and electron affinity among these layers.

Alternatively, the organic electroluminescent device according to the invention may have two luminescent layers each containing a different host material for further improvement in driving durability, and the fourth and fifth aspects of the invention is an organic electroluminescent device in such a configuration. Thus, the fourth and fifth aspects of the invention is an organic electroluminescent device having at least a plurality of organic compound layers between a pair of electrodes, wherein the plurality of organic compound layers include first and second luminescent layers containing a luminescent material and a host material, two or more hole-transporting layers, and two or more electron-transporting layers. The hole-transporting layers include a layer adjacent to the first luminescent layer, and the electron-transporting layers include a layer adjacent to the second luminescent layer. Each of the first and second luminescent layers contains a different host material and a luminescent material of a metal complex having a tri- or higher-dentate ligand. Furthermore, in the fifth aspect of the invention, when the ionization potential of the first luminescent layer is designated as Ip₀, the ionization potential of the hole-transporting layer adjacent to the first luminescent layer among the hole-transporting layers is designated as Ip₁, the ionization potential of the n-th hole-transporting layer from the first luminescent layer among the hole-transporting layers is designated as Ipₙ, the electron affinity of the second luminescent layer is designated as Ea₀, the electron affinity of the electron-transporting layer adjacent to the second luminescent layer among the electron-transporting layers is designated as Ea₁, and the electron affinity of the m-th electron-transporting layer from the second luminescent layer among the electron-transporting layers is designated as Eaₘ, these values satisfy the relationships represented by the following Formulae (1) and (2).

Ip₀>Ip₁>Ip₂> . . . >Ipₙ₋₁>Ipₙ Formula (1)

In formula (1), n is an integer of 2 or more.

Ea₀<Ea₁<Ea₂< . . . <Eaₘ₋₁<Eaₘ Formula (2)

In formula (2), m is an integer of 2 or more.

The ionization potential (Ip) of each layer in the luminescent device according to the invention means the ionization potential of a material having the greatest ionization potential among the materials contained in the layer in an amount of 10 wt % or more. The ionization potential in the present specification is a value determined by using AC-1 (manufactured by Riken Keiki Co., Ltd.), at room temperature (preferably in the range of 15° C. or more and 25° C. or less) in air. The operational principle of AC-1 is described in Chihaya Adachi et al., “Work Function Data of Organic Thin Films” CMC Publishing, published in 2004, the disclosure of which is incorporated by reference herein.

The electron affinity (Ea) of each layer in the luminescent device according to the invention means the electron affinity of a material having the greatest electron affinity among the materials contained in the layer in an amount of 10 wt % or more. As for the electron affinity in the invention, the ultraviolet/visible absorption spectrum of the film used for measurement of ionization potential (preferably, at a temperature in the range of 15° C. or more and 25° C. or less) was measured and the excitation energy was determined from the energy at the longest wavelength terminal in the absorption spectrum. The electron affinity was calculated from the values of the excitation energy and the ionization potential. In the present specification, the ultraviolet/visible absorption spectrum was measured by using a spectrophotometer UV3100 manufactured by Shimadzu Corporation.

In each of the luminescent device according to the invention, the ionization potentials (Ip) of the luminescent layer, the hole-transporting layer adjacent to the luminescent layer, and the other hole-transporting layers, and/or the electron affinities (Ea) of the luminescent layer, electron-transporting layer adjacent to the luminescent layer, and other electron-transporting layers should satisfy a particular relationship. That is, they should satisfy the relationship represented by the following Formula (1) in the first aspect, the relationship represented by the following Formula (2) in the second aspect, and the relationships represented by the following Formulae (1) and (2) in the third and fourth aspects.

Ip₀>Ip₁>Ip₂> . . . >Ipₙ₋₁>Ipₙ Formula (1)

In formula (1), n is an integer of 2 or more.

Ea₀<Ea₁<Ea₂< . . . <Eaₘ₋₁<Eaₘ Formula (2)

In formula (2), m is an integer of 2 or more.

The luminescent device according to the invention should have two or more electron-transporting layers and/or two or more hole-transporting layers. The number of the hole-transporting layers is preferably 3 or more for reducing the interlayer potential barrier, and is preferably 4 or less from the viewpoint of easiness of production. The number of the electron-transporting layers is also preferably 3 or more for reducing the interlayer potential barrier, and is preferably 4 or less from the viewpoint of easiness of production.

In the first, second, and third aspects, when there is only one luminescent layer, the ionization potential of the luminescent layer (Ip₀) is preferably 6.4 eV or less, more preferably 6.3 eV or less, and particularly preferably 6.2 eV or less. The electron affinity of the luminescent layer (Ea₀) is preferably 2.1 eV or more, more preferably 2.2 eV or more, and particularly preferably 2.3 eV or more.

The ionization potential of the hole-transporting layer adjacent to the luminescent layer (Ip₁) is preferably 6.2 to 5.3 eV, more preferably 6.1 to 5.4 eV, and particularly preferably 6.0 to 5.5 eV. The ionization potentials of other hole-transporting layers (Ip₂, Ip₃, . . . ) are preferably 5.8 eV or less, more preferably, 5.7 eV or less, and particularly preferably 5.6 eV or less.

The electron affinity of the electron-transporting layer adjacent to the luminescent layer (Ea₁) is preferably 2.2 to 3.1 eV, more preferably 2.3 to 3.0 eV, and particularly preferably 2.4 to 2.9 eV.

The electron affinities of other electron-transporting layers (Ea₂, Ea₃, . . . ) are preferably 2.6 eV or more, more preferably 2.7 eV or more, and particularly preferably, 2.8 eV or more.

The relationship of the ionization potentials or the electron affinities according to the invention is controlled by properly selecting and combining suitable materials showing a suitable ionization potential or an electron affinity from various materials for the layers.

As for the relationship in electron affinity among the two or more electron-transporting layers present between the cathode and the luminescent layer, the difference in electron affinity between neighboring layers is preferably 0.4 eV or less, more preferably, 0.2 eV or less, for reducing the driving voltage.

Specifically, when the relation of the Formula (2) is satisfied, the electron affinities of the luminescent layer and the electron-transporting layers satisfy the following relationships:

Ea₁−Ea₀≦0.4 eV; Ea₂−Ea₁≦0.4 eV; . . . ; and Eaₘ−Eaₘ₋₁≦0.4 eV; and more preferably

Ea₁−Ea₀≦0.2 eV; Ea₂−Ea₁≦0.2 eV; . . . ; and Eaₘ−Eaₘ₋₁≦0.2 eV.

When the differences in electron affinity between all neighboring electron-transporting layers are 0.2 eV or less, the number of electron-transporting layers should be increased occasionally, depending on the combination of the host material and the electrode material. In such a case, for obtaining a favorable effect, it is necessary to decide the configuration of the luminescent device, by considering both the number of the electron-transporting layers and the interlayer difference in electron affinity.

On the other hand, as for the ionization potentials of the two or more hole-transporting layers present between the anode and the luminescent layer, the differences in ionization potential between neighboring layers are preferably 0.4 eV or less, more preferably, 0.2 eV or less, for reducing the driving voltage.

Specifically, when the relationship of the Formula (1) is satisfied, the ionization potentials of the luminescent layer and the hole-transporting layers satisfy the following relationships:

Ip₀−Ip₁≦0.4 eV; Ip₁−Ip₂≦0.4 eV; . . . ; and Ipₙ₋₁−IPₙ≦0.4 eV; and more preferably,

Ip₀−Ip₁≦0.2 eV; Ip₁−Ip₂≦0.2 eV; . . . ; and Ipₙ₋₁−Ipₙ≦0.2 eV.

When the differences in ionization potential between all neighboring layers in the hole-transporting layer are 0.2 eV or less, the number of the hole-transporting layers should be increased occasionally, depending on the combination of the host material and the electrode material. In such a case, for obtaining a favorable effect, it is necessary to decide the configuration of the luminescent device by considering both the number of the hole-transporting layers and the difference in ionization potential between neighboring layers.

The luminescent device according to the invention contains a metal complex having a tridentate or higher-dentate ligand (hereinafter, referred to simply as “metal complex”) in the luminescent layer.

The metal complex according to the invention may be a metal complex having a chained ligand or a metal complex having a cyclic ligand. The metal complex is preferably a metal complex having a tridentate to octadentate chained ligand, more preferably a metal complex having a tridentate to hexadentate chained ligand, and still more preferably a metal complex having a tridentate or tetradentate chained ligand; and particularly preferably a metal complex having a tetradentate chained ligand.

The chained ligand preferably contains at least one nitrogen-containing heterocyclic ring (e.g., pyridine, quinoline, or pyrrole ring) that coordinates to the central metal (e.g., M¹¹ in the compound represented by Formula (I) described below) via the nitrogen. The nitrogen-containing heterocyclic ring is more preferably a nitrogen-containing six-membered heterocyclic ring.

The tridentate or higher-dentate ligand of the metal complex is preferably a tridentate or higher-dentate ligand excluding the ligands in the following group A:

Group A: tetradentate ligands containing a bipyridyl or phenanthroline as the partial structure, Schiff base-derived tetradentate ligands, phenylbipyridyl tridentate ligands, diphenylpyridine tridentate ligands, and terpyridine tridentate ligands.

The term “chained” used herein for the ligand contained in the metal complex described above refers to a structure of the ligand not forming a cyclic structure. For example, the compound represented by formula (I), which will be described below in detail, is a metal complex containing a chained ligand, and in the chained ligand contained in formula (I), L¹¹ and L¹⁴ do not bind to each other directly, not via Y¹², L¹², Y¹¹, L¹³, Y¹³, and M¹¹. Even if L¹¹, Y¹², L¹², Y¹¹, L¹³, Y¹³, or L¹⁴ has a ring structure (e.g., benzene, pyridine, or quinoline), when L¹¹ and L¹⁴ do not bind to each other directly, not via Y¹², L¹², Y¹¹, L¹³, Y¹³, and M¹¹, the ligand is called a chained ligand. An additional atom group may be present between L¹¹, and Y¹², Y¹² and L¹², L¹² and Y¹¹, Y¹¹ and L¹³, L¹³ and Y¹³, or Y¹³ and L¹⁴, forming a ring.

The term “cyclic” used for the ligand contained in the metal complex refers to a closed structure of the ligand encircling the central metal (e.g., phthalocyanine or crown ether ligand).

The atom in the metal complex coordinating to the metal ion is not particularly limited. Preferable examples thereof include an oxygen atom, a nitrogen atom, a carbon atom, a sulfur atom or a phosphorus atom, more preferably an oxygen atom, a nitrogen atom or carbon atom, and still more preferable examples thereof include a nitrogen atom and a carbon atom.

The metal ion in the metal complex is not particularly limited. In view of improving emission efficiency and driving durability and reducing of driving voltage, the metal is preferably a transition metal ion or a rare earth metal ion. Examples thereof include an iridium ion, a platinum ion, a gold ion, a rhenium ion, a tungsten ion, a rhodium ion, a ruthenium ion, an osmium ion, a palladium ion, a silver ion, a copper ion, a cobalt ion, a zinc ion, a nickel ion, a lead ion, an aluminum ion, a gallium ion, a rare-earth metal ion (such as an europium ion, a gadolinium ion, or a terbium ion). More preferable examples thereof include an iridium ion, a platinum ion, a gold ion, a rhenium ion, a tungsten ion, a palladium ion, a zinc ion, an aluminum ion, a galluim ion, a europium ion, a gadolinium ion, and a terbium ion. When the metal complex is used as a luminescent material, preferable examples of the metal ion include an iridium ion, a platinum ion, a rhenium ion, a tungsten ion, a europium ion, a gadolinium ion, and a terbium ion. When the metal complex is used as a charge transfer material or a host material in a luminescent layer, preferable examples of the metal ion include an iridium ion, a platinum ion, a palladium ion, a zinc ion, an aluminum ion, and a gallium ion.

In an embodiment, the metal ion in the metal complex is a platinum, iridium, rhenium, palladium, rhodium, ruthenium, or copper ion.

The metal complexes having a tridentate or higher-dentate ligand according to the invention may be used alone or in combination of two or more.

When two or more luminescent materials are used, a metal complex having a tridentate or higher-dentate ligand and another luminescent material may be used in combination. Examples of the other luminescent materials for use in the invention (luminescent materials other than metal complex having a tridentate or higher-dentate ligand) include fluorescent luminescent materials and/or phosphorescent luminescent materials. In the invention, at least one of the luminescent materials is a metal complex having a tridentate or higher-dentate ligand, and each of the luminescent materials is preferably a metal complex having a tridentate or higher-dentate ligand.

The luminescent material according to the invention may be a fluorescence-emitting compound or a phosphorescence-emitting compound, but is preferably a phosphorescence-emitting compound (more preferably, a compound emitting phosphorescence at −30° C. or higher, more preferably at −10° C. or higher; more preferably a compound emitting phosphorescence at 0° C. or higher; and particularly preferably a compound emitting phosphorescence at 10° C. or higher). When a phosphorescence-emitting compound is used, the compound may emit fluorescence at the same time, but a compound having a phosphorescence intensity twice or more of the fluorescence intensity at 20° C. is preferable, that having a phosphorescence intensity of 10 times or more is more preferable, and that having a phosphorescence intensity of 100 times or more is still more preferable.

The luminescent material according to the invention is preferably a material having an emission quantum yield (phosphorescence or fluorescence) of 10% or more at 20° C., preferably that having emission quantum yield of 15% or more, and more preferably that having an emission quantum yield of 20% or more at 20° C.

The total amount of the luminescent materials according to the invention used is preferably 0.1 to 50 wt %, more preferably 0.3 to 40 wt %, and still more preferably, 0.5 to 20 wt %, with respect to the weight of the luminescent layer.

When at least two kinds of luminescent materials are contained in a luminescent layer, the content ratio thereof is not particularly limited, but the ratio of luminescent material characterizing the emission spectrum/other luminescent material is preferably 100/1 to 1/10, more preferably 20/1 to 1/5, and still more preferably 5/1 to 1/2. In such a case, both the luminescent material characterizing the emission spectrum and the other luminescent material may be metal complexes having a tridentate or higher-dentate ligand, or only one of them is a metal complex having a tridentate or higher-dentate ligand.

Hereinafter, the metal complex having a tridentate or higher-dentate ligand according to the invention will be described in detail. The other components for the luminescent device according to the invention will be described in detail after the description on the metal complex having a tridentate or higher-dentate ligand.

When the ligand of the metal complex used in the invention is chained, the metal complex is preferably a compound represented by Formula (I) or (II) described in detail below.

The compound represented by Formula (I) will be described first.

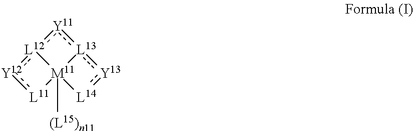

In Formula (I), M¹¹ represents a metal ion; L¹¹ to L¹⁵ each independently represent a ligand coordinated to M″; in no case does an additional atomic group connect L¹¹ and L¹⁴ to form a cyclic ligand; in no case, L¹⁵ is bonded to both L¹¹ and L¹⁴ to form a cyclic ligand; Y¹¹ to Y¹³ each independently represent a connecting group, a single bond, or a double bond; when Y¹¹, Y¹², or Y¹³ represent a connecting group, the bond between L¹¹ and Y¹², the bond between Y¹² and L¹², the bond between L¹² and Y¹¹, the bond between Y¹¹ and L¹³, the bond between L¹³ and Y¹³, and the bond between Y¹³ and L¹⁴ are each independently a single bond or a double bond; and n¹¹ represents an integer of 0 to 4. Each of the bonds connecting M¹¹ and each of L¹¹ to L¹⁵ may be selected from a coordinate bond, an ionic bond and a covalent bond.

Hereinafter, details of the compound represented by Formula (I) will be described.

In Formula (I), M¹¹ represents a metal ion. The metal ion is not particularly limited, but preferably a divalent or trivalent metal ion. Preferable examples of divalent or trivalent metal ion include a platinum ion, an iridium ion, a rhenium ion, a palladium ion, a rhodium ion, a ruthenium ion, a copper ion, a europium ion, a gadolinium ion, and a terbium ion. More preferable examples thereof include a platinum ion, an iridium ion, and a europium ion. Still more preferable examples thereof include a platinum ion and an iridium ion. Particularly preferable examples thereof include a platinum ion.

In Formula (I), L¹¹, L¹², L¹³, and L¹⁴ each independently represent a moiety coordinating to M¹¹. Preferable examples of the atom coordinating to M¹¹ contained in L¹¹, L¹², L¹³, or L¹⁴ include preferably a nitrogen atom, an oxygen atom, a sulfur atom, a carbon atom, and a phosphorus atom. More preferable examples thereof include a nitrogen atom, an oxygen atom, a sulfur atom, and a carbon atom. Still more preferable examples thereof include a nitrogen atom, an oxygen atom, and a carbon atom.

The bonds between M¹¹ and L¹¹, between M¹¹ and L¹², between M¹¹ and L¹³, between M¹¹ and L¹⁴ each may be independently selected from a covalent bond, an ionic bond, and a coordination bond. In this specification, the terms “ligand” and “coordinate” are used also when the bond between the central metal and the ligand is a bond (an ionic bond or a covalent bond) other than a coordination bond, as well as when the bond between the central metal and the ligand is a coordination bond, for convenience of the explanation.

The entire ligand comprising L¹¹, Y¹², L¹², Y¹¹, L¹³, Y¹³, and L¹⁴ is preferably an anionic ligand. The term “anionic ligand” used herein refers to a ligand having at least one anion bonded to the metal. The number of anions in the anionic ligand is preferably 1 to 3, more preferably 1 or 2, and still more preferably 2.

When the moiety represented by any of L¹¹, L¹², L¹³, and L¹⁴ coordinates to M¹¹ via a carbon atom, the moiety is not particularly limited, and examples thereof include imino ligands, aromatic carbon ring ligands (e.g., a benzene ligand, a naphthalene ligand, an anthracene ligand, and a phenanthrene ligand), and heterocyclic ligands [e.g., a thiophene ligand, a pyridine ligand, a pyrazine ligand, a pyrimidine ligand, a thiazole ligand, an oxazole ligand, a pyrrole ligand, an imidazole ligand, and a pyrazole ligand, ring-condensation products thereof (e.g., a quinoline ligand and a benzothiazole ligand), and tautomers thereof].

When the moiety represented by any of L¹¹, L¹², L¹³, and L¹⁴ coordinates to M¹¹ via a nitrogen atom, the moiety is not particularly limited, and examples thereof include nitrogen-containing heterocyclic ligands such as a pyridine ligand, a pyrazine ligand, a pyrimidine ligand, a pyridazine ligand, a triazine ligand, a thiazole ligand, an oxazole ligand, a pyrrole ligand, an imidazole ligand, a pyrazole ligand, a triazole ligand, an oxadiazole ligand, and a thiadiazole ligand, and ring-condensation products thereof (e.g., a quinoline ligand, a benzoxazole ligand, and a benzimidazole ligand), and tautomers thereof [in the invention, the following ligands (pyrrole tautomers) are also included in tautomers, in addition to normal isomers: the five-membered heterocyclic ligand of compound (24), the terminal five-membered heterocyclic ligand of compound (64), and the five-membered heterocycle ligand of compound (145), the compounds (24), (64), (145) being shown below as typical examples of the compound represented by formula (I)]; amino ligands such as alkylamino ligands (preferably having 2 to 30 carbon atoms, more preferably 2 to 20 carbon atoms, and particularly preferably 2 to 10 carbon atoms, such as methylamino), arylamino ligands (e.g., and phenylamino), acylamino ligands (preferably having 2 to 30 carbon atoms, more preferably 2 to 20 carbon atoms, and particularly preferably 2 to 10 carbon atoms, such as acetylamino and benzoylamino), alkoxycarbonylamino ligands (preferably having 2 to 30 carbon atoms, more preferably 2 to 20 carbon atoms, and particularly preferably 2 to 12 carbon atoms, such as methoxycarbonylamino), aryloxycarbonylamino ligands (preferably having 7 to 30 carbon atoms, more preferably 7 to 20 carbon atoms, and particularly preferably 7 to 12 carbon atoms, such as phenyloxycarbonylamino), sulfonylamino ligands (preferably having 1 to 30 carbon atoms, more preferably 1 to 20 carbon atoms, and particularly preferably 1 to 12 carbon atoms, such as methanesulfonylamino and benzenesulfonylamino), and imino ligands. These ligands may be substituted.

When the moiety represented by any of L¹¹, L¹², L¹³, and L¹⁴ coordinates to M¹¹ via an oxygen atom, the moiety is not particularly limited, and examples thereof include alkoxy ligands (preferably having 1 to 30 carbon atoms, more preferably 1 to 20 carbon atoms, and particularly preferably 1 to 10 carbon atoms, such as methoxy, ethoxy, butoxy, and 2-ethylhexyloxy), aryloxy ligands (preferably having 6 to 30 carbon atoms, more preferably 6 to 20 carbon atoms, and particularly preferably 6 to 12 carbon atoms, such as phenyloxy, 1-naphthyloxy, and 2-naphthyloxy), heterocyclic oxy ligands (preferably having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy), acyloxy ligands (preferably having 2 to 30 carbon atoms, more preferably 2 to 20 carbon atoms, and particularly preferably 2 to 10 carbon atoms, such as acetoxy and benzoyloxy), silyloxy ligands (preferably having 3 to 40 carbon atoms, more preferably 3 to 30 carbon atoms, and particularly preferably 3 to 24 carbon atoms, such as trimethylsilyloxy and triphenylsilyloxy), carbonyl ligands (e.g., ketone ligands, ester ligands, and amido ligands), and ether ligands (e.g., dialkylether ligands, diarylether ligands, and furyl ligands).

When the moiety represented by any of L¹¹, L¹², L¹³, and L¹⁴ coordinates to M¹¹ via a sulfur atom, the moiety is not particularly limited, and examples thereof include alkylthio ligands (preferably having 1 to 30 carbon atoms, more preferably 1 to 20 carbon atoms, and particularly preferably 1 to 12 carbon atoms, such as methylthio and ethylthio), arylthio ligands (preferably having 6 to 30 carbon atoms, more preferably 6 to 20 carbon atoms, and particularly preferably 6 to 12 carbon atoms, such as phenylthio), heterocyclic thio ligands (preferably having 1 to 30 carbon atoms, more preferably 1 to 20 carbon atoms, and particularly preferably 1 to 12 carbon atoms, such as pyridylthio, 2-benzimidazolylthio, 2-benzoxazolylthio, and 2-benzothiazolylthio), thiocarbonyl ligands (e.g., thioketone ligands and thioester ligands), and thioether ligands (e.g., dialkylthioether ligands, diarylthioether ligands, and thiofuryl ligands). These substitution ligands may respectively have a substitutent.

When the moiety represented by any of L¹¹, L¹², L¹³, and L¹⁴ coordinates to M¹¹ via a phosphorus atom, the moiety is not particularly limited, and examples thereof include dialkylphosphino groups, diarylphosphino groups, trialkylphosphine groups, triarylphosphine groups, phosphinine groups and the like. These groups may respectively have a substituent.

In a preferable embodiment, L¹¹ and L¹⁴ each independently represent a moiety selected from an aromatic carbon ring ligand, an alkyloxy ligand, an aryloxy ligand, an ether ligand, an alkylthio ligand, an arylthio ligand, an alkylamino ligand, an arylamino ligand, an acylamino ligand, or a nitrogen-containing heterocyclic ligand [e.g., a pyridine ligand, a pyrazine ligand, a pyrimidine ligand, a pyridazine ligand, a triazine ligand, a thiazole ligand, an oxazole ligand, a pyrrole ligand, an imidazole ligand, a pyrazole ligand, a triazole ligand, an oxadiazole ligand, a thiadiazole ligand, or a condensed ring ligand containing one or more of the above ligands (e.g., a quinoline ligand, a benzoxazole ligand, or a benzimidazole ligand), or a tautomer of any of the above ligands]; more preferably, an aromatic carbon ring ligand, an aryloxy ligand, an arylthio ligand, an arylamino ligand, a pyridine ligand, a pyrazine ligand, an imidazole ligand, a condensed ring ligand containing one or more of the above ligands (e.g., a quinoline ligand, a quinoxaline ligand, or a benzimidazole ligand), or a tautomer of any of the above ligands; still more preferably, an aromatic carbon ring ligand or an aryloxy ligand, an arylthio ligand, or an arylamino ligand; and particularly preferably, an aromatic carbon ring ligand or an aryloxy ligand.

In a preferable embodiment, L¹² and L¹³ each independently represent a moiety forming a coordination bond with M¹¹. The moiety forming a coordination bond with M¹¹ is preferably a pyridine, pyrazine, pyrimidine, triazine, thiazole, oxazole, pyrrole or triazole ring, a condensed ring containing one or more of the above rings (e.g., a quinoline ring, a benzoxazole ring, a benzimidazole ring, an indolenine ring), or a tautomer of any of the above rings; more preferably a pyridine, pyrazine, pyrimidine, or pyrrole ring, a condensed ring containing one or more of the above rings (e.g., a quinoline ring, a benzopyrrole ring), or a tautomer of any of the above rings; still more preferably a pyridine, pyrazine or pyrimidine ring, or a condensed ring containing one or more of the above rings (e.g., quinoline ring); particularly preferably a pyridine ring or a condensed ring containing a pyridine ring (e.g., a quinoline ring).

In Formula (I), L¹⁵ represents a ligand coordinating to M¹¹. L¹⁵ is preferably a monodentate to tetradentate ligand and more preferably a monodentate to tetradentate anionic ligand. The monodentate to tetradentate anionic ligand is not particularly limited, but is preferably a halogen ligand, a 1,3-diketone ligand (e.g., an acetylacetone ligand), a monoanionic bidentate ligand containing a pyridine ligand [e.g., a picolinic acid ligand or a 2-(2-hydroxyphenyl)-pyridine ligand], or a tetradentate ligand L¹¹, Y¹², L¹², Y¹¹, L¹³, Y¹³, and L¹⁴ can form; more preferably, a 1,3-diketone ligand (e.g., an acetylacetone ligand), a monoanionic bidentate ligand containing a pyridine ligand [e.g., a picolinic acid ligand or a 2-(2-hydroxyphenyl)-pyridine ligand], or a tetradentate ligand L¹¹, Y¹², L¹², Y¹¹, L¹³, Y¹³, and L¹⁴ can form; still more preferably, a 1,3-diketone ligand (e.g., an acetylacetone ligand) or a monoanionic bidentate ligand containing a pyridine ligand [e.g., a picolinic acid ligand or a 2-(2-hydroxyphenyl)-pyridine ligand); and particularly preferably, a 1,3-diketone ligand (e.g., an acetylacetone ligand). The number of coordination sites and the number of ligands do not exceed the valency of the metal. L¹⁵ does not bind to both L¹¹ and L¹⁴ to form a cyclic ligand.

In Formula (I), Y¹¹, Y¹² and Y¹³ each independently represent a connecting group or a single or double bond. The connecting group is not particularly limited, and examples thereof include a carbonyl connecting group, a thiocarbonyl connecting group, an alkylene group, an alkenylene group, an arylene group, a heteroarylene group, a connecting group which connects moieties via an oxygen atom, a nitrogen atom, a silicon atom or a sulfur atom, and connecting groups comprising combinations of connecting groups selected from the above. When Y¹¹ is a connecting group, the bond between L¹² and Y¹¹ and the bond between Y¹¹ and L¹³ are each independently a single or double bond. When Y¹² is a connecting group, the bond between L¹¹ and Y¹² and the bond between Y¹² and L¹² are each independently a single or double bond. When Y¹³ is a connecting group, the bond between L¹³ and Y¹³ and the bond between Y¹³ and L¹⁴ are each independently a single or double bond.

Specific examples of the connecting group include the following connecting groups.

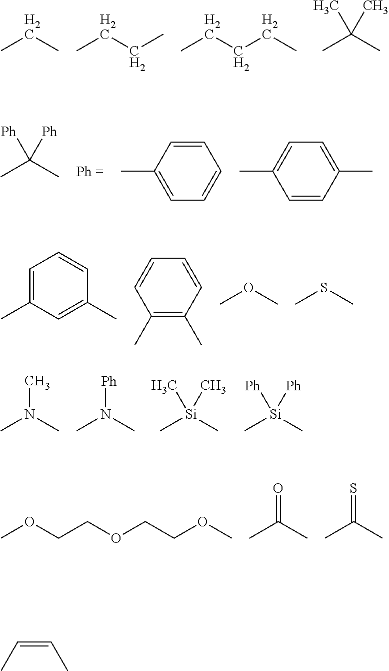

Preferably, Y¹¹, Y¹², and Y¹³ each independently represent a single bond, a double bond, a carbonyl connecting group, an alkylene connecting group, or an alkenylene group. Y¹¹ is more preferably a single bond or an alkylene group, and still more preferably an alkylene group. Each of Y¹² and Y¹³ is more preferably a single bond or an alkenylene group and still more preferably a single bond.

The ring formed by Y¹², L¹¹, L¹², and M¹¹, the ring formed by L¹¹, L¹², L¹³, and M¹¹, and the ring formed by Y¹³, L¹³, L¹⁴, and M¹¹ are each preferably a four- to ten-membered ring, more preferably a five- to seven-membered ring, and still more preferably a five- to six-membered ring.

In Formula (I), n¹¹ represents an integer of 0 to 4. When M¹¹ is a tetravalent metal, n¹¹ is 0. When M¹¹ is a hexavalent metal, n¹¹ is preferably 1 or 2 and more preferably 1. When M¹¹ is a hexavalent metal and n¹¹ is 1, L¹⁵ represents a bidentate ligand. When M¹¹ is a hexavalent metal and n¹¹ is 2, L¹⁵ represents a monodentate ligand. When M¹¹ is an octavalent metal, n¹¹ is preferably 1 to 4, more preferably, 1 or 2, and still more preferably 1. When M¹¹ is an octavalent metal and n¹¹ is 1, L¹⁵ represents a tetradentate ligand. When M¹¹ is an octavalent metal and n¹¹ is 2, L¹⁵ represents a bidentate ligand. When n¹¹ is 2 or larger, there are plural L¹⁵'s, and the L¹⁵'s may be the same as or different from each other.

Preferable embodiments of the compound represented by Formula (I) include compounds represented by the following Formulae (1), (2), (3) or (4).

Firstly, explanation of the compound represented by Formula (1) is provided.

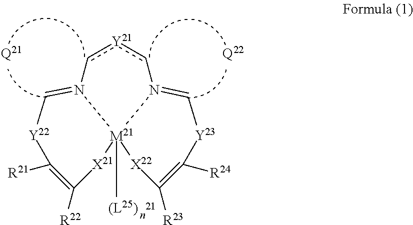

In Formula (1), M²¹ represents a metal ion; and Y²¹ represents a connecting group or a single or double bond. Y²³ and Y²³ each represent a single bond or a connecting group. Q²¹ and Q²² each represent an atomic group forming a nitrogen-containing heterocycle, and the bond between Y²¹ and the ring containing Q²¹ and the bond between Y²¹ and the ring containing Q²² are each a single or double bond. X²¹ and X²² each independently represent an oxygen atom, a sulfur atom, or a substituted or unsubstituted nitrogen atom. R²¹, R²², R²³, and R²⁴ each independently represent a hydrogen atom or a substituent. R²¹ and R²² may bind to each other to form a ring, and R²³ and R²⁴ may bind to each other to form a ring. L²⁵ represents a ligand coordinating to M²¹, and M²¹ represents an integer of 0 to 4.

The compound represented by formula (1) will be described in detail.

In Formula (1), the definition of M²¹ is the same as the definition of M¹¹ in Formula (I), and their preferable ranges are also similar.

Q²¹ and Q²² each independently represent an atomic group forming a nitrogen-containing heterocycle (ring containing a nitrogen atom coordinating to M²¹). The nitrogen-containing heterocycles formed by Q²¹ and Q²² are not particularly limited, and may be selected, for example, from a pyridine ring, a pyrazine ring, a pyrimidine ring, a triazine ring, a thiazole ring, an oxazole ring, a pyrrole ring, an imidazole ring, and a triazole ring, and condensed rings containing one or more of the above rings (e.g., a quinoline ring, a benzoxazole ring, a benzimidazole ring, a benzthiazole ring, an indole ring, and an indolenine ring), and tautomers thereof.

X²¹ and X²² each independently represent an oxygen atom, a sulfur atom, or a substituted or unsubstituted nitrogen atom. X²¹ and X²² are each preferably an oxygen atom, a sulfur atom, or a substituted nitrogen atom, more preferably an oxygen atom or a sulfur atom, and particularly preferably an oxygen atom.

The definition of Y²¹ is the same as that of Y¹¹ in Formula (1), and their preferable ranges are also similar.

Y²² and Y²³ each independently represent a single bond or a connecting group, preferably a single bond. The connecting group is not particularly limited, and examples thereof include a carbonyl connecting group, a thiocarbonyl connecting group, an alkylene group, an alkenylene group, an arylene group, a heteroarylene group, connecting groups which connects moieties via an oxygen atom, a nitrogen atom or a silicon atom, and connecting groups comprising combinations of connecting groups selected from the above.

The connecting group represented by Y²² or Y²³ is preferably a carbonyl connecting group, an alkylene connecting group, or an alkenylene connecting group, more preferably a carbonyl connecting group or an alkenylene connecting group, and still more preferably a carbonyl connecting group.

R²¹, R²², R²³, and R²⁴ each independently represent a hydrogen atom or a substituent. The substituent is not particularly limited, and examples thereof include alkyl groups (preferably having 1 to 30 carbon atoms, more preferably 1 to 20 carbon atoms, and particularly preferably 1 to 10 carbon atoms, and examples thereof include a methyl group, an ethyl group, an iso-propyl group, a tert-butyl group, a n-octyl group, a n-decyl group, a n-hexadecyl group, a cyclopropyl group, a cyclopentyl group, and a cyclohexyl group), alkenyl groups (preferably having 2 to 30 carbon atoms, more preferably 2 to 20 carbon atoms, and particularly preferably 2 to 10 carbon atoms, and examples thereof include a vinyl group, an allyl group, a 2-butenyl group, and a 3-pentenyl group), alkynyl groups (preferably having 2 to 30 carbon atoms, more preferably 2 to 20 carbon atoms, and particularly preferably 2 to 10 carbon atoms, and examples thereof include a propargyl group and a 3-pentynyl group), aryl groups (preferably having 6 to 30 carbon atoms, more preferably 6 to 20 carbon atoms, and particularly preferably 6 to 12 carbon atoms, and examples thereof include a phenyl group, a p-methylphenyl group, a naphthyl group, and an anthranyl group), amino groups (preferably having 0 to 30 carbon atoms, more preferably 0 to 20 carbon atoms, and particularly preferably 0 to 10 carbon atoms, and examples thereof include an amino group, a, methylamino group, a dimethylamino group, a diethylamino group, a dibenzylamino group, a diphenylamino group, and a ditolylamino group), alkoxy groups (preferably having 1 to 30 carbon atoms, more preferably 1 to 20 carbon atoms, and particularly preferably 1 to 10 carbon atoms, and examples thereof include a methoxy group, a ethoxy group, a butoxy group, and a 2-ethylhexyloxy group), aryloxy groups (preferably having 6 to 30 carbon atoms, more preferably 6 to 20 carbon atoms, and particularly preferably 6 to 12 carbon atoms, and examples thereof include a phenyloxy group, a 1-naphthyloxy group, and a 2-naphthyloxy group), heterocyclic oxy groups (preferably having 1 to 30 carbon atoms, more preferably 1 to 20 carbon atoms, and particularly preferably 1 to 12 carbon atoms, and examples thereof include a pyridyloxy group, a pyrazyloxy group, a pyrimidyloxy group, and a quinolyloxy group), acyl groups (preferably having 1 to 30 carbon atoms, more preferably 1 to 20 carbon atoms, and particularly preferably 1 to 12 carbon atoms, and examples thereof include a acetyl group, a benzoyl group, a formyl group, and a pivaloyl group), alkoxycarbonyl groups (preferably having 2 to 30 carbon atoms, more preferably 2 to 20 carbon atoms, and particularly preferably 2 to 12 carbon atoms, and examples thereof include a methoxycarbonyl group and an ethoxycarbonyl group), aryloxycarbonyl groups (preferably having 7 to 30 carbon atoms, more preferably 7 to 20 carbon atoms, and particularly preferably 7 to 12 carbon atoms, and examples thereof include a phenyloxycarbonyl group), acyloxy groups (preferably having 2 to 30 carbon atoms, more preferably 2 to 20 carbon atoms, and particularly preferably 2 to 10 carbon atoms, and examples thereof include an acetoxy group and a benzoyloxy group), acylamino groups (preferably having 2 to 30 carbon atoms, more preferably 2 to 20 carbon atoms, and particularly preferably 2 to 10 carbon atoms, and examples thereof include an acetylamino group and a benzoylamino group), alkoxycarbonylamino groups (preferably having 2 to 30 carbon atoms, more preferably 2 to 20 carbon atoms, and particularly preferably 2 to 12 carbon atoms, and examples thereof include a methoxycarbonylamino group), aryloxycarbonylamino groups (preferably having 7 to 30 carbon atoms, more preferably 7 to 20 carbon atoms, and particularly preferably 7 to 12 carbon atoms, and examples thereof include a phenyloxycarbonylamino group), sulfonylamino groups (preferably having 1 to 30 carbon atoms, more preferably 1 to 20 carbon atoms, and particularly preferably 1 to 12 carbon atoms, and examples thereof include a methanesulfonylamino group and a benzenesulfonylamino group), sulfamoyl groups (preferably having 0 to 30 carbon atoms, more preferably 0 to 20 carbon atoms, and particularly preferably 0 to 12 carbon atoms, and examples thereof include a sulfamoyl group, a methylsulfamoyl group, a dimethylsulfamoyl group, and a phenylsulfamoyl group),

carbamoyl groups (preferably having 1 to 30 carbon atoms, more preferably 1 to 20 carbon atoms, and particularly preferably 1 to 12 carbon atoms, and examples thereof include a carbamoyl group, a methylcarbamoyl group, a diethylcarbamoyl group, and a phenylcarbamoyl group), alkylthio groups (preferably having 1 to 30 carbon atoms, more preferably 1 to 20 carbon atoms, and particularly preferably 1 to 12 carbon atoms, and examples thereof include a methylthio group and an ethylthio group), arylthio groups (preferably having 6 to 30 carbon atoms, more preferably 6 to 20 carbon atoms, and particularly preferably 6 to 12 carbon atoms, and examples thereof include a phenylthio group), heterocyclic thio groups (preferably having 1 to 30 carbon atoms, more preferably 1 to 20 carbon atoms, and particularly preferably 1 to 12 carbon atoms, and examples thereof include a pyridylthio group, a 2-benzimidazolylthio group, a 2-benzoxazolylthio group, and a 2-benzothiazolylthio group), sulfonyl groups (preferably having 1 to 30 carbon atoms, more preferably 1 to 20 carbon atoms, and particularly preferably 1 to 12 carbon atoms, and examples thereof include a mesyl group and a tosyl group), sulfinyl groups (preferably having 1 to 30 carbon atoms, more preferably 1 to 20 carbon atoms, and particularly preferably 1 to 12 carbon atoms, and examples thereof include a methanesulfinyl group and a benzenesulfinyl group), ureido groups (preferably having 1 to 30 carbon atoms, more preferably 1 to 20 carbon atoms, and particularly preferably 1 to 12 carbon atoms, and examples thereof include a ureido group, a methylureido group, and a phenylureido group),

phosphoric amide groups (preferably having 1 to 30 carbon atoms, more preferably 1 to 20 carbon atoms, and particularly preferably 1 to 12 carbon atoms, and examples thereof include a diethylphosphoric amide group and a phenylphosphoric amide group), a hydroxy group, a mercapto group, halogen atoms (such as fluorine, chlorine, bromine, or iodine), a cyano group, a sulfo group, a carboxyl group, a nitro group, a hydroxamic acid group, sulfino groups, hydrazino groups, imino groups, heterocyclic groups (preferably having 1 to 30 carbon atoms and more preferably 1 to 12 carbon atoms; the heteroatom(s) may be selected from nitrogen, oxygen, and sulfur atoms), and examples thereof include an imidazolyl group, a pyridyl group, a quinolyl group, a furyl group, a thienyl group, a piperidyl group, a morpholino group, a benzoxazolyl group, a benzimidazolyl group, a benzothiazolyl group, a carbazolyl group, and an azepinyl group), silyl groups (preferably having 3 to 40 carbon atoms, more preferably 3 to 30 carbon atoms, and particularly preferably 3 to 24 carbon atoms, and examples thereof include a trimethylsilyl group and a triphenylsilyl group), and silyloxy groups (preferably having 3 to 40 carbon atoms, more preferably 3 to 30 carbon atoms, and particularly preferably 3 to 24 carbon atoms, and examples thereof include a trimethylsilyloxy group and a triphenylsilyloxy group). These substituents may have a substitutent(s).

In a preferable embodiment, R²¹, R²², R²³, and R²⁴ are each independently selected from alkyl groups or aryl groups. In another preferable embodiment, R²¹ and R²² are groups that bind to each other to form a ring structure (e.g., a benzo-condensed ring or a pyridine-condensed ring), and/or R²³ and R²⁴ are groups that bind to each other to form a ring structure or ring structures (e.g., a benzo-condensed ring or a pyridine-condensed ring). In a more preferable embodiment, R²¹ and R²² are groups that bind to each other to form a ring structure (e.g., a benzo-condensed ring or a pyridine-condensed ring), and/or R²³ and R²⁴ are groups that bind to each other to form a ring structure or ring structures (e.g., a benzo-condensed ring or a pyridine-condensed ring).

The definition of L²⁵ is similar to that of L¹⁵ in Formula (I), and their preferable ranges are also similar.

The definition of n²¹ is similar to that of n¹¹ in Formula (1), and their preferable ranges are also similar.

In Formula (1), examples of preferable embodiments are described below:

(1) the rings formed by Q²¹ and Q²² are pyridine rings, and Y²¹ is a connecting group;

(2) the rings formed by Q²¹ and Q²² are pyridine rings, Y²¹ is a single or double bond, and X²¹ and X²² are selected from sulfur atoms, substituted nitrogen atoms, and unsubstituted nitrogen atom;

(3) the rings formed by Q²¹ and Q²² are each a five-membered nitrogen-containing heterocycle, or a nitrogen-containing six-membered ring containing two or more nitrogen atoms.

Preferable examples of compounds represented by Formula (1) are compounds represented by the following Formula (1-A).

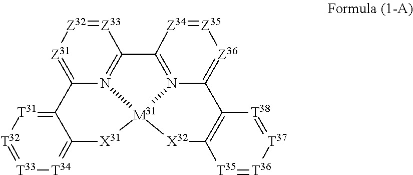

The compound represented by Formula (1-A) will be described below.

In Formula (1-A), the definition of M³¹ is similar to that of M¹¹ in Formula (I), and their preferable ranges are also similar.

Z³¹, Z³², Z³³, Z³⁴, Z³⁵, and Z³⁶ each independently represent a substituted or unsubstituted carbon or nitrogen atom, and preferably a substituted or unsubstituted carbon atom. The substituent on the carbon may be selected from the substituents described as examples of R²¹ in Formula (1). Z³¹ and Z³² may be bonded to each other via a connecting group to form a condensed ring (e.g., a benzo-condensed ring or a pyridine-condensed ring). Z³² and Z³³ may be bonded to each other via a connecting group to form a condensed ring (e.g., a benzo-condensed ring or a pyridine-condensed ring). Z³³ and Z³⁴ may be bonded to each other via a connecting group to form a condensed ring (e.g., a benzo-condensed ring or a pyridine-condensed ring). Z³⁴ and Z³⁵ may be bonded to each other via a connecting group to form a condensed ring (e.g., a benzo-condensed ring or a pyridine-condensed ring). Z³⁵ and Z³⁶ may be bonded to each other via a connecting group to form a condensed ring (e.g., a benzo-condensed ring or a pyridine-condensed ring). Z³¹ and T³¹ may be bonded to each other via a connecting group to form a condensed ring (e.g., a benzo-condensed ring or a pyridine-condensed ring). Z³⁶ and T³⁸ may be bonded to each other via a connecting group to form a condensed ring (e.g., a benzo-condensed ring or a pyridine-condensed ring).

The substituent on the carbon is preferably an alkyl group, an alkoxy group, an alkylamino group, an aryl group, a group capable of forming a condensed ring (e.g., a benzo-condensed ring or a pyridine-condensed ring), or a halogen atom, more preferably an alkylamino group, an aryl group, or a group capable of forming a condensed ring (e.g., a benzo-condensed ring or a pyridine-condensed ring), still more preferably an aryl group or a group capable of forming a condensed ring (e.g., a benzo-condensed ring or a pyridine-condensed ring), and particularly preferably a group capable of forming a condensed ring (e.g., a benzo-condensed ring or a pyridine-condensed ring).

T³¹, T³², T³³, T³⁴, T³⁵, T³⁶, and T³⁸ each independently represent a substituted or unsubstituted carbon or nitrogen atom, and more preferably a substituted or unsubstituted carbon atom. Examples of the substituents on the carbon include the groups described as examples of R²¹ in formula (1); T³¹ and T³² may be bonded to each other via a connecting group to form a condensed ring (e.g., a benzo-condensed ring or a pyridine-condensed ring). T³² and T³³ may be bonded to each other via a connecting group to form a condensed ring (e.g., a benzo-condensed ring or a pyridine-condensed ring). T³³ and T³⁴ may be bonded to each other via a connecting group to form a condensed ring (e.g., a benzo-condensed ring or a pyridine-condensed ring). T³⁵ and T³⁶ may be bonded to each other via a connecting group to form a condensed ring (e.g., a benzo-condensed ring or a pyridine-condensed ring). T³⁶ and T³⁷ may be bonded to each other via a connecting group to form a condensed ring (e.g., a benzo-condensed ring or a pyridine-condensed ring). T³⁷ and T³³ may be bonded to each other via a connecting group to form a condensed ring (e.g., a benzo-condensed ring or a pyridine-condensed ring).

The substituent on the carbon is preferably an alkyl group, an alkoxy group, an alkylamino group, an aryl group, a group capable of forming a condensed ring (e.g., a benzo-condensed ring or a pyridine-condensed ring), or a halogen atom; more preferably an aryl group, a group capable of forming a condensed ring (e.g., a benzo-condensed ring or pyridine-condensed ring), or a halogen atom; still more preferably an aryl group or a halogen atom, and particularly preferably an aryl group.

The definitions and preferable ranges of X³¹ and X³² are similar to the definitions and preferable ranges of X²¹ and X²² in Formula (1), respectively.

The compound represented by Formula (2) will be described below.

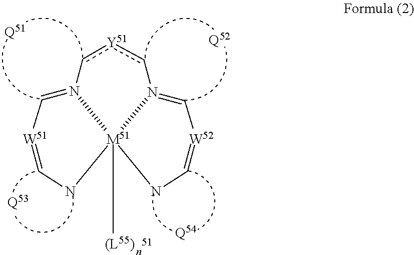

In Formula (2), the definition of M⁵¹ is similar to that of M¹¹ in Formula (I), and their preferable ranges are also similar.

The definitions of Q⁵¹ and Q⁵² are similar to the definitions of Q²¹ and Q²² in Formula (1), and their preferable ranges are also similar.

Q⁵³ and Q⁵⁴ each independently represent a group forming a nitrogen-containing heterocycle (ring containing a nitrogen atom coordinating to M⁵¹). The nitrogen-containing heterocycles formed by Q⁵³ and Q⁵⁴ are not particularly limited, and are preferably selected from tautomers of pyrrole compounds, tautomers of imidazole compounds (e.g., the five-membered heterocyclic ligand contained in the compound (29) shown below as a specific example of the compound represented by Formula (I)), tautomers of thiazole compounds (e.g., the five-membered heterocyclic ligand contained in the compound (30) shown below as a specific example of the compound represented by Formula (I)), and tautomers of oxazole compounds (e.g., the five-membered heterocyclic ligand contained in the compound (31) shown below as a specific example of the compound represented by Formula (I)), more preferably selected from tautomers of pyrrole, imidazole, and thiazole compounds; still more preferably selected from tautomers of pyrrole and imidazole compounds; and particularly preferably selected from tautomers of pyrrole compounds.

The definition of Y⁵¹ is similar to that of Y¹¹ in Formula (I), and their preferable range are also the same.

The definition of L⁵⁵ is similar to that of L¹⁵ in Formula (I), and their preferable ranges are also similar.

The definition of n⁵¹ is similar to that of n″, and their preferable ranges are also similar.

W⁵¹ and W⁵² each independently represent a substituted or unsubstituted carbon or nitrogen atom, more preferably an unsubstituted carbon or nitrogen atom, and still more preferably an unsubstituted carbon atom.

The compound represented by Formula (3) will be described below.

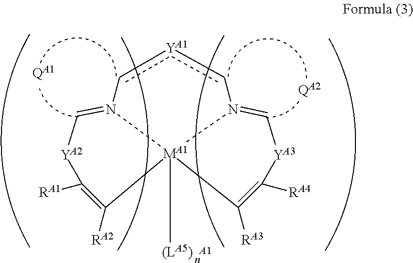

In Formula (3), the definitions and preferable ranges of M^{A1}, Q^{A1}, Q^{A2}, Y^{A1}, Y^{A2}, Y^{A3}, R^{A1}, R^{A2}, R^{A3}, R^{A4}, L^{A5}, and n^{A1} are similar to the definitions and preferable ranges of M²¹, Q²¹, Q²², Y²¹, Y²², Y²³, R²¹, R²², R²³, R²⁴, L²⁵, and n²¹ in Formula (1) respectively.

Preferable examples of compounds represented by Formula (3) are compounds represented by the following Formula (3-A) or (3-B).

The compound represented by Formula (3-A) will be described first.

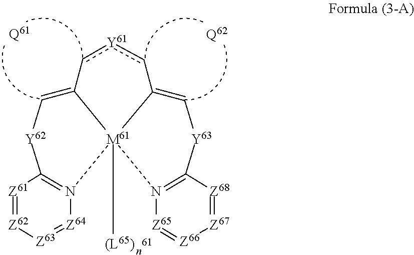

In Formula (3-A), the definitions of M⁶¹ is the same as that of M¹¹ in Formula (I), and their preferable ranges are also similar.

Q⁶¹ and Q⁶² each independently represent a ring forming group. The rings formed by Q⁶¹ and Q⁶² are not particularly limited, and examples thereof include a benzene ring, a pyridine ring, a pyridazine ring, a pyrimidine ring, a thiophene ring, an isothiazole ring, a furan ring, an isoxazole ring, and condensed rings thereof.

Each of the rings formed by Q⁶¹ and Q⁶² is preferably a benzene ring, a pyridine ring, a thiophene ring, a thiazole ring, or a condensed ring containing one or more of the above rings; more preferably a benzene ring, a pyridine ring, or a condensed ring containing one or more of the above rings; and still more preferably a benzene ring or a condensed ring containing a benzene ring.

The definition of Y⁶¹ is similar to that of Y¹¹ in Formula (I), and their preferable ranges are also similar.

Y⁶² and Y⁶³ each independently represent a connecting group or a single bond. The connecting group is not particularly limited, and examples thereof include a carbonyl connecting group, a thiocarbonyl connecting group, alkylene groups, alkenylene groups, arylene groups, heteroarylene groups, a connecting group which connects moieties via an oxygen atom, a nitrogen atom or a silicon atom, and connecting groups comprising combinations of connecting groups selected from the above.

Y⁶² and Y⁶³ are each independently selected, preferably from a single bond, a carbonyl connecting group, an alkylene connecting group, and an alkenylene group, more preferably from a single bond and an alkenylene group, and still more preferably from a single bond.

The definition of L⁶⁵ is similar to that of L¹⁵ in Formula (I), and their preferable ranges are also similar.

The definition of n⁶¹ is the same as the definition of n¹¹ in Formula (I), and their preferable ranges are also similar.

Z⁶¹, Z⁶², Z⁶⁴, Z⁶⁶, Z⁶⁷, and Z⁶⁸ each independently represent a substituted or unsubstituted carbon or nitrogen atom, and preferably a substituted or unsubstituted carbon atom. Examples of the substituent on the carbon include the groups described as examples of R²¹ in Formula (1). Z⁶¹ and Z⁶² may be bonded to each other via a connecting group to form a condensed ring (e.g., a benzo-condensed ring or a pyridine-condensed ring) Z⁶² and Z⁶³ may be bonded to each other via a connecting group to form a condensed ring (e.g., a benzo-condensed ring or a pyridine-condensed ring). Z⁶³ and Z⁶⁴ may be bonded to each other via a connecting group to form a condensed ring (e.g., a benzo-condensed ring or a pyridine-condensed ring). Z⁶⁵ and Z⁶⁶ may be bonded to each other via a connecting group to form a condensed ring (e.g., a benzo-condensed ring or a pyridine-condensed ring). Z⁶⁶ and Z⁶⁷ may be bonded to each other via a connecting group to form a condensed ring (e.g., a benzo-condensed ring or a pyridine-condensed ring). Z⁶⁷ and Z⁶⁸ may be bonded to each other via a connecting group to form a condensed ring (e.g., a benzo-condensed ring or a pyridine-condensed ring). The ring formed by Q⁶¹ may be bonded to Z⁶¹ via a connecting group to form a ring. The ring formed by Q⁶² may be bonded to Z⁶⁸ via a connecting group to form a ring.

The substituent on the carbon is preferably an alkyl group, an alkoxy group, an alkylamino group, an aryl group, a group capable of forming a condensed ring (e.g., benzo-condensed ring or pyridine-condensed ring), or a halogen atom, more preferably an alkylamino group, an aryl group, or a group capable of forming a condensed ring (e.g., benzo-condensed ring or pyridine-condensed ring), still more preferably an aryl group or a group capable of forming a condensed ring (e.g., benzo-condensed ring or pyridine-condensed ring), and particularly preferably a group capable of forming a condensed ring (e.g., benzo-condensed ring or pyridine-condensed ring).

The compound represented by Formula (3-B) will be described below.

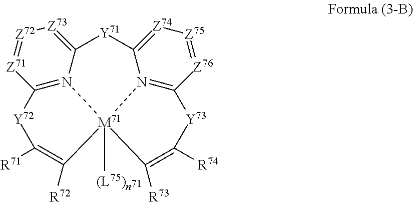

In Formula (3-B), the definition of M⁷¹ is similar to that of M¹¹ in Formula (I), and their preferable ranges are also similar.

The definitions and preferable ranges of Y⁷¹, Y⁷², and Y⁷³ are the same as the definition and preferable range of Y⁶¹, Y⁶², and Y⁶³ in Formula (3-A).

The definition of L⁷⁵ is similar to that of L¹⁵ in Formula (I), and their preferable ranges are also similar.

The definition of n⁷¹ is similar to that of n¹¹ in Formula (I), and their preferable ranges are also similar.

Z⁷¹, Z⁷², Z⁷³, Z⁷⁴, Z⁷⁵, and Z⁷⁶ each independently represent a substituted or unsubstituted carbon or nitrogen atom, and more preferably a substituted or unsubstituted carbon atom. Examples of the substituent on the carbon include the groups described as examples of R²¹ in Formula (1). In addition, Z⁷¹ and Z⁷² may be bonded to each other via a connecting group to form a ring (e.g., a benzene ring or a pyridine ring). Z⁷² and Z⁷³ may be bonded to each other via a connecting group to form a ring (e.g., a benzene ring or a pyridine ring). Z⁷³ and Z⁷⁴ may be bonded to each other via a connecting group to form a ring (e.g., a benzene ring or a pyridine ring). Z⁷⁴ and Z⁷⁵ may be bonded to each other via a connecting group to form a ring (e.g., a benzene ring or a pyridine ring). Z⁷⁵ and Z⁷⁶ may be bonded to each other via a connecting group to form a ring (e.g., a benzene ring or a pyridine ring). The definitions and preferable ranges of R⁷¹ to R⁷⁴ are similar to the definitions of R²¹ to R²⁴ in Formula (1), respectively.

Preferable examples of compounds represented by Formula (3-B) include compounds represented by the following formula (3-C).

The compound represented by Formula (3-C) will be described below.

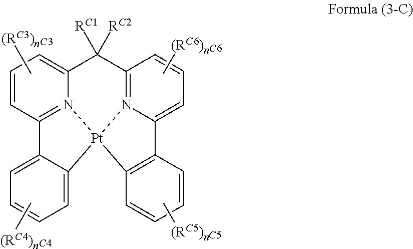

In Formula (3-C), R^{C1} and R^{C2} each independently represent a hydrogen atom or a substituent, and the substituents may be selected from the alkyl groups and aryl groups described as examples of R²¹ to R²⁴ in Formula (1). The definition of R^{C3}, R^{C4}, R^{C5}, and R^{C6} is the same as the definition of R²¹ to R²⁴ in Formula (1). Each of n^{C3} and n^{C6} represents an integer of 0 to 3; each of n^{C4} and n^{C5} represents an integer of 0 to 4; when there are plural R^{C3}s, R^{C4}s, R^{C5}s, or R^{C6}s, the plural R^{C3}s, R^{C4}s, R^{C5}s, or R^{C6}s may be the same as each other or different from each other, and may be bonded to each other to form a ring. R^{C3}, R^{C4}, R^{C5}, and R^{C6} each preferably represent an alkyl group, an aryl group, a heteroaryl group, or a halogen atom.

The compound represented by Formula (4) will be described below.

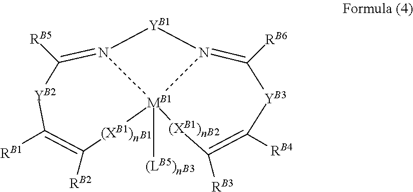

In Formula (4), the definitions and preferable ranges of M^{B1}, Y^{B2}, Y^{B3}, R^{B1}, R^{B2}, R^{B3}, R^{B4}, L^{B5}, n^{B3}, X^{B1}, and X^{B2} are similar to the definitions of M²¹, Y²², Y²³, R²¹, R²², R²³, R²⁴, L²⁵, n²¹, X²¹, X²² in Formula (1), respectively.

Y^{B1} represents a connecting group whose definition is similar to that of Y²¹ in Formula (1). Y^{B1} is preferably a vinyl group substituted at 1- or 2-position, a phenylene ring, a pyridine ring, a pyrazine ring, a pyrimidine ring, or an alkylene group having 2 to 8 carbons.

R^{B5} and R^{B6} each independently represent a hydrogen atom or a substituent, and the substituent may be selected from the alkyl groups, aryl groups, and heterocyclic groups described as examples of R²¹ to R²⁴ in Formula (1). However, Y^{B1} is not bonded to R^{B5} or R^{B6}. n^{B1} and n^{B2} each independently represent an integer of 0 or 1.

Preferable examples of the compound represented by Formula (4) include compounds represented by the following Formula (4-A).

The compound represented by Formula (4-A) will be described below.

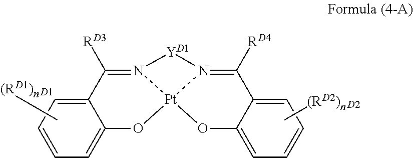

In Formula (4-A), R^{D3} and R^{D4} each independently represent a hydrogen atom or a substituent, and R^{D1} and R^{D2} each represent a substituent. The substituents represented by R^{D1}, R^{D2}, R^{D3}, and R^{D4} may be selected from the substituents described as examples of R^{B5} and R^{B6} in Formula (4), and have the same preferable range as R^{B5} and R^{B6} in Formula (4). n^{D1} and n^{D2} each represent an integer of 0 to 4. When there are plural R^{D1}s, the plural R^{D1}s may be the same as or different from each other or may be bonded to each other to form a ring. When there are plural R^{D2}'s, the plural R^{D2}'s may be the same as or different from each other or may be bonded to each other to form a ring. Y^{D1} represents a vinyl group substituted at 1- or 2-position, a phenylene ring, a pyridine ring, a pyrazine ring, a pyrimidine ring, or an alkylene group having 1 to 8 carbon atoms.

Preferable examples of the metal complex having a tridentate ligand according to the invention include compounds represented by the following Formula (5).

The compound represented by Formula (5) will be described below.

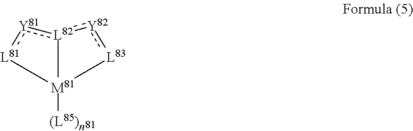

In Formula (5), the definition of M⁸¹ is similar to that of M¹¹ in Formula (I), and their preferable ranges are also similar.

The definitions and preferable ranges of L⁸¹, L⁸², and L⁸³ are similar to the definitions and preferable ranges of L¹¹, L¹², and L¹⁴ in Formula (I), respectively.

The definitions and preferable ranges of Y⁸¹ and Y⁸² are similar to the definitions and preferable ranges of Y¹¹ and Y¹² in Formula (I), respectively.

L⁸⁵ represents a ligand coordinating to M⁸¹. L⁸⁵ is preferably a mono- to tridentate ligand and more preferably a monodentate to tridentate anionic ligand. The mono- to tri-dentate anionic ligand is not particularly limited, but is preferably a halogen ligand or a tridentate ligand L⁸¹, Y⁸¹, L⁸², Y⁸², and L⁸³ can form, and more preferably a tridentate ligand L⁸¹, Y⁸¹, L⁸², Y⁸², and L⁸³ can form. L⁸⁵ is not directly bonded to L⁸¹ or L⁸³. The numbers of coordination sites and ligands do not exceed the valency of the metal.

n⁸¹ represents an integer of 0 to 5. When M⁸¹ is a tetravalent metal, n⁸¹ is 1, and L⁸⁵ represents a monodentate ligand. When M⁸¹ is a hexavalent metal, n⁸¹ is preferably 1 to 3, more preferably 1 or 3, and still more preferably 1. When M⁸¹ is hexavalent and n81 is 1, L⁸⁵ represents a tridentate ligand. When M⁸¹ is hexavalent and n⁸¹ is 2, L⁸⁵ represents a monodentate ligand and a bidentate ligand. When M⁸¹ is hexavalent and n⁸¹ is 3, L⁸⁵ represents a monodentate ligand. When M⁸¹ is an octavalent metal, n⁸¹ is preferably 1 to 5, more preferably 1 or 2, and still more preferably 1. When M⁸¹ is octavalent and n⁸¹ is 1, L⁸⁵ represents a pentadentate ligand. When M⁸¹ is octavalent and n⁸¹ is 2, L⁸⁵ represents a tridentate ligand and a bidentate ligand. When M⁸¹ is octavalent and n⁸¹ is 3, L⁸⁵ represents a tridentate ligand and two monodentate ligands, or represents two bidentate ligands and one monodentate ligand. When M⁸¹ is octavalent and n⁸¹ is 4, L⁸⁵ represents one bidentate ligand and three monodentate ligands. When M⁸¹ is octavalent and n⁸¹ is 5, L⁸⁵ represents five monodentate ligands. When n⁸¹ is 2 or larger, there are plural L⁸⁵'s, and the plural L⁸⁵'s may be the same as or different from each other.

In a preferable example of the compound represented by Formula (5), L⁸¹, L⁸², or L⁸³ each represent an aromatic carbon ring containing a carbon atom coordinating to M⁸¹, a heterocycle containing a carbon atom coordinating to M⁸¹, or a nitrogen-containing heterocycle containing a nitrogen atom coordinating to M⁸¹, wherein at least one of L⁸¹, L⁸², and L⁸³ is a nitrogen-containing heterocycle. Examples of the aromatic carbon ring containing a carbon atom coordinating to M⁸¹, heterocycle containing a carbon atom coordinating to M⁸¹, or nitrogen-containing heterocycle containing a nitrogen atom coordinating to M⁸¹ include the examples of ligands (moieties) each containing a nitrogen or carbon atom coordinating to M¹¹ in Formula (I) described in the explanation of formula (I). Preferable examples thereof are the same as in the description of ligands (moieties) each containing a nitrogen or carbon atom coordinating to M¹¹ in Formula (I). Y⁸¹ and Y⁸² each preferably represent a single bond or a methylene group.

Other preferable examples of compounds represented by Formula (5) include compounds represented by the following Formulae (5-A) and (5-B).

The compound represented by Formula (5-A) will be described below.

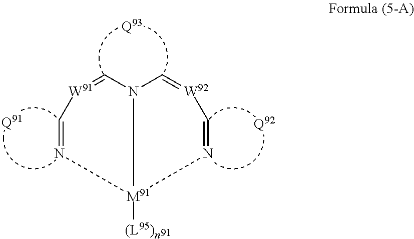

In Formula (5-A), the definition of M⁹¹ is similar to that of M⁸¹ in Formula (5), and their preferable ranges are also similar.

Q⁹¹ and Q⁹² each represent a group forming a nitrogen-containing heterocycle (ring containing a nitrogen atom coordinating to M⁹¹). The nitrogen-containing heterocycles formed by Q⁹¹ and Q⁹² are not particularly limited, and examples thereof include a pyridine ring, a pyrazine ring, a pyrimidine ring, a pyridazine ring, a triazine ring, a thiazole ring, an oxazole ring, a pyrrole ring, a pyrazole ring, a imidazole, a triazole ring, and condensed rings containing one or more of the above rings (e.g., a quinoline ring, a benzoxazole ring, a benzimidazole ring, and an indolenine ring), and tautomers thereof.

Each of the nitrogen-containing heterocycles formed by Q⁹¹ and Q⁹² is preferably a pyridine ring, a pyrazole ring, a thiazole ring, an imidazole ring, a pyrrole ring, a condensed ring containing one or more of the above ring (e.g., a quinoline ring ring, a benzothiazole ring, a benzimidazole ring, or an indolenine ring), or a tautomer of any of the above rings; more preferably a pyridine ring, a pyrrole ring, a condensed ring containing one or more of these rings (e.g., a quinoline ring), or a tautomer of any of the above rings; more preferably a pyridine ring or a condensed ring containing a pyridine ring (e.g., a quinoline ring); and particularly preferably a pyridine ring.

Q⁹³ represents a group forming a nitrogen-containing heterocycle (ring containing a nitrogen atom coordinating to M⁹¹). The nitrogen-containing heterocycle formed by Q⁹³ is not particularly limited, but is preferably a pyrrole ring, an imidazole ring, a tautomer of a triazole ring, or a condensed ring containing one or more of the above rings (e.g., benzopyrrole), and more preferably a tautomer of a pyrrole ring or a tautomer of a condensed ring containing a pyrrole ring (e.g., benzopyrrole).

The definitions and preferable ranges of W⁹¹ and W⁹² are similar to the definitions and preferable ranges of W⁵¹ and W⁵² in Formula (2), respectively.

The definition of L⁹⁵ is similar to that of L⁸⁵ in Formula (5), and their preferable ranges are also similar.

The definition of n⁹¹ is similar to that of n⁸¹ in Formula (5), and their preferable ranges are also similar.

The compound represented by Formula (5-B) will be described next.

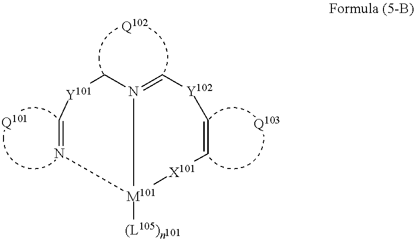

In Formula (5-B), the definition of M¹⁰¹ is similar to that of M⁸¹ in Formula (5), and their preferable ranges are also similar.

The definition of Q¹⁰² is similar to that of Q²¹ in Formula (1), and their preferable ranges are also similar.

The definition of Q¹⁰¹ is similar to that of Q⁹¹ in Formula (5-A), and their preferable ranges are also similar.

Q¹⁰³ represents a group forming an aromatic ring. The aromatic ring formed by Q¹⁰³ is not particularly limited, but is preferably a benzene ring, a furan ring, a thiophene ring, a pyrrole ring, or a condensed ring containing one or more of the above rings (e.g., a naphthalene ring), more preferably a benzene ring or a condensed ring containing a benzene ring (e.g., naphthalene ring), and particularly preferably a benzene ring.

The definitions and preferable ranges of Y¹⁰¹ and Y¹⁰² are similar to the definition and preferable range of Y²² in Formula (1).

The definition of L¹⁰⁵ is similar to that of L⁸⁵ in Formula (5), and their preferable ranges are also similar.

The definition of n¹⁰¹ is similar to that of n⁸¹ in Formula (5), and their preferable ranges are also similar.

The definition of X¹⁰¹ is similar to that of X²¹ in Formula (1), and their preferable ranges are also similar.

The compound represented by Formula (II) will be described below.

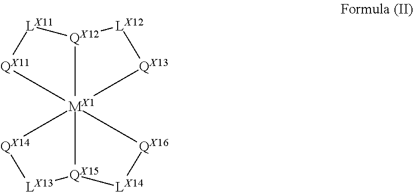

In Formula (II), M^{X1} represents a metal ion. Q^{X11} to Q^{X16} each independently to represent an atom coordinating to M^{X1} or an atomic group containing an atom coordinating to M^{X1}. L^{X11} to L^{X14} each independently represent a single bond, a double bond or a connecting group.

Namely, in Formula (II), the atomic group comprising Q^{X11}-L^{X11}-Q^{X12}-L^{X12}-Q^{X13} and the atomic group comprising Q^{X14}-L^{X13}-Q^{X15}-L^{X14}-Q^{X16} each form a tridentate ligand.

In addition, each of the bond between M^{X1} and each of Q^{X11} to Q^{X16} may be a to coordination bond or a covalent bond.

The compound represented by Formula (II) will be described in detail below.

In Formula (II), M^{X1} represents a metal ion. The metal ion is not particularly limited, but is preferably a monovalent to trivalent metal ion, more preferably a divalent or trivalent metal ion, and still more preferably a trivalent metal ion. Specifically, a platinum ion, an iridium ion, a rhenium ion, a palladium ion, a rhodium ion, a ruthenium ion, a copper ion, a europium ion, a gadolinium, and a terbium ion are preferable. Among these, an iridium ion and a europium ion are more preferable, and an iridium ion is still more preferable.

Q^{X11} to Q^{X16} each represent an atom coordinating to M^{X1} or an atomic group containing an atom coordinating to M^{X1}.

When any of Q^{X11} to Q^{X16} is an atom coordinating to M^{X1}, specific examples of the atom include a carbon atom, a nitrogen atom, an oxygen atom, a silicon atom, a phosphorus atom, and a sulfur atom. Preferable specific examples of the atom include a nitrogen atom, an oxygen atom, a sulfur atom, and a phosphorus atom. More preferable specific examples of the atom include a nitrogen atom and an oxygen atom.

When any of Q^{X11} to Q^{X16} is an atomic group containing a carbon atom coordinating to M^{X1}, examples of the atomic group coordinating to M^{X1} via a carbon atom include imino groups, aromatic hydrocarbon ring groups (such as a benzene ring group or a naphthalene ring group), heterocyclic groups (such as a thiophene group, a pyridine group, a pyrazine group, a pyrimidine group, a pyridazine group, a triazine group, a thiazole group, an oxazole group, a pyrrole group, an imidazole group, a pyrazole group, or a triazole group), condensed rings containing one or more of the above rings, and tautomers thereof.

When any of Q^{X11} to Q^{X16} is an atomic group containing a nitrogen atom coordinating to M^{X1}, examples of the atomic group coordinating to M^{X1} via a nitrogen atom include nitrogen-containing heterocyclic groups, amino groups, and imino groups. Examples of the nitrogen-containing heterocyclic groups include pyridine, pyrazine, pyrimidine, pyridazine, triazine, thiazole, oxazole, pyrrole, imidazole, pyrazole, or triazole. Examples of the amino groups include alkylamino groups (preferably having 2 to 30 carbon atoms, more preferably 2 to 20 carbon atoms, and particularly preferably 2 to 10 carbon atoms, and examples thereof include a methylamino group), arylamino groups (e.g., a phenylamino group)], acylamino groups (preferably having 2 to 30 carbon atoms, more preferably 2 to 20 carbon atoms, and particularly preferably 2 to 10 carbon atoms, and examples thereof include an acetylamino group and a benzoylamino group), alkoxycarbonylamino groups (preferably having 2 to 30 carbon atoms, more preferably 2 to 20 carbon atoms, and particularly preferably 2 to 12 carbon atoms, and examples thereof include a methoxycarbonylamino group), aryloxycarbonylamino groups (preferably having 7 to 30 carbon atoms, more preferably 7 to 20 carbon atoms, and particularly preferably 7 to 12 carbon atoms, and examples thereof include a phenyloxycarbonylamino group), and sulfonylamino groups (preferably having 1 to 30 carbon atoms, more preferably 1 to 20 carbon atoms, and particularly preferably 1 to 12 carbon atoms, and examples thereof include a methanesulfonylamino and benzenesulfonylamino group). These groups may have a substitutent(s).

When any of Q^{X11} to Q^{X16} is an atomic group containing an oxygen atom coordinating to M^{X1}, examples of the atomic groups coordinating to M^{X1} via an oxygen atom include alkoxy groups (preferably having 1 to 30 carbon atoms, more preferably 1 to 20 carbon atoms, and particularly preferably 1 to 10 carbon atoms, and examples thereof include a methoxy group, an ethoxy group, a butoxy group, and a 2-ethylhexyloxygroup), aryloxy groups (preferably having 6 to 30 carbon atoms, more preferably 6 to 20 carbon atoms, and particularly preferably 6 to 12 carbon atoms, and examples thereof include a phenyloxy group, a 1-naphthyloxygroup, and a 2-naphthyloxy group), heterocyclic oxy groups (preferably having 1 to 30 carbon atoms, more preferably 1 to 20 carbon atoms, and particularly preferably 1 to 12 carbon atoms, and examples thereof include a pyridyloxy group, a pyrazyloxy group, a pyrimidyloxy group, and a quinolyloxy group), acyloxy groups (preferably having 2 to 30 carbon atoms, more preferably 2 to 20 carbon atoms, and particularly preferably 2 to 10 carbon atoms, and examples thereof include an acetoxy group and a benzoyloxy group), silyloxy groups (preferably having 3 to 40 carbon atoms, more preferably 3 to 30 carbon atoms, and particularly preferably 3 to 24 carbon atoms, and examples thereof include a trimethylsilyloxy group and a triphenylsilyloxy), carbonyl groups (e.g., ketone groups, ester groups, and amido groups), and ether groups (e.g., dialkylether groups, diarylether groups, and furyl groups).

When any of Q^{X11} to Q^{X16} is an atomic group containing a silicon atom coordinating to M^{X1}, examples of the atomic group coordinating to M^{X1} via a silicon atom include alkylsilyl groups (preferably having 3 to 30 carbon atoms, and examples thereof include a trimethylsilyl group), and arylsilyl groups (preferably, having 18 to 30 carbon atoms, and examples thereof include a triphenylsilyl group). These groups may have a substituent(s).

When any of Q^{X11} to Q^{X16} is an atomic group containing a sulfur atom coordinating to M^{X1}, examples of the atomic group coordinating to M^{X1} via a sulfur atom include alkylthio groups (preferably having 1 to 30 carbon atoms, more preferably 1 to 20 carbon atoms, and particularly preferably 1 to 12 carbon atoms, and examples thereof include a methylthio group and and an ethylthio group), arylthio groups (preferably having 6 to 30 carbon atoms, more preferably 6 to 20 carbon atoms, and particularly preferably 6 to 12 carbon atoms, and examples thereof include a phenylthio group), heterocyclic thio groups (preferably having 1 to 30 carbon atoms, more preferably 1 to 20 carbon atoms, and particularly preferably 1 to 12 carbon atoms, and examples thereof include a pyridylthio group, a 2-benzimidazolylthio group, a 2-benzoxazolylthio group, and a 2-benzothiazolylthio group), thiocarbonyl groups (e.g., a thioketone group and a thioester group), and thioether groups (e.g., a dialkylthioether group, a diarylthioether group, and a thiofuryl group).

When any of Q^{X11} to Q^{X16} is an atomic group containing a phosphorus atom coordinating to M^{X1}, examples of the atomic group coordinating to M^{X1} via a phosphorus atom include dialkylphosphino groups, diarylphosphino groups, trialkyl phosphines, triaryl phosphines, and phosphinine groups. These groups may have a substituent(s).

The atomic groups represented by Q^{X11} to Q^{X16} are each preferably an aromatic hydrocarbon ring group containing a carbon atom coordinating to M^{X1}, an aromatic heterocyclic group containing a carbon atom coordinating to M^{X1}, a nitrogen-containing aromatic heterocyclic group containing a nitrogen atom coordinating to M^{X1}, an alkyloxy group, an aryloxy group, an alkylthio group, an arylthio group, or an dialkylphosphino group, and more preferably an aromatic hydrocarbon ring group containing a carbon atom coordinating to M^{X1}, an aromatic heterocyclic group containing a carbon atom coordinating to M^{X1}, or a nitrogen-containing aromatic heterocyclic group containing a nitrogen atom coordinating to M^{X1}.

The bond between M^{X1} and each of Q^{X11} to Q^{X16} may be a coordination bond or a covalent bond.

In Formula (II), L^{X11} to L^{X14} each represent a single or double bond or a connecting group. The connecting group is not particularly limited, but preferably a connecting group containing one or more atoms selected from carbon, nitrogen, oxygen, sulfur, and silicon. Examples of the connecting group are shown below, however, the scope of thereof is not limited by these.

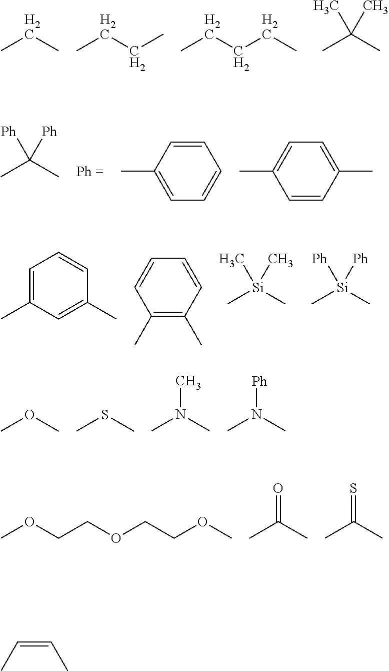

These connecting groups may have a substituent(s), and the substituent may be selected from the examples of the substituents represented by R²¹ to R²⁴ in Formula (1), and the preferable range thereof is also the same as in Formula (1). L^{X11} to L^{X14} are each preferably a single bond, a dimethylmethylene group, or a dimethylsilylene group.

Among compounds represented by Formula (II), compounds represented by the following Formula (X2) are more preferable, and compounds represented by the following Formula (X3) are still more preferable.

The compound represented by Formula (X2) is described first.

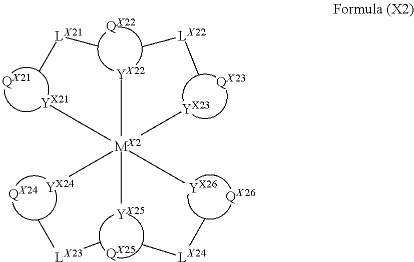

In Formula (X2), M^{X2} represents a metal ion. Y^{X21} to Y^{X26} each represent an atom coordinating to M^{X2}; and Q^{X21} to Q^{X26} each represent an atomic group forming an aromatic ring or an aromatic heterocycle respectively with Y^{X21} to Y^{X26}. L^{X21} to L^{X24} each represent a single or double bond or a connecting group. The bond between M^{X2} and each of Y^{X21} to Y^{X26} may be a coordination bond, an ionic bond or a covalent bond.

The compound represented by Formula (X2) will be described below in detail.

In Formula (X2), the definition of M^{X2} is similar to that of M^{X1} in Formula (II), and their preferable ranges are also similar. Y^{X21} to Y^{X26} each represent an atom coordinating to M^{X2}. The bond between M^{X2} and each of Y^{X21} to Y^{X26} may be a coordination bond, an ionic bond or a covalent bond. Each of Y^{X21} to Y^{X26} is a carbon atom, a nitrogen atom, an oxygen atom, a sulfur atom, a phosphorus atom, or a silicon atom, and preferably a carbon atom or a nitrogen atom. Q^{X21} to Q^{X26} represent atomic groups forming rings containing Y^{X21} to Y^{X26}, respectively, and the rings are each independently selected from aromatic hydrocarbon rings and aromatic heterocycles. The aromatic hydrocarbon rings and aromatic heterocycles may be selected from a benzene ring, a pyridine ring, a pyrazine ring, a pyrimidine ring, a pyridazine ring, a triazine ring, a pyrrole ring, a pyrazole ring, an imidazole ring, a triazole ring, an oxazole ring, a thiazole ring, an oxadiazole ring, a thiadiazole ring, a thiophene ring, and a furan ring; preferably selected from a benzene ring, a pyridine ring, a pyrazine ring, a pyrimidine ring, a pyrazole ring, an imidazole ring, and a triazole ring; more preferably selected from a benzene ring, a pyridine ring, a pyrazine ring, a pyrazole ring, and a triazole ring; and particularly preferably selected from a benzene ring and a pyridine ring. The aromatic rings may have a condensed ring or a substituent.

The definitions and preferable ranges of L^{X21} to L^{X24} are similar to the definitions and preferable ranges of L^{X11} to L^{X14} in Formula (II), respectively.

Compounds represented by the following Formula (X3) are more preferable examples of the compounds represented by Formula (II).

The compound represented by Formula (X3) will be described below.

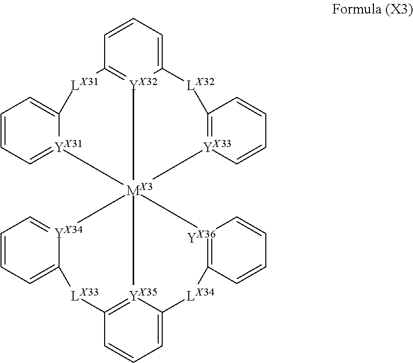

In Formula (X3), M^{X3} represents a metal ion. Y^{X31} to Y^{X36} each represent a carbon atom, a nitrogen atom, or a phosphorus atom. L^{X31} to L^{X34} each represent a single bond, a double bond or a connecting group. The bond between M^{X3} and each of Y^{X31} to Y^{X36} may be a coordination bond, an ionic bond or a covalent bond.

The definition of M^{X3} is similar to that of M^{X1} in Formula (II) above, and their preferable ranges are also similar. Y^{X31} to Y^{X36} each represent an atom coordinating to M^{X3}. The bond between M^{X3} and each of Y^{X31} to Y^{X36} may be a coordination bond or a covalent bond. Y^{X31} to Y^{X36} each represent a carbon atom, a nitrogen atom, or a phosphorus atom, and preferably a carbon atom or a nitrogen atom. The definitions and preferable ranges of L^{X31} to L^{X34} are similar to the definitions and preferable ranges of L^{X11} to L^{X14} in Formula (II), respectively.

Specific examples of compounds represented by the Formula (I), (II) or (5) include the compounds (1) to (242) described in Japanese Patent Application No. 2004-162849 and compounds (243) to (246) (their structures being shown below). The invention is not limited thereto.

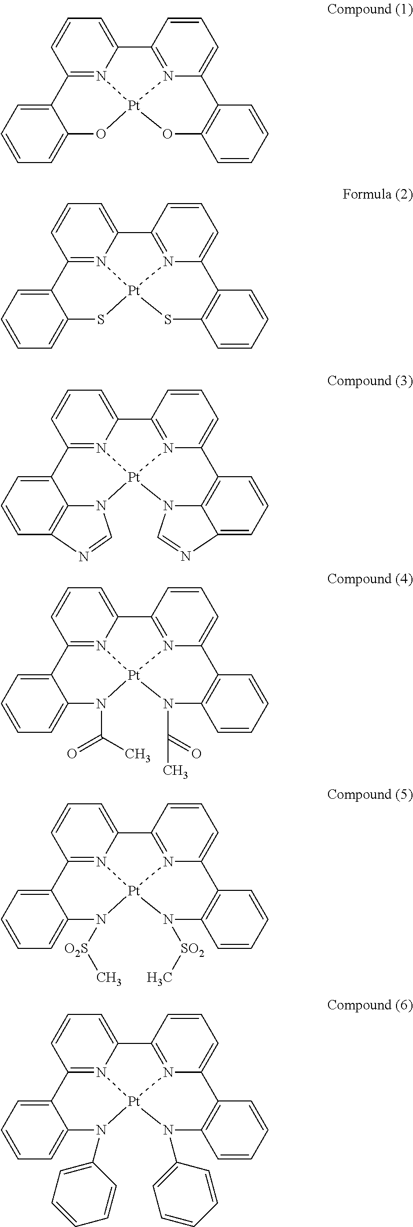

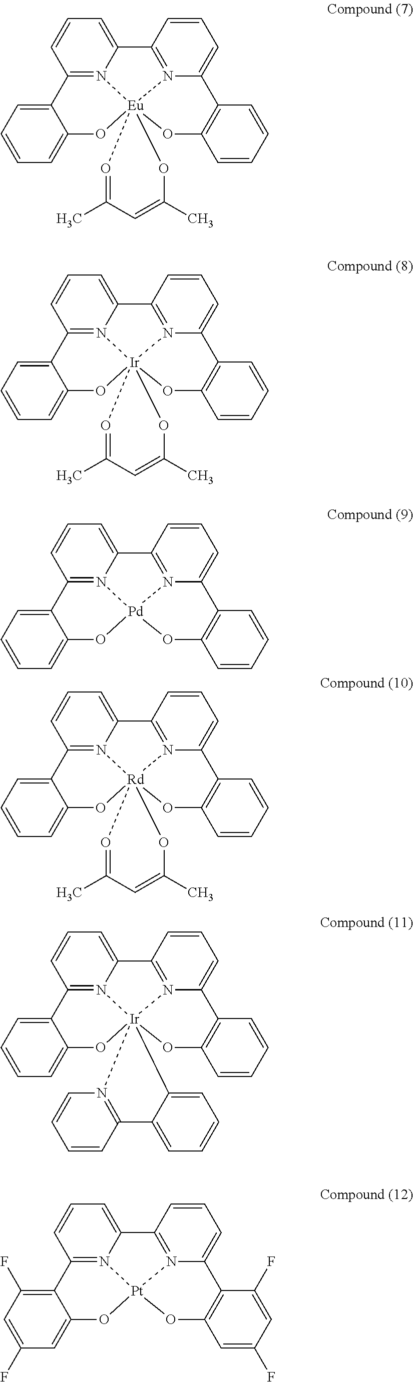

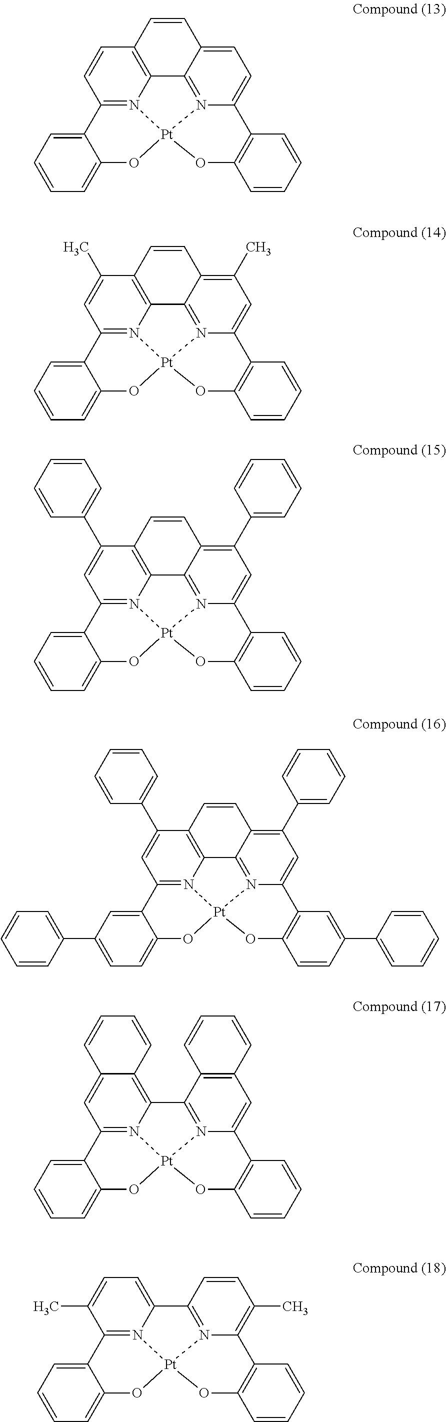

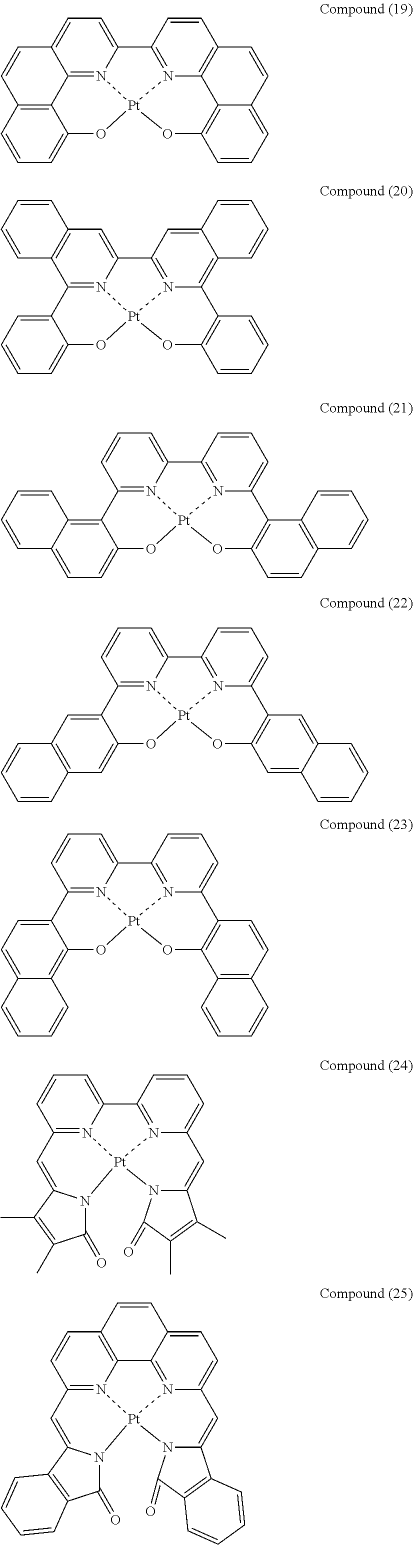

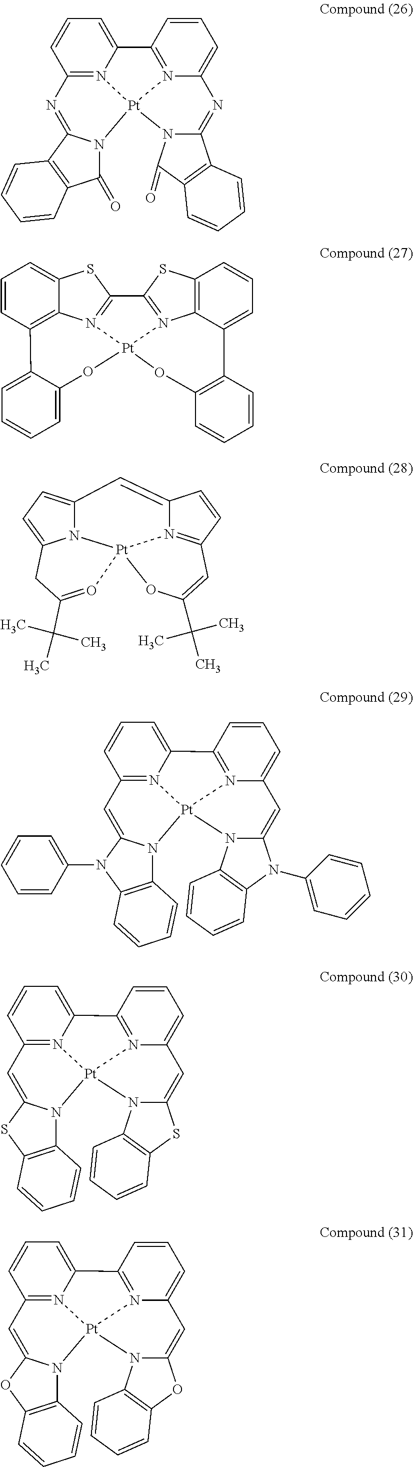

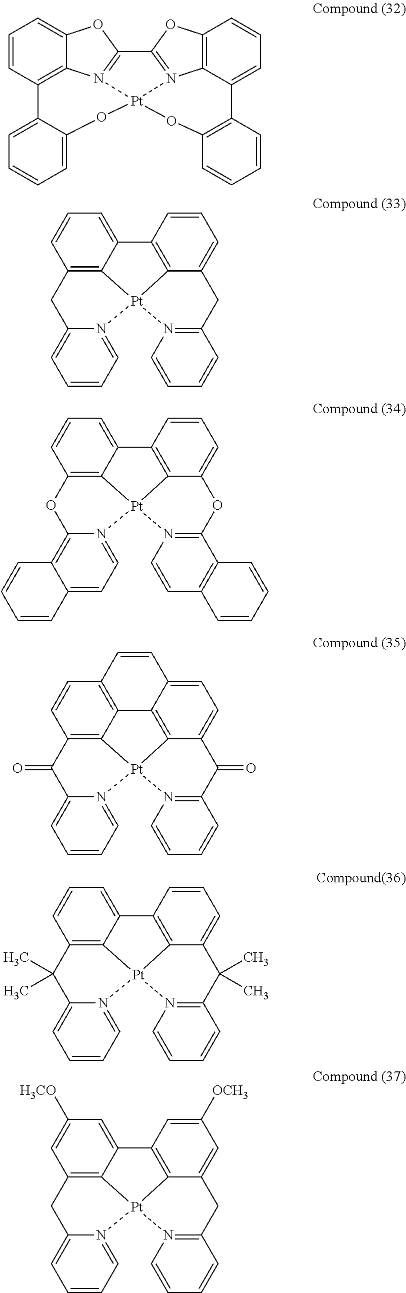

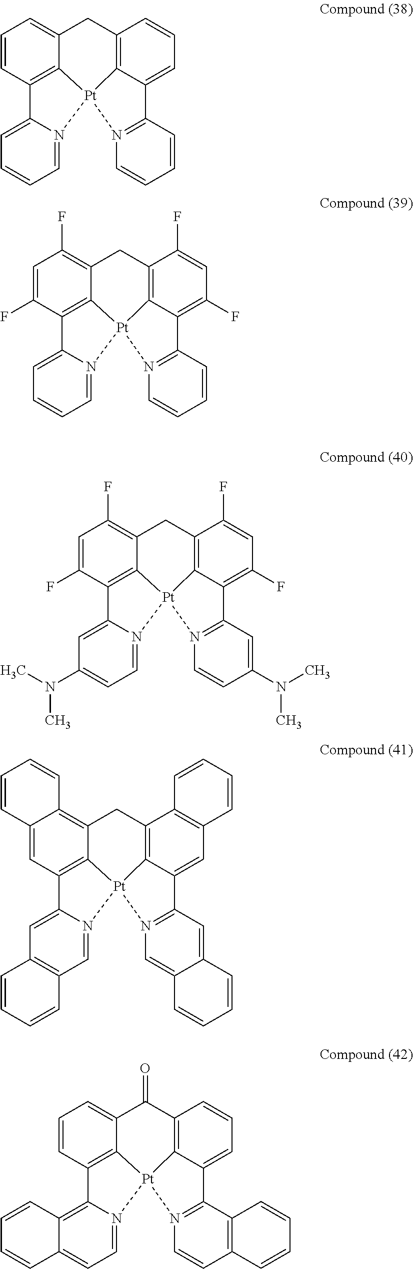

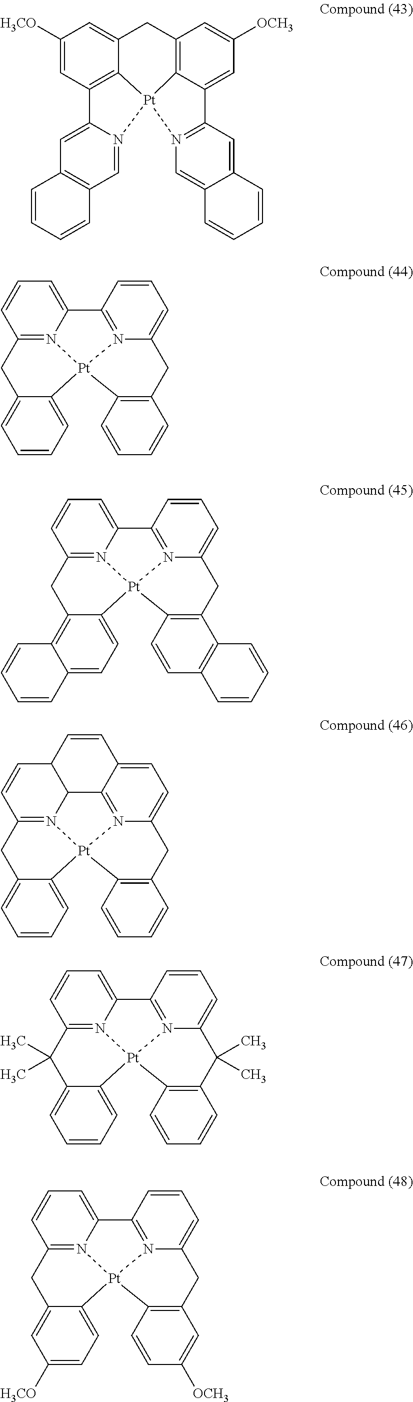

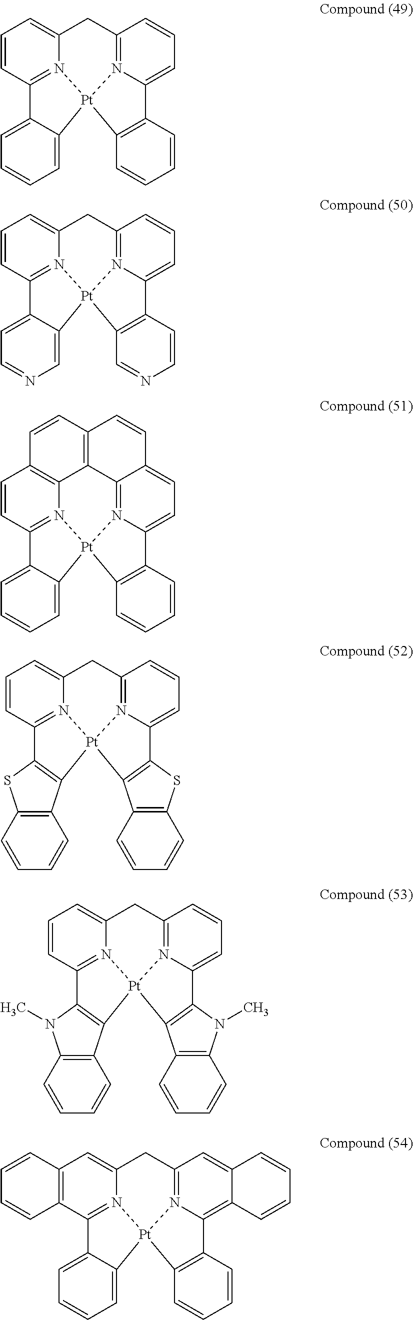

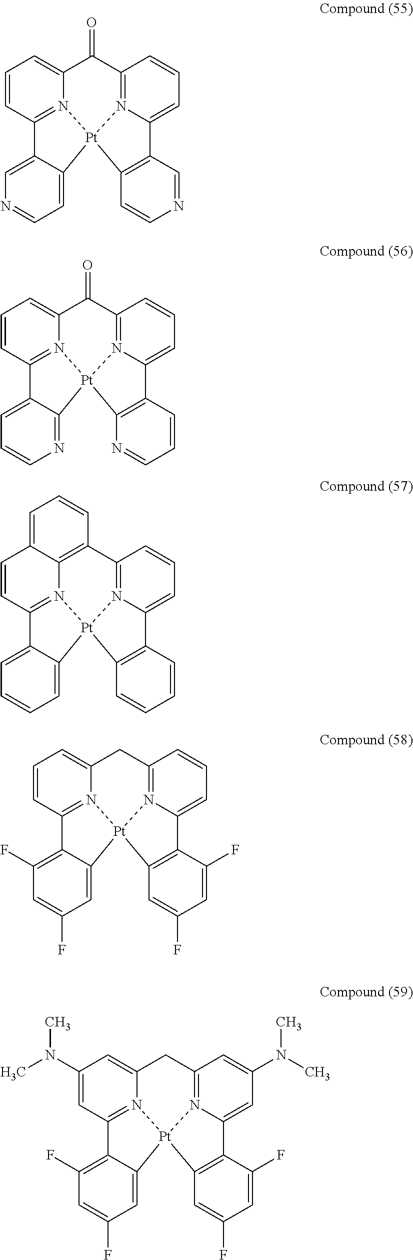

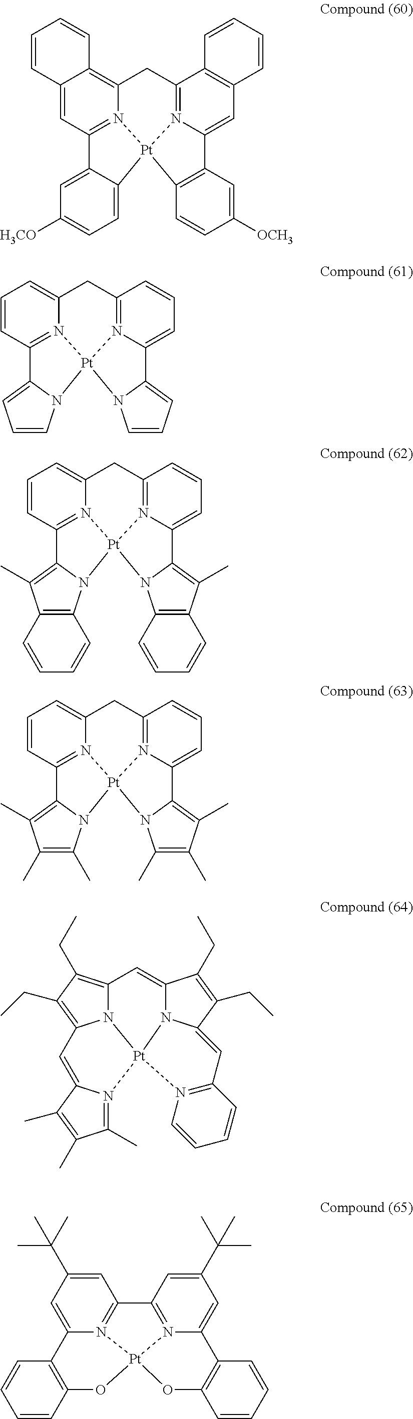

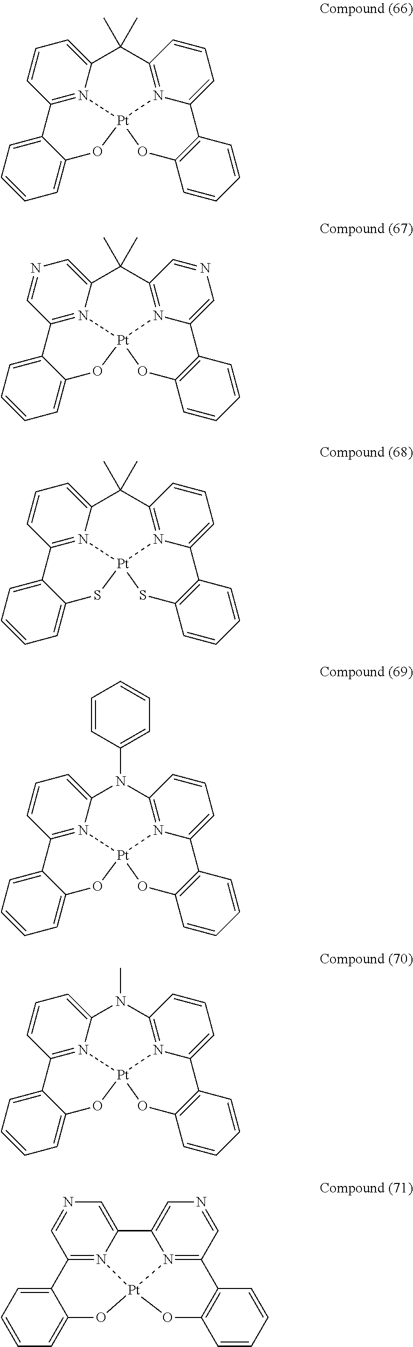

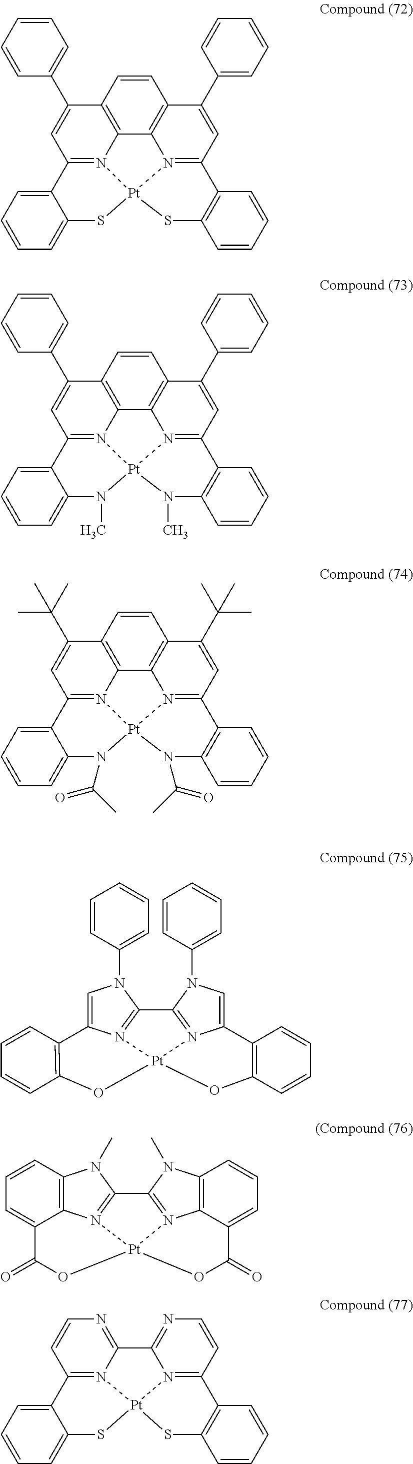

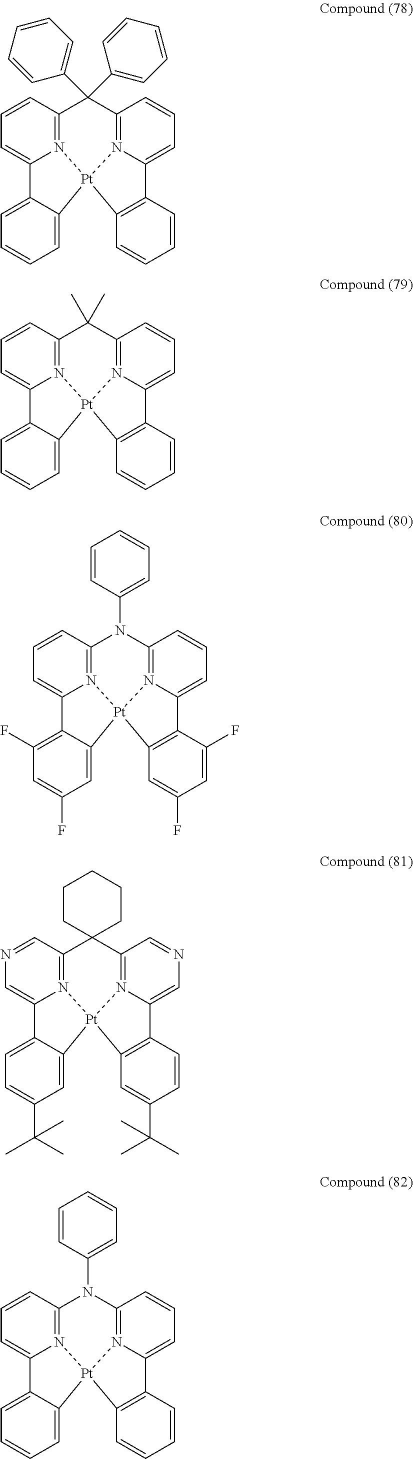

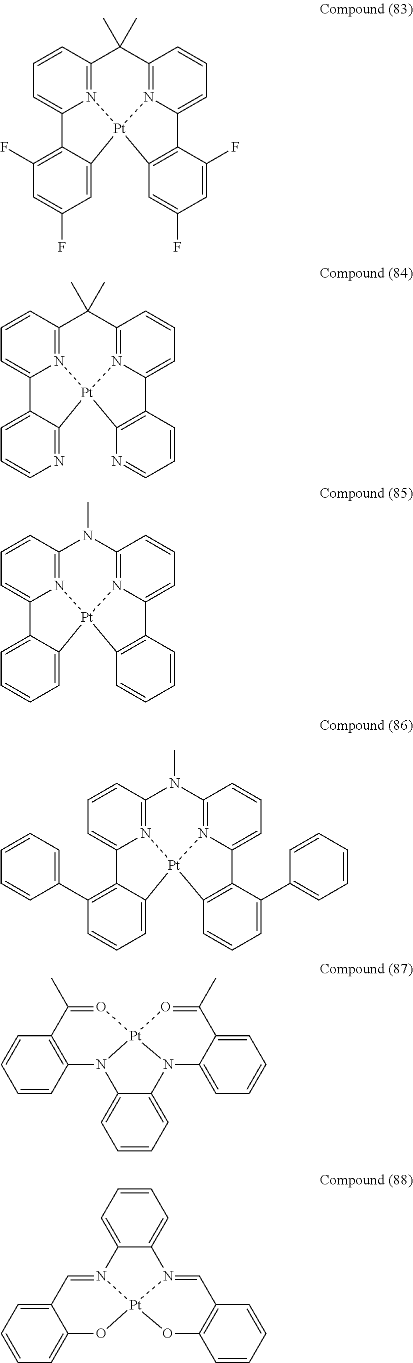

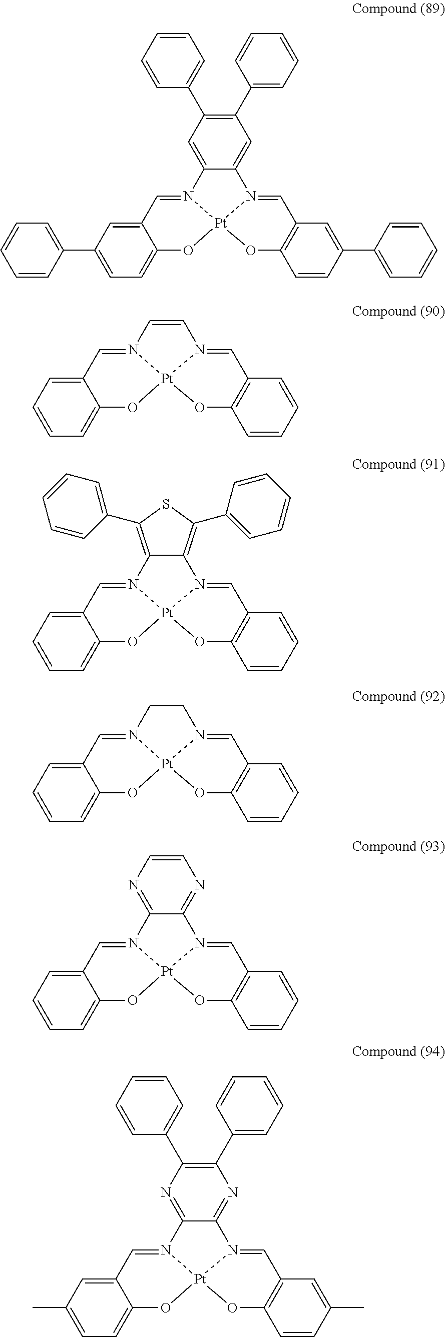

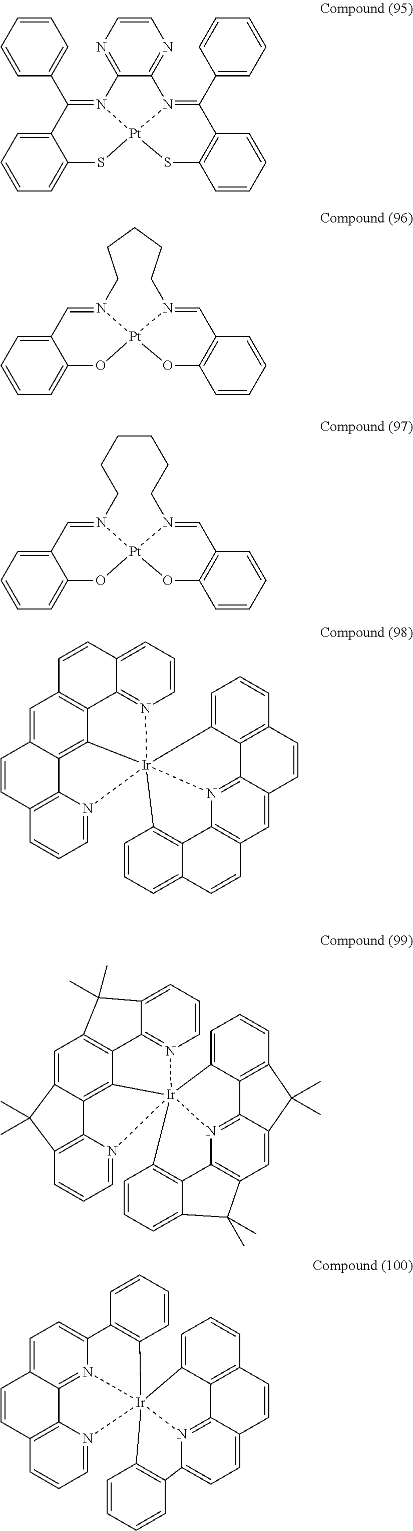

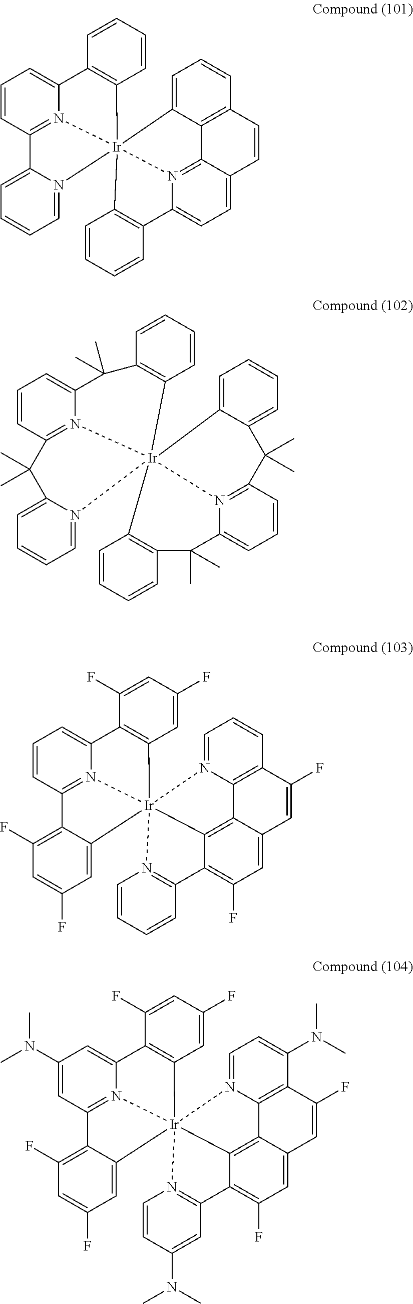

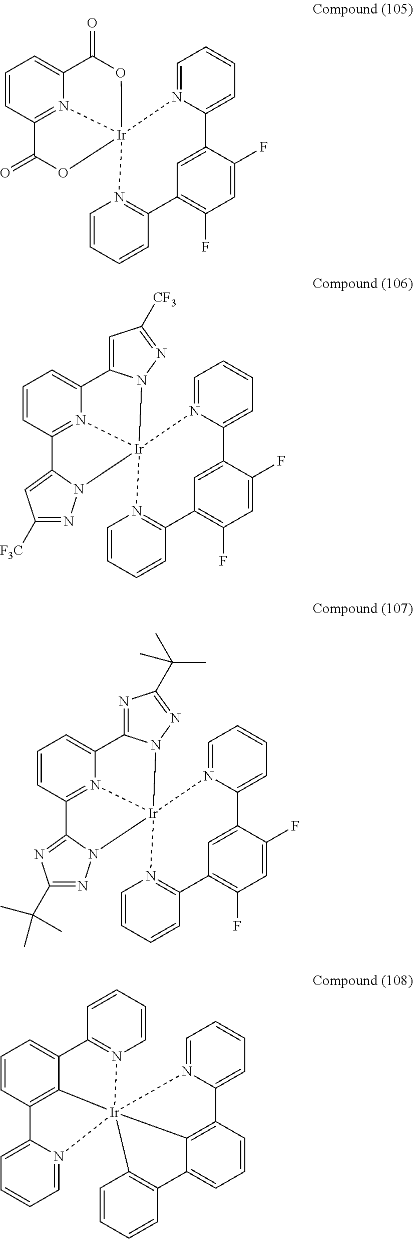

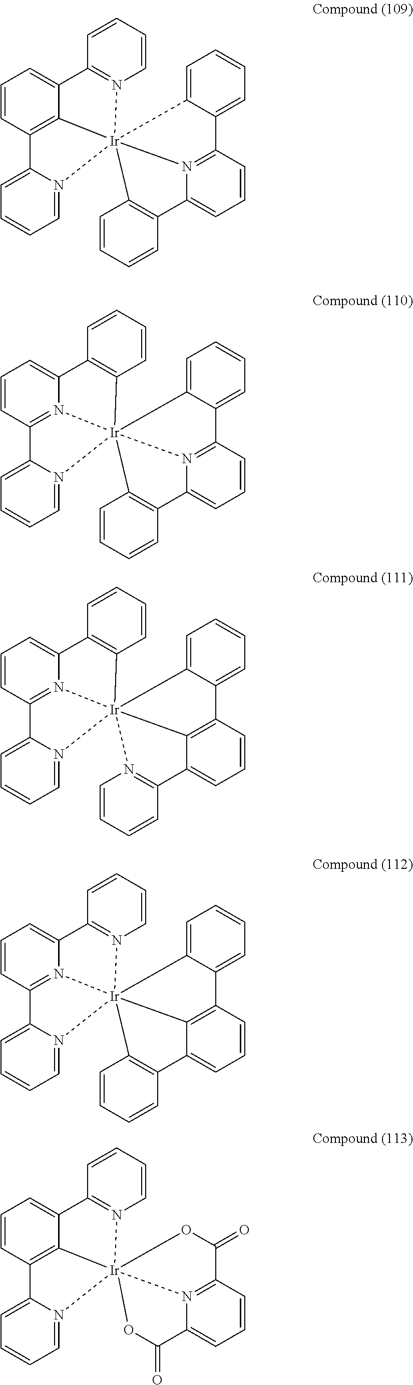

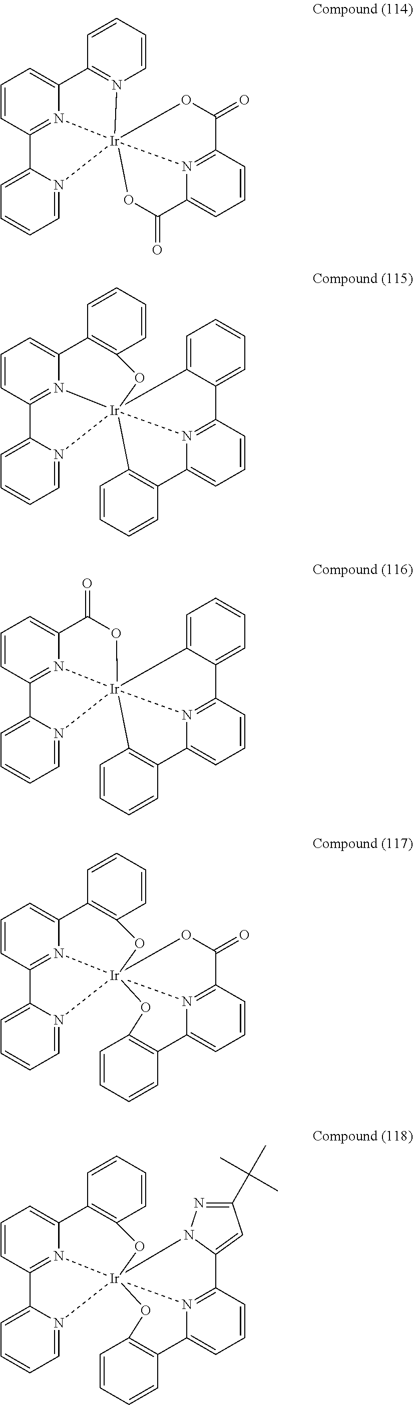

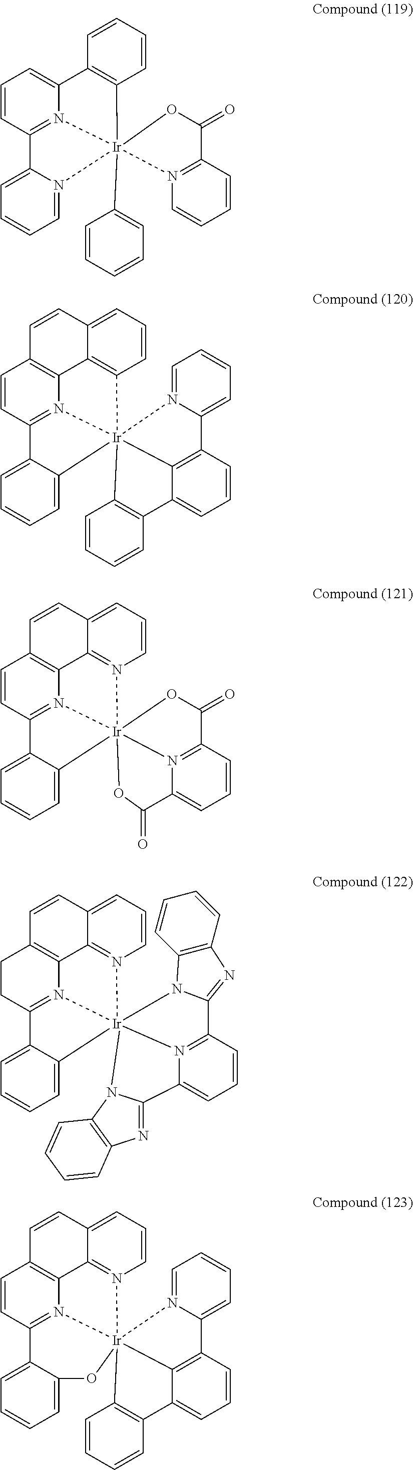

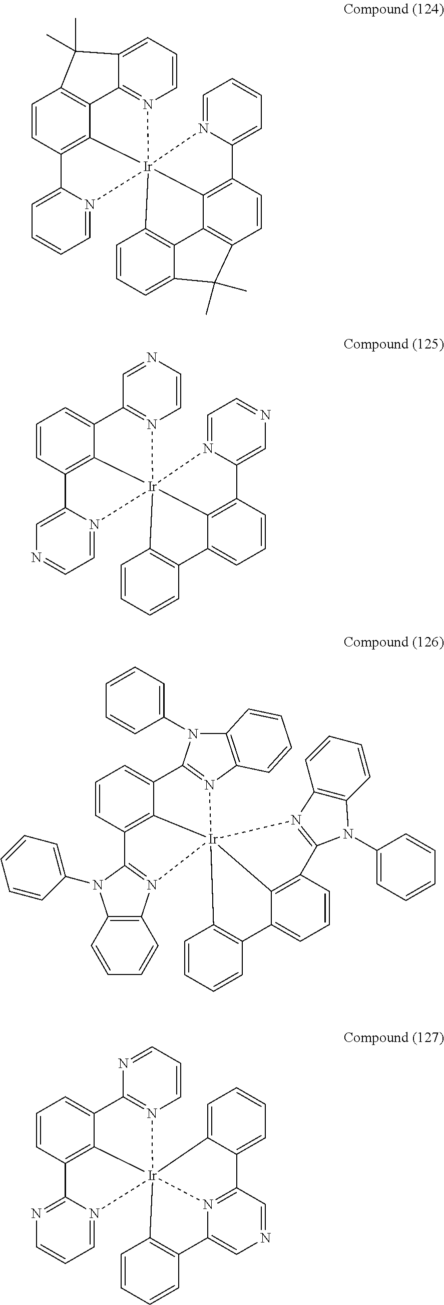

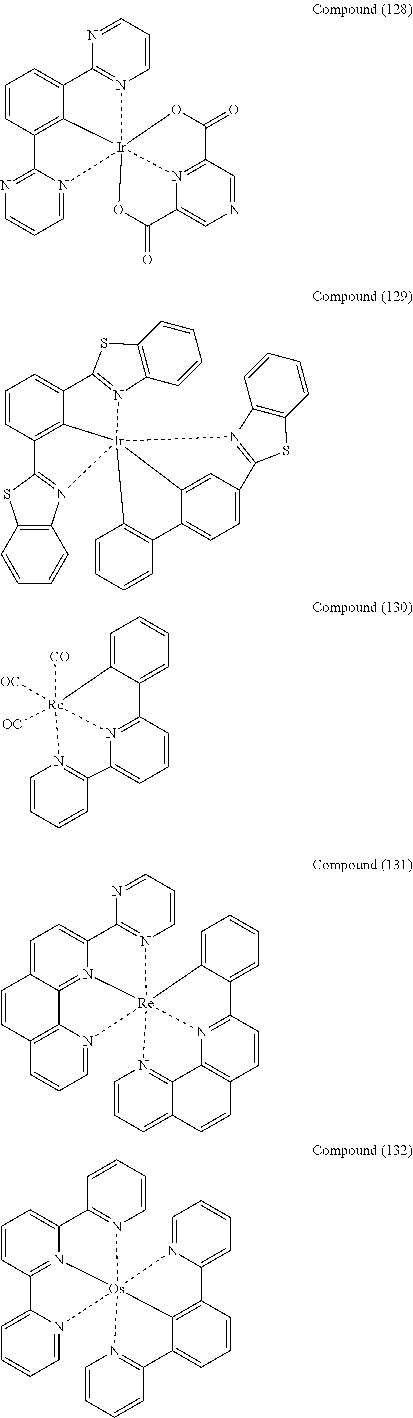

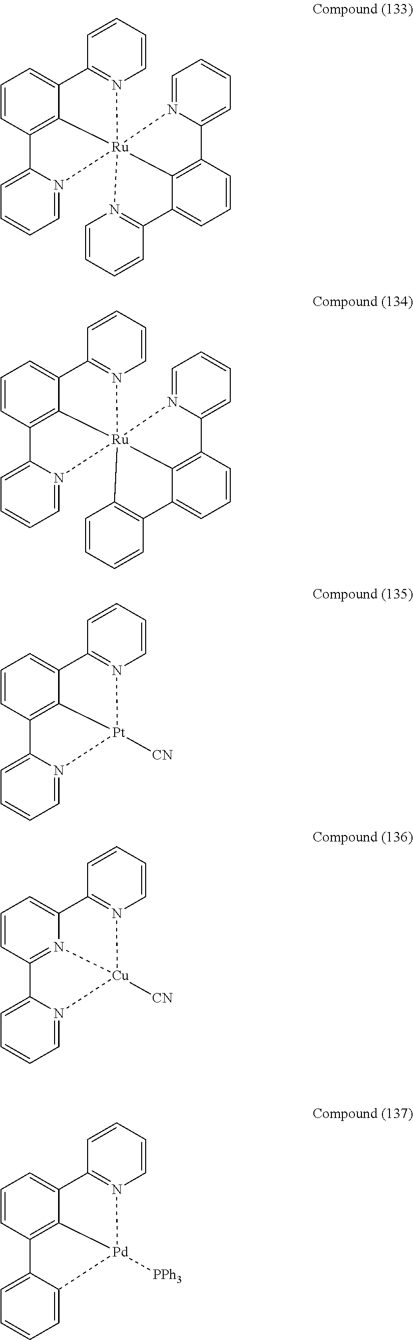

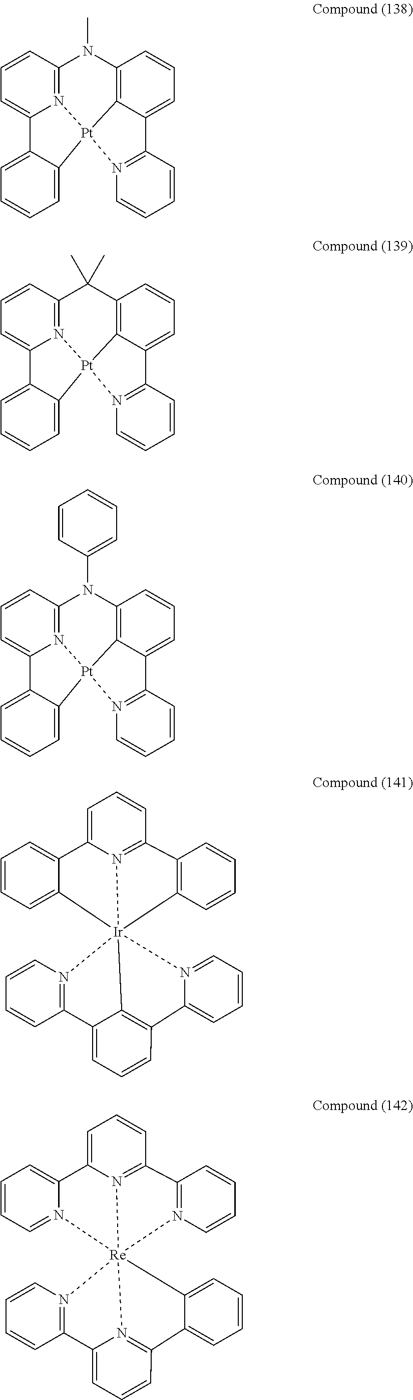

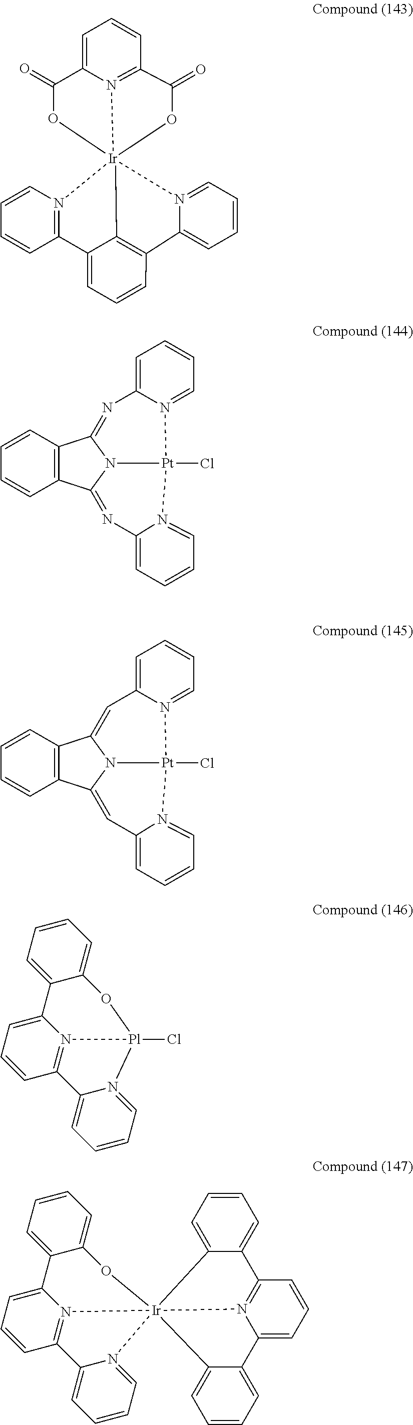

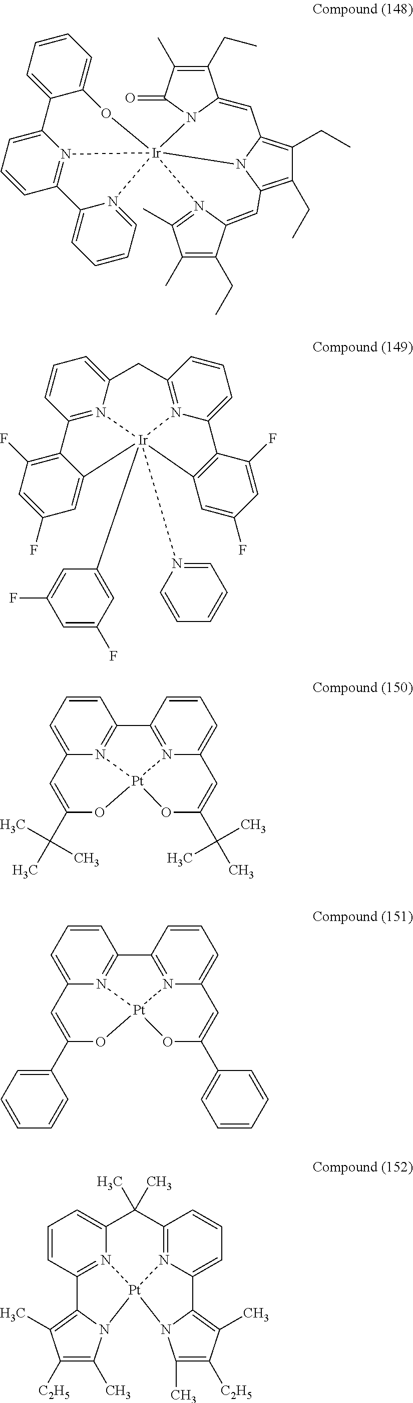

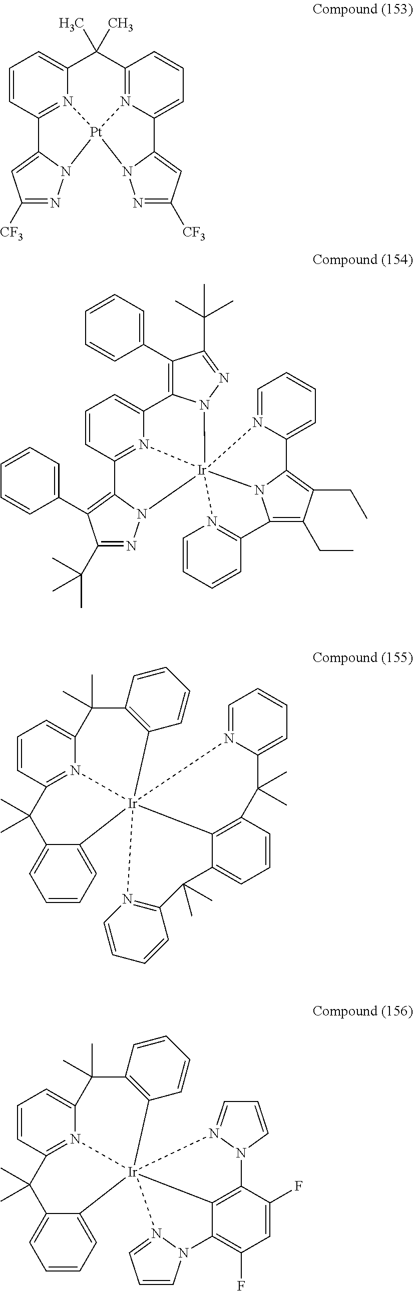

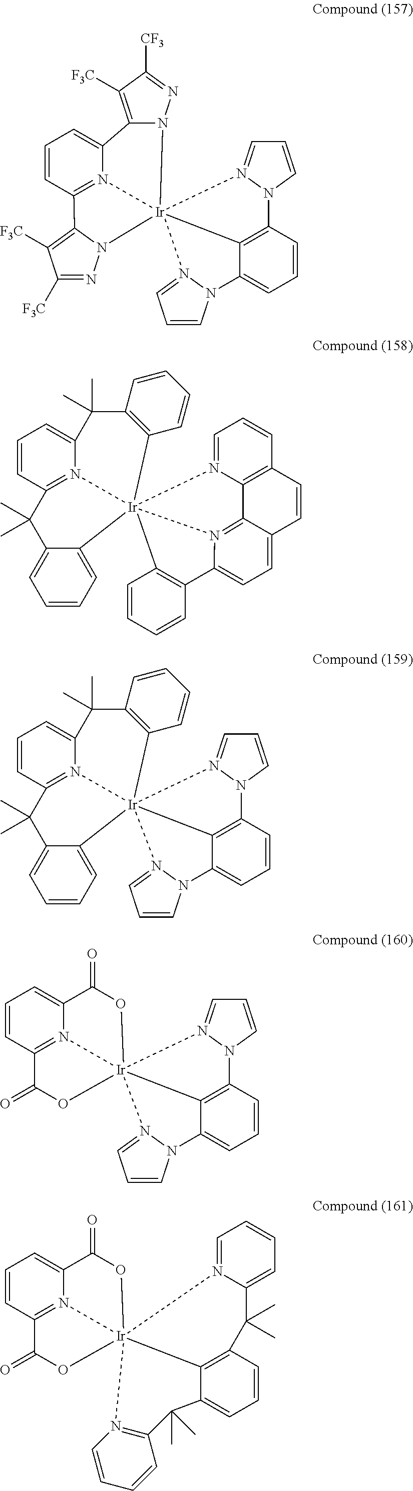

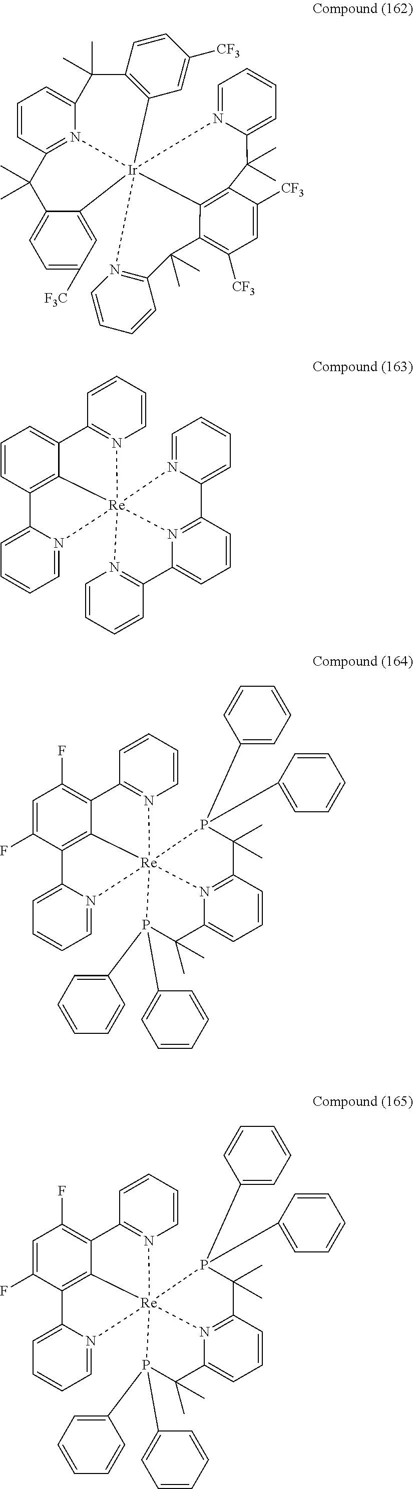

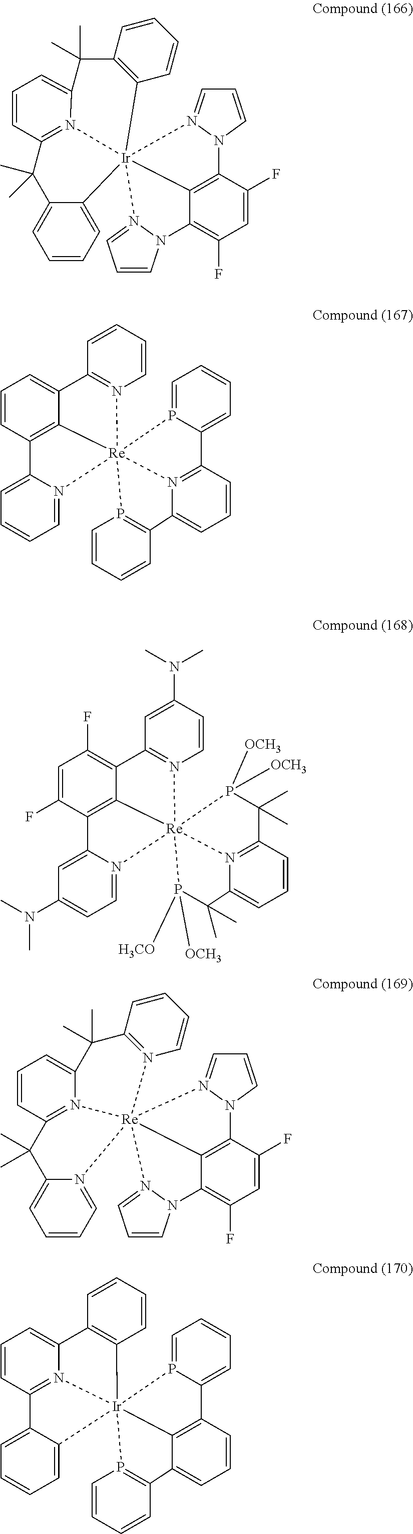

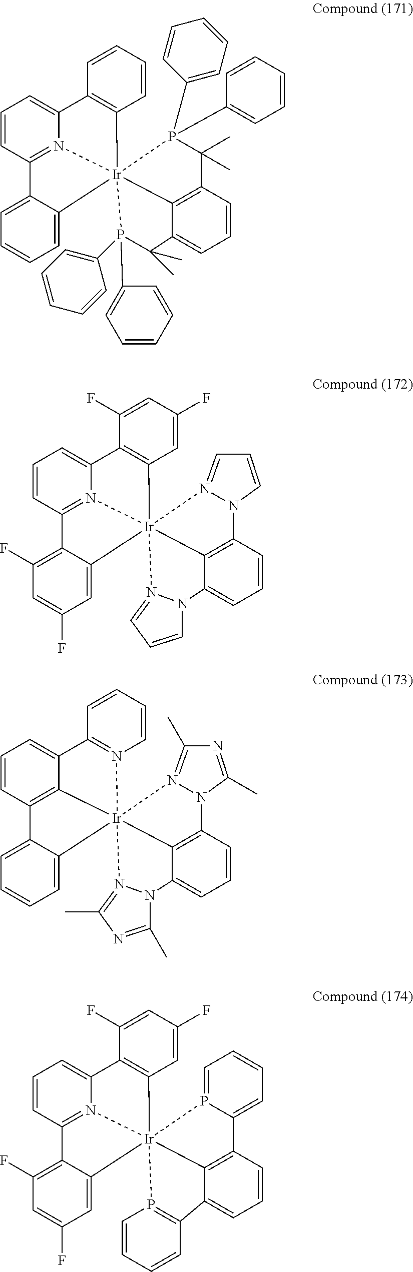

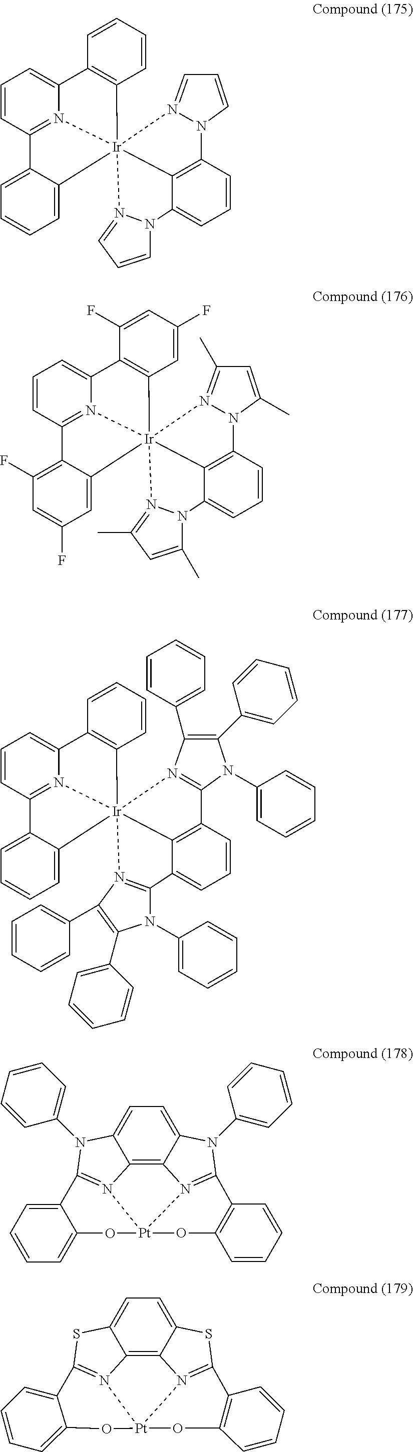

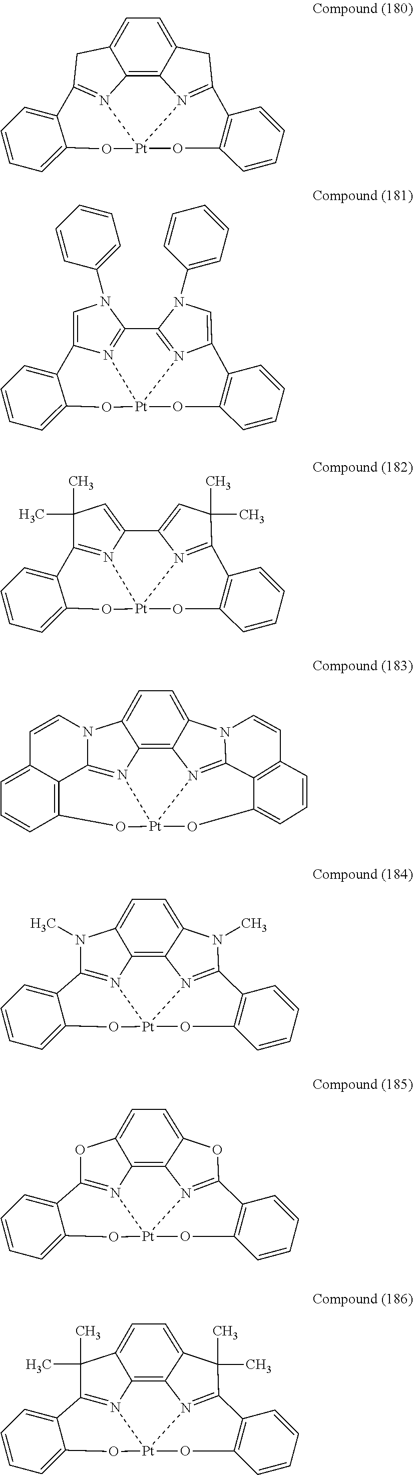

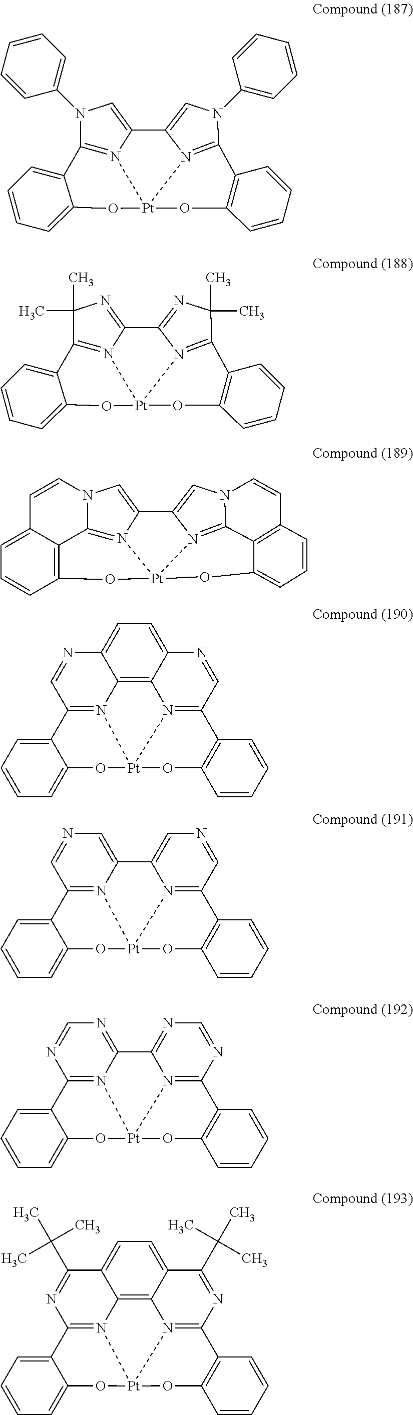

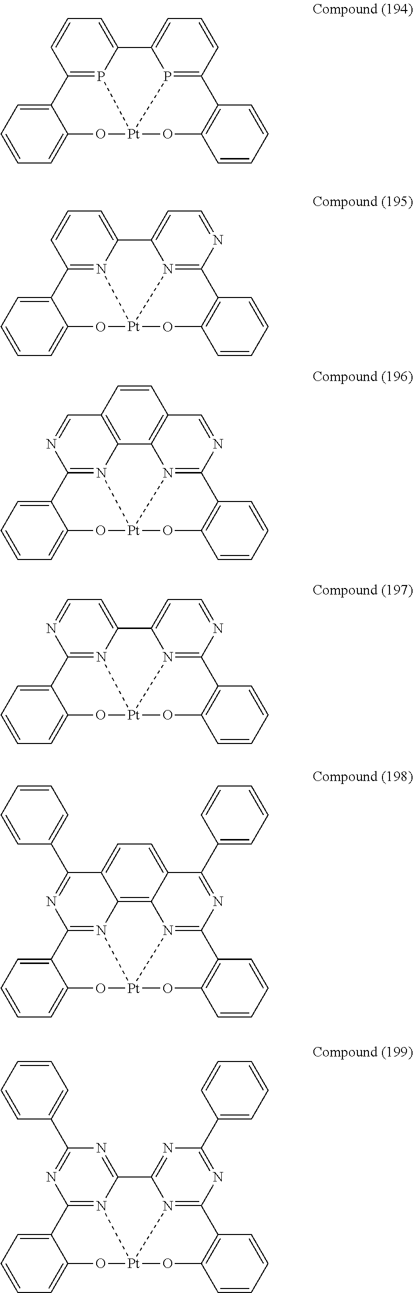

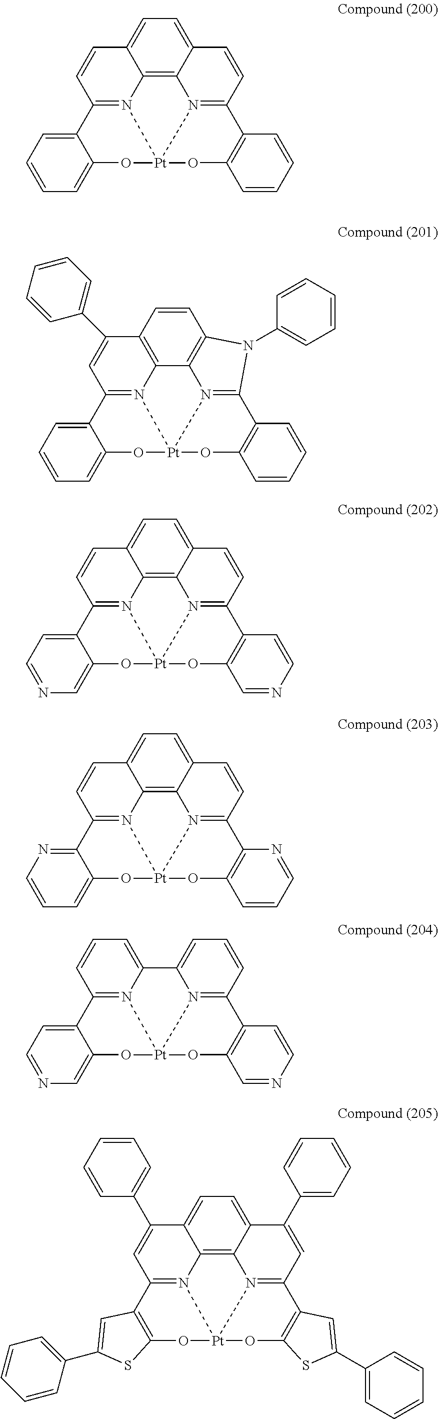

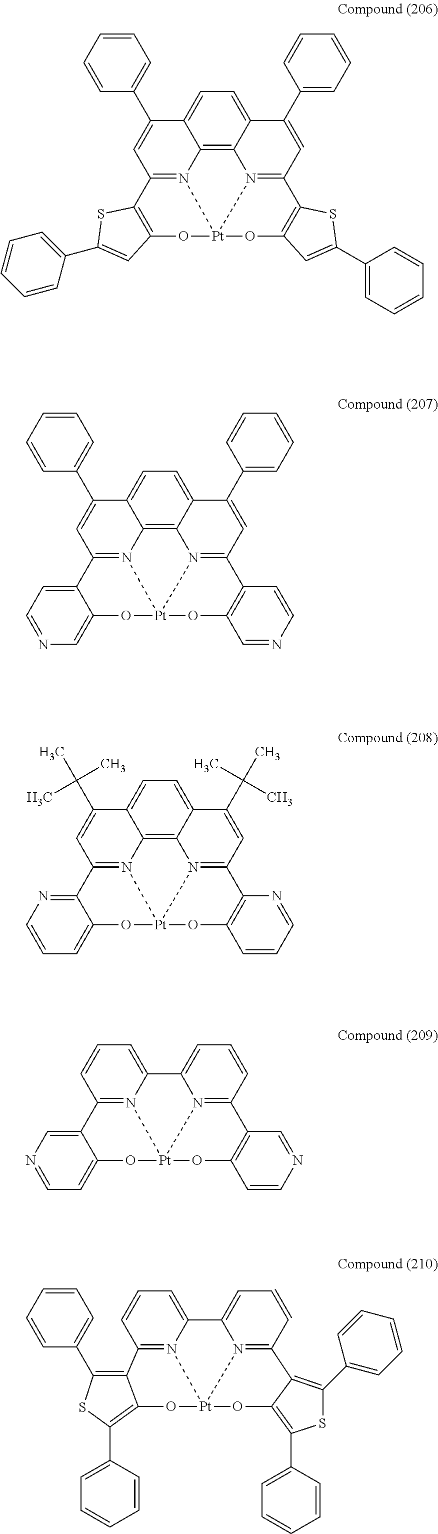

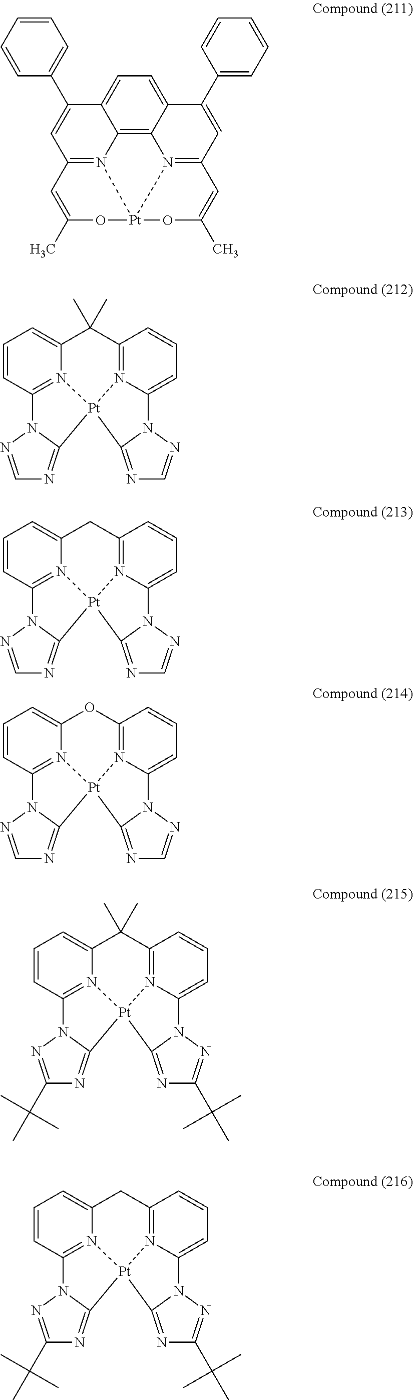

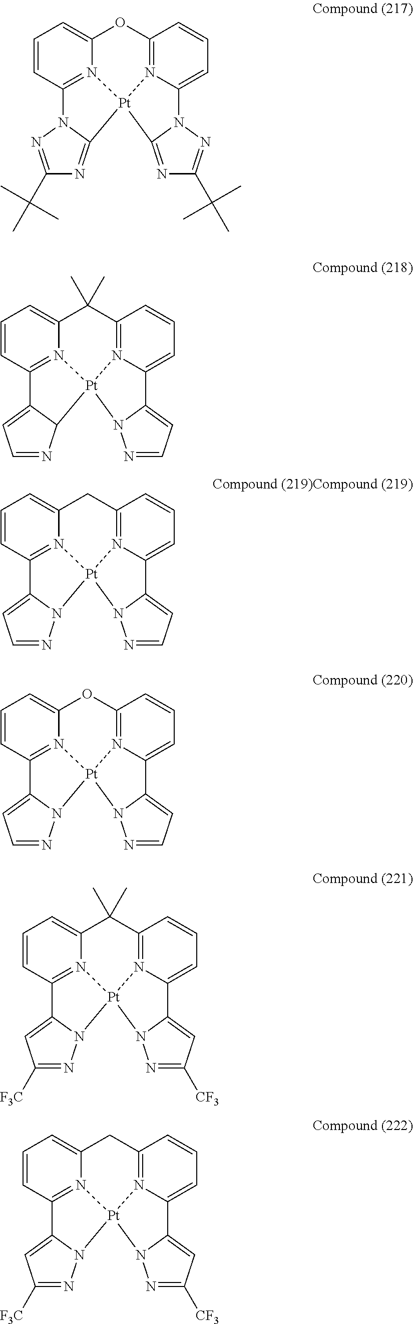

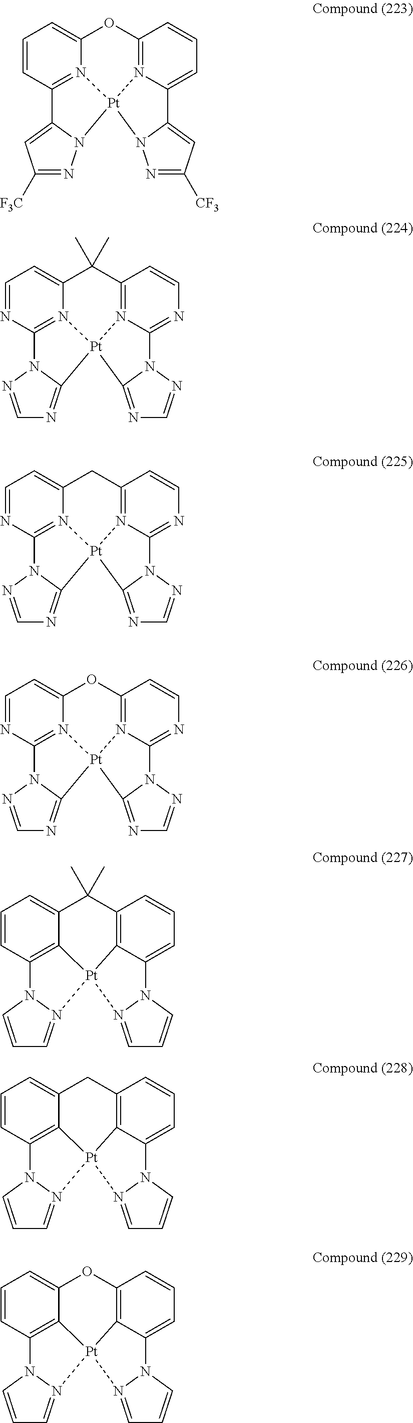

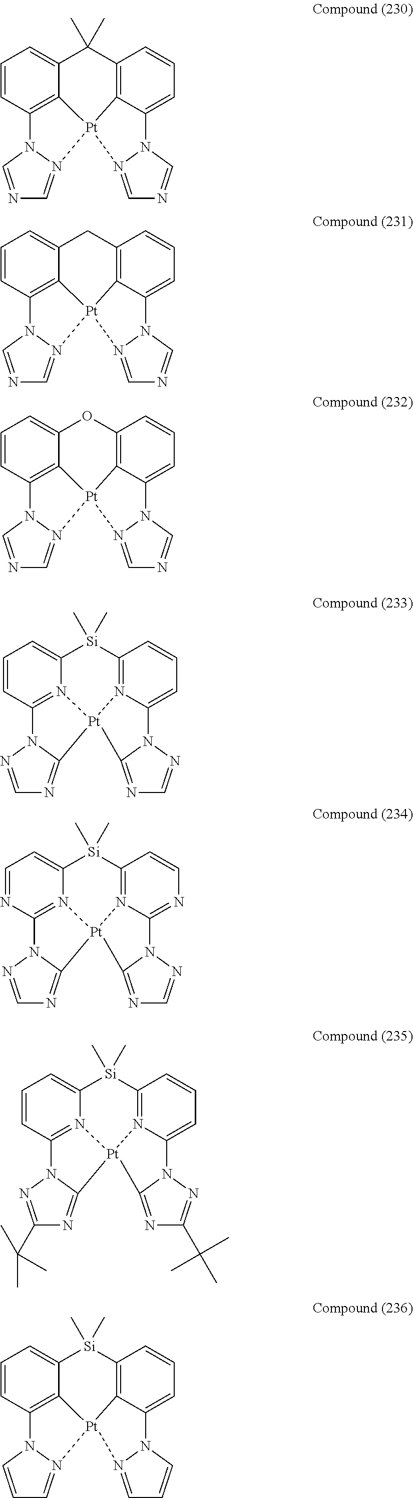

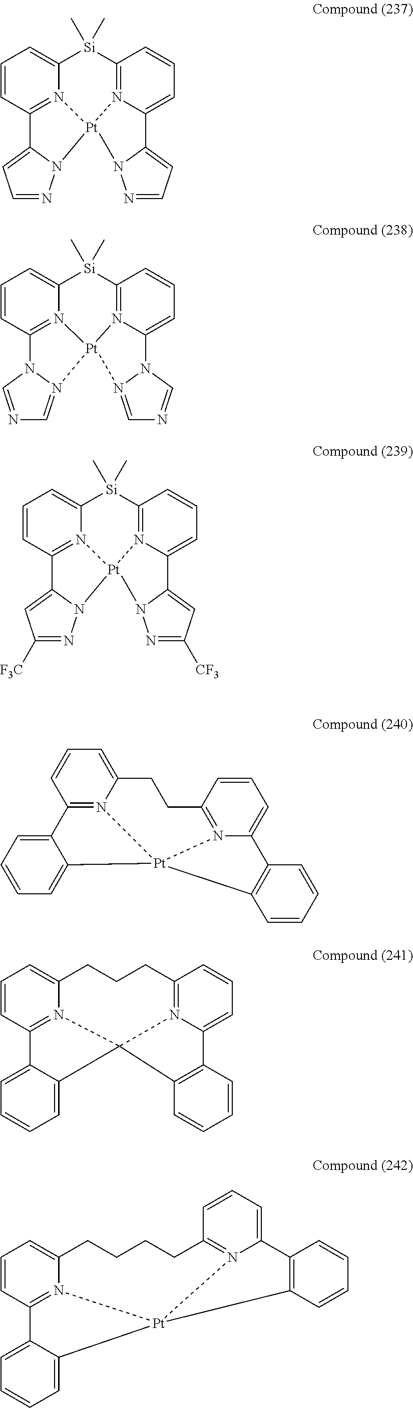

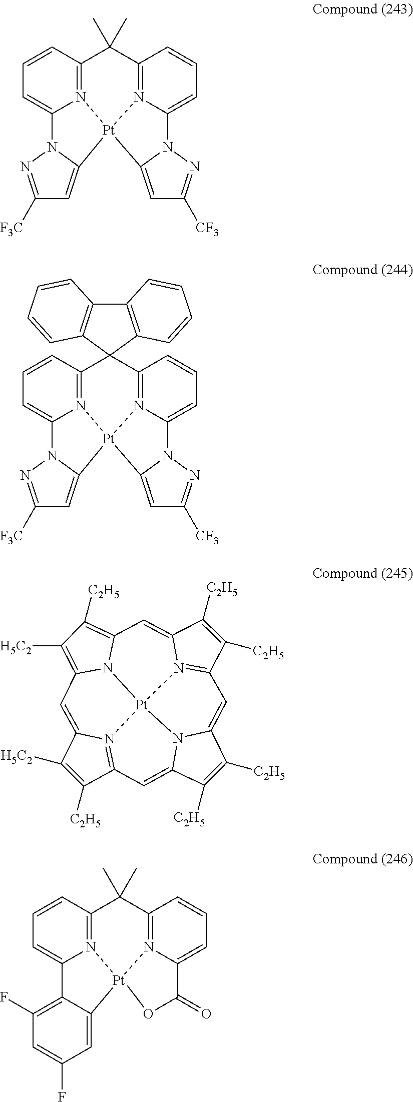

### Method of Preparing the Metal Complex According to the Invention

The metal complexes according to the invention [compounds represented by Formula (I), (1), (1-A), (2), (3), (3-A), (3-B), (3-C), (4), (4-A), (5), (5-A), (5-B) and Formula (II), (X2), or (X3)] can be prepared by various methods.

For example, a metal complex within the scope of the invention can be prepared by allowing a ligand or a dissociated form of the ligand to react with a metal compound under heating or at a temperature which is not higher than room temperature, 1) in the presence of a solvent (such as a halogenated solvent, an alcohol solvent, an ether solvent, an ester solvent, a ketone solvent, a nitrite solvent, an amide solvent, a sulfone solvent, a sulfoxide solvent, or water), 2) in the absence of a solvent but in the presence of a base (an inorganic or organic base such as sodium methoxide, potassium t-butoxide, triethylamine, or potassium carbonate), or 3) in the absence of a base. The heating may be conducted efficiently by a normal method or by using a microwave.

The reaction period at the preparation of the metal complex according to the invention may be changed according to the activity of the raw materials and is not particularly limited. It is preferably in a range of 1 minute to 5 days, more preferably in a range of 5 minutes to 3 days, and still more preferably in a range of 10 minutes to 1 day.

The reaction temperature for the preparation of the metal complex according to the invention may be changed according to the reaction activity, and is not particularly limited. The reaction temperature is preferably 0° C. to 300° C., more preferably 5° C. to 250° C., and still more preferably 10° C. to 200° C.

Each of the metal complexes according to the invention, i.e., the compounds represented by Formula (I), (1), (1-A), (2), (3), (3-A), (3-B), (3-C), (4), (4-A), (5), (5-A), or (5-B) and the compound represented by Formulae (II), (X2), or (X3), can be prepared by properly selecting a ligand that forms the partial structure of the desirable complex. For example, a compound represented by Formula (1-A) can be prepared by adding 6,6′-bis(2-hydroxyphenyl)-2,2′-bipyridyl ligand or a modified compound thereof (e.g., 2,9-bis(2-hydroxyphenyl)-1,10-phenanthroline ligand, 2,9-bis(2-hydroxyphenyl)-4,7-diphenyl-1,10-phenanthroline ligand, 6,6′-bis(2-hydroxy-5-tert-butylphenyl)-2,2′-bipyridyl ligand) to a metal compound in an amount of preferably 0.1 to 10 equivalences, more preferably 0.3 to 6 equivalences, and still more preferably 0.5 to 4 equivalences, with respect to the quantity of metal compound. The reaction solvent, reaction time, and reaction temperature at the preparation of the compound represented by Formula (1-A) are the same as in the method for preparing the metal complexes according to the invention described above.

The modified compounds of 6,6′-bis(2-hydroxyphenyl)-2,2′-bipyridyl ligand can be prepared by any one of known preparative methods.

In an embodiment, a modified compound is prepared by allowing a 2,2′-bipyridyl compound (e.g., 1,10-phenanthroline) to react with an anisole compound (e.g., 4-fluoroanisole) according to the method described in Journal of Organic Chemistry, 741, 11, (1946), the disclosure of which is incorporated herein by reference. In another embodiment, a modified compound is prepared by performing Suzuki coupling reaction using a halogenated 2,2′-bipyridyl compound (e.g., 2,9-dibromo-1,10-phenanthroline) and a 2-methoxyphenylboronic acid compound (e.g., 2-methoxy-5-fluorophenylboronic acid) as starting materials and then deprotecting the methyl group (according to the method described in Journal of Organic Chemistry, 741, 11, (1946) or under heating in pyridine hydrochloride salt). In another embodiment, a modified compound can be prepared by performing Suzuki coupling reaction using a 2,2′-bipyridylboronic acid compound [e.g., 6,6′-bis(4,4,5,5-tetramethyl-1,3,2-dioxaboronyl)-2,2′-bipyridyl] and a halogenated anisole compound (e.g., 2-bromoanisole) as starting materials and then deprotecting the methyl group (according to the method described in Journal of Organic Chemistry, 741, 11, (1946) or under heating in pyridine hydrochloride salt).

When the above-mentioned ligand for the metal complex according to the invention is a cyclic ligand, the metal complex is preferably a compound represented by the following Formula (III).

Hereinafter, the compound represented by the following Formula (III) will be described.

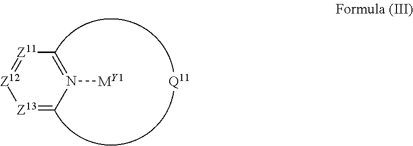

In Formula (III), Q¹¹ represents an atomic group forming a nitrogen-containing heterocycle. Z¹¹, Z¹², and Z¹³ each independently represent a substituted carbon atom, an unsubstituted carbon atom, a substituted nitrogen atom, or an unsubstituted nitrogen atom. M^{Y1} represents a metal ion that may have an additional ligand.

In Formula (III), Q¹¹ represents an atomic group forming a nitrogen-containing heterocycle together with the two carbon atoms bonded to Q¹¹ and the nitrogen atom directly bonded to these carbon atoms. The number of the atoms constituting the nitrogen-containing heterocycle containing Q¹¹ is not particularly limited. It is preferably 12 to 20, more preferably 14 to 16, and still more preferably 16.

Z¹¹, Z¹², and Z¹³ each independently represent a substituted or unsubstituted carbon or nitrogen atom. At least one of Z¹¹, Z¹², and Z¹³ is preferably a nitrogen atom.

Examples of the substituent on the carbon atom include alkyl groups (preferably having 1 to 30 carbon atoms, more preferably 1 to 20 carbon atoms, and particularly preferably 1 to 10 carbon atoms, and examples thereof include a methyl group, an ethylgroup, an iso-propyl group, a tert-butyl group, a n-octyl group, a n-decyl group, a n-hexadecyl group, a cyclopropyl group, a cyclopentyl group, and a cyclohexyl group), alkenyl groups (preferably having 2 to 30 carbon atoms, more preferably 2 to 20 carbon atoms, and particularly preferably 2 to 10 carbon atoms, and examples thereof include a vinyl group, an allyl group, a 2-butenyl group, and a 3-pentenyl group), alkynyl groups (preferably having 2 to 30 carbon atoms, more preferably 2 to 20 carbon atoms, and particularly preferably 2 to 10 carbon atoms, and examples thereof include a propargyl group and a 3-pentynyl group),

aryl groups (preferably having 6 to 30 carbon atoms, more preferably 6 to 20 carbon atoms, and particularly preferably 6 to 12 carbon atoms, and examples thereof include a phenyl group, a p-methylphenyl group, a naphthyl group, and a anthranyl group), amino groups (preferably having 0 to 30 carbon atoms, more preferably 0 to 20 carbon atoms, and particularly preferably 0 to 10 carbon atoms, and examples thereof include an amino group, a methylamino group, a dimethylamino group, a diethylamino group, a dibenzylamino group, a diphenylamino group, and a ditolylamino group), alkoxy groups (preferably having 1 to 30 carbon atoms, more preferably 1 to 20 carbon atoms, and particularly preferably 1 to 10 carbon atoms, and examples thereof include a methoxy group, an ethoxy group, a butoxy group, and a 2-ethylhexyloxy group), aryloxy groups (preferably having 6 to 30 carbon atoms, more preferably 6 to 20 carbon atoms, and particularly preferably 6 to 12 carbon atoms, and examples thereof include a phenyloxy group, a 1-naphthyloxy group, and a 2-naphthyloxy group), heterocyclic oxy groups (preferably having 1 to 30 carbon atoms, more preferably 1 to 20 carbon atoms, and particularly preferably 1 to 12 carbon atoms, and examples thereof include a pyridyloxy group, a pyrazyloxy group, a pyrimidyloxy group, and a quinolyloxy group),

acyl groups (preferably having 1 to 30 carbon atoms, more preferably 1 to 20 carbon atoms, and particularly preferably 1 to 12 carbon atoms, and examples thereof include an acetyl group, a benzoyl group, a formyl group, and a pivaloyl group), alkoxycarbonyl groups (preferably having 2 to 30 carbon atoms, more preferably 2 to 20 carbon atoms, and particularly preferably 2 to 12 carbon atoms, and examples thereof include a methoxycarbonyl group and a ethoxycarbonyl group), aryloxycarbonyl groups (preferably having 7 to 30 carbon atoms, more preferably 7 to 20 carbon atoms, and particularly preferably 7 to 12 carbon atoms, and examples thereof include a phenyloxycarbonyl group), acyloxy groups (preferably having 2 to 30 carbon atoms, more preferably 2 to 20 carbon atoms, and particularly preferably 2 to 10 carbon atoms, and examples thereof include an acetoxy group and a benzoyloxy group), acylamino groups (preferably having 2 to 30 carbon atoms, more preferably 2 to 20 carbon atoms, and particularly preferably 2 to 10 carbon atoms, and examples thereof include an acetylamino group and a benzoylamino group),

alkoxycarbonylamino groups (preferably having 2 to 30 carbon atoms, more preferably 2 to 20 carbon atoms, and particularly preferably 2 to 12 carbon atoms, and examples thereof include a methoxycarbonylamino group), aryloxycarbonylamino groups (preferably having 7 to 30 carbon atoms, more preferably 7 to 20 carbon atoms, and particularly preferably 7 to 12 carbon atoms, and examples thereof include a phenyloxycarbonylamino group), sulfonylamino groups (preferably having 1 to 30 carbon atoms, more preferably 1 to 20 carbon atoms, and particularly preferably 1 to 12 carbon atoms, and examples thereof include a methanesulfonylamino group and a benzene sulfonylamino group), sulfamoyl groups (preferably having 0 to 30 carbon atoms, more preferably 0 to 20 carbon atoms, and particularly preferably 0 to 12 carbon atoms, and examples thereof include a sulfamoyl group, a methylsulfamoyl group, a dimethylsulfamoyl group, and a phenylsulfamoyl group),

carbamoyl groups (preferably having 1 to 30 carbon atoms, more preferably 1 to 20 carbon atoms, and particularly preferably 1 to 12 carbon atoms, and examples thereof include a carbamoyl group, a methylcarbamoyl group, a diethylcarbamoyl group, and a phenylcarbamoyl group), alkylthio groups (preferably having 1 to 30 carbon atoms, more preferably 1 to 20 carbon atoms, and particularly preferably 1 to 12 carbon atoms, and examples thereof include a methylthio group and a ethylthio group), arylthio groups (preferably having 6 to 30 carbon atoms, more preferably 6 to 20 carbon atoms, and particularly preferably 6 to 12 carbon atoms, and examples thereof include a phenylthio group), heterocyclic thio groups (preferably having 1 to 30 carbon atoms, more preferably 1 to 20 carbon atoms, and particularly preferably 1 to 12 carbon atoms, and examples thereof include a pyridylthio group, a 2-benzimidazolylthio group, a 2-benzoxazolylthio group, and a 2-benzothiazolylthio group),

sulfonyl groups (preferably having 1 to 30 carbon atoms, more preferably 1 to 20 carbon atoms, and particularly preferably 1 to 12 carbon atoms, and examples thereof include a mesyl group and a tosyl group), sulfinyl groups (preferably having 1 to 30 carbon atoms, more preferably 1 to 20 carbon atoms, and particularly preferably 1 to 12 carbon atoms, and examples thereof include a methanesulfinyl group and a benzenesulfinyl group), ureido groups (preferably having 1 to 30 carbon atoms, more preferably 1 to 20 carbon atoms, and particularly preferably 1 to 12 carbon atoms, and examples thereof include a ureido group, a methylureido group, and a phenylureido group), phosphoric amide groups (preferably having 1 to 30 carbon atoms, more preferably 1 to 20 carbon atoms, and particularly preferably 1 to 12 carbon atoms, and examples thereof include a diethylphosphoric amide group and a phenylphosphoric amide group), a hydroxy group, a mercapto group, halogen atoms (e.g., fluorine, chlorine, bromine, and iodine),

a cyano group, a sulfo group, a carboxyl group, a nitro group, a hydroxamic acid group, sulfino groups, hydrazino groups, imino groups, heterocyclic groups (preferably having 1 to 30 carbon atoms, and particularly preferably 1 to 12 carbon atoms; the heteroatom(s) may be selected from nitrogen, oxygen and sulfur atoms; examples of the heterocyclic groups include imidazolyl, pyridyl, quinolyl, furyl, thienyl, piperidyl, morpholino, benzoxazolyl, benzimidazolyl, benzothiazolyl, carbazolyl, and azepinyl), silyl groups (preferably having 3 to 40 carbon atoms, more preferably 3 to 30 carbon atoms, and particularly preferably 3 to 24 carbon atoms, and examples thereof include a trimethylsilyl group and a triphenylsilyl group), silyloxy groups (preferably having 3 to 40 carbon atoms, more preferably 3 to 30 carbon atoms, and particularly preferably 3 to 24 carbon atoms, and examples thereof include a trimethylsilyloxy group and a triphenylsilyloxy group), and the like. These substituents may have a substituent(s).

Among these substituents, the substituent on the carbon atom is preferably an alkyl group, an aryl, a heterocyclic group or a halogen atom, more preferably an aryl group or a halogen atom, and still more preferably a phenyl group or a fluorine atom.

The substituent on the nitrogen atom may be selected from the substituents described as examples of the substituent on the carbon atom, and have the same preferable range as in the case of the substituent on the carbon atom.

In Formula (III), M^{Y1} represents a metal ion that may have an additional ligand. M^{Y1} preferably represents a metal ion having no ligand.

The metal ion represented by M^{Y1} is not particularly limited. It is preferably a divalent or trivalent metal ion. The divalent or trivalent metal ion is preferably a cobalt ion, a magnesium ion, a zinc ion, a palladium ion, a nickel ion, a copper ion, a platinum ion, a lead ion, an aluminum ion, an iridium ion, or a europium ion, more preferably a cobalt ion, a magnesium ion, a zinc ion, a palladium ion, a nickel ion, a copper ion, a platinum ion, or a lead ion, still more preferably a copper ion, or a platinum ion, and particularly preferably a platinum ion. M^{Y1} may or may not be bound to an atom contained in Q¹¹, and is preferably bound to an atom contained in Q¹¹.

The additional ligand that M^{Y1} may have is not particularly limited, but is preferably a monodentate or bidentate ligand, and more preferably a bidentate ligand. The coordinating atom is not particularly limited, but preferably an oxygen atom, a sulfur atom, a nitrogen atom, a carbon atom, or a phosphorus atom, more preferably an oxygen atom, a nitrogen atom, or a carbon atom, and still more preferably an oxygen atom or a nitrogen atom.

Preferable examples of compounds represented by Formula (III) include compounds represented by the following Formulae (a) to (j) and the tautomers thereof.

Compounds represented by Formula (III) are more preferably selected from compounds represented by Formula (a) or (b) and tautomers thereof, and still more preferably selected from compounds represented by Formula (b).

Compounds represented by Formula (c) or (g) are also preferable as the compounds represented by Formula (HI).

A compound represented by Formula (c) is preferably a compound represented by Formula (d), a tautomer of a compound represented by Formula (d), a compound represented by Formula (e), a tautomer of a compound represented by Formula (e), a compound represented by Formula (f) or a tautomer of a compound represented by Formula (f); more preferably a compound represented by Formula (d), a tautomer of a compound represented by Formula (d), a compound represented by Formula (e), or a tautomer of a compound represented by Formula (e); and still more preferably a compound represented by Formula (d) or a tautomer of a compound represented by Formula (d).

A compound represented by Formula (g) is preferably a compound represented by Formula (h), a tautomers of a compound represented by Formula (h), a compound represented by Formula (i), a tautomer of a compound represented by Formula (i), a compounds represented by Formula (j) or a tautomer of a compounds represented by Formula (j); more preferably a compound represented by Formula (h), a tautomers of a compound represented by Formula (h), a compound represented by Formula (i), or a tautomer of a compound represented by Formula (i); and still more preferably a compound represented by Formula (h) or a tautomer of a compound represented by Formula (h).

Hereinafter, the compounds represented by Formulae (a) to (j) will be described in detail.

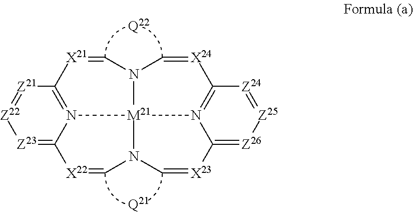

The compound represented by Formula (a) will be described below.

In Formula (a), the definitions and preferable ranges of Z²¹, Z²², Z²³, Z²⁴, Z²⁵, Z²⁶, and M¹¹ are similar to the definitions and preferable ranges of corresponding Z¹¹, Z¹², Z¹³, Z¹¹, Z¹², Z¹³, and M^{Y1} in Formula (III), respectively.

Q²¹ and Q²² each represent a group forming a nitrogen-containing heterocycle. Each of the nitrogen-containing heterocycles formed by Q²¹ and Q²² is not particularly limited, but is preferably a pyrrole ring, an imidazole ring, a triazole ring, a condensed ring containing one or more of the above rings (e.g., benzopyrrole), or a tautomer of any of the above rings (e.g., in Formula (b) below, the nitrogen-containing five-membered ring substituted by R⁴³ and R⁴⁴, or by R⁴⁵ and R⁴⁶ is defined as a tautomer of pyrrole), and more preferably a pyrrole ring or a condensed ring containing a pyrrole ring (e.g., benzopyrrole).

X²¹, X²², X²³, and X²⁴ each independently represent a substituted or unsubstituted carbon atom or a nitrogen atom, preferably an unsubstituted carbon or a nitrogen atom, and more preferably a nitrogen atom.

The compound represented by Formula (b) will be described below.

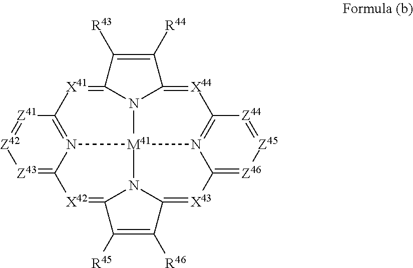

In Formula (b), the definitions and preferable ranges of Z⁴¹, Z⁴², Z⁴³, Z⁴⁴, Z⁴⁵, Z⁴⁶, X⁴¹, X⁴², X⁴³, X⁴⁴, and M⁴¹ are similar to the definitions and preferable ranges of Z²¹, Z²², Z²³, Z²⁴, Z²⁵, Z²⁶, X²¹, X²², X²³, X²⁴, and M²¹ in Formula (a), respectively.

R⁴³, R⁴⁴, R⁴⁵, and R⁴⁶ are each preferably selected from a hydrogen atom, the alkyl groups and the aryl groups described as examples of the substituent on Z¹¹ or Z¹² in Formula (III), a group in which R⁴³ and R⁴⁴ are bonded to each other to form a ring structure (e.g., a benzo-condensed ring or a pyridine-condensed ring) and a group in which R⁴⁵ and R⁴⁶ are bonded to each other to form a ring structure (e.g., a benzo-condensed ring or a pyridine-condensed ring). R⁴³, R⁴⁴, R⁴⁵, and R⁴⁶ are each more preferably selected from an alkyl group, an aryl group, a group in which R⁴³ and R⁴⁴ are bonded to each other to form a ring structure (e.g., a benzo-condensed ring or a pyridine-condensed ring) and a group in which R⁴⁵ and R⁴⁶ are bonded to each other to form a ring structure (e.g., a benzo-condensed ring or a pyridine-condensed ring). It is still more preferable that R⁴³ and R⁴⁴ are bonded to each other to form a ring structure (e.g., a benzo-condensed ring or a pyridine-condensed ring) and/or R⁴⁵ and R⁴⁶ are bonded to each other to form a ring structure (e.g., a benzo-condensed ring or a pyridine-condensed ring).

R⁴³, R⁴, R⁴⁵, and R⁴⁶ each independently represent a hydrogen atom or a substituent. Examples of the substituent include the groups described as examples of the substituent on the carbon atom represented by Z¹¹ or Z¹² in Formula (TIT).

The compound represented by Formula (c) will be described below.

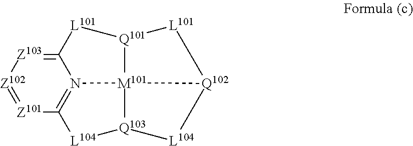

In Formula (c), Z¹⁰¹, Z¹⁰², and Z¹⁰³ each independently represent a substituted or unsubstituted carbon or nitrogen atom. At least one of Z¹⁰¹, Z¹⁰², and Z¹⁰³ is preferably a nitrogen atom.

L¹⁰¹, L¹⁰², L¹⁰³, and L¹⁰⁴ each independently represent a single bond or a connecting group. The connecting group is not particularly limited, and examples thereof include a carbonyl connecting group, an alkylene group, an alkenylene group, an arylene group, a heteroarylene group, a nitrogen-containing heterocycle connecting group, a connecting group which connects moieties via an oxygen atom, a sulfur atom or a silicon atom, an amino connecting group, an imino connecting group, a carbonyl connecting group, and connecting groups comprising combinations thereof.

L¹⁰¹, L¹⁰², L¹⁰³, and L¹⁰⁴ are each preferably a single bond, an alkylene group, an alkenylene group, an amino connecting group, or an imino connecting group, more preferably a single bond, an alkylene connecting group, an alkenylene connecting group, or an imino connecting group, and still more preferably a single bond or an alkylene connecting group.

Q¹⁰¹ and Q¹⁰³ each independently represent a group containing a carbon atom coordinating to M¹⁰¹, a group containing a nitrogen atom coordinating to M¹⁰¹, a group containing a phosphorus atom coordinating to M¹⁰¹, a group containing an oxygen atom coordinating to M¹⁰¹, or a group containing a sulfur atom coordinating to M¹⁰¹.

The group containing a carbon atom coordinating to M¹⁰¹ is preferably an aryl group containing a coordinating carbon atom, a five-membered ring heteroaryl group containing a coordinating carbon atom, or a six-membered ring heteroaryl group containing a coordinating carbon atom; more preferably, an aryl group containing a coordinating carbon atom, a nitrogen-containing five-membered ring heteroaryl group containing a coordinating carbon atom, or a nitrogen-containing six-membered ring heteroaryl group containing a coordinating carbon atom; and still more preferably, an aryl group containing a coordinating carbon atom.

The group containing a nitrogen atom coordinating to M¹⁰¹ is preferably a nitrogen-containing five-membered ring heteroaryl group containing a coordinating nitrogen atom or a nitrogen-containing six-membered ring heteroaryl group containing a coordinating nitrogen atom, and more preferably a nitrogen-containing six-membered ring heteroaryl group containing a coordinating nitrogen atom.

The group containing a phosphorus atom coordinating to M¹⁰¹ is preferably an alkyl phosphine group containing a coordinating phosphorus atom, an aryl phosphine group containing a coordinating phosphorus atom, an alkoxyphosphine group containing a coordinating phosphorus atom, an aryloxyphosphine group containing a coordinating phosphorus atom, a heteroaryloxyphosphine group containing a coordinating phosphorus atom, a phosphinine group containing a coordinating phosphorus atom, or a phosphor group containing a coordinating phosphorus atom; more preferably, an alkyl phosphine group containing a coordinating phosphorus atom or an aryl phosphine group containing a coordinating phosphorus atom.

The group containing an oxygen atom coordinating to M¹⁰¹ is preferably an oxy group or a carbonyl group containing a coordinating oxygen atom, and more preferably an oxy group.

The group containing a sulfur atom coordinating to M¹⁰¹ is preferably a sulfide group, a thiophene group, or a thiazole group, and more preferably a thiophene group.

Each of Q¹⁰¹ and Q¹⁰³ is preferably a group containing a carbon atom coordinating to M¹⁰¹, a group containing a nitrogen atom coordinating to M¹⁰¹, or a group containing a an oxygen atom coordinating to M¹⁰¹; more preferably a group containing a carbon atom or a group containing a nitrogen atom coordinating to M¹⁰¹; and still more preferably a group containing a carbon atom coordinating to M¹⁰¹.

Q¹⁰² represents a group containing a nitrogen atom coordinating to M¹⁰¹, a group containing a phosphorus atom coordinating to M¹⁰¹, a group containing an oxygen atom coordinating to M¹⁰¹ or a group containing a sulfur atom coordinating to M¹⁰¹, and preferably a group containing a nitrogen atom coordinating to M¹⁰¹.

The definition of M¹⁰¹ is similar to that of M¹¹ in Formula (I), and their preferable ranges are also similar.

The compound represented by Formula (d) will be described below.

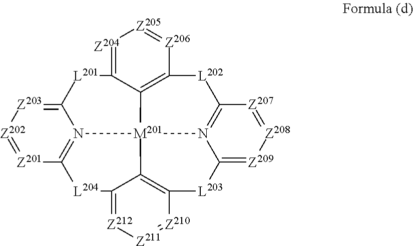

In Formula (d), the definitions and preferable ranges of Z²⁰¹, Z²⁰², Z²⁰³, Z²⁰⁷, Z²⁰⁸, Z²⁰⁹, L²⁰¹, L²⁰², L²⁰³, L²⁰⁴, and M²⁰¹ are similar to the definitions and preferable ranges Z¹⁰¹, Z¹⁰², Z¹⁰³, Z¹⁰¹, Z¹⁰², Z¹⁰³, L¹⁰¹, L¹⁰², L¹⁰³, L¹⁰⁴, and M¹⁰¹ in Formula (c), respectively. Z²⁰⁴, Z²⁰⁵, Z²⁰⁶, Z²¹⁰, Z²¹¹, and Z²¹² each represent a substituted or unsubstituted carbon or a substituted or unsubstituted nitrogen atom, and preferably a substituted or unsubstituted carbon atom.

The compound represented by Formula (e) will be described below.

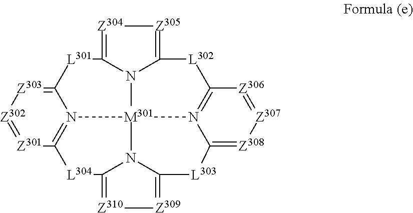

In Formula (e), the definitions and preferable ranges of Z³⁰¹, Z³⁰², Z³⁰³, Z³⁰⁴, Z³⁰⁵, Z³⁰⁶, Z³⁰⁷, Z³⁰⁸, Z³⁰⁹, Z³¹⁰, L³⁰¹, L³⁰², L³⁰³, L³⁰⁴, and M³⁰¹ are similar to the definitions and preferable ranges of corresponding Z²⁰¹, Z²⁰², Z²⁰³, Z²⁰⁴, Z²⁰⁶, Z²⁰⁷, Z²⁰⁸, Z²⁰⁹, Z²¹⁰, Z²¹², L¹⁰¹, L¹⁰², L¹⁰³, L¹⁰⁴, and m¹⁰¹ in formulae (d) and (c), respectively.

The compound represented by Formula (f) will be described below.

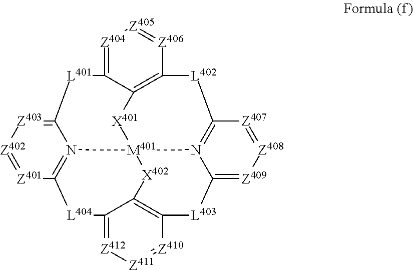

In Formula (f), the definitions and preferable ranges of Z⁴⁰¹, Z⁴⁰², Z⁴⁰³, Z⁴⁰⁴, Z⁴⁰⁵, Z⁴⁰⁶, Z⁴⁰⁷, Z⁴⁰⁸, Z⁴⁰⁹, Z⁴¹⁰, Z⁴¹¹, Z⁴¹², L⁴⁰¹, L⁴⁰², L⁴⁰³, L⁴⁰⁴, and M⁴⁰¹ are similar to the definitions and preferable ranges of corresponding Z²⁰¹, Z²⁰², Z²⁰³, Z²⁰⁴, Z²⁰⁵, Z²⁰⁶, Z²⁰⁷, Z²⁰⁸, Z²⁰⁹, Z²¹⁰, Z²¹¹, Z²¹², L¹⁰¹, L¹⁰², L¹⁰³, L¹⁰⁴, and M¹⁰¹ in formulae (d) and (c), respectively. X⁴⁰¹ and X⁴⁰² each represent an oxygen atom or a substituted or unsubstituted nitrogen or a sulfur atom, preferably an oxygen atom or a substituted nitrogen atom, and more preferably an oxygen atom.

The compound represented by Formula (g) will be described below.

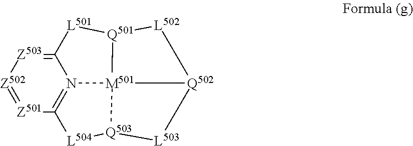

In Formula (g), the definitions and preferable ranges of Z⁵⁰¹, Z⁵⁰², Z⁵⁰³, L⁵⁰¹, L⁵⁰², L⁵⁰³, L⁵⁰⁴, Q⁵⁰¹, Q⁵⁰², Q⁵⁰³, and M⁵⁰¹ are similar to the definitions and preferable ranges of corresponding Z¹⁰¹, Z¹⁰², Z¹⁰³, L¹⁰³, L¹⁰², L¹⁰³, L¹⁰⁴, Q¹⁰¹, Q¹⁰³, Q¹⁰², and M¹⁰¹ in Formula (c), respectively.

The compound represented by Formula (h) will be described below.

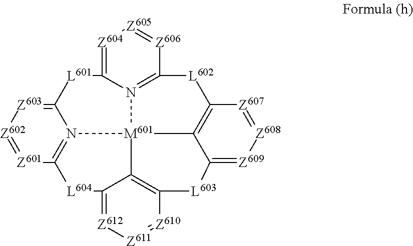

In Formula (h), the definitions and preferable ranges of Z⁶⁰¹, Z⁶⁰², Z⁶⁰³, Z⁶⁰⁴, Z⁶⁰⁵, Z⁶⁰⁶, Z⁶⁰⁷, Z⁶⁰⁸, Z⁶⁰⁹, Z⁶¹⁰, Z⁶¹¹, Z⁶¹², L⁶⁰¹, L⁶⁰², L⁶⁰³, L⁶⁰⁴, and M⁶⁰¹ are similar to the definitions and preferable ranges of corresponding Z²⁰¹, Z²⁰², Z²⁰³, Z²⁰⁷, Z²⁰⁸, Z²⁰⁹, Z²⁰⁴, Z²⁰⁵, Z²⁰⁶, Z²¹⁰, Z²¹¹, Z²¹², L¹⁰¹, L¹⁰², L¹⁰³, L¹⁰⁴, and M¹⁰¹ in Formulae (d) and (c), respectively.

The compound represented by Formula (i) will be described below.

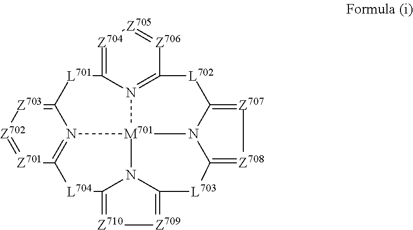

In Formula (i), the definitions and preferable ranges of Z⁷⁰¹, Z⁷⁰², Z⁷⁰³, Z⁷⁰⁴, Z⁷⁰⁵, Z⁷⁰⁶, Z⁷⁰⁷, Z⁷⁰⁸, Z⁷⁰⁹, Z⁷¹⁰, L⁷⁰¹, L⁷⁰², L⁷⁰³, L⁷⁰⁴, and M⁷⁰¹ are similar to the definitions and preferable ranges of corresponding Z²⁰¹, Z²⁰², Z²⁰³, Z²⁰⁷, Z²⁰⁸, Z²⁰⁹, Z²⁰⁴, Z²⁰⁶, Z²¹⁰, Z²¹², L¹⁰¹, L¹⁰², L¹⁰³, L¹⁰⁴, and M¹⁰¹ in Formulae (d) and (c), respectively.

The compound represented by Formula (j) will be described below.

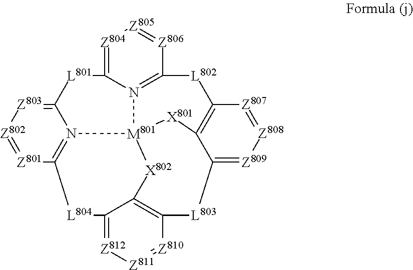

In Formula (j), the definitions and preferable ranges of Z⁸⁰¹, Z⁸⁰², Z⁸⁰³, Z⁸⁰⁴, Z⁸⁰⁵, Z⁸⁰⁶, Z⁸⁰⁷, Z⁸⁰⁸, Z⁸⁰⁹, Z⁸¹⁰, Z⁸¹¹, Z⁸¹², L⁸⁰¹, L⁸⁰², L⁸⁰³, L⁸⁰⁴, M⁸⁰¹, X⁸⁰¹, and X⁸⁰² are similar to the definitions and preferable ranges of corresponding Z²⁰¹, Z²⁰², Z²⁰³, Z²⁰⁷, Z²⁰⁸, Z²⁰⁹, Z²⁰⁴, Z²⁰⁵, Z²⁰⁶, Z²¹⁰, Z²¹¹, Z²¹², L¹⁰¹, L¹⁰², L¹⁰³, L¹⁰⁴, M¹⁰¹, X⁴⁰¹, and X⁴⁰² in Formulae (d), (c), and (f), respectively.

Specific examples of compounds represented by Formula (III) include compounds (2) to (8), compounds (15) to (20), compound (27) to (32), compounds (36) to (38), compounds (42) to (44), compounds (50) to (52), and compounds (57) to (154) described in Japanese Patent Application No. 2004-88575, the disclosure of which is incorporated herein by reference. The structures of the above compounds are shown below, however, the scope of the invention is not limited thereto.

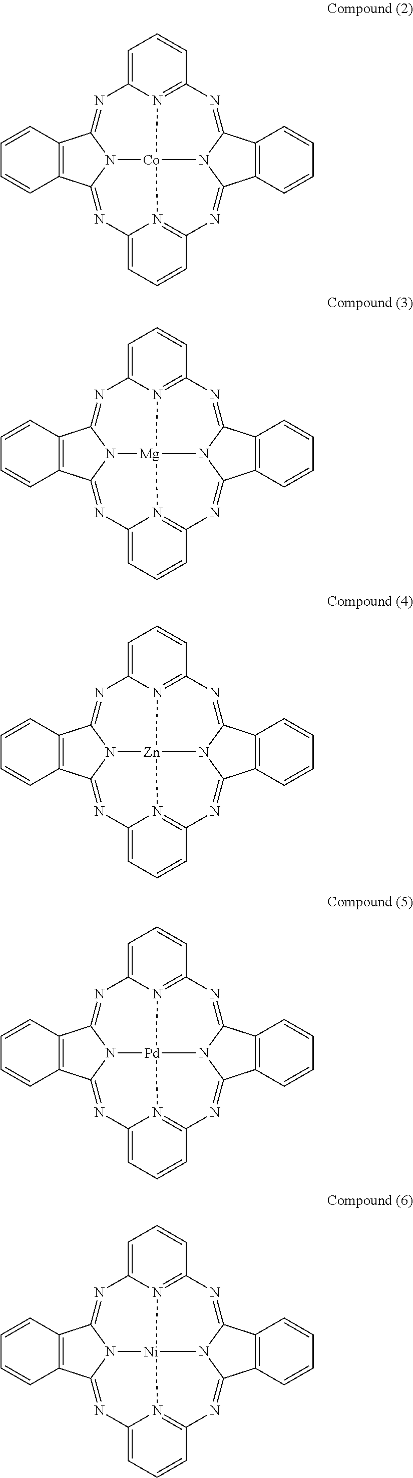

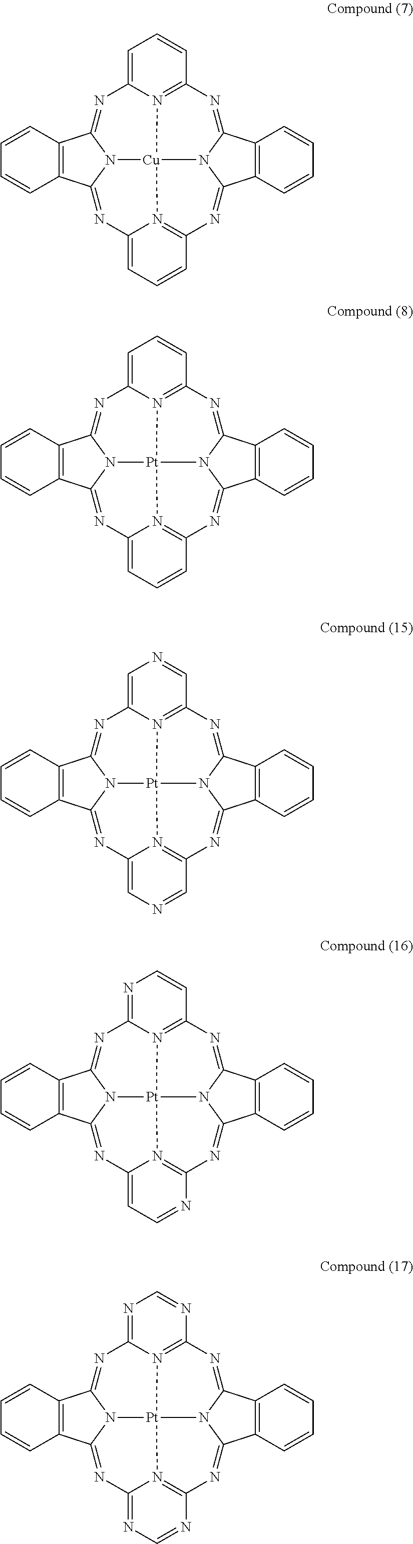

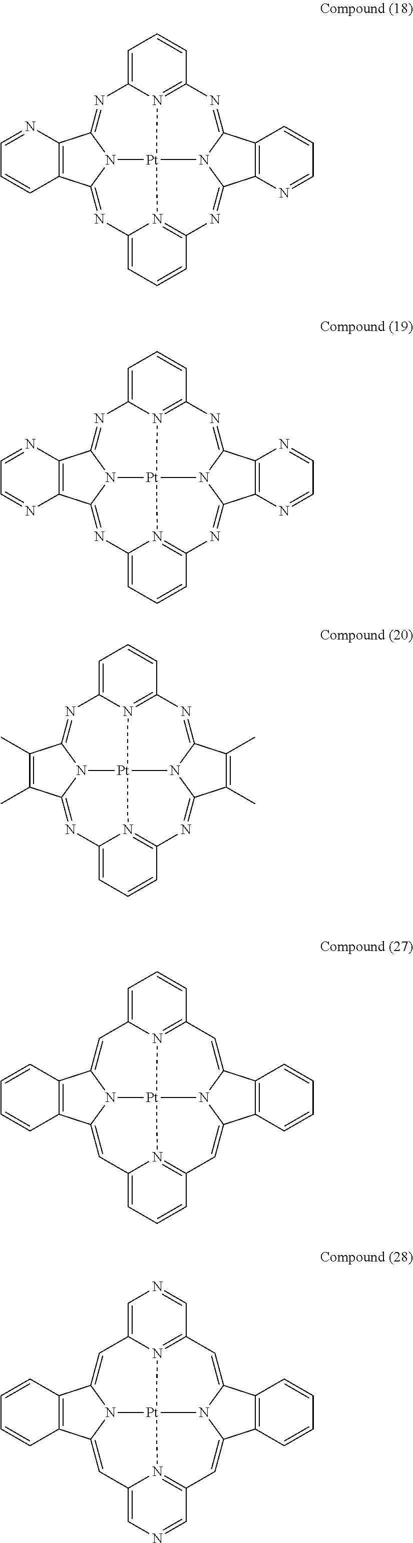

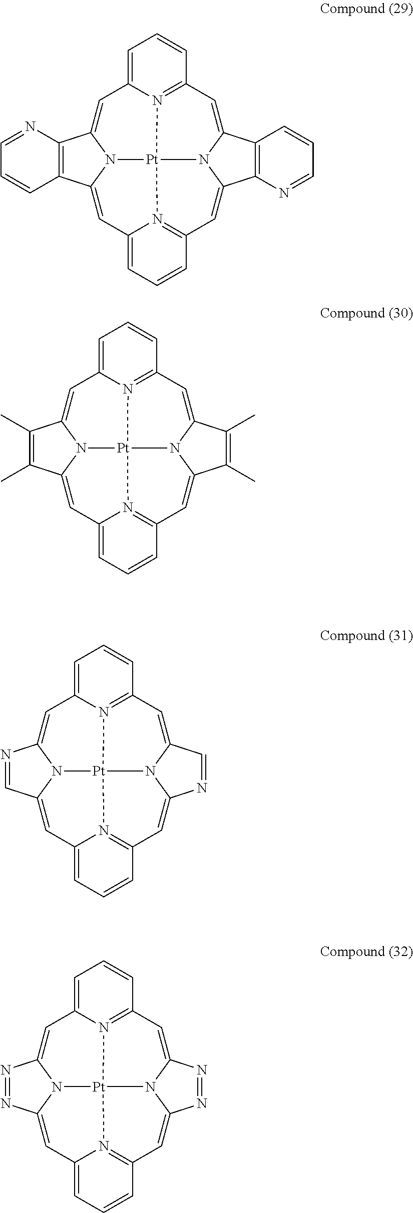

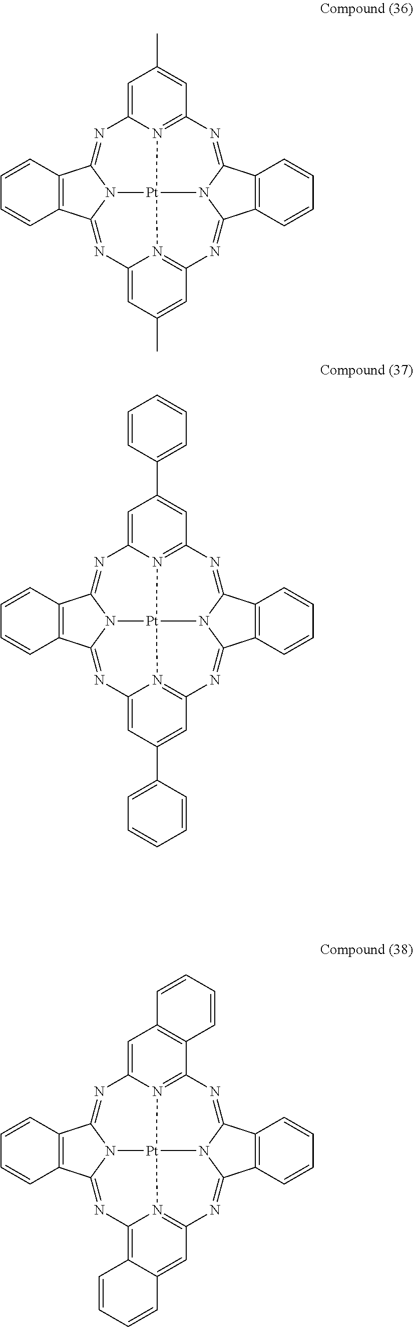

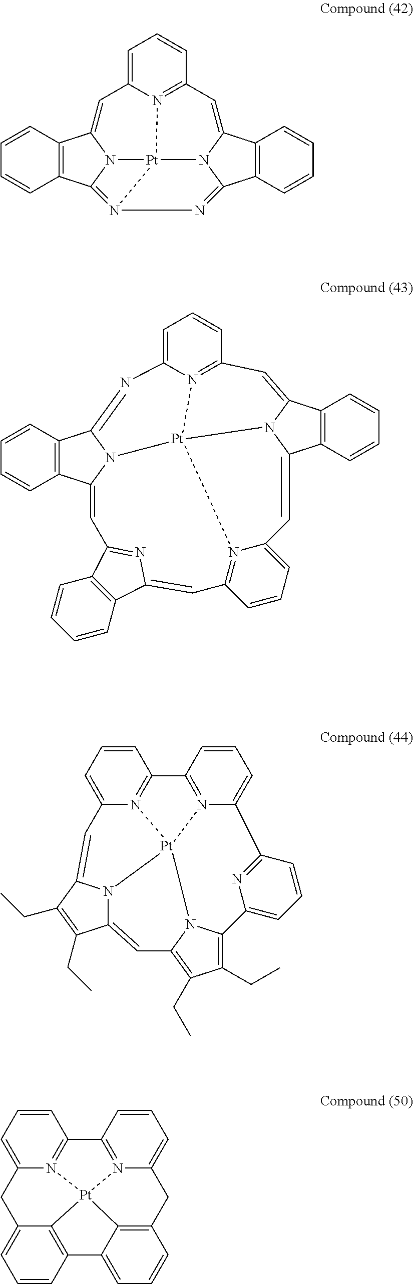

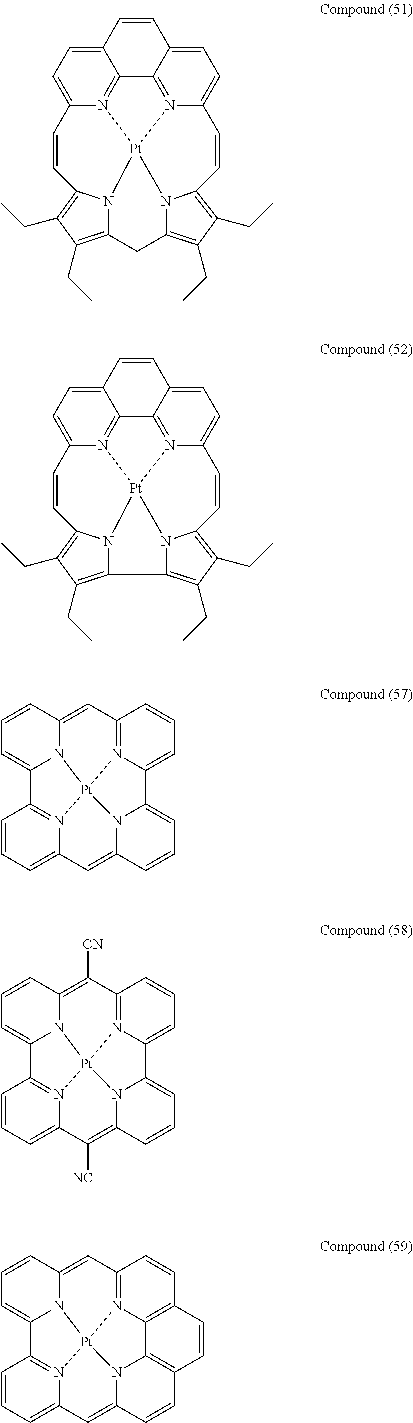

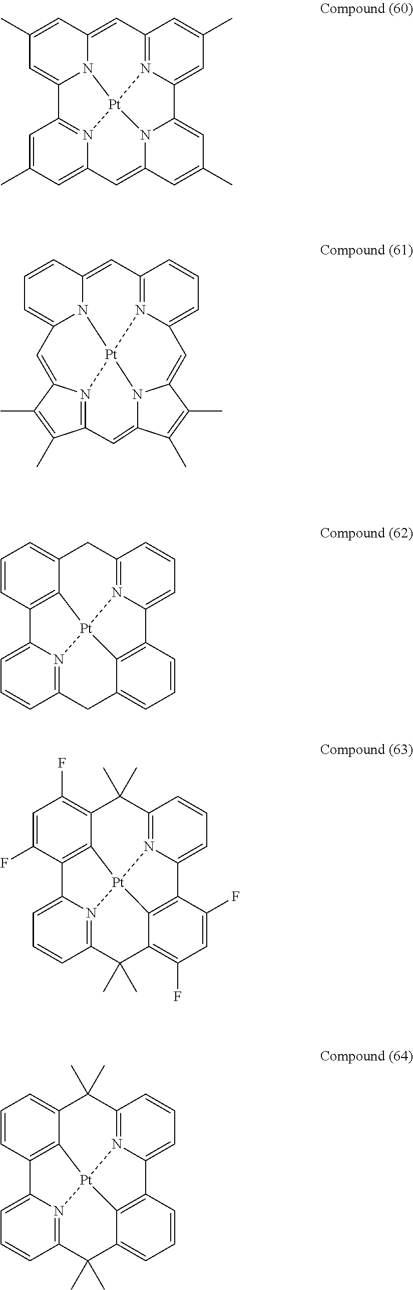

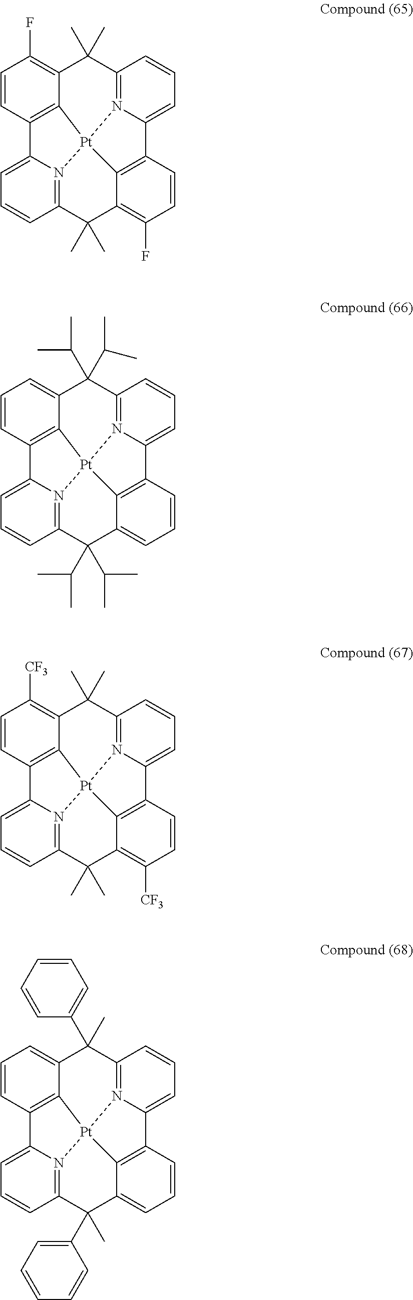

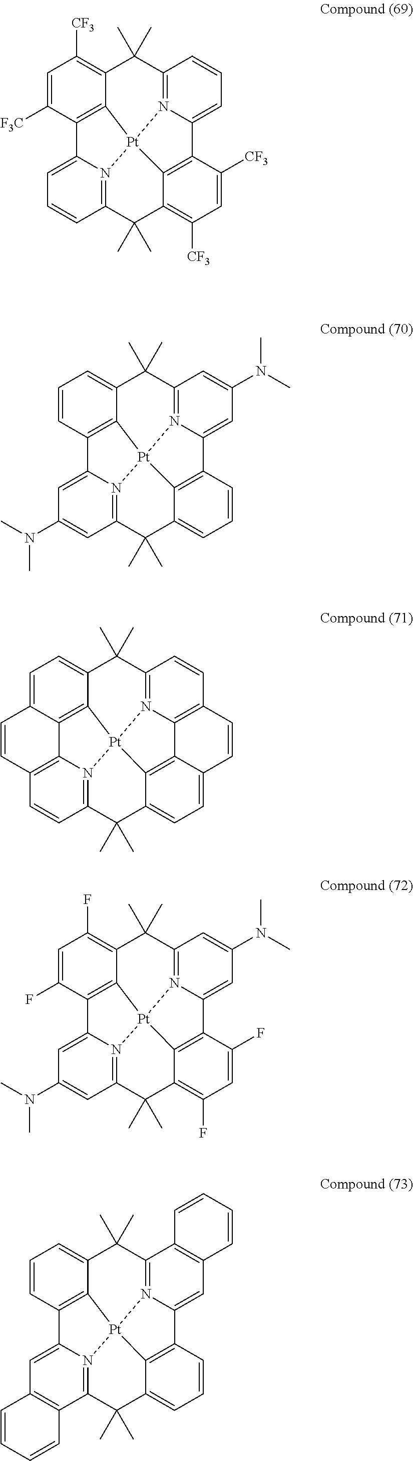

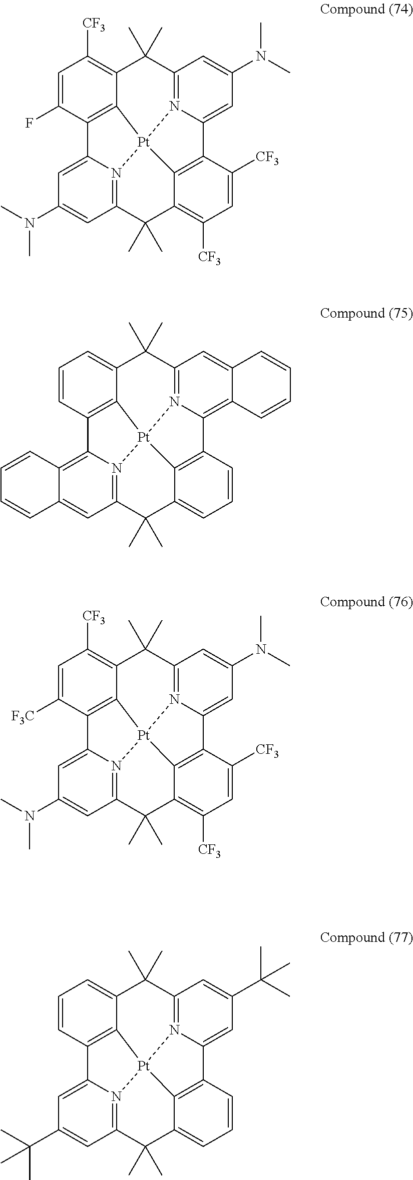

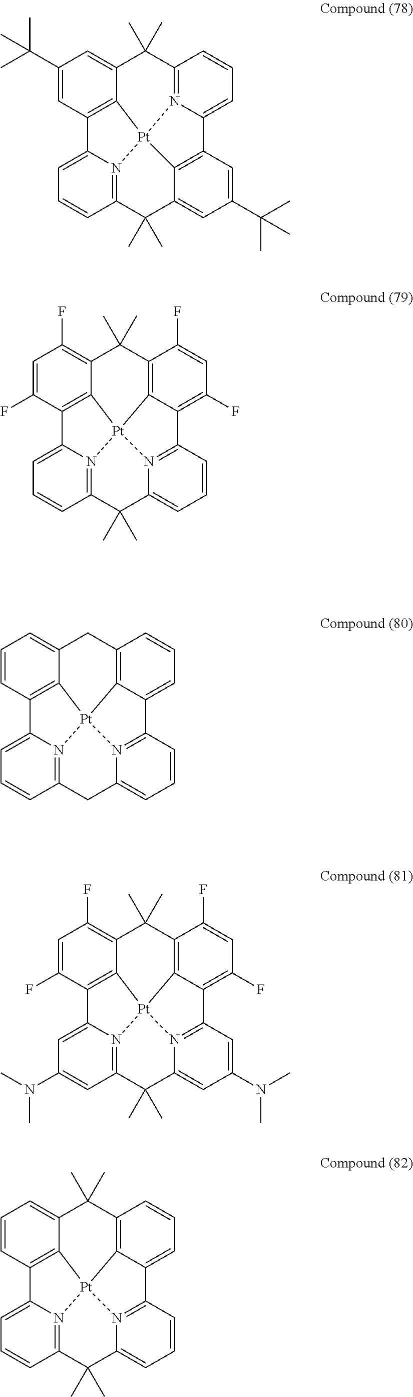

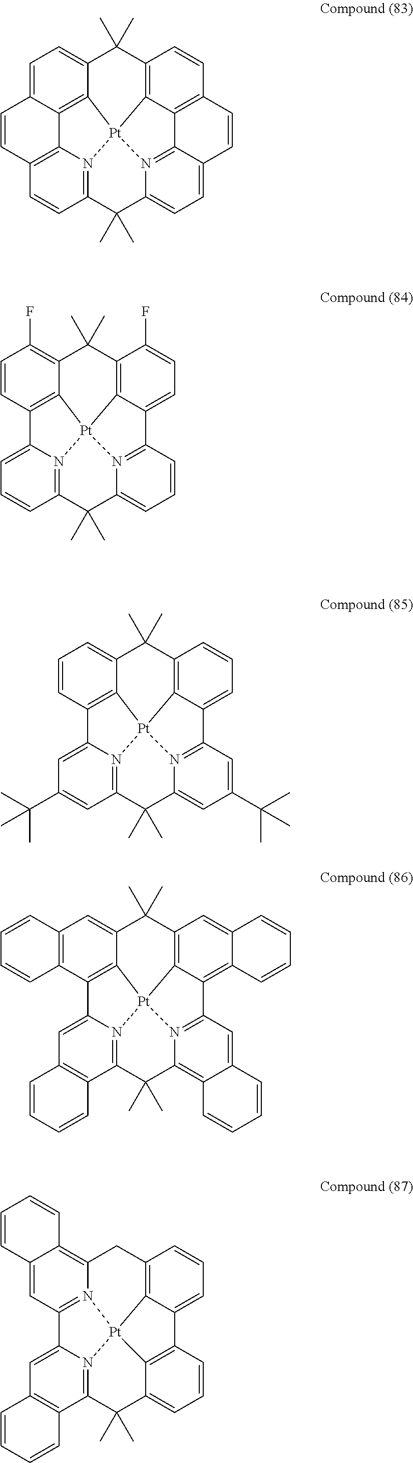

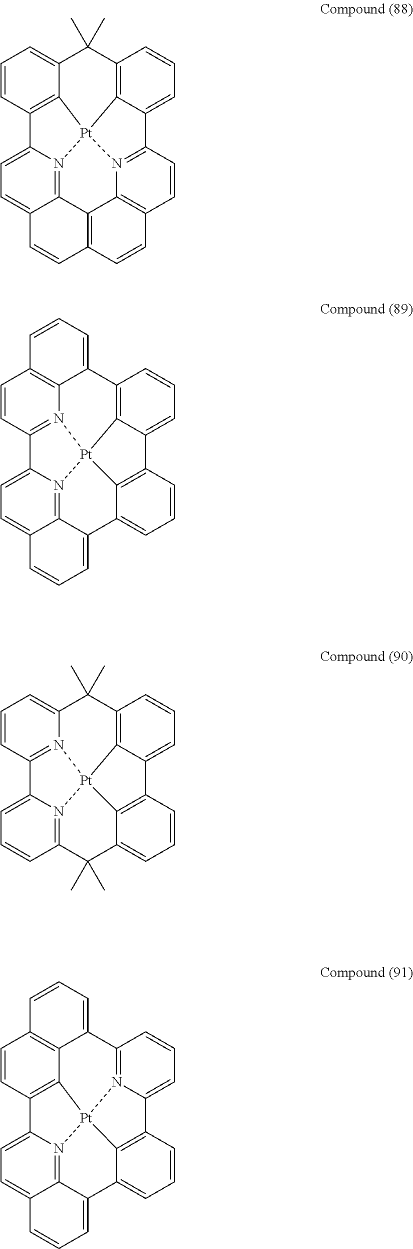

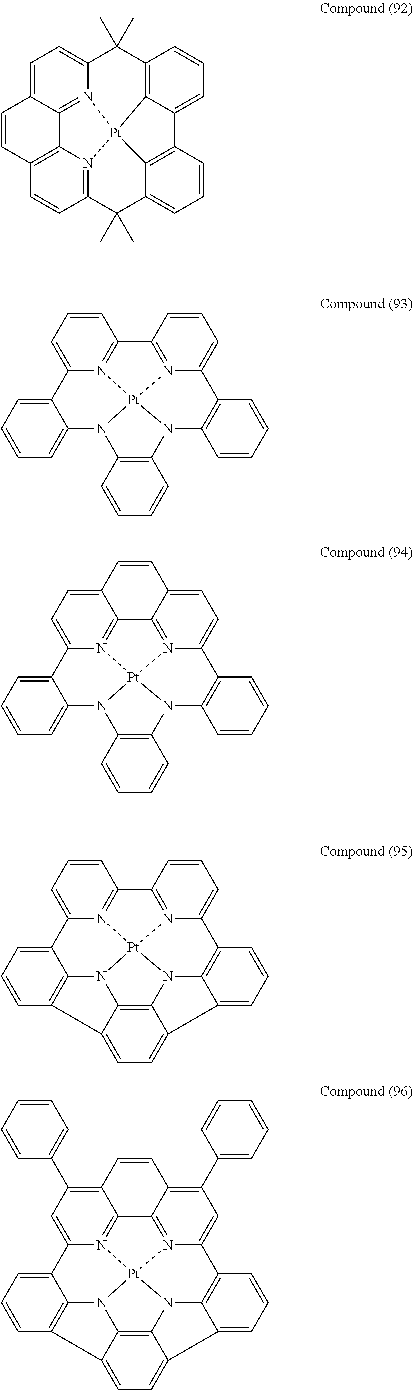

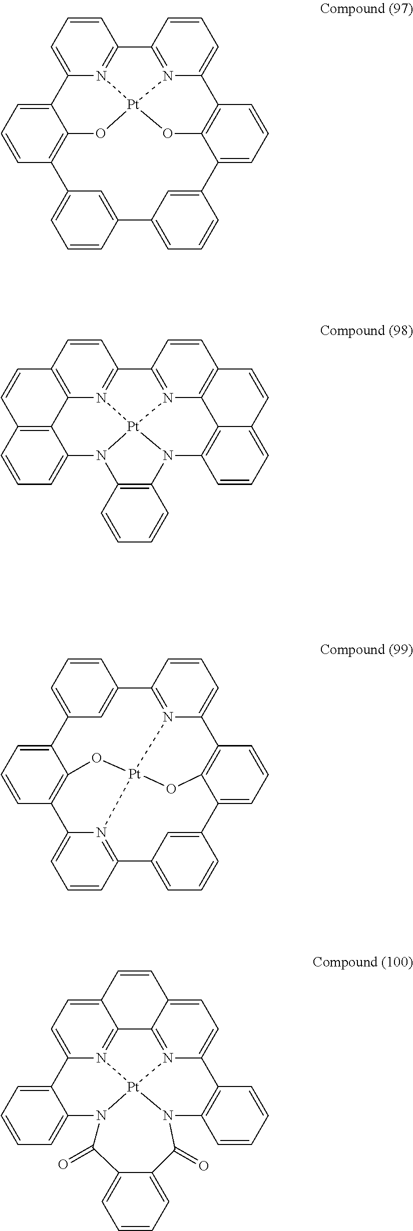

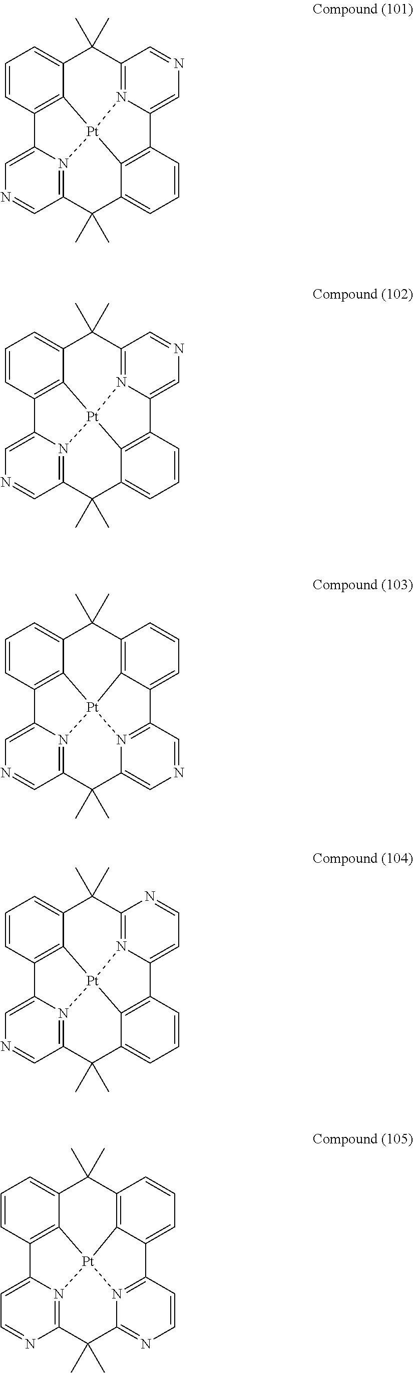

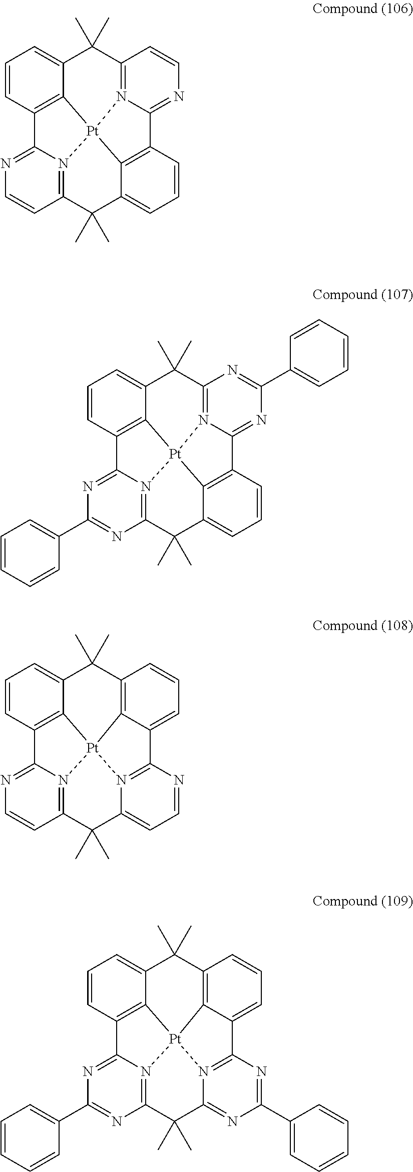

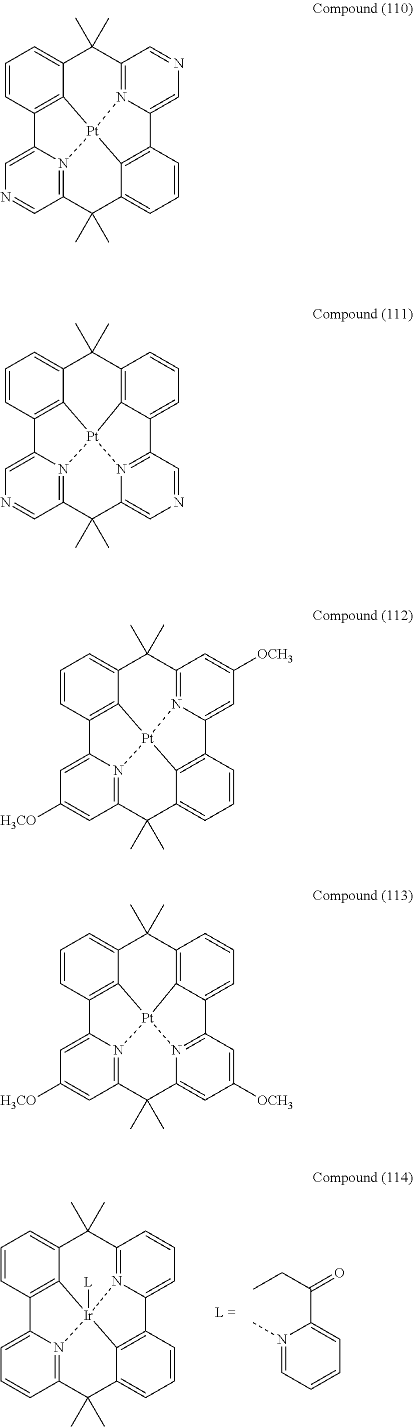

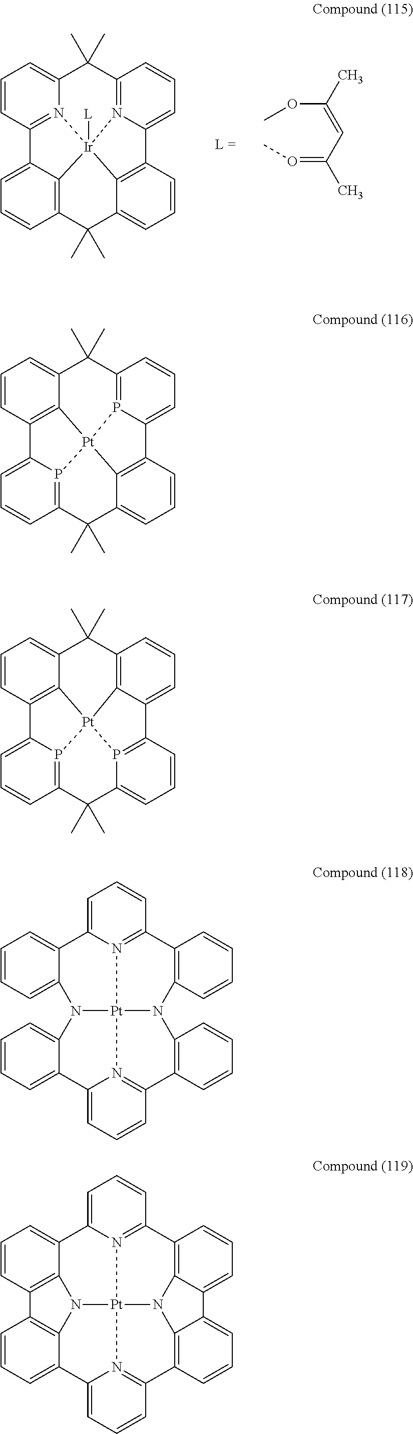

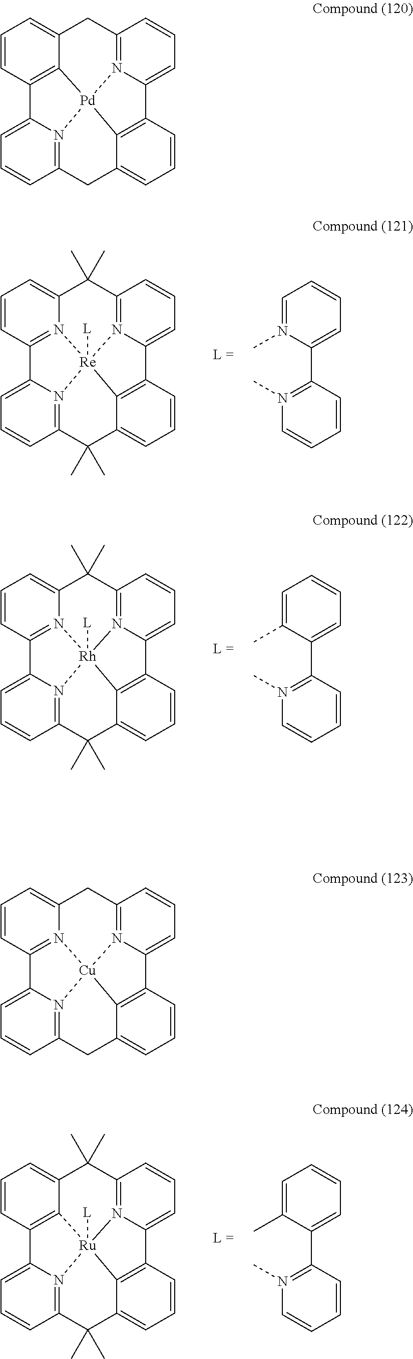

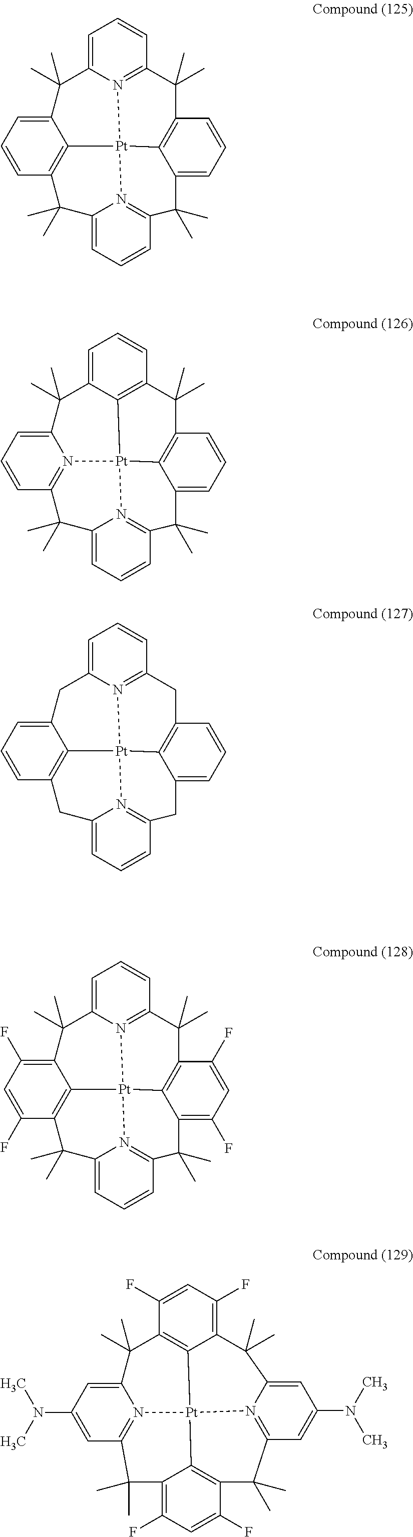

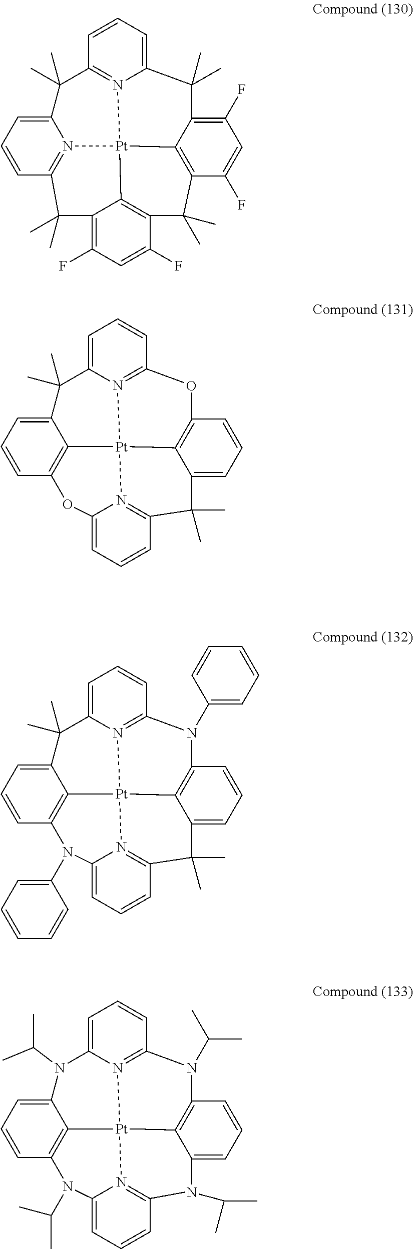

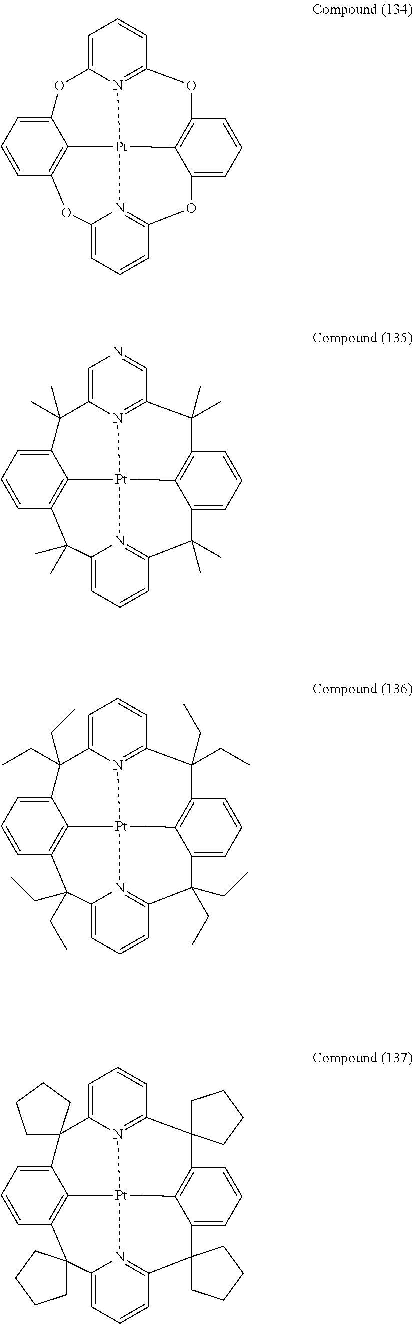

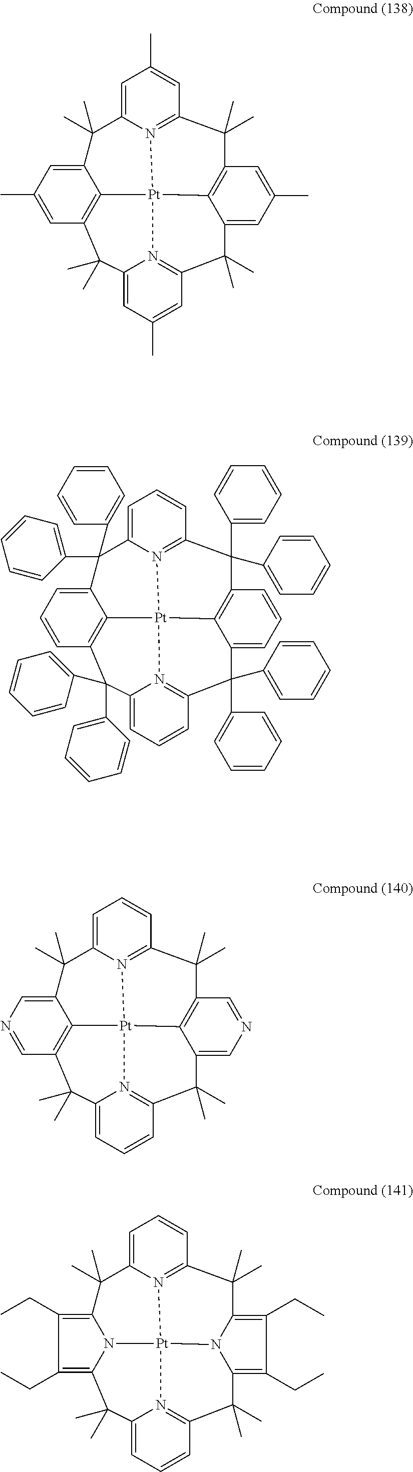

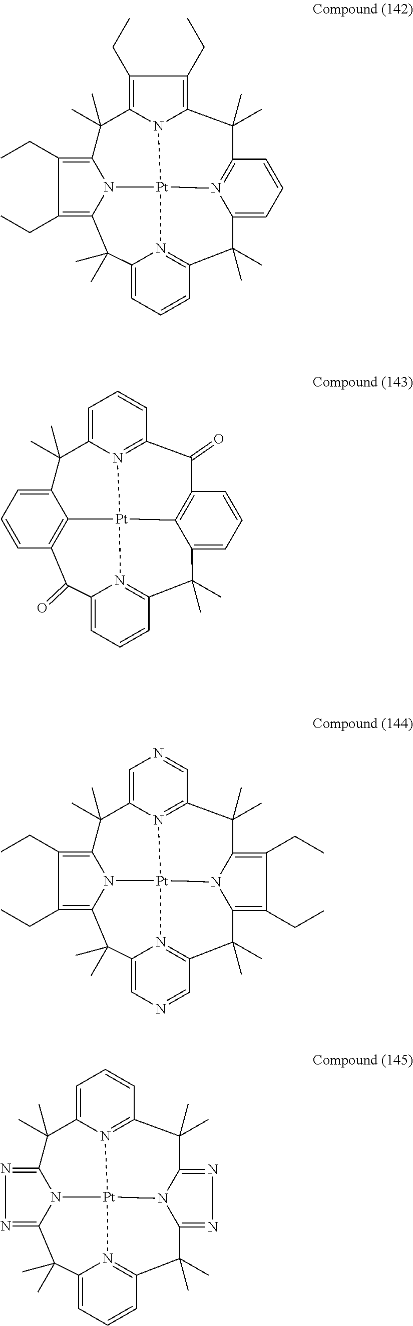

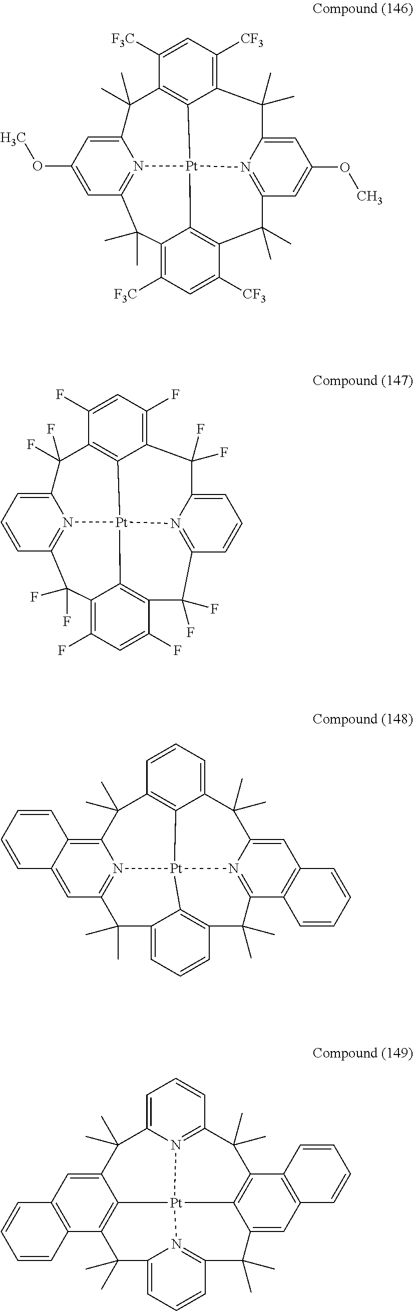

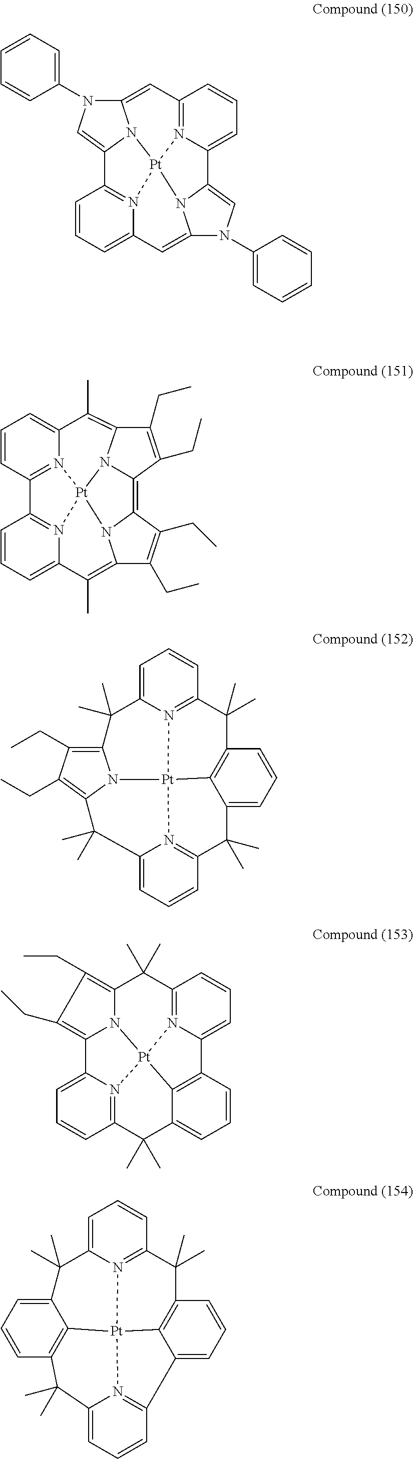

Preferable examples of the metal complex usable in the invention further include compounds represented by Formulae (A-1), (B-1), (C-1), (D-1), (E-1), or (F-1) described below.

Formula (A-1) is described below.

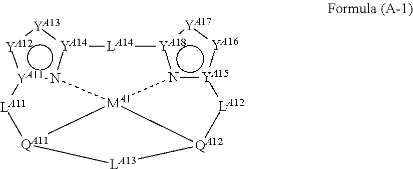

In Formula (A-1), M^{A1} represents a metal ion. Y^{A11}, Y^{A14}, Y^{A15} and Y^{A18} each independently represent a carbon atom or a nitrogen atom. Y^{A12}, Y^{A13}, Y^{A16} and Y^{A17} each independently represent a substituted or unsubstituted carbon atom, a substituted or unsubstituted nitrogen atom, an oxygen atom or a sulfur atom. L^{A11}, L^{A12}, L^{A13} and L^{A14} each represent a connecting group, and may be the same as each other or different from each other. Q^{A11} and Q^{A12} each independently represent a partial structure containing an atom bonded to M^{A1}. The bond between the atom in the partial structure and M^{A1} may be, for example, a covalent bond.

The compound represented by Formula (A-1) will be described in detail.

M^{A1} represents a metal ion. The metal ion is not particularly limited. It is preferably a divalent metal ion, more preferably Pt²⁺, Pd²⁺, Cu²⁺, Ni²⁺, Co²⁺, Zn²⁺, Mg²⁺ or Pb²⁺, still more preferably Pt²⁺ or Cu²⁺, and further more preferably Pt²⁺.

Y^{A11}, Y^{A14}, Y^{A15} and Y^{A18} each independently represent a carbon atom or a nitrogen atom. Each of Y^{A11}, Y^{A14}, Y^{A15} and Y^{A18} is preferably a carbon atom.

Y^{A12}, Y^{A13}, Y^{A16} and Y^{A17} each independently represent a substituted or unsubstituted carbon atom, a substituted or unsubstituted nitrogen atom, an oxygen atom or a sulfur atom. Each of Y^{A12}, Y^{A13}, Y^{A16} and Y^{A17} is preferably a substituted or unsubstituted carbon atom or a substituted or unsubstituted nitrogen atom.

L^{A11}, L^{A12}, L^{A13} and L^{A14} each independently represent a divalent connecting group. The divalent connecting group represented by L^{A11}, L^{A12}, L^{A13}, L^{A14} may be, for example, a single bond or a connecting group formed of atoms selected from carbon, nitrogen, silicon, sulfur, oxygen, germanium, phosphorus and the like, more preferably a single bond, a substituted or unsubstituted carbon atom, a substituted or unsubstituted nitrogen atom, a substituted silicon atom, an oxygen atom, a sulfur atom, a divalent aromatic hydrocarbon cyclic group or a divalent aromatic heterocyclic group, still more preferably a single bond, a substituted or unsubstituted carbon atom, a substituted or unsubstituted nitrogen atom, a substituted silicon atom, a divalent aromatic hydrocarbon cyclic group or a divalent aromatic heterocyclic group, and further more preferably a single bond or a substituted or unsubstituted methylene group. Examples of the divalent connecting group represented by L^{A11}, L^{A12}, L^{A13} or L^{A14} include the following groups:

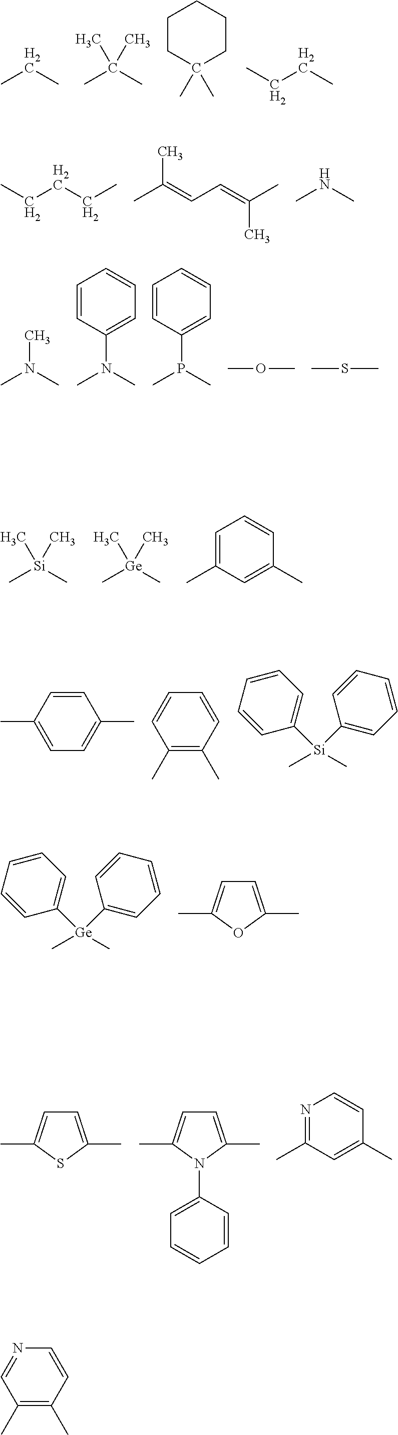

The divalent connecting group represented by L^{A11}, L^{A12}, L^{A13} or L^{A14} may further have a substituent. The substituent which can be introduced into the divalent connecting group may be, and examples thereof include, an alkyl group (preferably those having 1 to 30 carbon atoms, more preferably those having 1 to 20 carbon atoms, particularly preferably those having 1 to 10 carbon atoms, and examples thereof include a methyl group, an ethyl group, an iso-propyl group, a tert-butyl group, a n-octyl group, a n-decyl group, a n-hexadecyl group, a cyclopropyl group, a cyclopentyl group, a cyclohexyl group, and the like), an alkenyl group (preferably those having 2 to 30 carbon atoms, more preferably those having 2 to 20 carbon atoms, particularly preferably those having 2 to 10 carbon atoms, and examples thereof include a vinyl group, an allyl group, a 2-butenyl group, a 3-pentenyl group, and the like), an alkynyl group (preferably those having 2 to 30 carbon atoms, more preferably those having 2 to 20 carbon atoms, particularly preferably those having 2 to 10 carbon atoms, and examples thereof include a propargyl group, a 3-pentynyl group, and the like),

an aryl group (preferably those having 6 to 30 carbon atoms, more preferably those having 6 to 20 carbon atoms, particularly preferably those having 6 to 12 carbon atoms, and examples thereof include a phenyl group, a p-methylphenyl group, a naphthyl group, an anthranyl group, and the like), an amino group preferably those having 0 to 30 carbon atoms, more preferably those having 0 to 20 carbon atoms, particularly preferably those having 0 to 10 carbon atoms, and examples thereof include an amino group, a methylamino group, a dimethylamino group, a diethylamino group, a dibenzylamino group, a diphenylamino group, a ditolylamino group, and the like), an alkoxy group (preferably those having 1 to 30 carbon atoms, more preferably those having 1 to 20 carbon atoms, particularly preferably those having 1 to 10 carbon atoms, and examples thereof include a methoxy group, an ethoxy group, a butoxy group, a 2-ethylhexyloxy group, and the like), an aryloxy group (preferably those having 6 to 30 carbon atoms, more preferably those having 6 to 20 carbon atoms, particularly preferably those having 6 to 12 carbon atoms, and examples thereof include a phenyloxy group, a 1-naphthyloxy group, a 2-naphthyloxy group, and the like),

a heterocyclic oxy group (preferably those having 1 to 30 carbon atoms, more preferably those having 1 to 20 carbon atoms, particularly preferably those having 1 to 12 carbon atoms, and examples thereof include a pyridyloxy group, a pyrazyloxy group, a pyrimidyloxy group, a quinolyloxy group, and the like), an acyl group (preferably those having 1 to 30 carbon atoms, more preferably those having 1 to 20 carbon atoms, particularly preferably those having 1 to 12 carbon atoms, and examples thereof include an acetyl group, a benzoyl group, a formyl group, a pivaloyl group, and the like), an alkoxycarbonyl group (preferably those having 2 to 30 carbon atoms, more preferably those having 2 to 20 carbon atoms, particularly preferably those having 2 to 12 carbon atoms, and examples thereof include a methoxycarbonyl group, an ethoxycarbonyl group, and the like), an aryloxycarbonyl group (preferably those having 7 to 30 carbon atoms, more preferably those having 7 to 20 carbon atoms, particularly preferably those having 7 to 12 carbon atoms, and examples thereof include a phenyloxycarbonyl group and the like),

an acyloxy group (preferably those having 2 to 30 carbon atoms, more preferably those having 2 to 20 carbon atoms, particularly preferably those having 2 to 10 carbon atoms, and examples thereof include an acetoxy group, a benzoyloxy group, and the like), an acylamino group (preferably those having 2 to 30 carbon atoms, more preferably those having 2 to 20 carbon atoms, particularly preferably those having 2 to 10 carbon atoms, and examples thereof include an acetylamino group, a benzoylamino group and the like), an alkoxycarbonylamino group (preferably those having 2 to 30 carbon atoms, more preferably those having 2 to 20 carbon atoms, particularly preferably those having 2 to 12 carbon atoms, and examples thereof include a methoxycarbonylamino group and the like), an aryloxycarbonylamino group (preferably those having 7 to 30 carbon atoms, more preferably those having 7 to 20 carbon atoms, particularly preferably those having 7 to 12 carbon atoms, and examples thereof include a phenyloxycarbonylamino group and the like),

a sulfonylamino group (preferably those having 1 to 30 carbon atoms, more preferably those having 1 to 20 carbon atoms, particularly preferably those having 1 to 12 carbon atoms, and examples thereof include a methanesulfonylamino group, a benzenesulfonylamino group and the like), a sulfamoyl group (preferably those having 0 to 30 carbon atoms, more preferably those having 0 to 20 carbon atoms, particularly preferably those having 0 to 12 carbon atoms, and examples thereof include a sulfamoyl group, a methylsulfamoyl group, a dimethylsulfamoyl group, a phenylsulfamoyl group and the like), a carbamoyl group (preferably those having 1 to 30 carbon atoms, more preferably those having 1 to 20 carbon atoms, particularly preferably those having 1 to 12 carbon atoms, and examples thereof include a carbamoyl group, a methylcarbamoyl group, a diethylcarbamoyl group, a phenylcarbamoyl group and the like),

an alkylthio group (preferably those having 1 to 30 carbon atoms, more preferably those having 1 to 20 carbon atoms, particularly preferably those having 1 to 12 carbon atoms, and examples thereof include a methylthio group, an ethylthio group, and the like), an arylthio group (preferably those having 6 to 30 carbon atoms, more preferably those having 6 to 20 carbon atoms, particularly preferably those having 6 to 12 carbon atoms, and examples thereof include a phenylthio group and the like), a heterocyclic thio group (preferably those having 1 to 30 carbon atoms, more preferably those having 1 to 20 carbon atoms, particularly preferably those having 1 to 12 carbon atoms, and examples thereof include a pyridylthio group, a 2-benzimidazolylthio group, a 2-benzoxazolylthio group, a 2-benzthiazolylthio group and the like), a sulfonyl group (preferably those having 1 to 30 carbon atoms, more preferably those having 1 to 20 carbon atoms, particularly preferably those having 1 to 12 carbon atoms, and examples thereof include a mesyl group, a tosyl group and the like), a sulfinyl group (preferably those having 1 to 30 carbon atoms, more preferably those having 1 to 20 carbon atoms, particularly preferably those having 1 to 12 carbon atoms, and examples thereof include a methanesulfinyl group, a benzenesulfinyl group and the like),

a ureido group (preferably those having 1 to 30 carbon atoms, more preferably those having 1 to 20 carbon atoms, particularly preferably those having 1 to 12 carbon atoms, and examples thereof include a ureido group, a methylureido group, a phenylureido group and the like), a phosphoric amide group (preferably those having 1 to 30 carbon atoms, more preferably those having 1 to 20 carbon atoms, particularly preferably those having 1 to 12 carbon atoms, and examples thereof include a diethylphosphoric amide group, a phenylphosphoric amide group, and the like), a hydroxy group, a mercapto group, a halogen atom (and examples thereof include a fluorine atom, chlorine atom, bromine atom, iodine atom), a cyano group, a sulfo group, a carboxyl group, a nitro group, a hydroxamic acid group, a sulfino group, a hydrazino group, an imino group,

a heterocyclic group (preferably those having 1 to 30 carbon atoms, more preferably those having 1 to 12 carbon atoms containing a heteroatom such as a nitrogen atom, an oxygen atom or a sulfur atom, specific examples thereof include an imidazolyl group, a pyridyl group, a quinolyl group, a furyl group, a thienyl group, a piperidyl group, a morpholino group, a benzoxazolyl group, a benzimidazolyl group, a benzthiazolyl group, a carbazolyl group, an azepinyl group, and the like), a silyl group (preferably those having 3 to 40 carbon atoms, more preferably those having 3 to 30 carbon atoms, particularly preferably those having 3 to 24 carbon atoms, and examples thereof include a trimethylsilyl group, a triphenylsilyl group and the like) or a silyloxy group (preferably those having 3 to 40 carbon atoms, more preferably those having 3 to 30 carbon atoms, particularly preferably those having 3 to 24 carbon atoms, and examples thereof include a trimethylsilyloxy group, a triphenylsilyloxy group and the like).

These substituents may further have a substituent(s). Substituents which can be introduced to these substituents are each preferably selected from an alkyl group, an aryl group, a heterocyclic group, a halogen atom and a silyl group, more preferably selected from an alkyl group, an aryl group, a heterocyclic group and a halogen atom, and still more preferably selected from an alkyl group, an aryl group, an aromatic heterocyclic group and a fluorine atom.

Q^{A11} and Q^{A12} each independently represent a partial structure containing an atom bonded to M^{A1}. The bond between the atom in the partial structure and M^{A1} may be, for example, a covalent bond. Q^{A11} and Q^{A12} each independently preferably represent a group having a carbon atom bonded to M^{A1}, a group having a nitrogen atom bonded to M^{A1}, a group having a silicon atom bonded to M^{A1}, a group having a phosphorus atom bonded to M^{A1}, a group having an oxygen atom bonded to M^{A1} or a group having a sulfur atom bonded to M^{A1}, more preferably a group having a carbon atom, a nitrogen atom, an oxygen atom, or a sulfur atom bonded to M^{A1}, still more preferably a group having a carbon group or nitrogen atom bonded to M^{A1}, and further more preferably a group having a carbon atom bonded to M^{A1}.

The group bonded to M^{A1} via a carbon atom is preferably an aryl group having a carbon atom bonded to M^{A1}, a 5-membered cyclic heteroaryl group having a carbon atom bonded to M^{A1} or a 6-membered cyclic heteroaryl group having a carbon atom bonded to M^{A1}, more preferably an aryl group having a carbon atom bonded to M^{A1}, a nitrogen-containing 5-membered cyclic heteroaryl group having a carbon atom bonded to M^{A1} or a nitrogen-containing 6-membered cyclic heteroaryl group having a carbon atom bonded to M^{A1}, and still more preferably an aryl group having a carbon atom bonded to M^{A1}.

The group bonded to M^{A1} via a nitrogen atom is preferably a substituted amino group or a nitrogen-containing 5-membered cyclic heteroaryl group having a nitrogen atom bonded to M^{A1}, more preferably a nitrogen-containing 5-membered cyclic heteroaryl group having a nitrogen atom bonded to M^{A1}.

The group bonded to M^{A1} via a phosphorus atom is preferably a substituted phosphino group. The group having a silicon atom bonded to M^{A1} is preferably a substituted silyl group. The group having an oxygen atom bonded to M^{A1} is preferably an oxy group, and the group having a sulfur atom bonded to M^{A1} is preferably a sulfide group.

The compound represented by Formula (A-1) is more preferably a compound represented by the following Formula (A-2), (A-3) or (A-4).

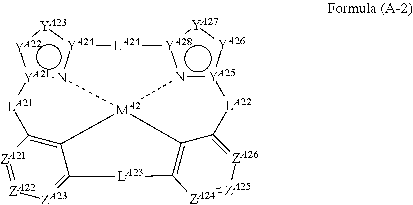

In Formula (A-2), M^{A2} represents a metal ion. Y^{A21}, Y^{A24}, Y^{A25} and Y^{A28} each independently represent a carbon atom or a nitrogen atom. Y^{A22}, Y^{A23}, Y^{A26} and Y^{A27} each independently represent a substituted or unsubstituted carbon atom, a substituted or unsubstituted nitrogen atom, an oxygen atom or a sulfur atom. L^{A21}, L^{A22}, L^{A23} and L^{A24} each independently represent a connecting group. Z^{A21}, Z^{A22}, Z^{A23}, Z^{A24}, Z^{A25} and Z^{A26} each independently represent a nitrogen atom or a substituted or unsubstituted carbon atom.

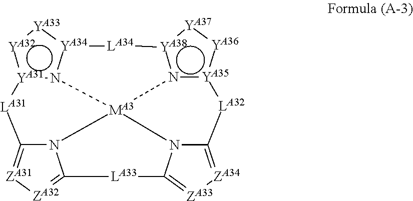

In Formula (A-3), M^{A3} represents a metal ion. Y^{A31}, Y^{A34}, Y^{A35} and Y^{A38} each independently represent a carbon atom or a nitrogen atom. Y^{A32}, Y^{A33}, Y^{A36} and Y^{A37} each independently represent a substituted or unsubstituted carbon atom, a substituted or unsubstituted nitrogen atom, an oxygen atom or a sulfur atom. L^{A31}, L^{A32}, L^{A33} and L^{A34} each independently represent a connecting group. Z^{A31}, Z^{A32}, Z^{A33} and Z^{A34} each independently represent a nitrogen atom or a substituted or unsubstituted carbon atom.

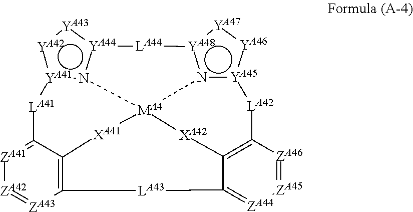

In Formula (A-4), M^{A4} represents a metal ion. Y^{A41}, Y^{A44} Y^{A45} and Y^{A48} each independently represent a carbon atom or a nitrogen atom. Y^{A42}, Y^{A43}, Y^{A46} and Y^{A47} each independently represent a substituted or unsubstituted carbon atom, a substituted or unsubstituted nitrogen atom, an oxygen atom or a sulfur atom. L^{A41}, L^{A42}, L^{A43} and L^{A44} each independently represent a connecting group. Z^{A41}, Z^{A42}, Z^{A43}, Z^{A44}, Z^{A45} and Z^{A46} each independently represent a nitrogen atom or a substituted or unsubstituted carbon atom. X^{A41} and X^{A42} each independently represent an oxygen atom, a sulfur atom or a substituted or unsubstituted nitrogen atom.

The compound represented by Formula (A-2) will be described in detail.

M^{A2}, Y^{A21}, Y^{A24}, Y^{A25}, Y^{A28}, Y^{A22}, Y^{A23}, Y^{A26}, Y^{A27}, L^{A21}, L^{A22}, L^{A23} and L^{A24} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L^{A12}, L^{A13} and L^{A14} in Formula (A-1) respectively, and their preferable examples are also the same.

Z^{A21}, Z^{A22}, Z^{A23}, Z^{A24}, Z^{A25} and Z^{A26} each independently represent a nitrogen atom or a substituted or unsubstituted carbon atom. Z^{A21}, Z^{A22}, Z^{A23}, Z^{A24}, Z^{A25} and Z^{A26} each independently represent preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

The compound represented by Formula (A-3) will be described in detail.

M^{A3}, Y^{A31}, Y^{A34}, Y^{A35}, Y^{A38}, Y^{A32}, Y^{A33}, Y^{A36}, Y^{A37}, L^{A31}, L^{A32}, L^{A33} and L^{A34} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L^{A12}, L^{A13} and L^{A14} in Formula (A-1) respectively, and their preferable examples are also the same.

Z^{A31}, Z^{A32}, Z^{A33} and Z^{A34} each independently represent a nitrogen atom or a substituted or unsubstituted carbon atom. Each of Z^{A31}, Z^{A32}, Z^{A33} and Z^{A34} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

The compound represented by Formula (A-4) will be described in detail.

M^{A4}, Y^{A41}, Y^{A44}, Y^{A45}, Y^{A48}, Y^{A42}, Y^{A43}, Y^{A46}, Y^{A47}, L^{A41}, L^{A42}, L^{A43} and L^{A44} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L^{A12}, L^{A13} and L^{A14} in Formula (A-1) respectively, and their preferable examples are also the same.

Z^{A41}, Z^{A42}, Z^{A43}, Z^{A44}, Z^{A45} and Z^{A46} each independently represent a nitrogen atom or a substituted or unsubstituted carbon atom. Each of Z^{A41}, Z^{A42}, Z^{A43}, Z^{A44}, Z^{A45} and Z^{A46} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

X^{A41} and X^{A42} each independently represent an oxygen atom, a sulfur atom or a substituted or unsubstituted nitrogen atom. Each of X^{A41} and X^{A42} is preferably an oxygen atom or a sulfur atom, and more preferably an oxygen atom.

Specific examples of the compound represented by Formula (A-1) are shown below. However, the specific examples should not be construed as limiting the invention.

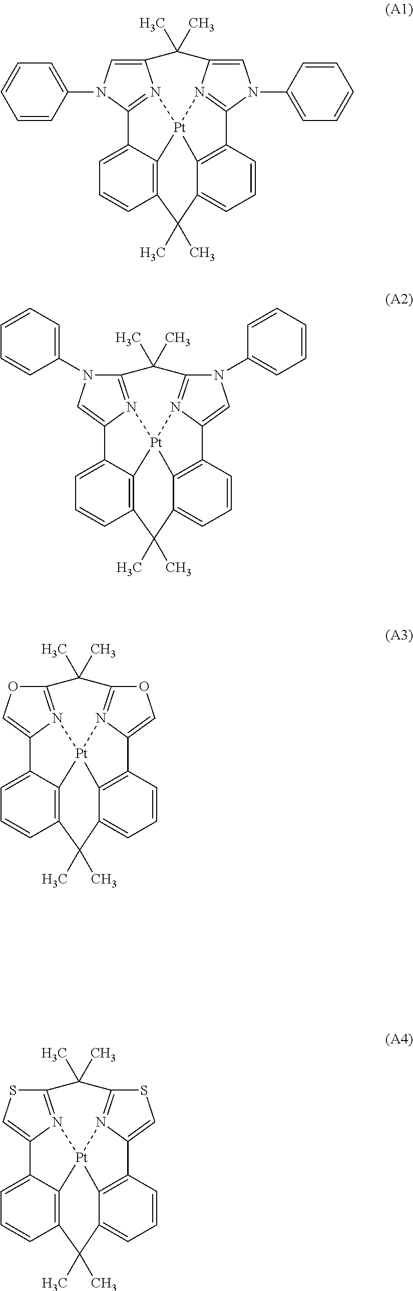

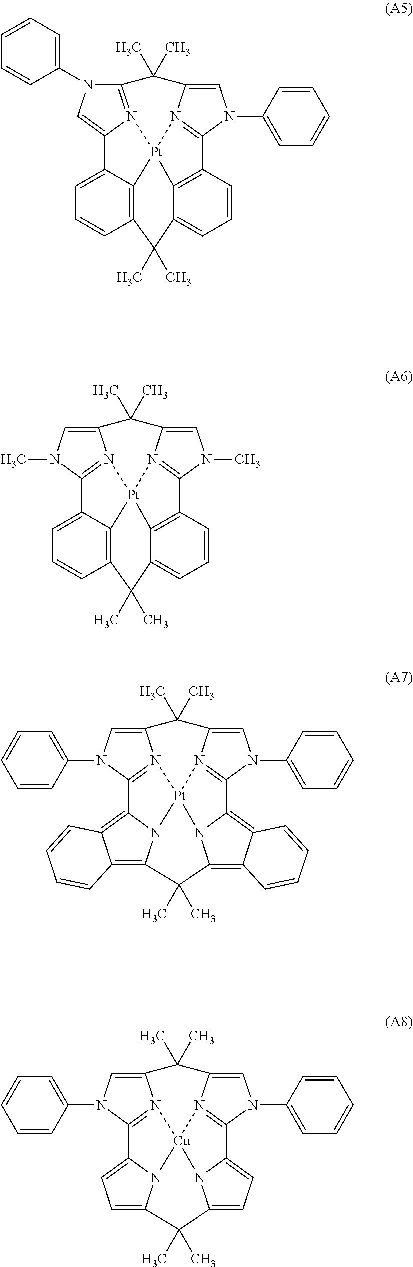

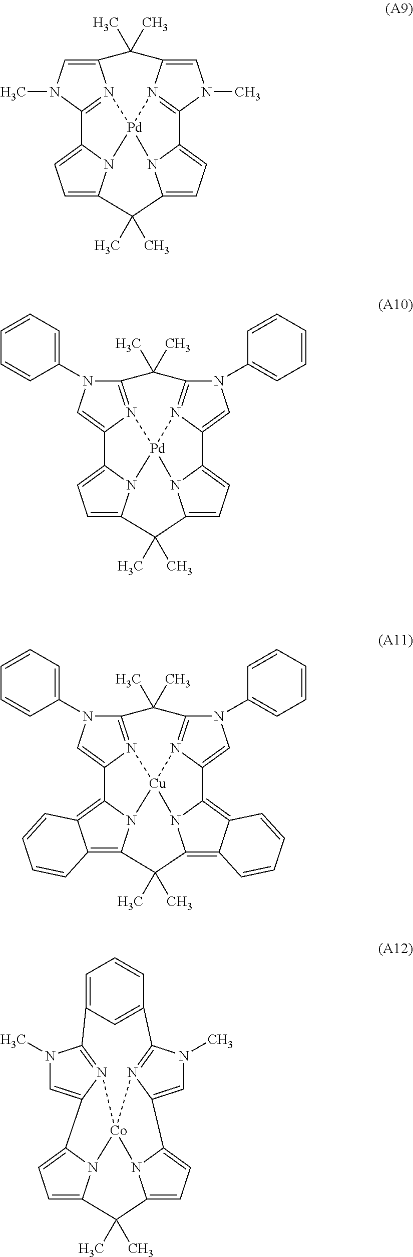

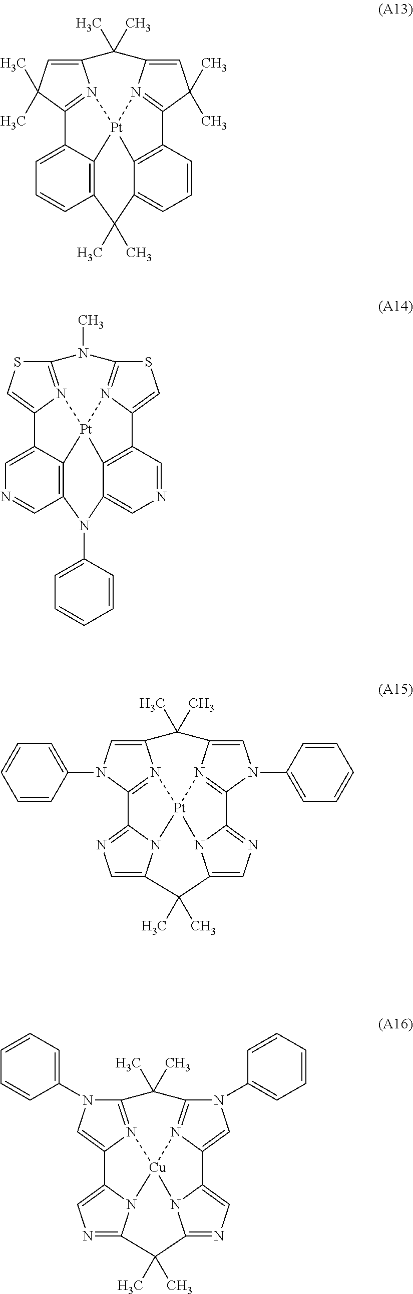

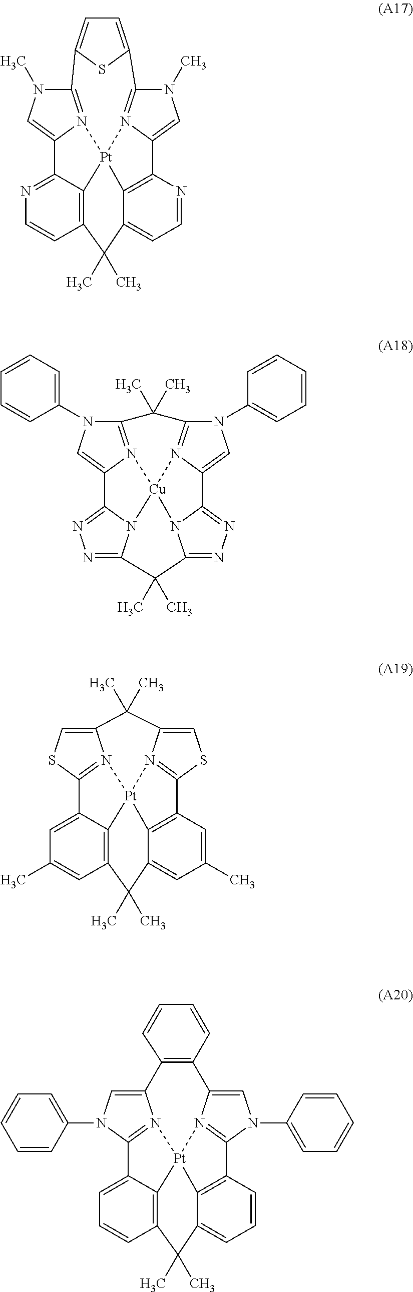

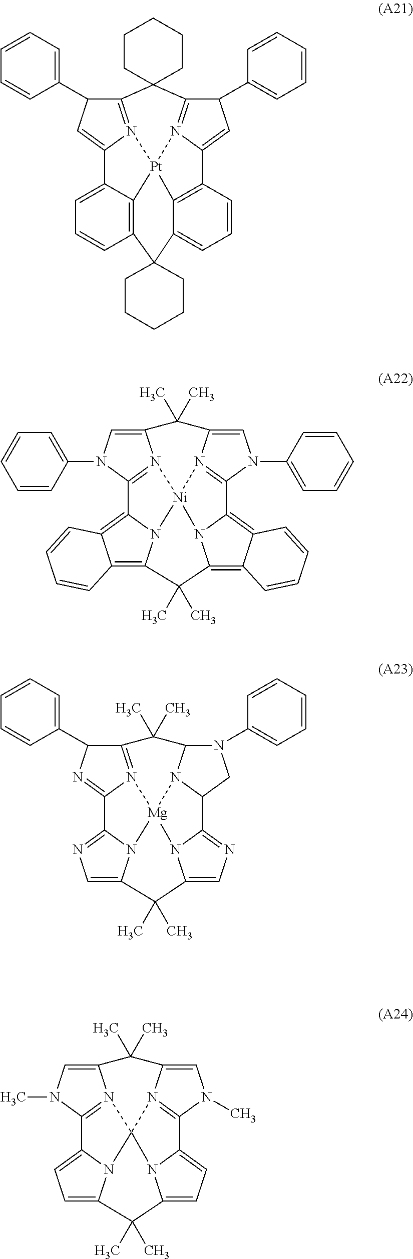

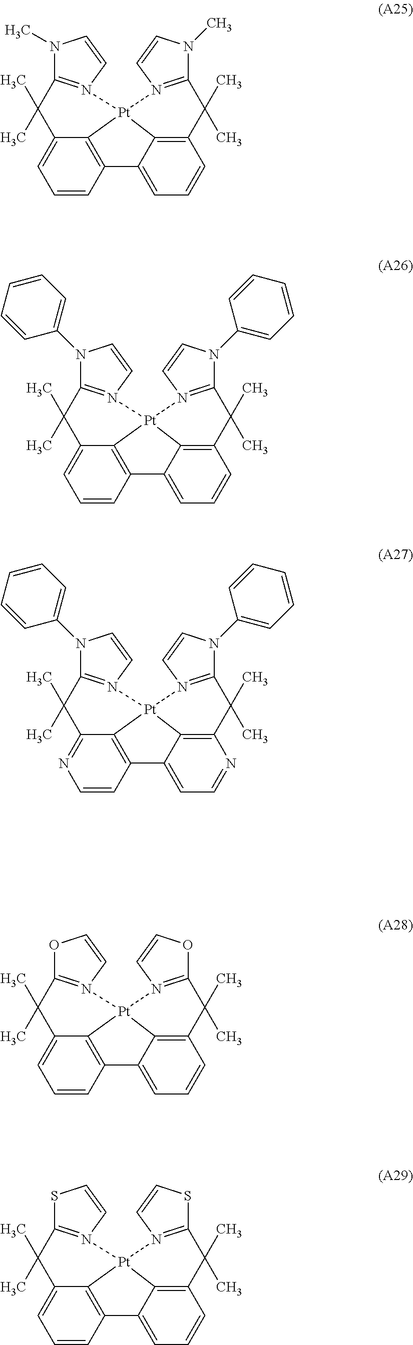

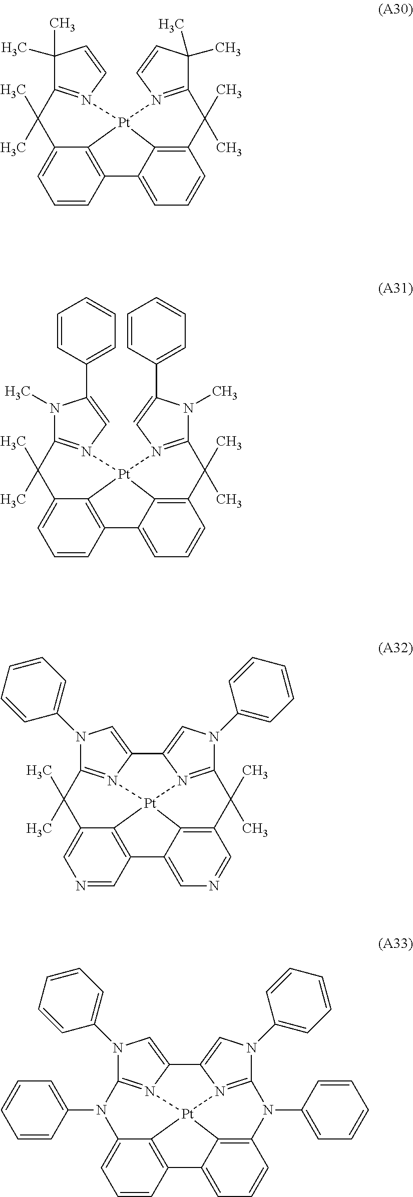

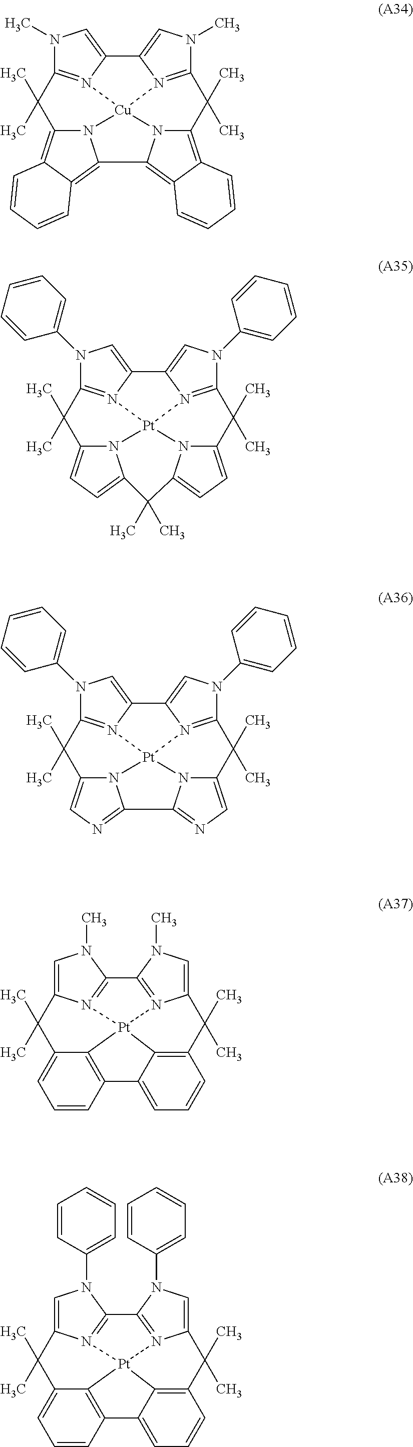

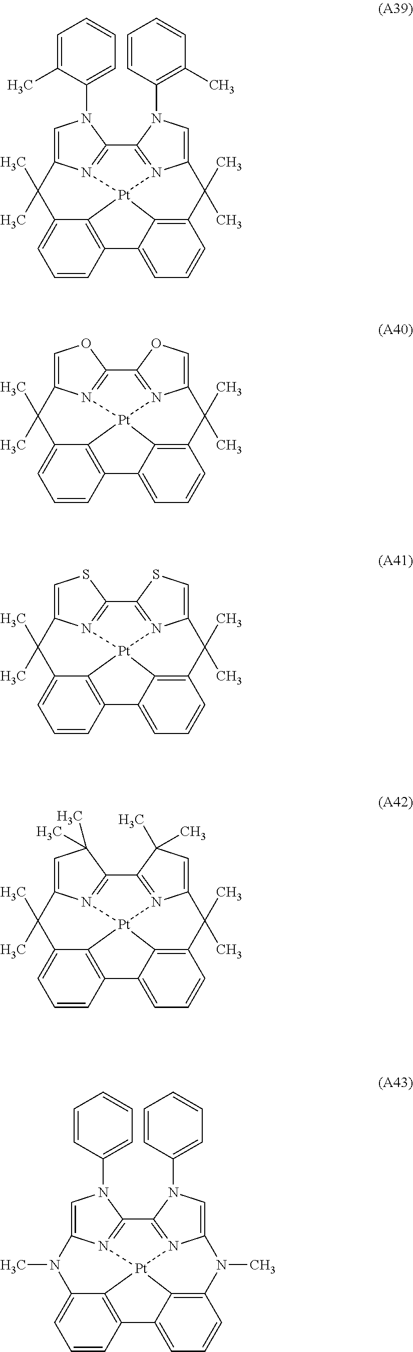

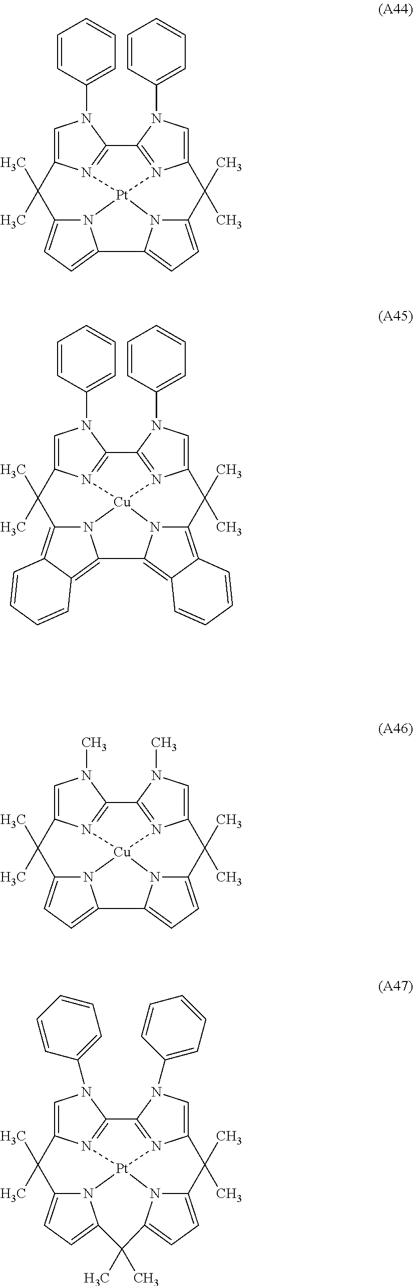

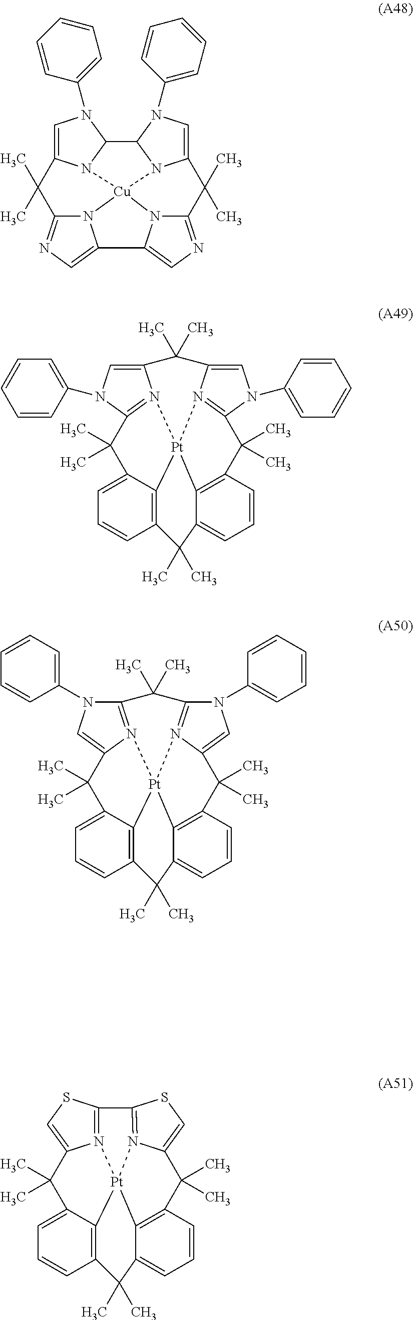

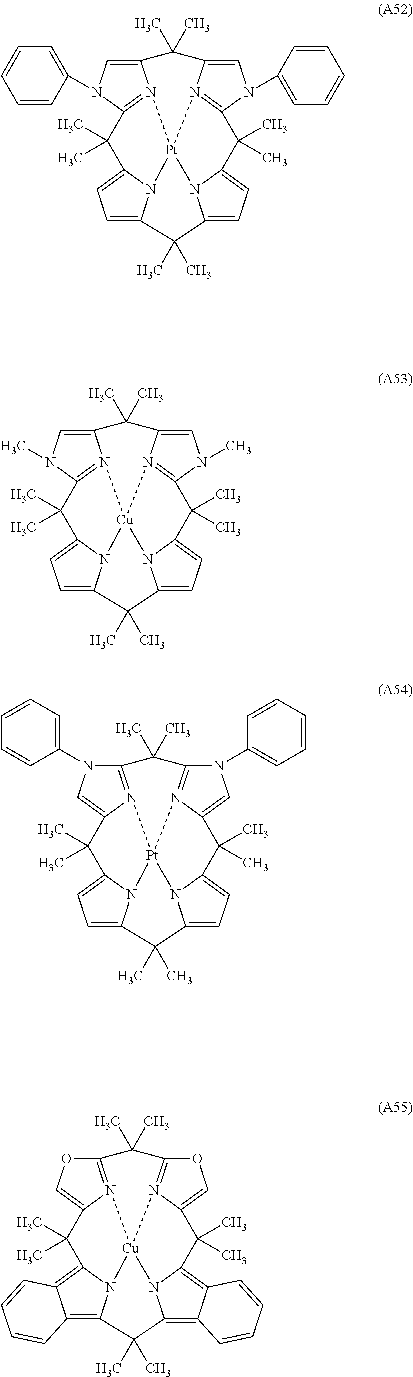

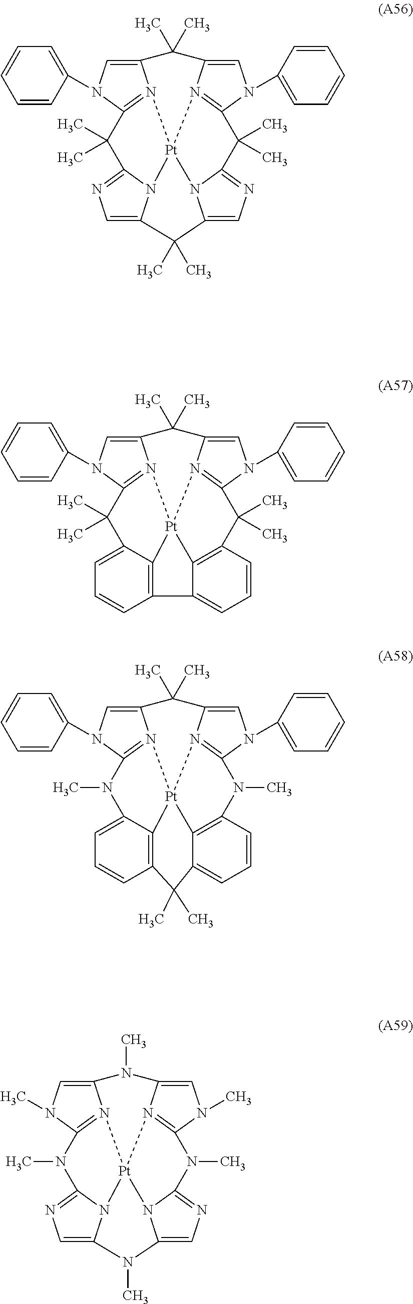

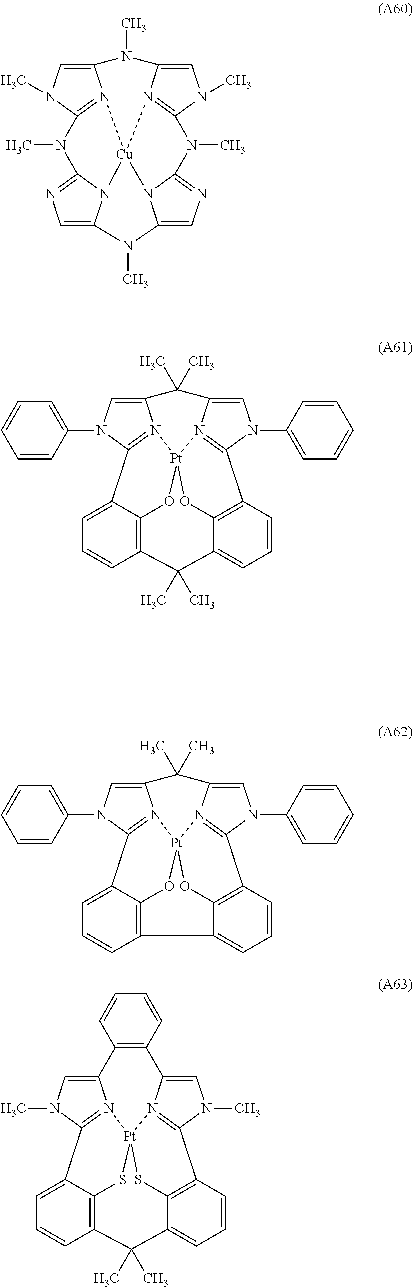

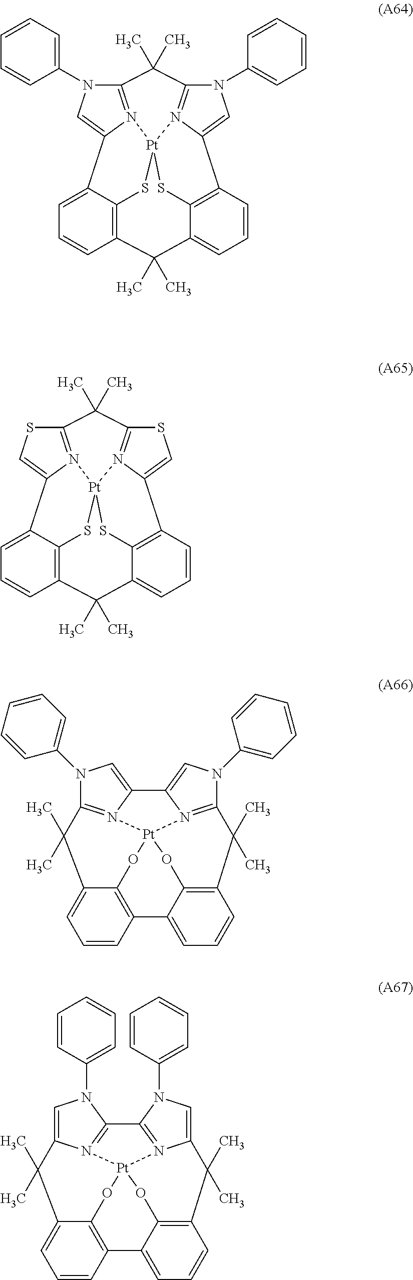

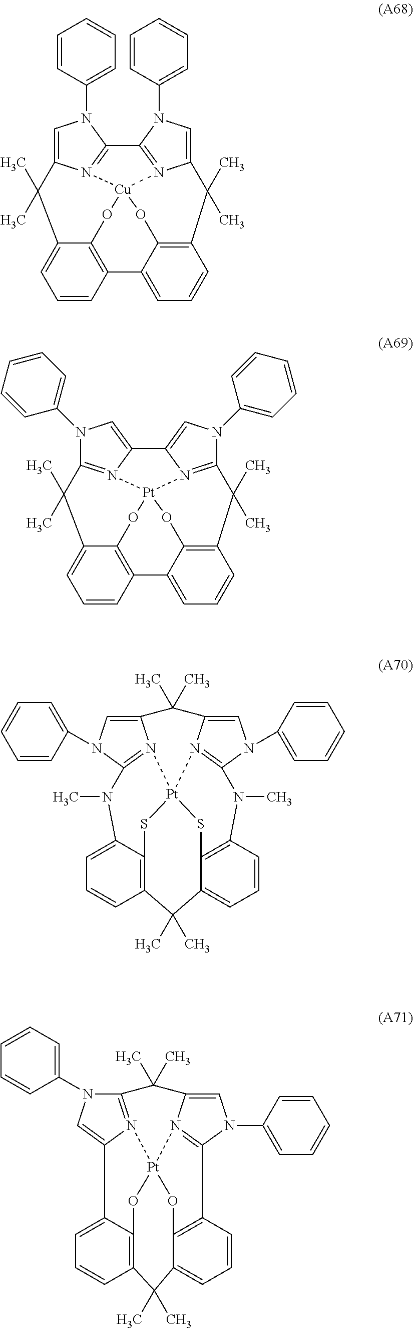

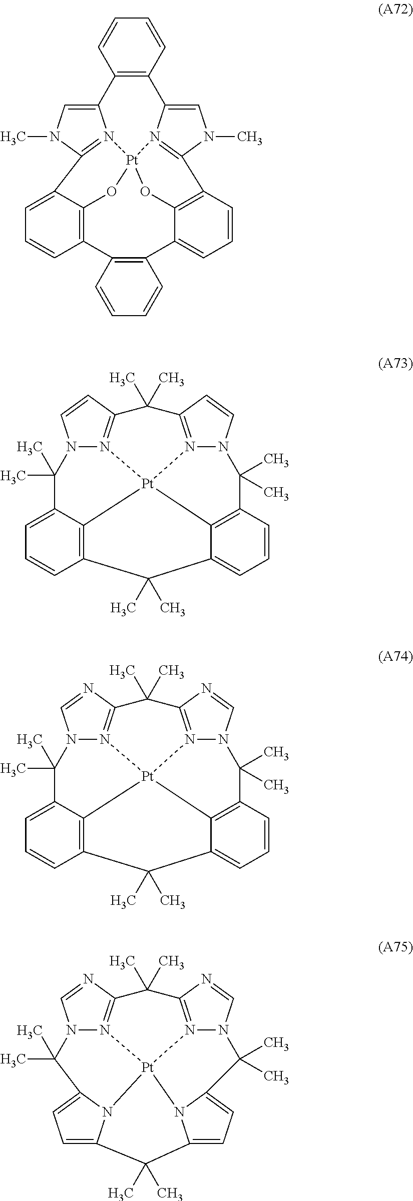

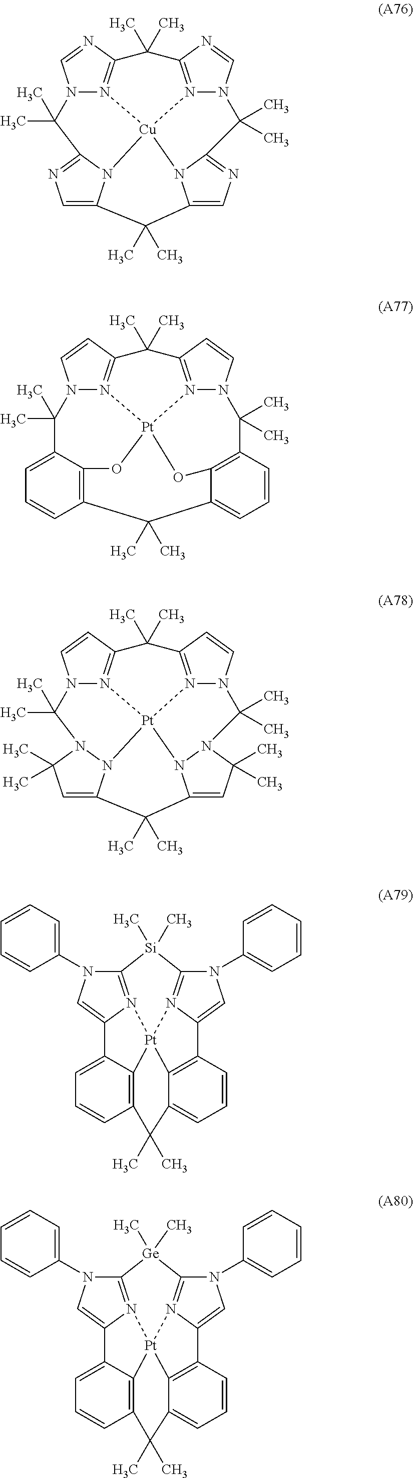

Compounds represented by Formula (B-1) shown below are also preferable as metal complexes usable in the invention.

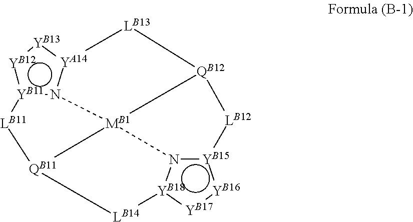

In Formula (B-1), M^{B1} represents a metal ion. Y^{B11}, Y^{B14}, Y^{B15} and Y^{B18} each independently represent a carbon atom or a nitrogen atom. Y^{B12}, Y^{B13}, Y^{B16} and Y^{B17} each independently represent a substituted or unsubstituted carbon atom, a substituted or unsubstituted nitrogen atom, an oxygen atom or a sulfur atom. L^{B11}, L^{B12}, L^{B13} and L^{B14} each independently represent a connecting group. Q^{B11} and Q^{B12} each independently represent a partial structure containing an atom bonded to M^{B1}. The bond between the atom in the partial structure and M^{B1} may be, for example, a covalent bond.

The compound represented by Formula (B-1) will be described in detail.

In Formula (B-1), M^{B1}, Y^{B11}, Y^{B14}, Y^{B15}, Y^{B18}, Y^{B12}, Y^{B13}, Y^{B16}, Y^{B17}, L^{B11}, L^{B12} L^{B13}, L^{B14}, Q^{B11} and Q^{B12} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L^{A12}, L^{A13}, L^{A14}, Q^{A11} and Q^{A12} in Formula (A-1) respectively, and their preferable examples are also the same.

More preferable examples of the compound represented by Formula (B-1) include compounds represented by the following Formula (B-2), (B-3) or (B-4).

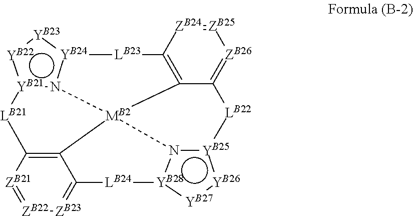

In Formula (B-2), M^{B2} represents a metal ion. Y^{B21}, Y^{B24}, Y^{B25} and Y^{B28} each independently represent a carbon atom or a nitrogen atom. Y^{B22}, Y^{B23}, Y^{B26} and Y^{B27} each independently represent a substituted or unsubstituted carbon atom, a substituted or unsubstituted nitrogen atom, an oxygen atom or a sulfur atom. L^{B21}, L^{B22}, L^{B23} and L^{B24} each independently represent a connecting group. Z^{B21}, Z^{B22}, Z^{B23}, Z^{B24}, Z^{B25} and Z^{B26} each independently represent a nitrogen atom or a substituted or unsubstituted carbon atom.

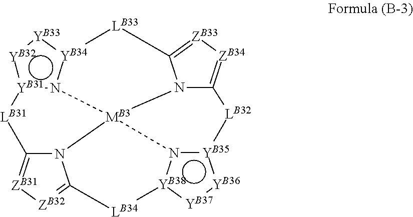

In Formula (B-3), M^{B3} represents a metal ion. Y^{B31}, Y^{B34}, Y^{B35} and Y^{B38} each independently represent a carbon atom or a nitrogen atom. Y^{B32}, Y^{B33}, Y^{B36} and Y^{B37} each independently represent a substituted or unsubstituted carbon atom, a substituted or unsubstituted nitrogen atom, an oxygen atom or a sulfur atom. L^{B31}, L^{B32}, L^{B33} and L^{B34} each independently represent a connecting group. Z^{B31}, Z^{B32}, Z^{B33} and Z^{B34} each independently represent a nitrogen atom or a substituted or unsubstituted carbon atom.

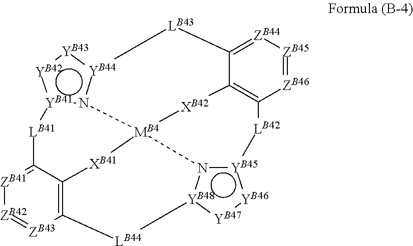

In Formula (B-4), M^{B4} represents a metal ion. Y^{B41}, Y^{B44}, Y^{B45} and Y^{B48} each independently represent a carbon atom or a nitrogen atom. Y^{B42}, Y^{B43}, Y^{B46} and Y^{B47} each independently represent a substituted or unsubstituted carbon atom, a substituted or unsubstituted nitrogen atom, an oxygen atom or a sulfur atom. L^{B41}, L^{B42}, L^{B43} and L^{B44} each independently represent a connecting group. Z^{B41}, Z^{B42}, Z^{B43}, Z^{B44}, Z^{B45} and Z^{B46} each independently represent a nitrogen atom or a substituted or unsubstituted carbon atom. X^{B41} and X^{B42} each independently represent an oxygen atom, a sulfur atom or a substituted or unsubstituted nitrogen atom.

The compound represented by Formula (B-2) will be described in detail.

In Formula (B-2), M^{B2}, Y^{B21}, Y^{B24}, Y^{B25}, Y^{B28}, Y^{B22}, Y^{B23}, Y^{B26}, Y^{B27}, L^{B21}, L^{B22}, L^{B23} and L^{B24} have the same definitions as corresponding M^{B1}, Y^{B11}, Y^{B14}, Y^{B15}, Y^{B18}, Y^{B12}, Y^{B13}, Y^{B16}, Y^{B17}, L^{B11}, L^{B12}, L^{B13} and L^{B14} in Formula (B-1) respectively, and their preferable examples are also the same.

Z^{B21}, Z^{B22}, Z^{B23}, Z^{B24}, Z^{B25} and Z^{B26} each independently represent a nitrogen atom or a substituted or unsubstituted carbon atom. Each of Z^{B21}, Z^{B22}, Z^{B23}, Z^{B24}, Z^{B25} and Z^{B26} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

The compound represented by Formula (B-3) will be described in detail.

In Formula (B-3), M^{B3}, Y^{B31}, Y^{B34}, Y^{B35}, Y^{B38}, Y^{B32}, Y^{B33}, Y^{B36}, Y^{B37}, L^{B31}, Y^{B32}, L^{B33} and L^{B34} have the same definitions as corresponding M^{B1}, Y^{B11}, Y^{B14}, Y^{B15}, Y^{B18}, Y^{B12}, Y^{B13}, Y^{B16}, Y^{B17}, L^{B11}, L^{B12}, L^{B13} and L^{B14} in Formula (B-1) respectively, and their preferable examples are also the same.

Z^{B31}, Z^{B32}, Z^{B33} and Z^{B34} each independently represent a nitrogen atom or a substituted or unsubstituted carbon atom. Each of Z^{B31}, Z^{B32}, Z^{B33} and Z^{B34} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

The compound represented by Formula (B-4) will be described in detail.

In Formula (B-4), M^{B4}, Y^{B41}, Y^{B44}, Y^{B45}, Y^{B48}, Y^{B42}, Y^{B43}, Y^{B46}, Y^{B47}, L^{B41}, L^{B42}, Z^{B43} and L^{B44} have the same definitions as corresponding M^{B1}, Y^{B11}, Y^{B14}, Y^{B15}, T^{B18}, Y^{B12}, Y^{B13}, Y^{B16}, Y^{B17}, L^{B11}, L^{B12}, L^{B13} and L^{B14} in Formula (B-1) respectively, and their preferable examples are also the same.

Z^{B41}, Z^{B42}, Z^{B43}, Z^{B44}, Z^{B45} and Z^{B46} each independently represent a nitrogen atom or a substituted or unsubstituted carbon atom. Each of Z^{B41}, Z^{B42}, Z^{B43}, Z^{B44}, Z^{B45} and Z^{B46} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

X^{B41} and X^{B42} each independently represent an oxygen atom, a sulfur atom or a substituted or unsubstituted nitrogen atom. Each of X^{B41} and X^{B42} is preferably an oxygen atom or a sulfur atom, and more preferably an oxygen atom.

Specific examples of the compounds represented by Formula (B-1) are illustrated below, but the invention is not limited thereto.

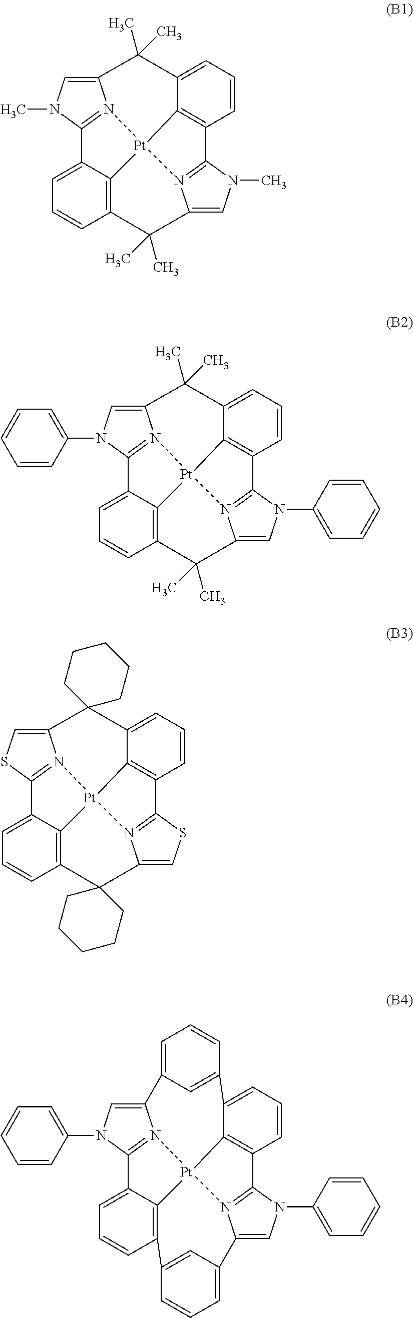

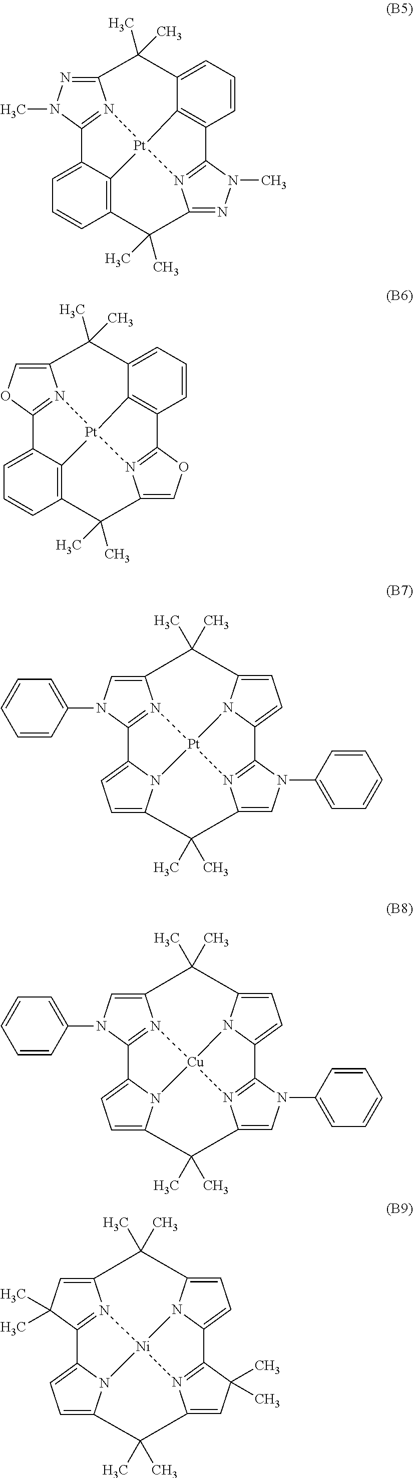

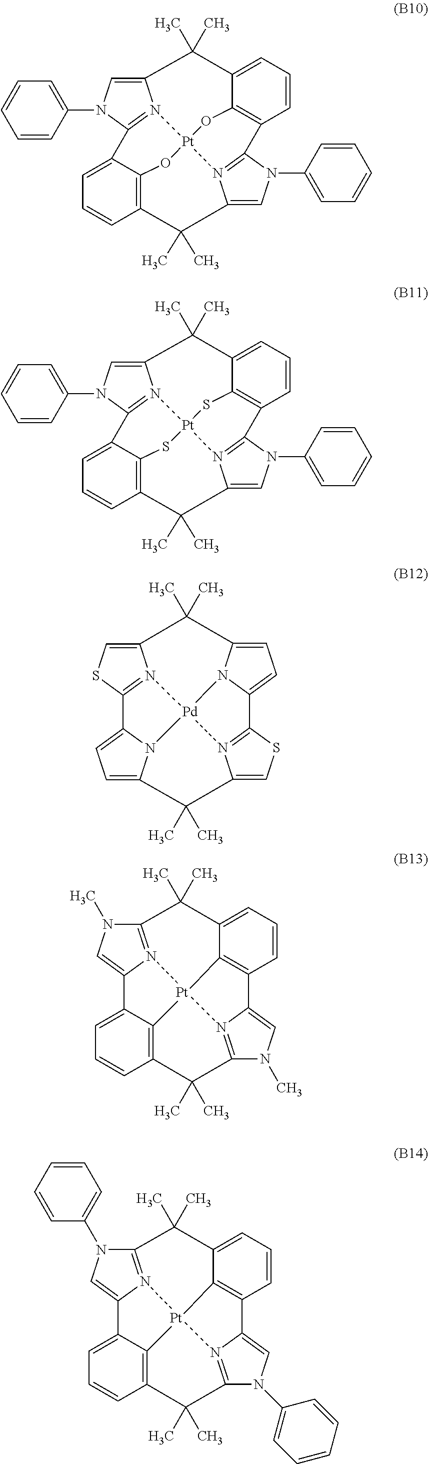

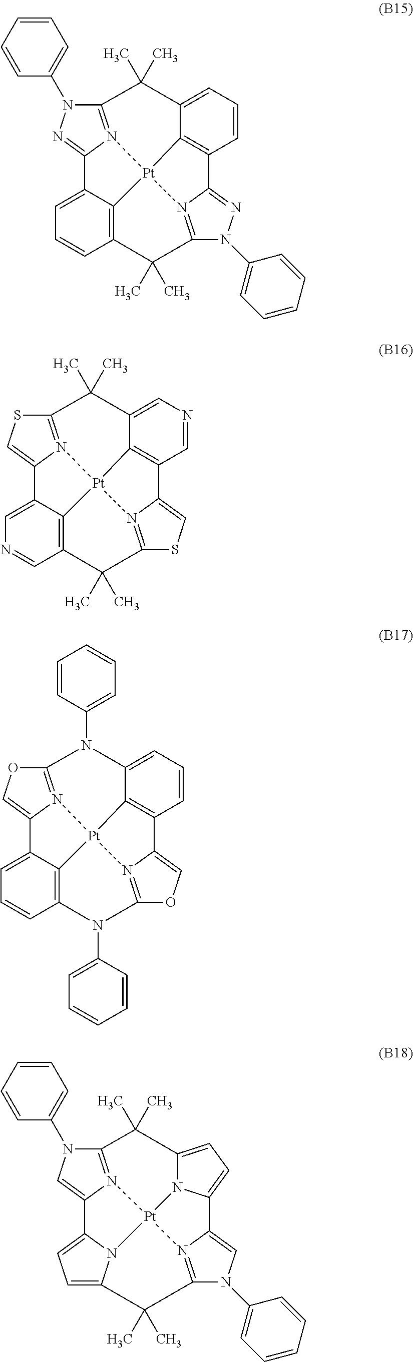

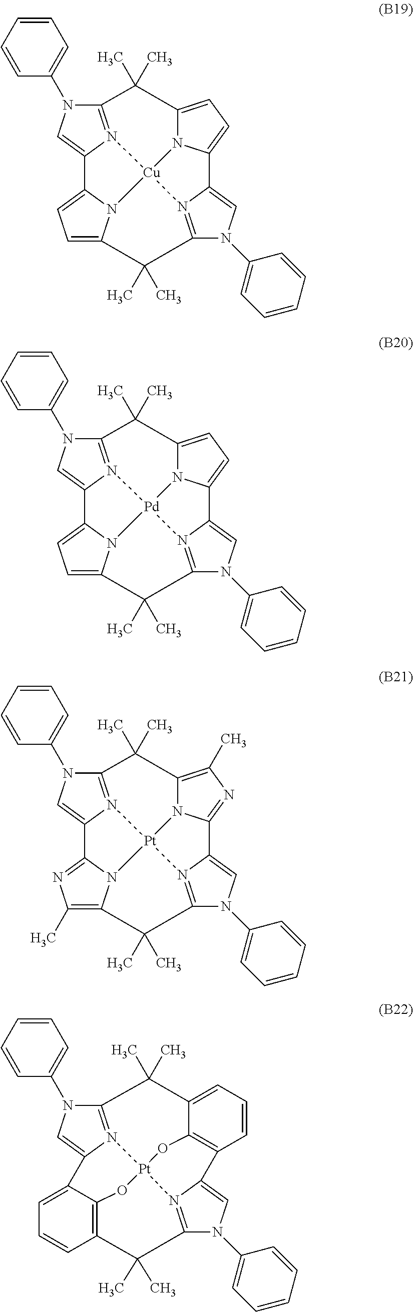

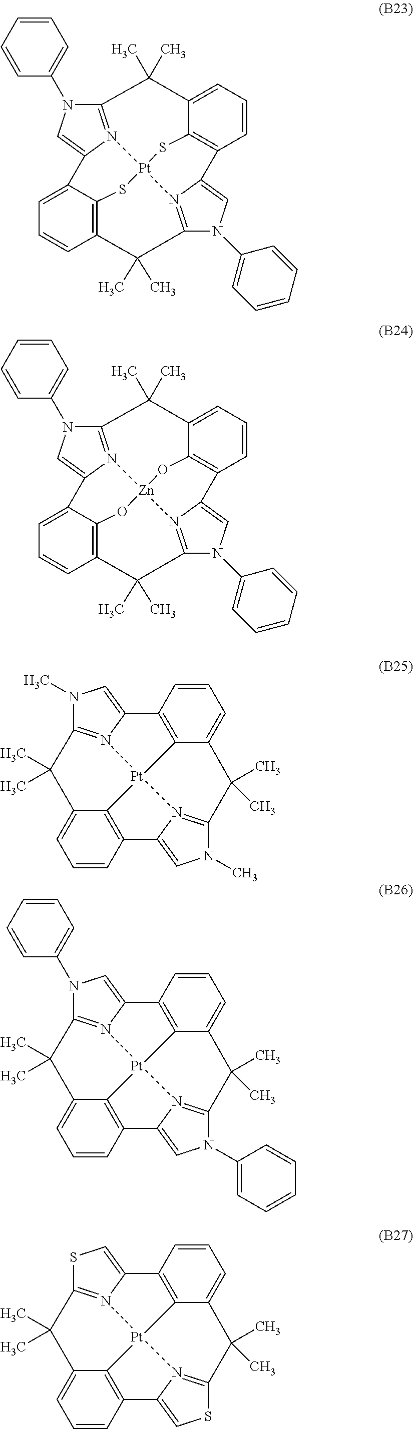

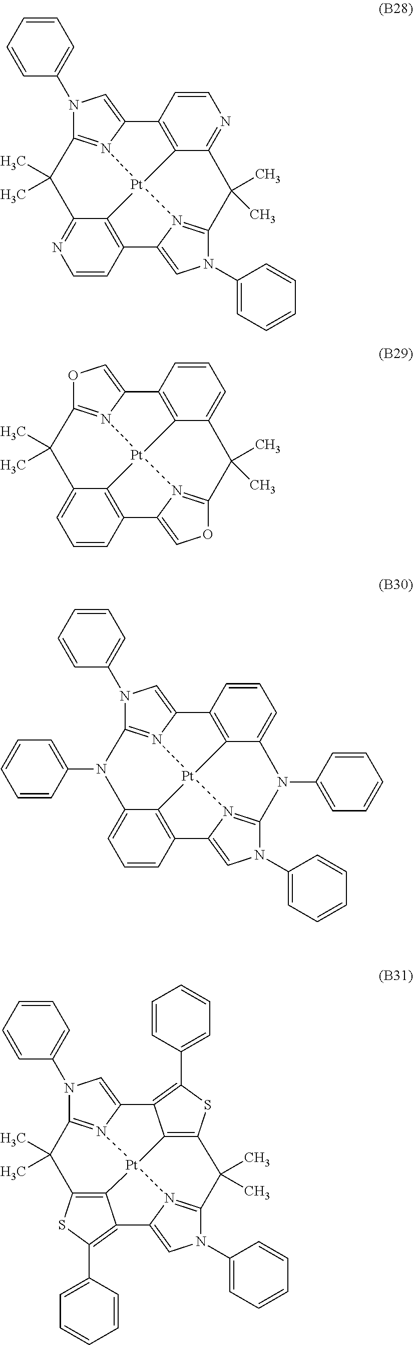

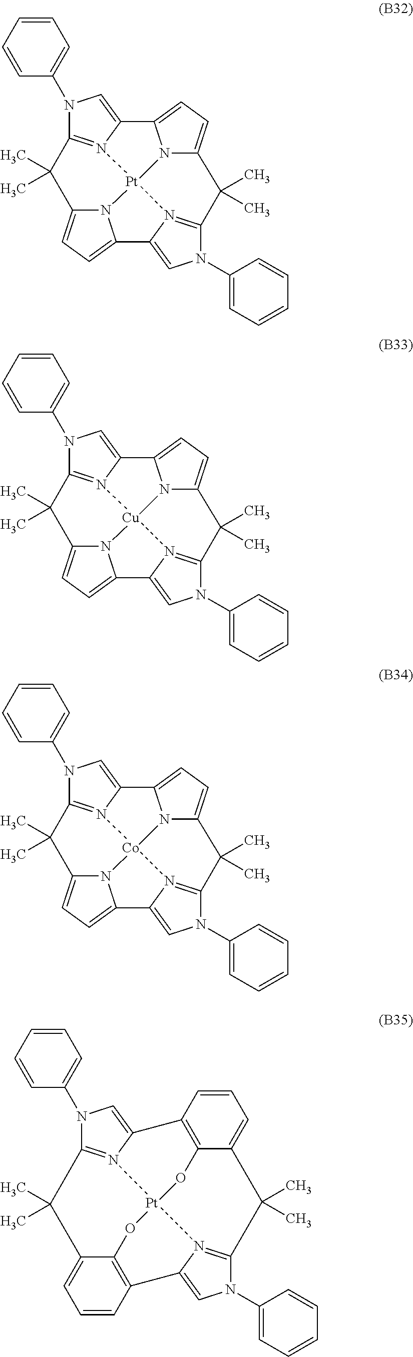

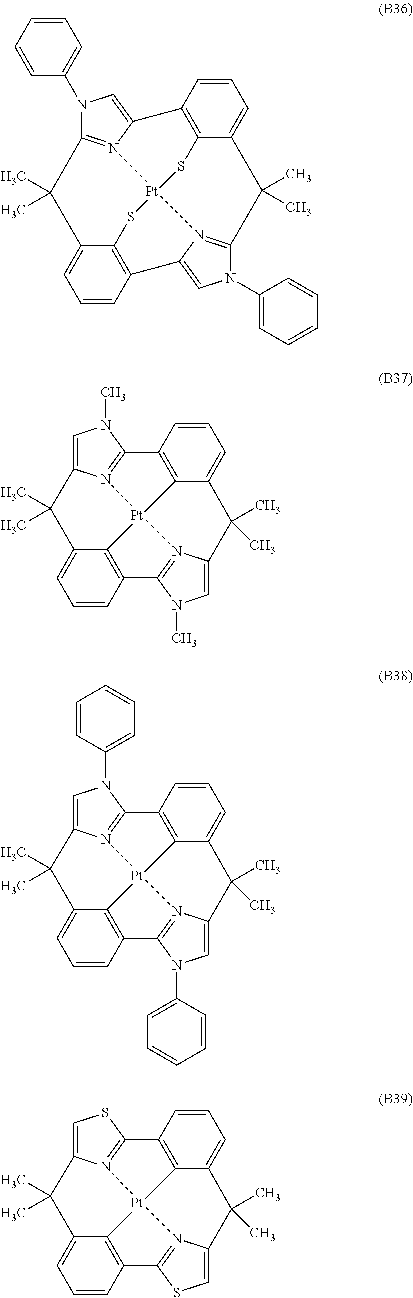

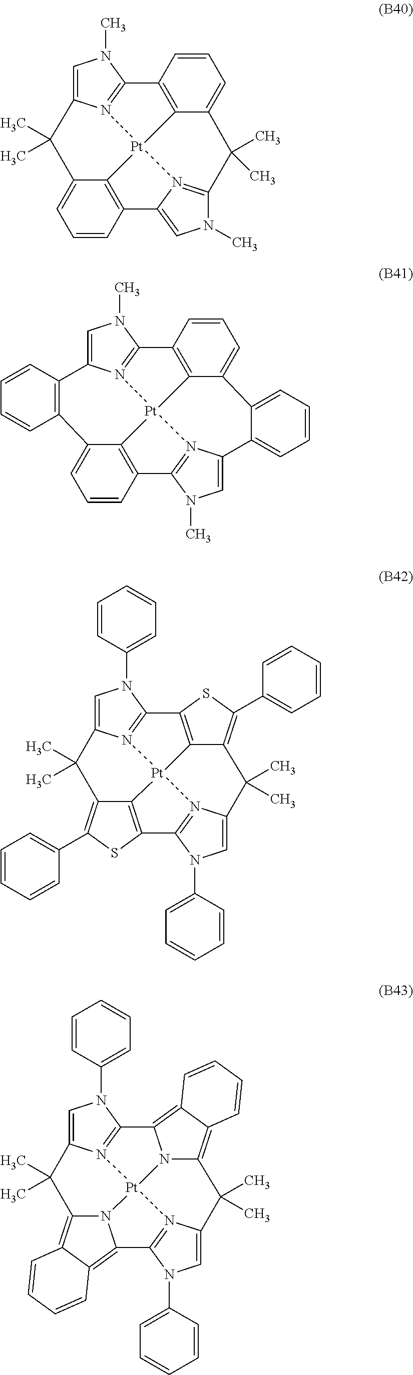

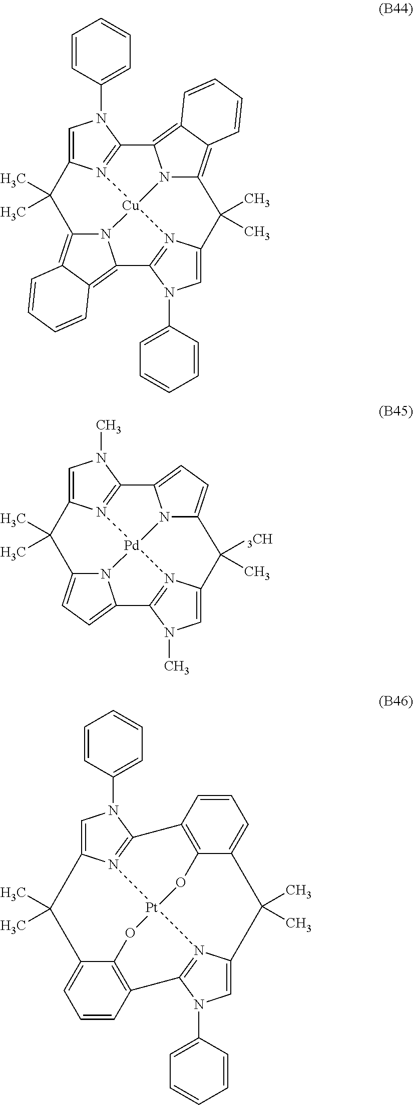

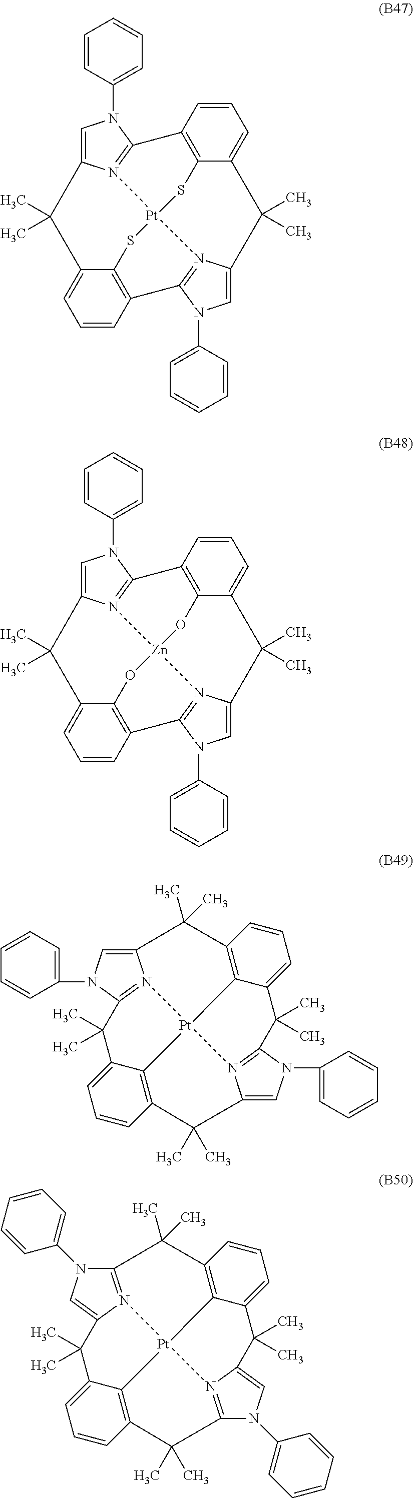

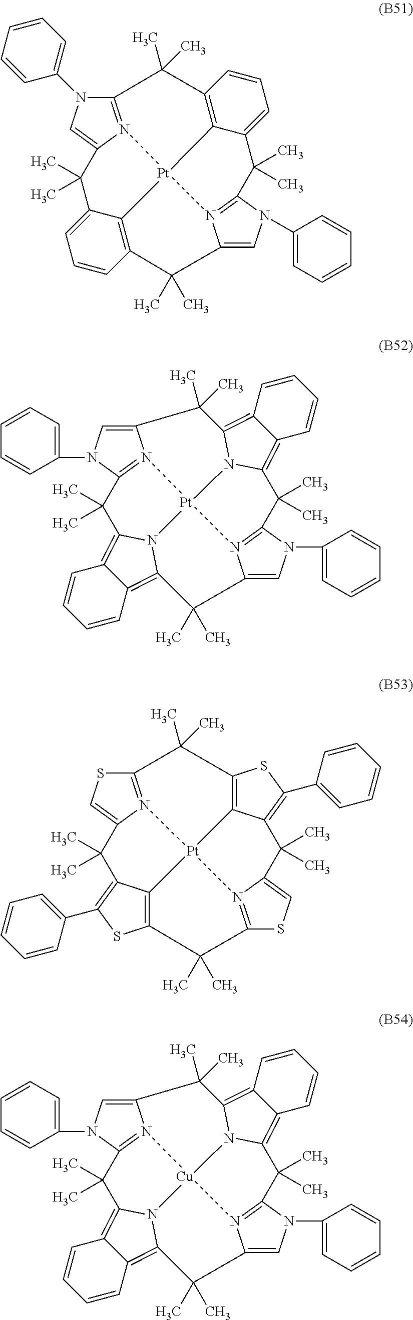

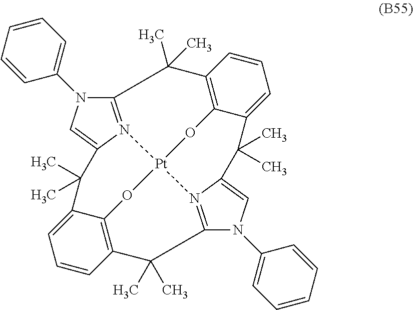

An example of preferable metal complexes usable in the invention is a compound represented by the following Formula (C-1).

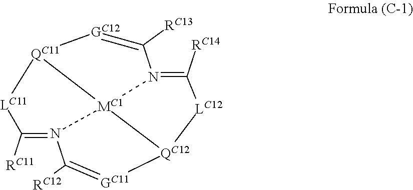

In Formula (C-1), M^{C1} represents a metal ion. R^{C11} and R^{C12} each independently represent a hydrogen atom or a substituent. When R^{C11} and R^{C12} represent substituents, the substituents may be bonded to each other to form a 5-membered ring. R^{C13} and R^{C14} each independently represent a hydrogen atom or a substituent. When R^{C13} and R^{C14} represent substituents, the substituents may be bonded to each other to form a 5-membered ring. G^{C11} and G^{C12} each independently represent a nitrogen atom or a substituted or unsubstituted carbon atom. L^{C11} and L^{C12} each independently represent a connecting group. Q^{C11} and Q^{C12} each independently represent a partial structure containing an atom bonded to M^{C1}. The bond between the atom in the partial structure and M^{C1} may be, for example, a covalent bond.

Formula (C-1) will be described in detail.

In Formula (C-1), M^{C1}, L^{C11}, L^{C12}, Q^{C11} and Q^{C12} have the same definitions as corresponding M^{A1}, L^{A11}, L^{A12}, Q^{A11} and Q^{A12} in Formula (A-1) respectively, and their preferable examples are also the same.

G^{C11} and G^{C12} each independently represent a nitrogen atom or a substituted or unsubstituted carbon atom, preferably a nitrogen atom or an unsubstituted carbon atom, and more preferably a nitrogen atom.

R^{C11} and R^{C12} each independently represent a hydrogen atom or a substituent. R^{C11} and R^{C12} may be bonded to each other to form a 5-membered ring. R^{C13} and R^{C14} each independently represent a hydrogen atom or a substituent. R^{C13} and R^{C14} may be bonded to each other to form a 5-membered ring.

The substituent represented by R^{C11}, R^{C12}, R^{C13}, R^{C14} may be, for example, an alkyl group (preferably having 1 to 30 carbon atoms, more preferably having 1 to 20 carbon atoms, particularly preferably having 1 to 10 carbon atoms; and examples thereof include a methyl group, an ethyl group, an iso-propyl group, a group, a tert-butyl group, a n-octyl group, a n-decyl group, a n-hexadecyl group, a cyclopropyl group, a cyclopentyl group, a cyclohexyl group, etc.), an alkenyl group (preferably having 2 to 30 carbon atoms, more preferably having 2 to 20 carbon atoms, particularly preferably having 2 to 10 carbon atoms; and examples thereof include a vinyl group, an allyl group, a 2-butenyl group, a 3-pentenyl group and the like), an alkynyl group (preferably having 2 to 30 carbon atoms, more preferably having 2 to 20 carbon atoms, particularly preferably having 2 to 10 carbon atoms; and examples thereof include a propargyl group, a 3-pentynyl group and the like), an aryl group (preferably having 6 to 30 carbon atoms, more preferably having 6 to 20 carbon atoms, particularly preferably having 6 to 12 carbon atoms; and examples thereof include phenyl, p-methylphenyl, naphthyl, anthranyl, etc.), an amino group (preferably having 0 to 30 carbon atoms, more preferably having 0 to 20 carbon atoms, particularly preferably having 0 to 10 carbon atoms; and examples thereof include an amino group, a methylamino group, a dimethylamino group, a diethylamino group, a dibenzylamino group, a diphenylamino group, a ditolylamino group and the like), an alkoxy group (preferably having 1 to 30 carbon atoms, more preferably having 1 to 20 carbon atoms, particularly preferably having 1 to 10 carbon atoms; and examples thereof include a methoxy group, an ethoxy group, a butoxy group, a 2-ethylhexyloxy group and the like), an aryloxy group (preferably a having 6 to 30 carbon atoms, more preferably having 6 to 20 carbon atoms, particularly preferably having 6 to 12 carbon atoms; and examples thereof include a phenyloxy group, a 1-naphthyloxy group, a 2-naphthyloxy group and the like),

a heterocyclic oxy group (preferably having 1 to 30 carbon atoms, more preferably having 1 to 20 carbon atoms, particularly preferably having 1 to 12 carbon atoms; and examples thereof include a pyridyloxy group, a pyrazyloxy group, a pyrimidyloxy group, a quinolyloxy group and the like), an acyl group (preferably having 1 to 30 carbon atoms, more preferably having 1 to 20 carbon atoms, particularly preferably having 1 to 12 carbon atoms; and examples thereof include an acetyl group, a benzoyl group, a formyl group, a pivaloyl group and the like), an alkoxycarbonyl group (preferably having 2 to 30 carbon atoms, more preferably having 2 to 20 carbon atoms, particularly preferably having 2 to 12 carbon atoms; and examples thereof include a methoxycarbonyl group, an ethoxycarbonyl group and the like), an aryloxycarbonyl group (preferably having 7 to 30 carbon atoms, more preferably having 7 to 20 carbon atoms, particularly preferably having 7 to 12 carbon atoms; and examples thereof include a phenyloxycarbonyl group and the like),

an acyloxy group (preferably having 2 to 30 carbon atoms, more preferably having 2 to 20 carbon atoms, particularly preferably having 2 to 10 carbon atoms; and examples thereof include an acetoxy group, a benzoyloxy group and the like), an acylamino group (preferably having 2 to 30 carbon atoms, more preferably having 2 to 20 carbon atoms, particularly preferably having 2 to 10 carbon atoms; and examples thereof include an acetylamino group, a benzoylamino group and the like), an alkoxycarbonylamino group (preferably having 2 to 30 carbon atoms, more preferably having 2 to 20 carbon atoms, particularly preferably having 2 to 12 carbon atoms; and examples thereof include a methoxycarbonylamino group and the like), an aryloxycarbonylamino group (preferably having 7 to 30 carbon atoms, more preferably having 7 to 20 carbon atoms, particularly preferably having 7 to 12 carbon atoms; and examples thereof include a phenyloxycarbonylamino group and the like),

an alkylthio group (preferably having 1 to 30 carbon atoms, more preferably having 1 to 20 carbon atoms, particularly preferably having 1 to 12 carbon atoms; and examples thereof include a methylthio group, an ethylthio group and the like), an arylthio group (preferably having 6 to 30 carbon atoms, more preferably having 6 to 20 carbon atoms, particularly preferably having 6 to 12 carbon atoms; and examples thereof include a phenylthio group and the like), a heterocyclic thio group (preferably having 1 to 30 carbon atoms, more preferably having 1 to 20 carbon atoms, particularly preferably having 1 to 12 carbon atoms; and examples thereof include a pyridylthio group, a 2-benzimidazolylthio group, a 2-benzoxazolylthio group, a 2-benzthiazolylthio group and the like), a halogen atom (such as a fluorine atom, chlorine atom, bromine atom, iodine atom), a cyano group,

a heterocyclic group (preferably having 1 to 30 carbon atoms, more preferably having 1 to 12 carbon atoms, and containing a heteroatom such as a nitrogen atom, oxygen atom or a sulfur atom, specifically an imidazolyl group, a pyridyl group, a quinolyl group, a furyl group, a thienyl group, a, piperidyl group, a morpholino group, a benzoxazolyl group, a benzimidazolyl group, a benzthiazolyl group, a carbazolyl group, azepinyl group and the like), a silyl group (preferably having 3 to 40 carbon atoms, more preferably having 3 to 30 carbon atoms, particularly preferably having 3 to 24 carbon atoms; and examples thereof include a trimethylsilyl group, a triphenylsilyl group and the like) or a silyloxy group (preferably having 3 to 40 carbon atoms, more preferably having 3 to 30 carbon atoms, particularly preferably having 3 to 24 carbon atoms; and examples thereof include a trimethylsilyloxy group, a triphenylsilyloxy group and the like).

The substituent represented by R^{C11}, R^{C12}, R^{C13} or R^{C14} is preferably an alkyl group, an aryl group, or such a group that R^{C11} and R^{C12}, or R^{C13} and R^{C14}, are bonded to each other to form a 5-membered ring. In a particularly preferable embodiment, R^{C11} and R^{C12}, or R^{C13} and R^{C14}, are bonded to each other to form a 5-membered ring.

The compound represented by Formula (C-1) is more preferably a compound represented by Formula (C-2).

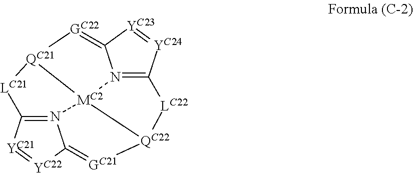

In Formula (C-2), M^{C2} represents a metal ion.

Y^{C21}, Y^{C22}, Y^{C23} and Y^{C24} each independently represent a nitrogen atom or a substituted or unsubstituted carbon atom. G^{C21} and G^{C22} each independently represent a nitrogen atom or a substituted or unsubstituted carbon atom. L^{C21} and L^{C22} each independently represent a connecting group. Q^{C21} and Q^{C22} each independently represent a partial structure containing an atom bonded to M^{C2}. The bond between the atom in the partial structure and M^{C2} may be, for example, a covalent bond.

Formula (C-2) will be described in detail.

In Formula (C-2), M^{C2}, L^{C21}, L^{C22}, Q^{C21}, Q^{C22}, G^{C21} and G^{C22} have the same definitions as corresponding M^{C1}, L^{C11}, L^{C12}, Q^{C11}, Q^{C12}, G^{C11} and G^{C12} in Formula (C-1) respectively, and their preferable examples are also the same.

Y^{C21}, Y^{C22}, Y^{C23} and Y^{C24} each independently represent a nitrogen atom or a substituted or unsubstituted carbon atom, preferably a substituted or unsubstituted carbon atom, and more preferably an unsubstituted carbon atom.

The compound represented by Formula (C-2) is more preferably a compound represented by the following Formula (C-3), (C-4) or (C-5).

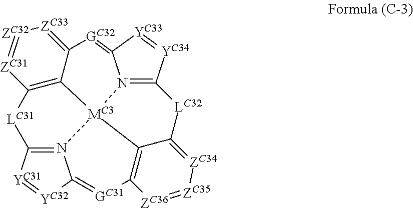

In Formula (C-3), M^{C3} represents a metal ion.

Y^{C31}, Y^{C32}, Y^{C33} and Y^{C34} each independently represent a nitrogen atom or a substituted or unsubstituted carbon atom. G^{C31} and G^{C32} each independently represent a nitrogen atom or a substituted or unsubstituted carbon atom. L^{C31} and L^{C32} each independently represent a connecting group. Z^{C31}, Z^{C32}, Z^{C33}, Z^{C34}, Z^{C35} and Z^{C36} each independently represent a nitrogen atom or a substituted or unsubstituted carbon atom.

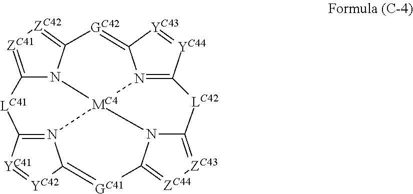

In Formula (C-4), M^{C4} represents a metal ion.

Y^{C41}, Y^{C42}, Y^{C43} and Y^{C44} each independently represent a nitrogen atom or a substituted or unsubstituted carbon atom. G^{C41} and G^{C42} each independently represent a nitrogen atom or a substituted or unsubstituted carbon atom. L^{C41} and L^{C42} each independently represent a connecting group. Z^{C41}, Z^{C42}, Z^{C43} and Z^{C44} each independently represent a nitrogen atom or a substituted or unsubstituted carbon atom.

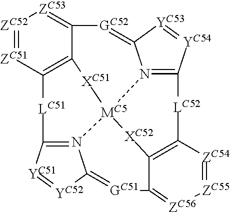

In Formula (C-5), M^{C5} represents a metal ion.

Y^{C51}, Y^{C52}, Y^{C53} and Y^{C54} each independently represent a nitrogen atom or a substituted or unsubstituted carbon atom. G^{C51} and G^{C52} each independently represent a nitrogen atom or a substituted or unsubstituted carbon atom. L^{C51} and L^{C52} each independently represent a connecting group. Z^{C51}, Z^{C52}, Z^{C53}, Z^{C54}, Z^{C55} and Z^{C56} each independently represent a nitrogen atom or a substituted or unsubstituted carbon atom. X^{C51} and X^{C52} each independently represent an oxygen atom, a sulfur atom or a substituted or unsubstituted nitrogen atom.

The compound represented by Formula (C-3) will be described in detail.

In Formula (C-3), M^{C3}, L^{C31}, L^{C32}, G^{C31} and G^{C32} have the same definitions as corresponding M^{C1}, L^{C11}, L^{C12}, G^{C11} and G^{C12} in Formula (C-1) respectively, and their preferable examples are also the same.

Z^{C31}, Z^{C32}, Z^{C33}, Z^{C34}, Z^{C35} and Z^{C36} each independently represent a nitrogen atom or a substituted or unsubstituted carbon atom. Each of Z^{C31}, Z^{C32}, Z^{C33}, Z^{C34}, Z^{C35} and Z^{C36} is preferably a substituted or unsubstituted carbon atom, and more preferably an unsubstituted carbon atom.

The compound represented by Formula (C-4) is described in more detail.

In Formula (C-4), M^{C4}, L^{C41}, L^{C42}, G^{C41} and G^{C42} have the same definitions as corresponding M^{C1}, L^{C11}, L^{C12}, G^{C11} and G^{C12} in Formula (C-1) respectively, and their preferable examples are also the same.

Z^{C41}, Z^{C42}, Z^{C43}, and Z^{C44} each independently represent a nitrogen atom or a substituted or unsubstituted carbon atom. Each of Z^{C41}, Z^{C42}, Z^{C43} and Z^{C44} is preferably a substituted or unsubstituted carbon atom, and more preferably an unsubstituted carbon atom.

The compound represented by Formula (C-5) is described in more detail.

M^{C5}, L^{C51}, L^{C52}, G^{C51} and G^{C52} have the same definitions as corresponding M^{C1}, L^{C11}, L^{C12}, G^{C11} and G^{C12} in Formula (C-1) respectively, and their preferable examples are also the same.

Z^{C51}, Z^{C52}, Z^{C53}, Z^{C54}, Z^{C55} and Z^{C56} each independently represent a nitrogen atom or a substituted or unsubstituted carbon atom. Each of Z^{C51}, Z^{C52}, Z^{C53}, Z^{C54}, Z^{C55} and Z^{C56} is preferably a substituted or unsubstituted carbon atom, and more preferably an unsubstituted carbon atom.

X^{C51} and X^{C52} each independently represent an oxygen atom, a sulfur atom or a substituted or unsubstituted nitrogen atom. Each of X^{C51} and X^{C52} is preferably an oxygen atom or a sulfur atom, and more preferably an oxygen atom.

Specific examples of the compounds represented by Formula (C-1) are illustrated below, however, the invention is not limited thereto.

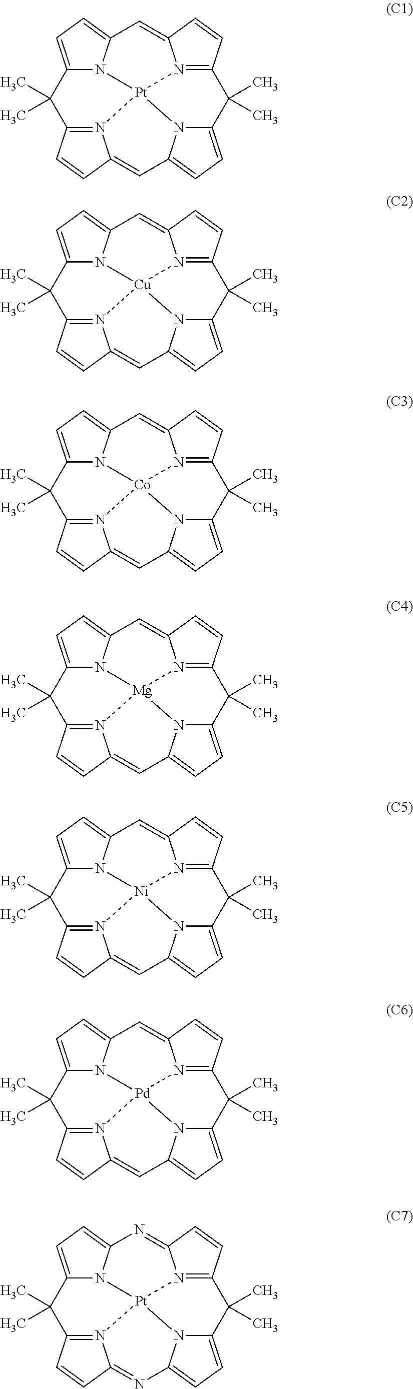

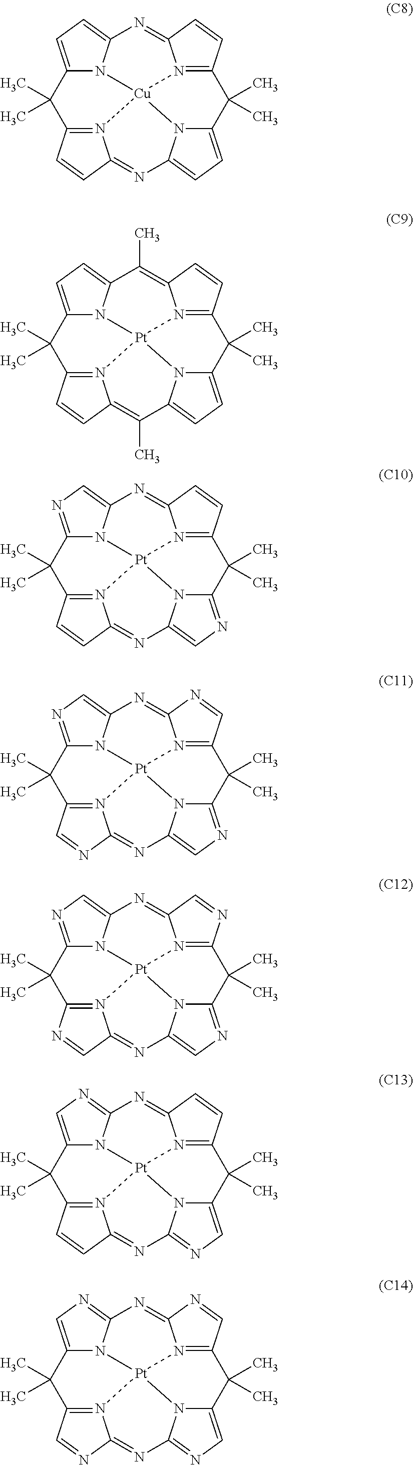

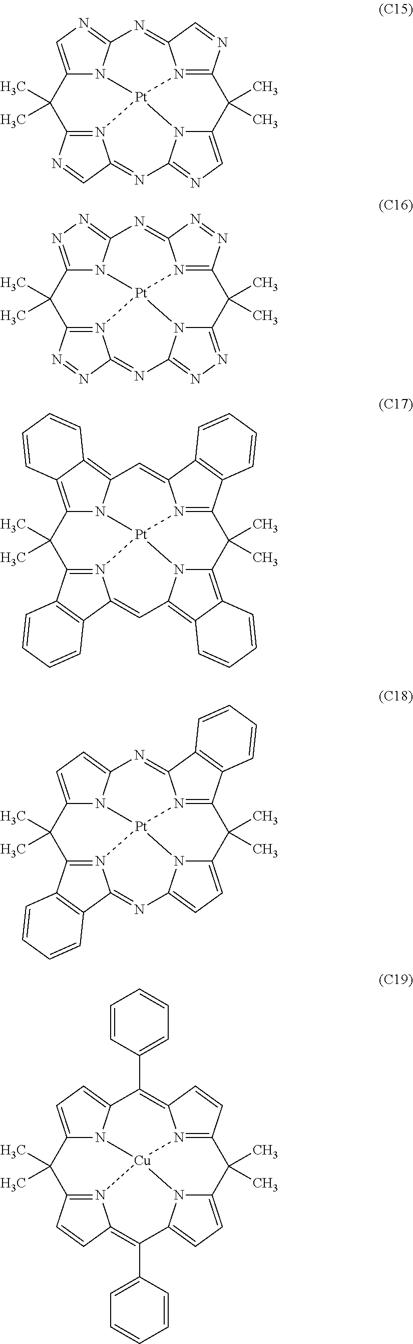

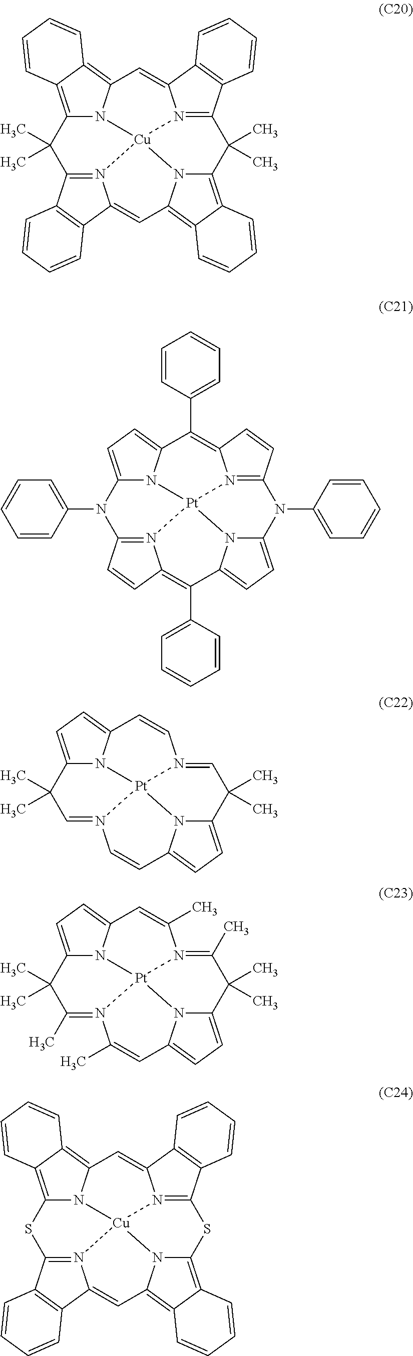

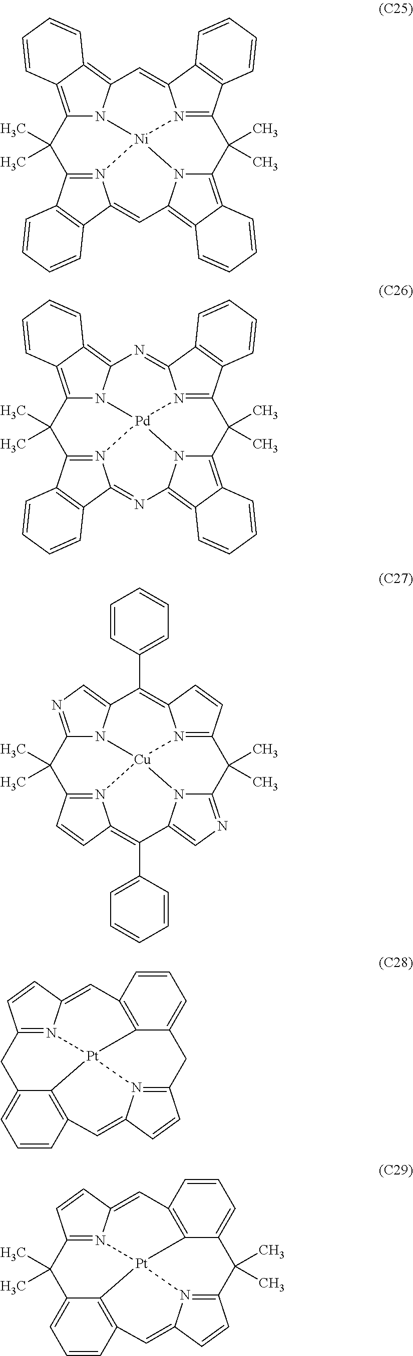

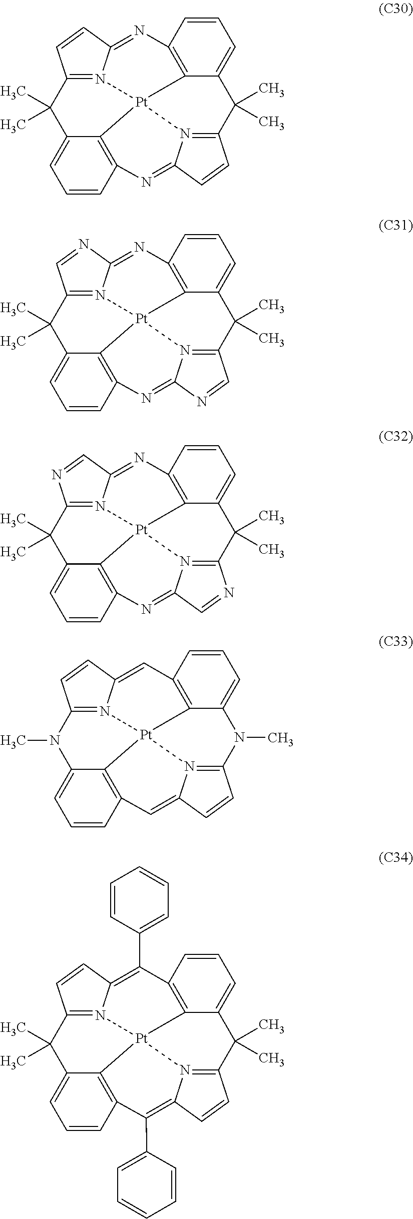

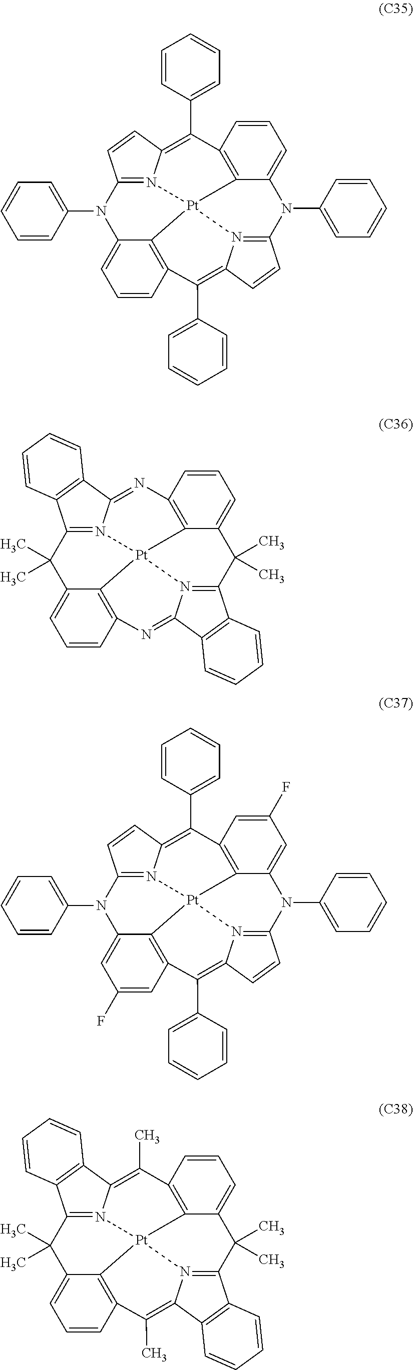

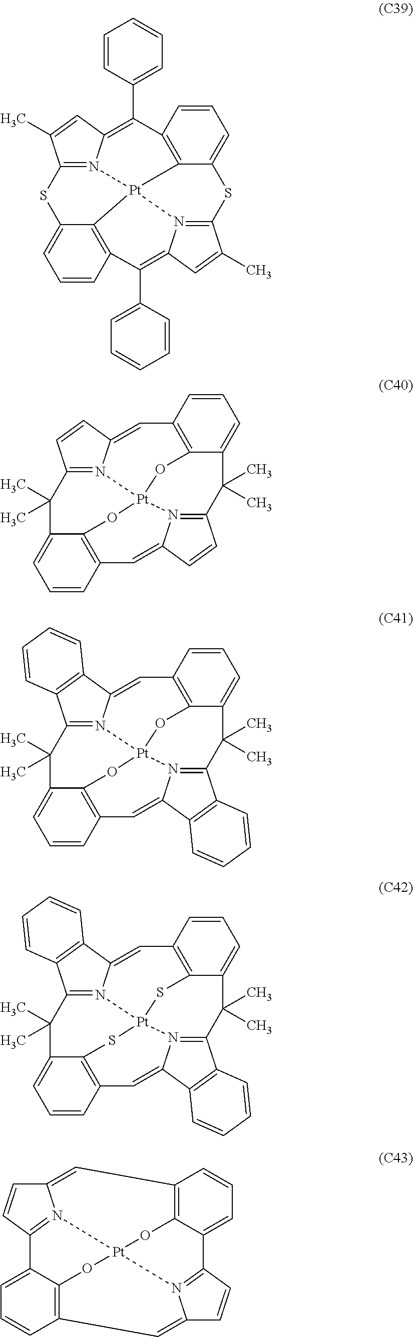

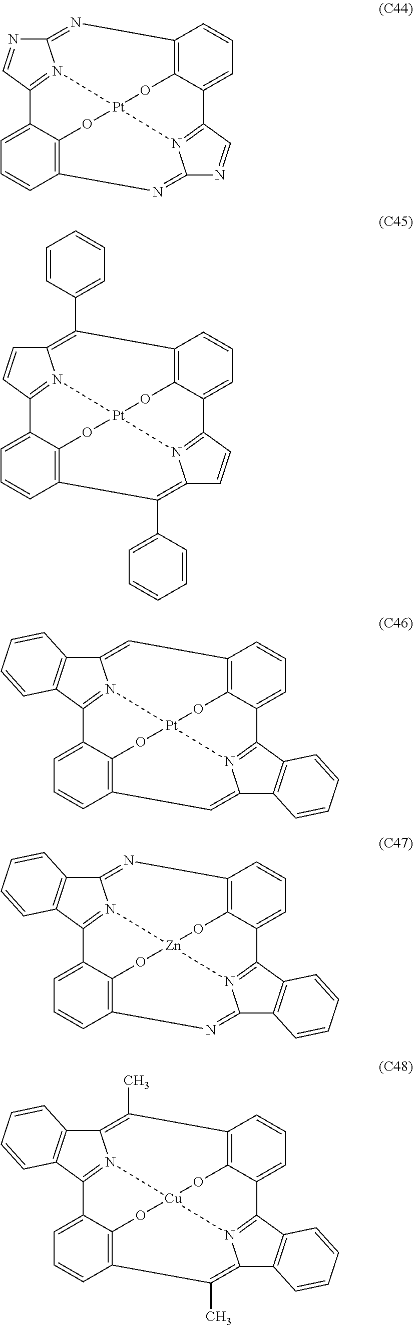

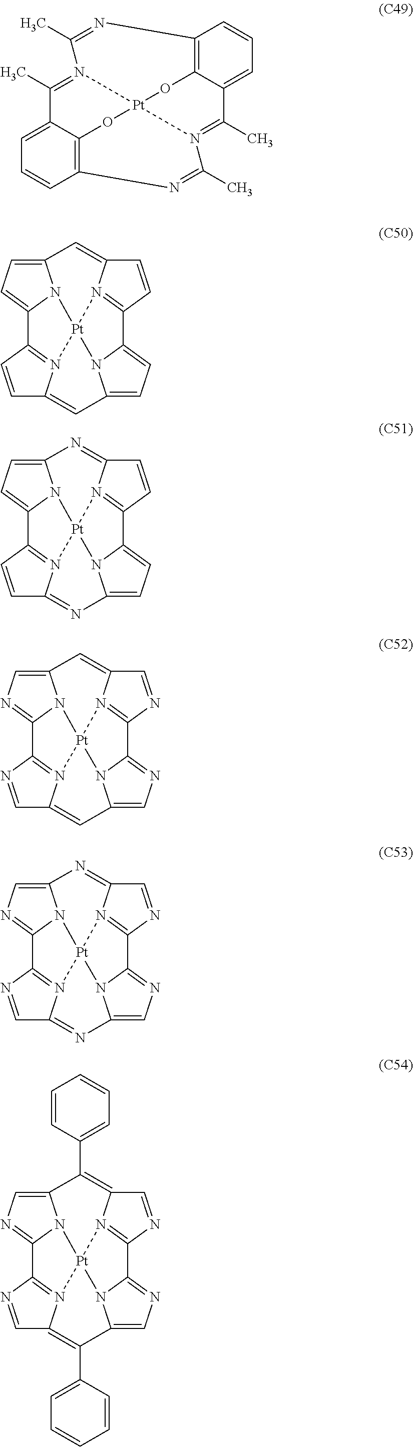

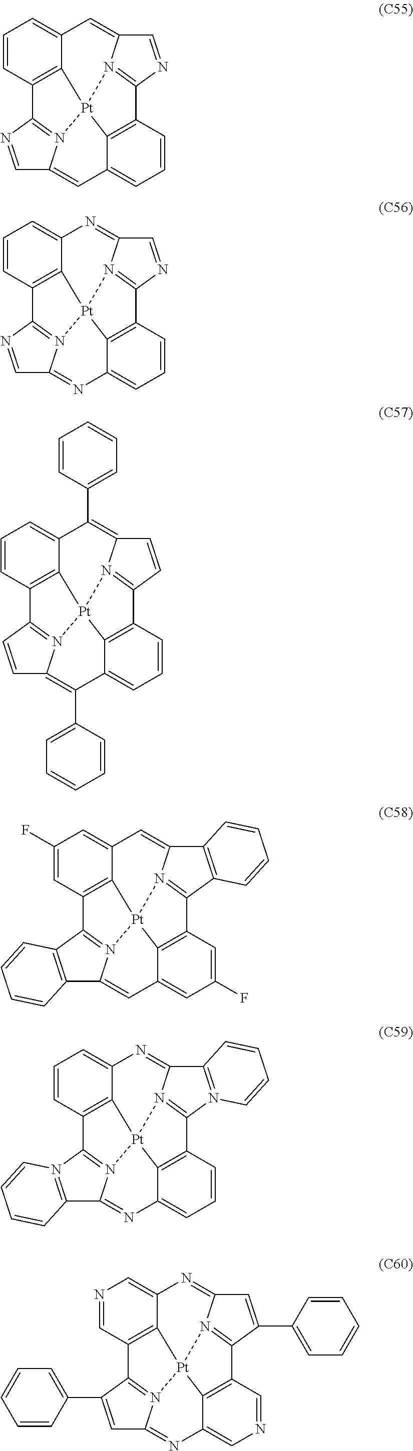

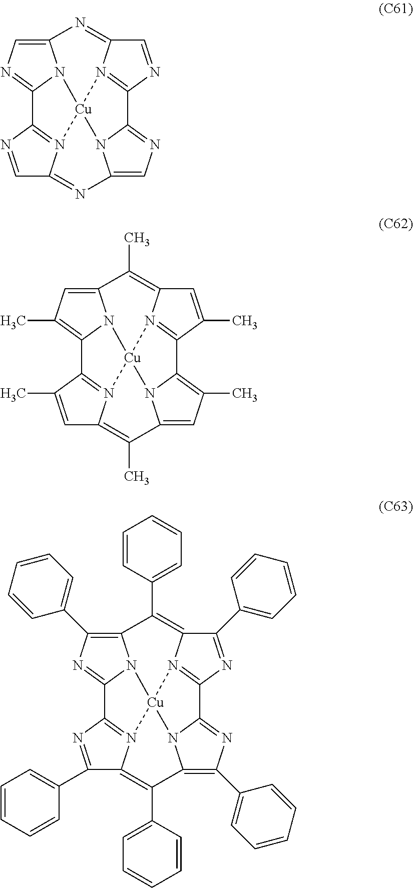

An example of preferable metal complexes usable in the invention is a compound represented by the following Formula (D-1).

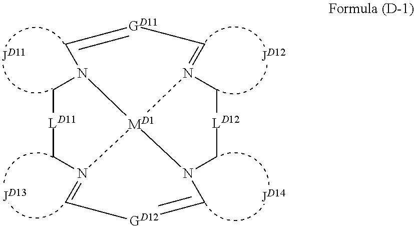

In Formula (D-1), M^{D1} represents a metal ion.

G^{D11} and G^{D12} each independently represent a nitrogen atom or a substituted or unsubstituted carbon atom. J^{D11}, J^{D12}, J^{D13} and J^{D14} each independently represent an atomic group necessary for forming a 5-membered ring. L^{D11} and L^{D12} each independently represent a connecting group.

Formula (D-1) will be described in detail.

In Formula (D-1), M^{D1}, L^{D11} and L^{D12} have the same definitions as corresponding M^{A1}, L^{A11} and L^{A12} in Formula (A-1) respectively, and their preferable examples are also the same.

G^{D11} and G^{D12} have the same definitions as corresponding G^{C11} and G^{C12} in Formula (C-1) respectively, and their preferable examples are also the same.

J^{D11}, J^{D12}, J^{D13} and J^{D14} each independently represent such an atomic group that a nitrogen-containing 5-membered heterocycle containing the atomic group is formed.

The compound represented by Formula (D-1) is more preferably a compound represented by the following Formula (D-2), (D-3) or (D-4).

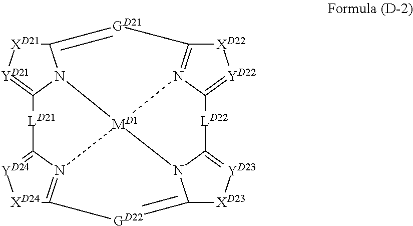

In Formula (D-2), M^{D2} represents a metal ion.

G^{D21} and G^{D22} each independently represent a nitrogen atom or a substituted or unsubstituted carbon atom.

Y^{D21}, Y^{D22}, Y^{D23} and Y^{D24} each independently represent a nitrogen atom or a substituted or unsubstituted carbon atom.

X^{D21}, X^{D22}, X^{D23} and X^{D24} each independently represent an oxygen atom, a sulfur atom, —NR^{D21}— or —C(R^{D22})R^{D23}—.

R^{D21}, R^{D22} and R^{D23} each independently represent a hydrogen atom or a substituent. L^{D21} and L^{D22} each independently represent a connecting group.

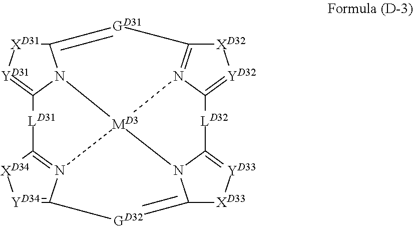

In Formula (D-3), M^{D3} represents a metal ion.

G^{D31} and G^{D32} each independently represent a nitrogen atom or a substituted or unsubstituted carbon atom.

Y^{D31}, Y^{D32}, Y^{D33} and Y^{D34} each independently represent a nitrogen atom or a substituted or unsubstituted carbon atom.

X^{D31}, X^{D32}, X^{D33} and X^{D34} each independently represent an oxygen atom, a sulfur atom —NR^{D31}— or —C(R^{D32})R^{D33}—.

R^{D31}, R^{D32} and R^{D33} each independently represent a hydrogen atom or a substituent. L^{D31} and L^{D32} each independently represent a connecting group.

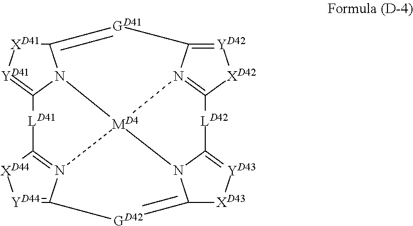

In Formula (D-4), M^{D4} represents a metal ion.

G^{D41} and G^{D42} each independently represent a nitrogen atom or a substituted or unsubstituted carbon atom.

Y^{D41}, Y^{D42}, Y^{D43} and Y^{D44} each independently represent a nitrogen atom or a substituted or unsubstituted carbon atom.

X^{D41}, X^{D42}, X^{D43} and X^{D44} each independently represent an oxygen atom, a sulfur atom, —NR^{D41}— or —C(R^{D42})R^{D43}—. R^{D41}, R^{D42} and R^{D43} each independently represent a hydrogen atom or a substituent. L^{D41} and L^{D42} each independently represent a connecting group.

Formula (D-2) will be described in detail.

In Formula (D-2), M^{D2}, L^{D21}, L^{D22}, G^{D21} and G^{D22} have the same definitions as corresponding M^{D1}, L^{D11}, L^{D12}, G^{D11} and G^{D12} in Formula (D-1) respectively, and their preferable examples are also the same.

Y^{D21}, Y^{D22}, Y^{D23} and Y^{D24} each independently represent a nitrogen atom or a substituted or unsubstituted carbon atom, preferably a substituted or unsubstituted carbon atom, and more preferably an unsubstituted carbon atom.

X^{D21}, X^{D22}, X^{D23} and X^{D24} each independently represent an oxygen atom, a sulfur atom, —NR^{D21}— or —C(R^{D22})R^{D23}—, preferably a sulfur atom, —NR^{D21}— or —C(R^{D22})R^{D23}—, more preferably —NR^{D21}— or —C(R^{D22})R^{D23}—, and further more preferably —NR^{D21}—.

R^{D21}, R^{D22} and R^{D23} each independently represent a hydrogen atom or a substituent. The substituent represented by R^{D21}, R^{D22} or R^{D23} may be, for example, an alkyl group (preferably those having 1 to 20 carbon atoms, more preferably those having 1 to 12 carbon atoms, particularly preferably those having 1 to 8 carbon atoms, and examples thereof include a methyl group, an ethyl group, an iso-propyl group, a tert-butyl group, a n-octyl group, a n-decyl group, a n-hexadecyl group, a cyclopropyl group, a cyclopentyl group, a cyclohexyl group and the like), an alkenyl group (preferably those having 2 to 20 carbon atoms, more preferably those having 2 to 12 carbon atoms, particularly preferably those having 2 to 8 carbon atoms, and examples thereof include a vinyl group, an allyl group, a 2-butenyl group, a 3-pentenyl group and the like), an alkynyl group (preferably those having 2 to 20 carbon atoms, more preferably those having 2 to 12 carbon atoms, particularly preferably those having 2 to 8 carbon atoms, and examples thereof include a propargyl group, a 3-pentynyl group and the like),

an aryl group (preferably those having 6 to 30 carbon atoms, more preferably those having 6 to 20 carbon atoms, particularly preferably those having 6 to 12 carbon atoms group, and examples thereof include a phenyl group, a p-methylphenyl group, a naphthyl group, and the like), a substituted carbonyl group (preferably those having 1 to 20 carbon atoms, more preferably those having 1 to 16 carbon atoms, particularly preferably those having 1 to 12 carbon atoms group, and examples thereof include a acetyl group, a benzoyl group, a methoxycarbonyl group, a phenyloxycarbonyl group, a dimethylaminocarbonyl group, a phenylaminocarbonyl group, and the like), a substituted sulfonyl group (preferably those having 1 to 20 carbon atoms, more preferably those having 1 to 16 carbon atoms, particularly preferably those having 1 to 12 carbon atoms group, and examples thereof include a mesyl group, a tosyl group and the like), or

a heterocyclic group (including an aliphatic heterocyclic group and aromatic heterocyclic group, preferably those having 1 to 50 carbon atoms, more preferably those having 1 to 30 carbon atoms, more preferably those having 2 to 23 carbon atoms, preferably containing an oxygen atom, a sulfur atom or a nitrogen atom, and examples thereof include an imidazolyl group, a pyridyl group, a furyl group, a piperidyl group, a morpholino group, a benzoxazolyl group, a triazolyl group and the like). Each of R^{D21}, R^{D22} and R^{D23} is preferably an alkyl group, aryl group or aromatic heterocyclic group, more preferably an alkyl or aryl group, and still more preferably an aryl group.

Formula (D-3) will be described in detail.

In Formula (D-3), M^{D3}, L^{D31}, L^{D32}, G^{D31} and G^{D32} have the same definitions as corresponding M^{D1}, L^{D11}, L^{D12}, G^{D11} and G^{D12} in Formula (D-1) respectively, and their preferable examples are also the same.

X^{D31}, X^{D32}, X^{D33} and X^{D34} have the same definitions as corresponding X^{D21}, X^{D22}, X^{D23} and X^{D24} in Formula (D-2) respectively, and their preferable examples are also the same.

Y^{D31}, Y^{D32}, Y^{D33} and Y^{D34} have the same definitions as corresponding Y^{D21} Y^{D22}, Y^{D23} and Y^{D24} in Formula (D-2) respectively, and their preferable examples are also the same.

Formula (D-4) will be described in detail.

In Formula (D-4), M^{D4}, L^{D41}, L^{D42}, G^{D41} and G^{D42} have the same definitions as corresponding M^{D1}, L^{D11}, L^{D12}, G^{D11} and G^{D12} in Formula (D-1) respectively, and their preferable examples are also the same.

X^{D41}, X^{D42}, X^{D43} and X^{D44} have the same definitions as corresponding X^{D21}, X^{D22}, R^{D23} and X^{D24} in Formula (D-2) respectively, and their preferable examples are also the same. Y^{D41}, Y^{D42}, Y^{D43} and Y^{D44} have the same definitions as corresponding Y^{D21}, Y^{D22}, Y^{D23} and Y^{D24} in Formula (D-2) respectively, and their preferable examples are also the same.

Specific examples of the compounds represented by Formula (D-1) are illustrated below, but the invention is not limited thereto.

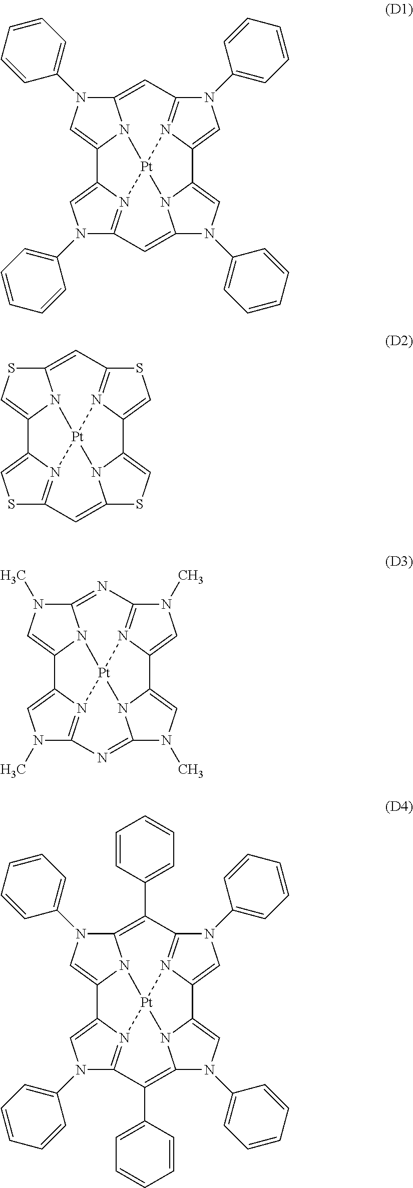

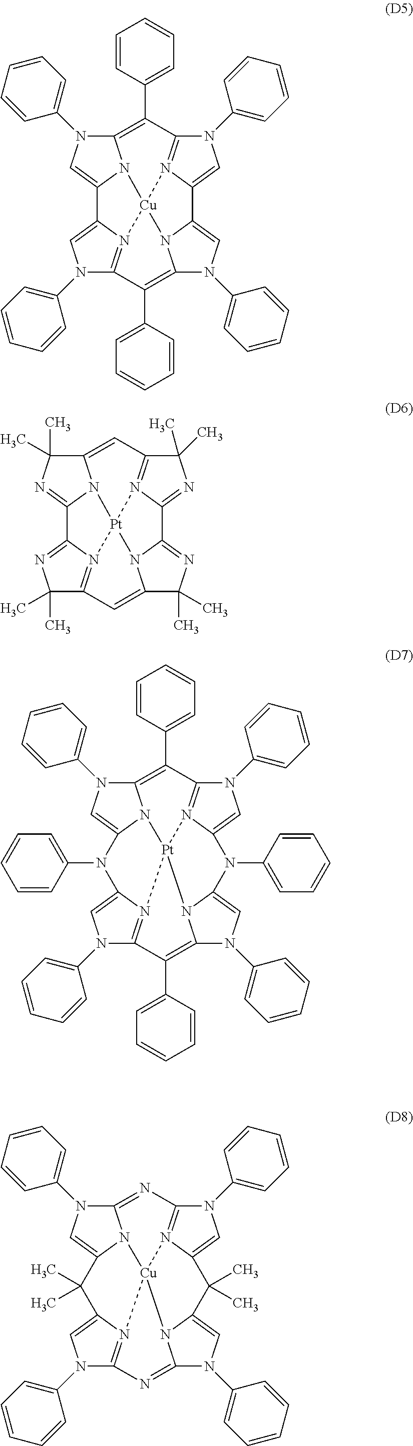

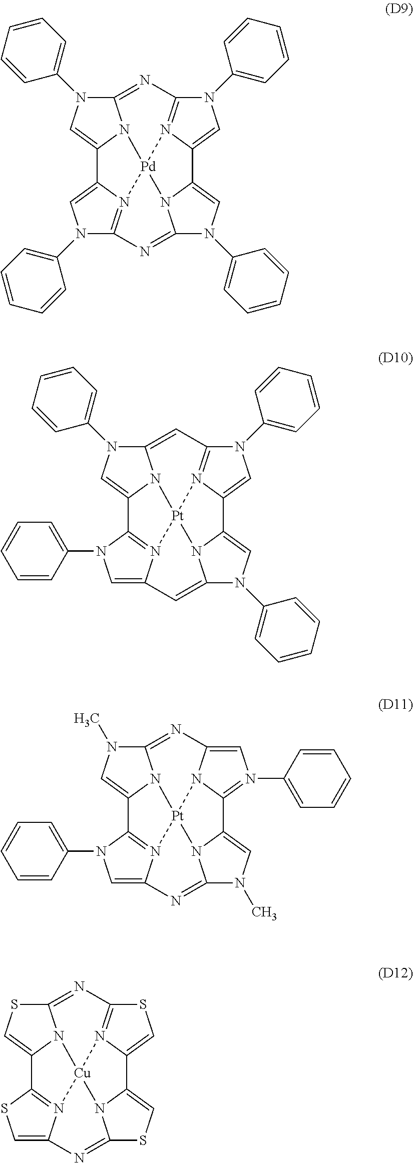

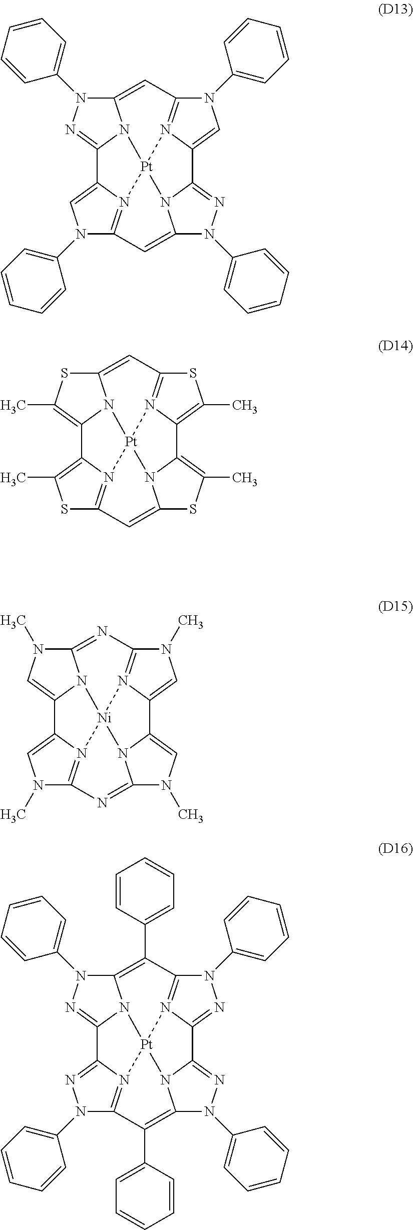

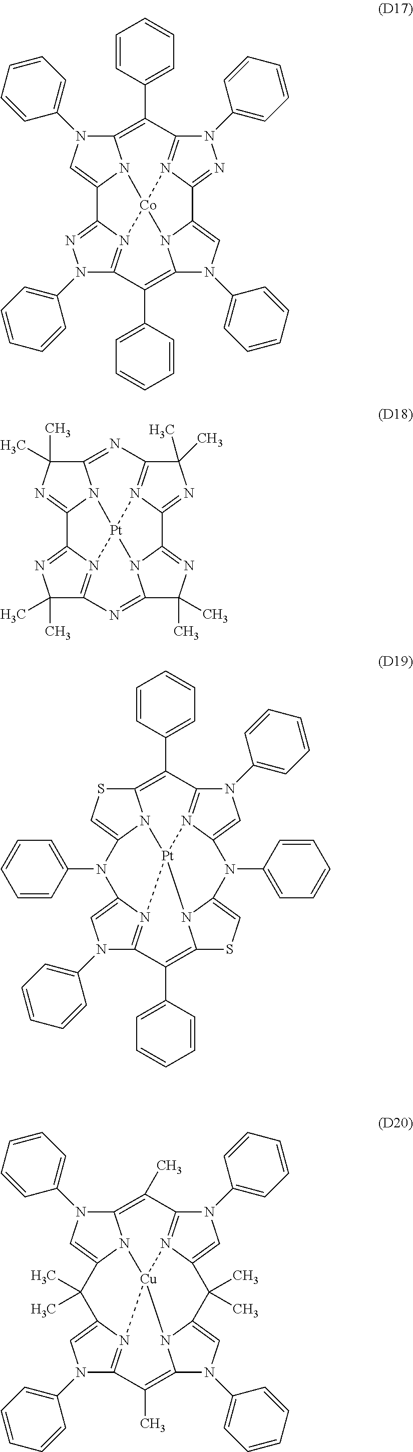

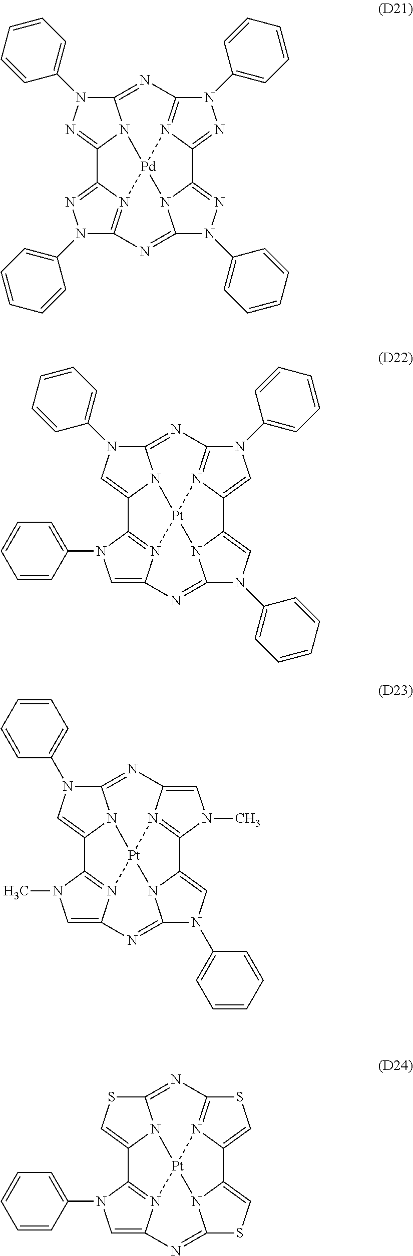

An example of preferable metal complexes usable in the invention is a compound represented by the following Formula (E-1).

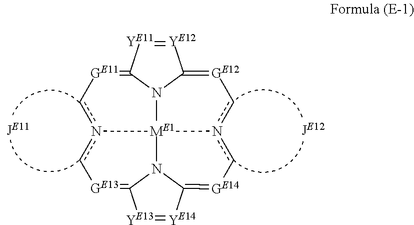

In Formula (E-1), M^{E1} represents a metal ion. J^{E11} and J^{E12} each independently represent an atomic group necessary for forming a 5-membered ring. G^{E11}, G^{E12}, G^{E13} and G^{E14} each independently represent a nitrogen atom or a substituted or unsubstituted carbon atom. Y^{E11}, Y^{E12}, Y^{E13} and Y^{E14} each independently represent a nitrogen atom or a substituted or unsubstituted carbon atom.

Formula (E-1) will be described in detail.

M^{E1} has the same definition as M^{A1} in Formula (A-1), and its preferable examples are also the same. G^{E11}, G^{E12}, G^{E13} and G^{E14} have the same definition as G^{C11} and G^{C12} in Formula (C-1), and their preferable examples are also the same.

J^{E11} and J^{E12} have the same definition as J^{D11} to J^{D14} in Formula (D-1), and their preferable examples are also the same. Y^{E11}, Y^{E12}, Y^{E13} and Y^{E14} have the same definitions as corresponding Y^{C21} to Y^{C24} in Formula (C-2) respectively, and their preferable examples are also the same.

The compound represented by Formula (E-1) is more preferably a compound represented by the following Formula (E-2) or (E-3).

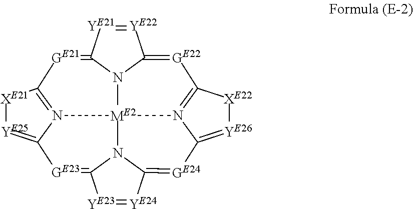

In Formula (E-2), M^{E2} represents a metal ion. G^{E21}, G^{E22}, G^{E23} and G^{E24} each independently represent a nitrogen atom or a substituted or unsubstituted carbon atom. Y^{E21}, Y^{E22}, Y^{E23}, Y^{E24}, Y^{E25} and Y^{E26} each independently represent a nitrogen atom or a substituted or unsubstituted carbon atom.

X^{E21} and X^{E22} each independently represent an oxygen atom, a sulfur atom, —NR^{E21}— or —C(R^{E22})R^{E23}—. R^{E21}, R^{E22} and R^{E23} each independently represent a hydrogen atom or a substituent.

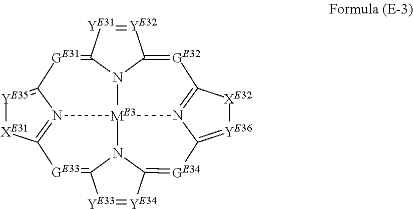

In Formula (E-3), M^{E3} represents a metal ion. G^{E31}, G^{E32}, G^{E33} and G^{E34} each independently represent a nitrogen atom or a substituted or unsubstituted carbon atom. Y^{E31}, Y^{E32}, Y^{E33}, Y^{E34}, Y^{E35} and Y^{E36} each independently represent a nitrogen atom or a substituted or unsubstituted carbon atom. X^{E31} and X^{E32} each independently represent an oxygen atom, a sulfur atom, —NR^{E31}— or —C(R^{E32})R^{E33}— R^{E31}, R^{E32} and R^{E33} each independently represent a hydrogen atom or a substituent.

Formula (E-2) will be described in detail.

In Formula (E-2), M^{E2}, G^{E21}, G^{E22}, G^{E23}, G^{E24}, Y^{E21}, Y^{E22}, Y^{E23} and Y^{E24} have the same definitions as corresponding M^{E1}, G^{E11}, G^{E12}, G^{E13}, G^{E14}, Y^{E11}, Y^{E12}, Y^{E13} and Y^{E14} in Formula (E-1) respectively, and their preferable examples are also the same. X^{E21} and X^{E22} have the same definitions corresponding X^{D21} and X^{D22} in Formula (D-2) respectively, and their preferable examples are also the same.

Formula (E-3) will be described in detail.

In Formula (E-3), M^{E3}, G^{E31}, G^{E32}, G^{E33}, G^{E34}, Y^{E31}, Y^{E32}, Y^{E33} and Y^{E34} have the same definitions as corresponding M^{E1}, G^{E11}, G^{E12}, G^{E13}, G^{E14}, Y^{E11}, Y^{E12}, Y^{E13} and Y^{E14} in Formula (E-1) respectively, and their preferable examples are also the same. X^{E31} and X^{E32} have the same definitions as corresponding X^{E21} and X^{E22} in Formula (E-2) respectively, and their preferable examples are also the same.

Specific examples of the compounds represented by Formula (E-1) are illustrated below, but the invention is not limited thereto.

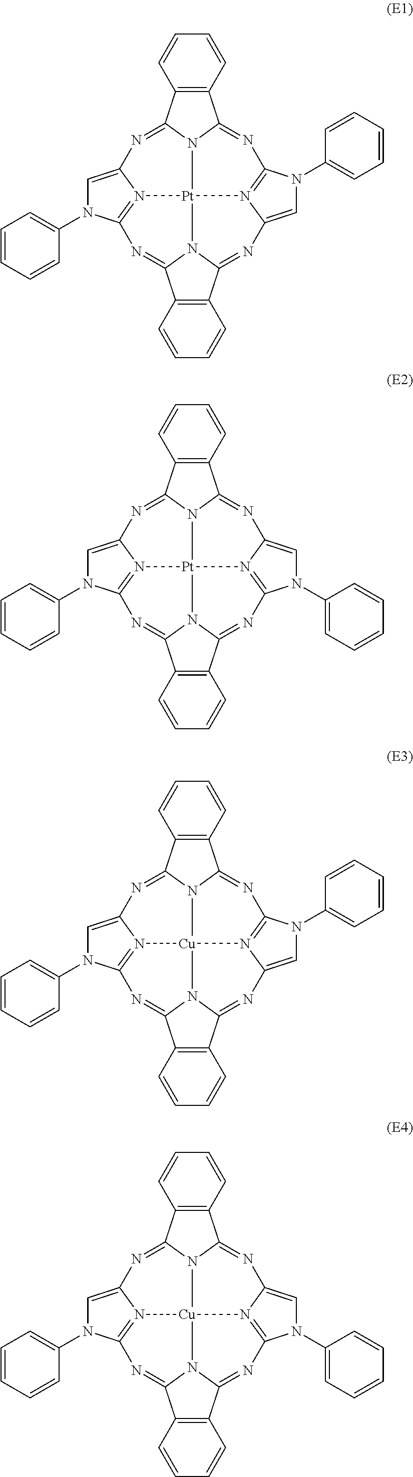

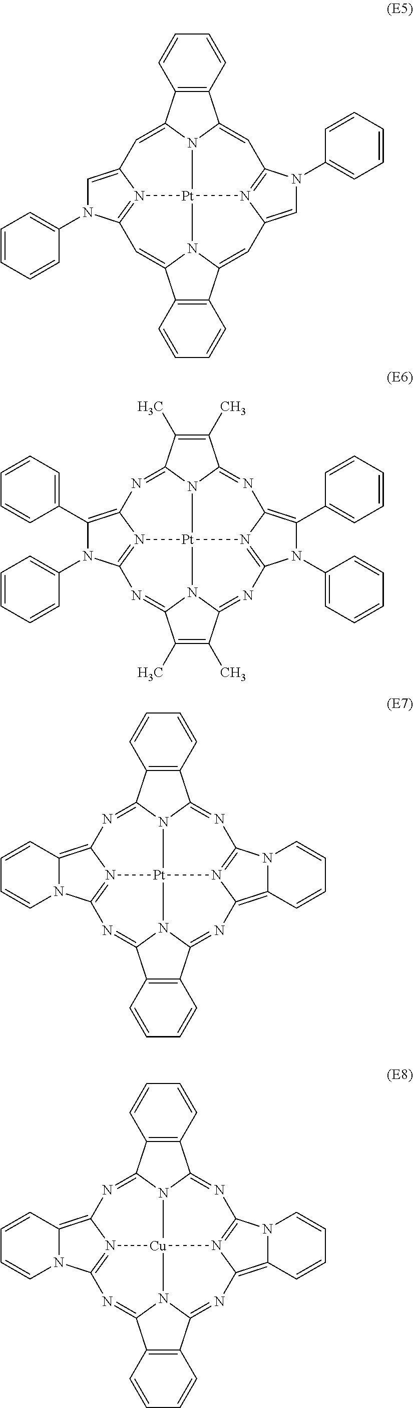

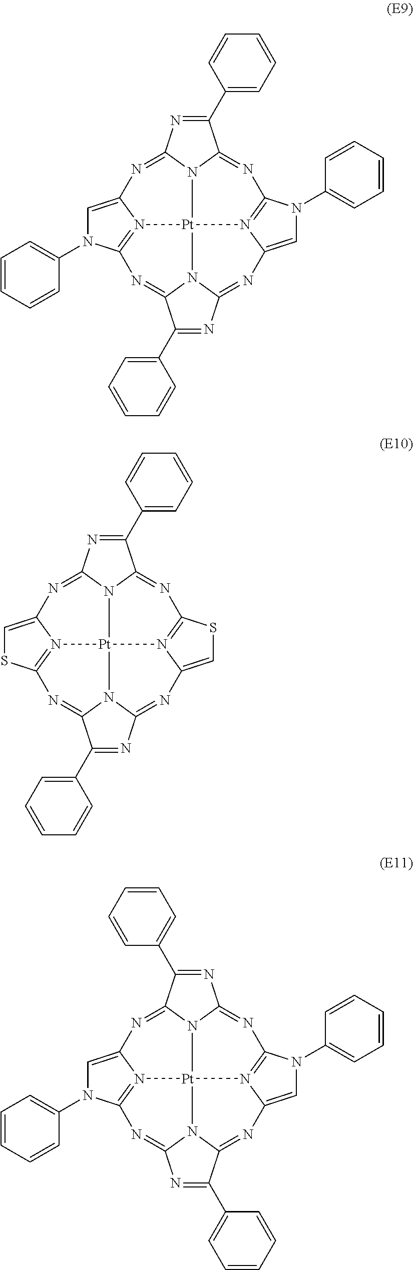

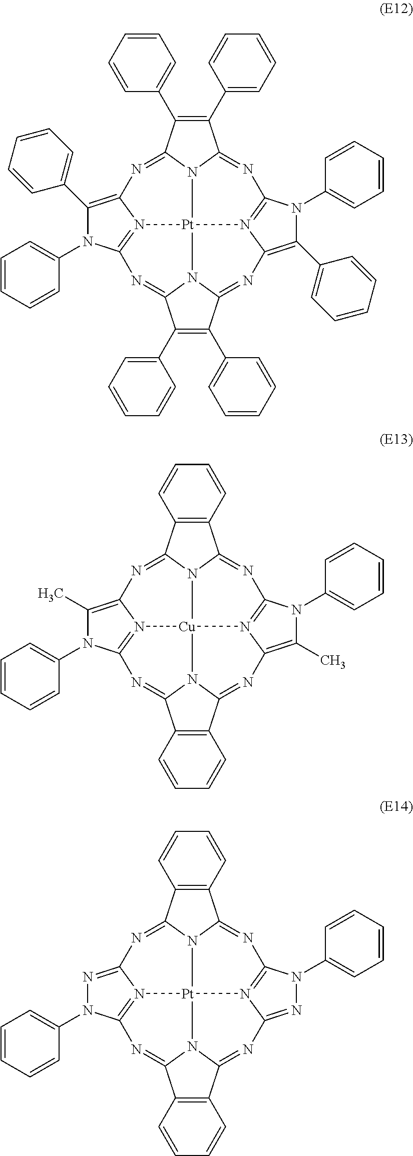

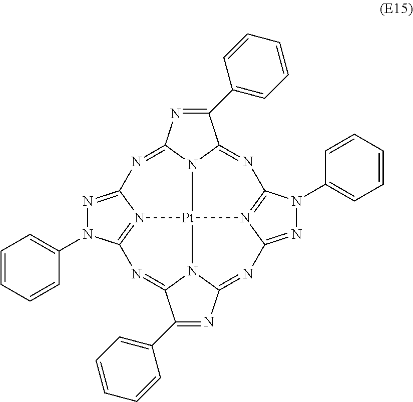

An example of metal complexes usable in the invention is a compound represented by the following Formula (F-1).

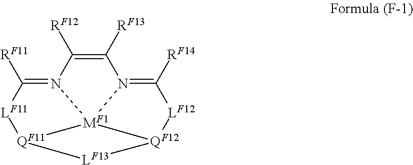

In Formula (F-1), M^{F1} represents a metal ion. L^{F11}, L^{F12} and L^{F13} each independently represent a connecting group. R^{F11}, R^{F12}, R^{F13} and R^{F14} each independently represent a hydrogen atom or a substituent. R^{F11} and R^{F12} may, if possible, be bonded to each other to form a 5-membered ring. R^{F12} and R^{F13} may, if possible, be bonded to each other to form a ring. R^{F13} and R^{F14} may, if possible, be bonded to each other to form a 5-membered ring. Q^{F11} and Q^{F12} each independently represent a partial structure containing an atom bonded to M^{F1}. The bond between the atom in the partial structure and M^{F1} may be, for example, a covalent bond.

The compound represented by Formula (F-1) will be described in detail.

In Formula (F-1), M^{F1}, L^{F11}, L^{F12}, L^{F13}, Q^{F11} and Q^{F12} have the same definitions as corresponding M^{A1}, L^{A11}, L^{A12}, L^{A13}, Q^{A11} and Q^{A12} in Formula (A-1) respectively, and their preferable examples are also the same. R^{F11}, R^{F12}, R^{F13} and R^{F14} each independently represent a hydrogen atom or a substituent. R^{F11} and R^{F12} may, if possible, be bonded to each other to form a 5-membered ring. R^{F12} and R^{F13} may, if possible, be bonded to each other to form a ring. R^{F13} and R^{F14} may, if possible, be bonded to each other to form a 5-membered ring. The substituent represented by R^{F11}, R^{F12}, R^{F13} or R^{F14} may be selected from the above-mentioned examples of the substituent represented by R^{C11} to R^{C14} in Formula (C-1). In a preferable embodiment, R^{F11} and R^{F12} are bonded to each other to form a 5-membered ring, and R^{F13} and R^{F14} are bonded to each other to form a 5-membered ring. In another preferable embodiment, R^{F12} and R^{F13} are bonded to each other to form an aromatic ring.

The compound represented by Formula (F-1) is more preferably a compound represented by Formula (F-2), (F-3) or (F-4).

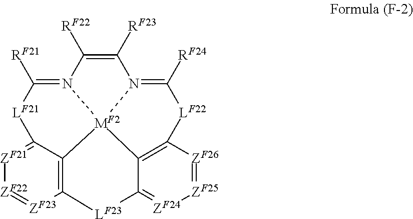

In Formula (F-2), M^{F2} represents a metal ion. L^{F21}, L^{F22} and L^{F23} each independently represent a connecting group. R^{F21}, R^{F22}, R^{F23} and R^{F24} each independently represent a substituent. R^{F21} and R^{F22} may, if possible, be bonded to each other to form a 5-membered ring. R^{F22} and R^{F23} may, if possible, be bonded to each other to form a ring. R^{F23} and R^{F24} may, if possible, be bonded to each other to form a 5-membered ring. Z^{F21}, Z^{F22}, Z^{F23}, Z^{F24}, Z^{F25} and Z^{F26} each independently represent a nitrogen atom or a substituted or unsubstituted carbon atom.

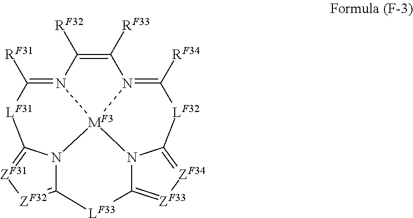

In Formula (F-3), M^{F3} represents a metal ion. L^{F31}, L^{F32} and L^{F33} each independently represent a connecting group. R^{F31}, R^{F32}, R^{F33} and R^{F34} each independently represent a substituent. R^{F31} and R^{F32} may, if possible, be bonded to each other to form a 5-membered ring. R^{F32} and R^{F33} may, if possible, be bonded to each other to form a ring. R^{F33} and R^{F34} may, if possible, be bonded to each other to form a 5-membered ring. Z^{F31}, Z^{F32}, Z^{F33} and Z^{F34} each independently represent a nitrogen atom or a substituted or unsubstituted carbon atom.

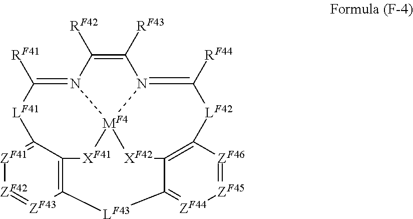

In Formula (F-4), M^{F4} represents a metal ion. L^{F41}, L^{F42} and L^{F43} each independently represent a connecting group. R^{F41}, R^{F42}, R^{F43} and R^{F44} each independently represent a substituent. R^{F41} and R^{F42} may, if possible, be bonded to each other to form a 5-membered ring. R^{F42} and R^{F43} may, if possible, be bonded to each other to form a ring. R^{F43} and R^{F44} may, if possible, be bonded to each other to form a 5-membered ring. Z^{F41}, Z^{F42}, Z^{F43}, Z^{F44}, Z^{F45} and Z^{F46} each independently represent a nitrogen atom or a substituted or unsubstituted carbon atom. X^{F41} and X^{F42} each independently represent an oxygen atom, a sulfur atom or a substituted or unsubstituted nitrogen atom.

The compound represented by Formula (F-2) will be described in detail.

M^{F2}, L^{F21}, L^{F22}, L^{F23}, R^{F21}, R^{F22}, R^{F23} and R^{F24} have the same definitions as corresponding M^{F1}, L^{F11}, L^{F12}, R^{F13} and R^{F14} in Formula (F-1) respectively, and their preferable examples are also the same.

Z^{F21}, Z^{F22}, Z^{F23}, Z^{F24}, Z^{F25} and Z^{F26} each independently represent a nitrogen atom or a substituted or unsubstituted carbon atom. Each of Z^{F21}, Z^{F22}, Z^{F23}, Z^{F24}, Z^{F25} and Z^{F26} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

The compound represented by Formula (F-3) will be described in detail.

In Formula (F-3), M^{F3}, L^{F31}, L^{F32}, L^{F33}, R^{F31}, R^{F32}, R^{F33} and R^{F34} have the same definitions as corresponding M^{F1}, L^{F11}, L^{F12}, L^{F13}, R^{F11}, R^{F12}, R^{F13} and R^{F14} in Formula (F-1) respectively, and their preferable examples are also the same. Z^{F31}, Z^{F32}, en and Z^{F34} each independently represent a nitrogen atom or a substituted or unsubstituted carbon atom. Each of Z^{F31}, Z^{F32}, Z^{F33} and Z^{F34} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

The compound represented by Formula (F-4) will be described in detail.

In Formula have the same (F-4), M^{F4}, L^{F41}, L^{F42}, L^{F43}, R^{F41}, R^{F42}, R^{F43} and R^{F44} definitions as corresponding M^{F1}, L^{F11}, L^{F12}, L^{F13}, R^{F11}, R^{F12}, R^{F13} and R^{F14} in Formula (F-1) respectively, and their preferable examples are also the same.

Z^{F41}, Z^{F42}, Z^{F43}, Z^{F44}, Z^{F45} and Z^{F46} each independently represent a nitrogen atom or a substituted or unsubstituted carbon atom. Each of Z^{F41}, Z^{F42}, Z^{F43}, Z^{F44}, Z^{F45} and Z^{F46} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in Formula (A-1).

X^{F41} and X^{F42} each independently represent an oxygen atom, a sulfur atom or a substituted or unsubstituted nitrogen atom. Each of X^{F41} and X^{F42} is preferably an oxygen atom or a sulfur atom, and more preferably an oxygen atom.

Specific examples of the compounds represented by Formula (F-1) are illustrated below, but the invention is not limited thereto.

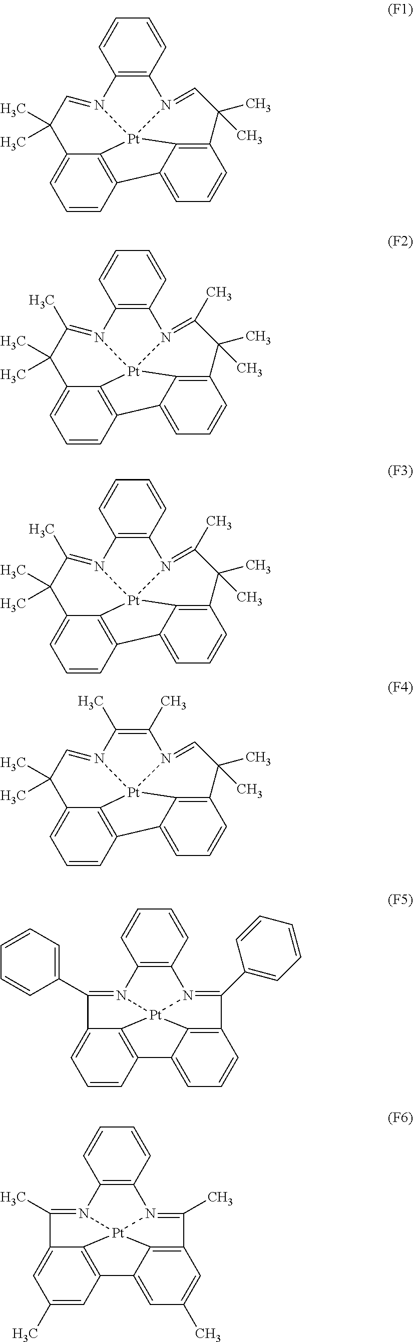

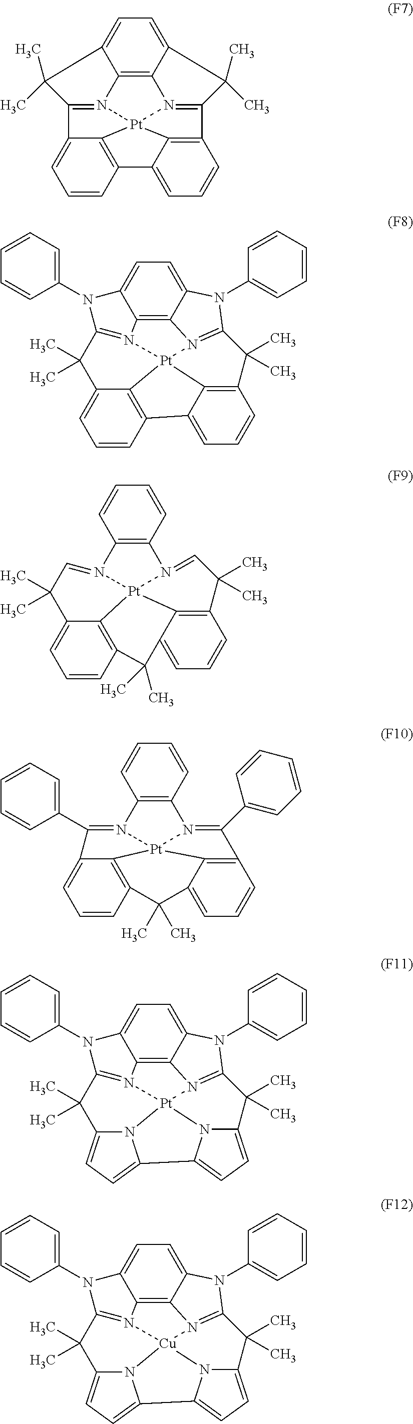

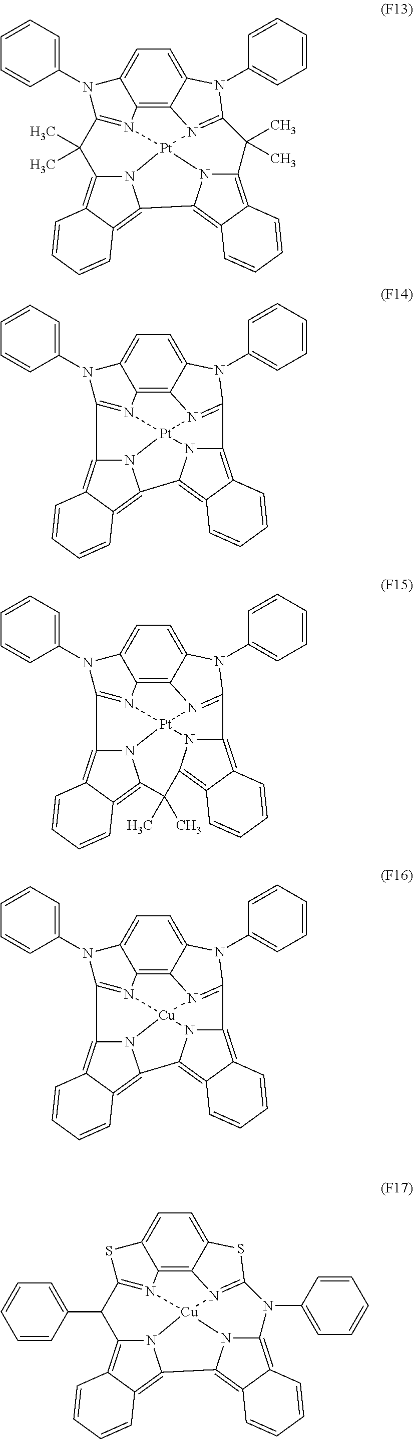

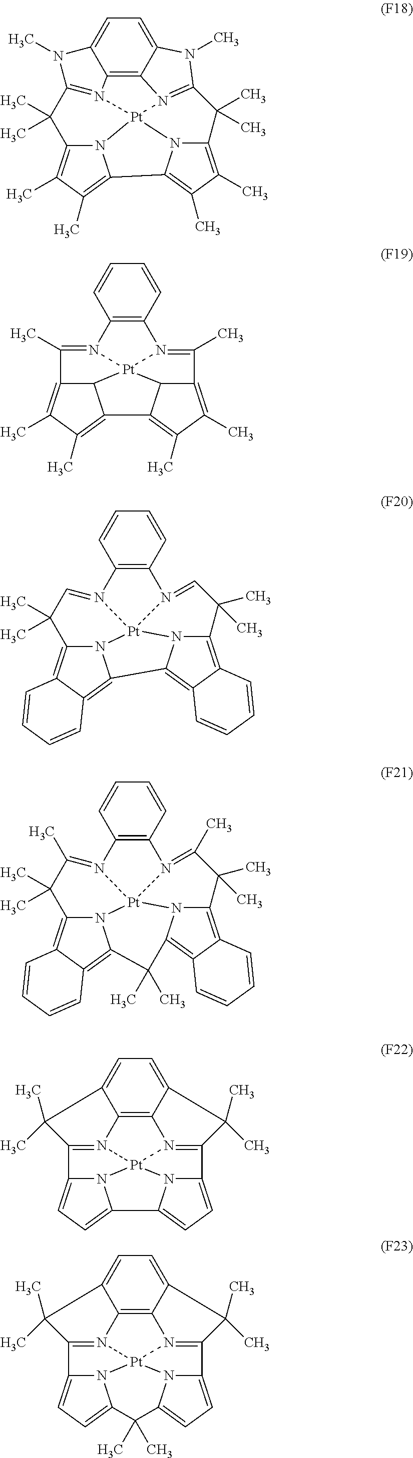

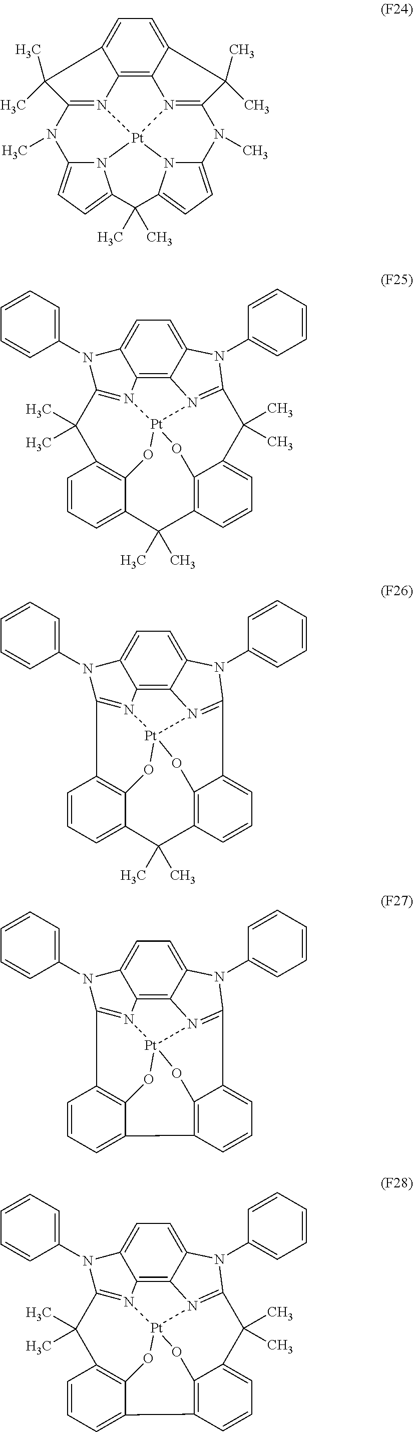

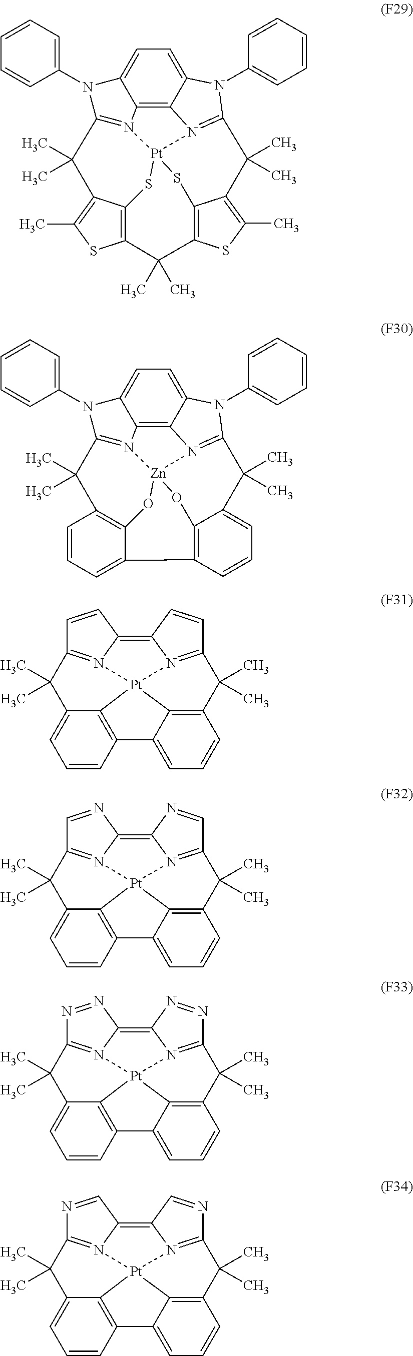

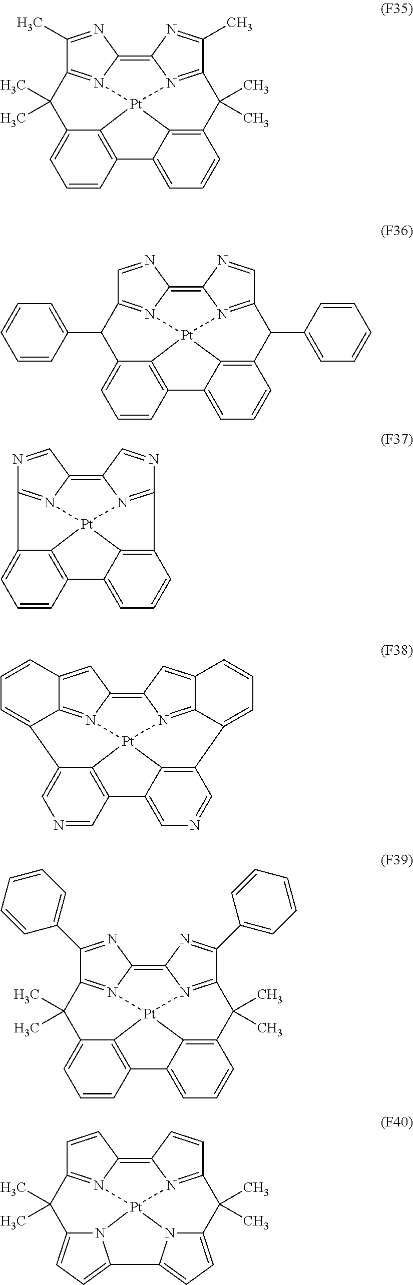

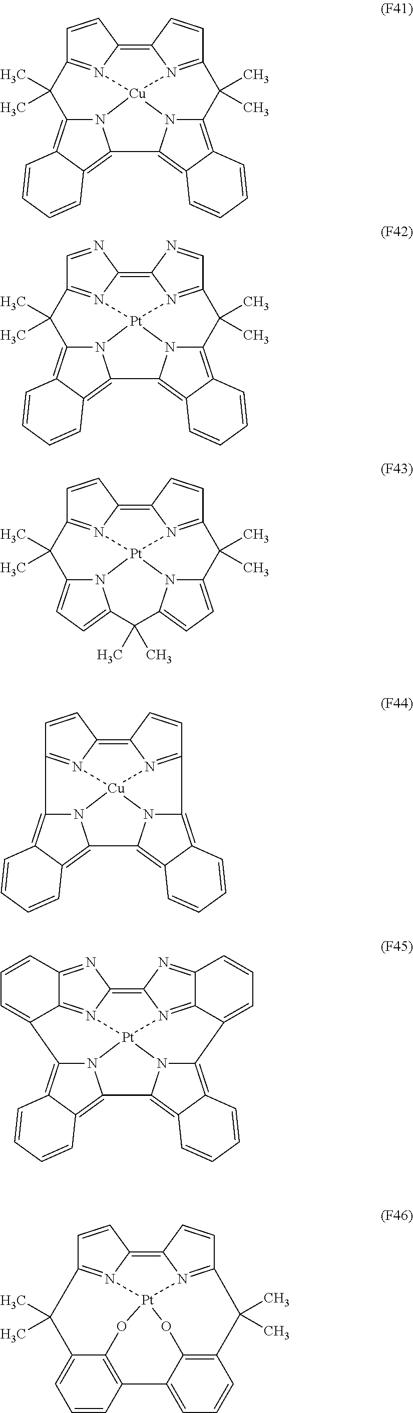

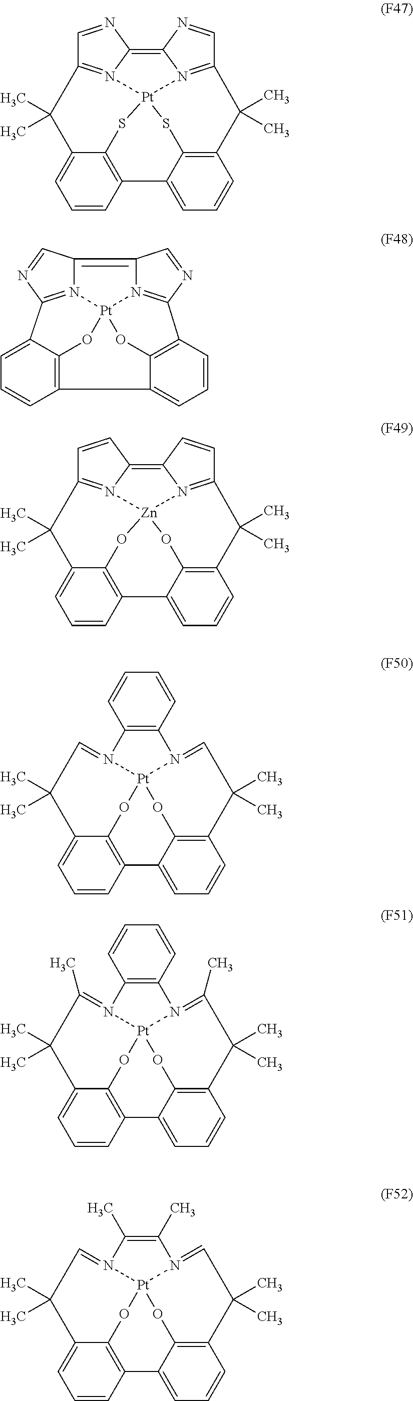

Compounds represented by any one of Formulae (A-1) to (F−1) can be synthesized by known methods.

The organic electroluminescent device according to the invention is a device having a plurality of organic compound layers between a pair of electrodes, anode and cathode. The organic compound layers include a luminescent layer and two or more hole-transporting layers and/or electron-transporting layers. The device may have additionally a luminescent layer, a hole-injecting layer, an electron-injecting layer, a protective layer, or the like in addition to these layers. In addition, each of these layers may have other functions. Various materials may be used in preparing each layer.

Components for the organic electroluminescent device according to the invention will be described below.

Organic electroluminescent devices are grouped grossly into bottom emission system and top emission system. The device according to the invention can be preferably used in both of the systems. Hereinafter, the invention will be described in detail, taking the bottom emission system as an example. An organic electroluminescent device in the bottom emission system normally has a configuration of anode/hole-transporting layer/luminescent layer/cathode from the substrate side, or anode/hole-transporting layer/luminescent layer/electron-transporting layer/cathode from the substrate side. In the invention, the device has a configuration having a luminescent layer and a plurality of hole-transporting layers including a layer adjacent to the luminescent layer and/or a configuration having a luminescent layer and plurality of electron-transporting layers including a layer adjacent to the luminescent layer. Each layer may be divided into a plurality of secondary layers.

In addition, at least one electrode, anode or cathode, is preferably transparent because the device is a luminescent device. Normally, the anode is transparent.

Typical configuration of the bottom emission luminescent device according to the invention is, from the substrate side, (1) transparent anode/multiple hole-transporting layers/luminescent layer/electron-transporting layer/cathode (the first aspect), (2) transparent anode/hole-transporting layer/luminescent layer/multiple electron-transporting layers/cathode (second aspect), or (3) transparent anode/multiple hole-transporting layers/single- or bi-layered luminescent layer/multiple electron-transporting layers/cathode (third and fourth aspects).

### <Substrate>

The substrate for use in the invention preferably does not scatter or attenuate the light emitted from the organic compound layer. Typical examples thereof include inorganic materials such as yttrium-stabilized zirconia (YSZ) and glass; and organic materials such as polyesters (e.g., polyethylene terephthalate, polybutylene phthalate, and polyethylene naphthalate), polystyrene, polycarbonate, polyether sulfone, polyarylate, polyimide, polycycloolefin, norbornene resin, and poly(chlorotrifluoroethylene). When it is an organic material, the organic material is preferably superior in heat resistance, dimensional stability, solvent resistance, electric insulation, and processability.

The shape, structure, and size of the substrate are not particularly limited, and may be selected properly according to the application and purpose of the luminescent device. Generally, the shape is planer. The structure may be a single-layered structure or a laminated structure, and may be formed with a single part or two or more parts.

The substrate may transparent and colorless or transparent and colored, but is preferably transparent and colorless, because such a substrate does not scatter or attenuate the light emitted from the luminescent layer.

A moisture-barrier layer (gas barrier layer) may be formed on the front or rear face (transparent electrode side) of the substrate. An inorganic material such as silicon nitride or silicon oxide is favorably used as the material for the moisture-barrier layer (gas barrier layer). The moisture-barrier layer (gas barrier layer) can be formed, for example, by high-frequency sputtering. A hardcoat layer, an undercoat layer, or the like may be formed additionally on a thermoplastic substrate as needed.

### <Anode>

The anode has normally a function of supplying holes into the organic compound layer, and the shape, structure, size, and the like thereof is not particularly limited and selected properly according to the application and purpose of the luminescent device. As described above, the anode is formed normally as a transparent anode.

Favorable examples of the materials for anode include metals, alloys, metal oxides, organic conductive compounds, and the mixture thereof; and materials having a work function of 4.0 eV or more are preferable. Typical examples thereof include semiconductive metal oxides such as antimony or fluorine-doped tin oxide (ATO and FTO), tin oxide, zinc oxide, indium oxide, indium tin oxide (ITO), and indium zinc oxide (IZO); metals such as gold, silver, chromium, and nickel; mixtures or laminates of these metals with a conductivite metal oxide; inorganic conductive substances such as copper iodide and copper sulfide; organic conductive materials such as polyaniline, polythiophene, and polypyrrole and the laminates thereof with ITO; and the like.

The anode can be formed on a substrate according to a method properly selected, for example by a printing method, a wet method such as coating, a physical method such as vacuum deposition, sputtering, or ion plating, or a chemical method such as CVD or plasma CVD, taking into considering the compatibility with the material. For example, when ITO is selected as the material for transparent anode, the transparent anode is formed by direct-current or high frequency sputtering, vacuum deposition, ion plating, or the like. Alternatively, when an organic conductive compound is selected as the material for transparent anode, the anode can be formed by a wet coating method.

The location of the anode in the luminescent device is not particularly limited and selected properly according to the application and purpose of the luminescent device, but preferably formed on a substrate. In such a case, the anode may be formed entirely or partially on one face of the substrate. Patterning of the anode may be performed by chemical etching such as photolithography, physical etching with laser or the like, vacuum deposition or sputtering over a mask, a lift-off method, or a printing method.

The thickness of the anode is decided properly according to the material used, and normally 10 nm to 50 μm and preferably 50 nm to 20 μm. The resistance of the transparent anode is preferably 10³ Ω/sq or less and more preferably, 10² Ω/sq or less.

When a transparent anode is formed and the light is extracted from the anode side, the transmittance is preferably 60% or more and more preferably 70% or more. The transmittance can be determined according to a known method by using a spectrophotometer. In such a case, the anode may be transparent and colorless or transparent and colored. Various anodes are described in detail in “Tohmeidodenmaku No Shintenkai (Developments of Transparent Conductive Films)” edited by Yutaka Sawada, published by CMC (1999), the disclosure of which is incorporated by reference herein, and the anodes described therein may be applied to the invention. When a plastic substrate lower in heat resistance is used, an anode of ITO or IZO is preferably formed at a low temperature of 150° C. or lower.

### <Cathode>

The cathode normally has a function of injecting electrons into the organic compound layer, and the shape, structure, size, and the like thereof is not particularly limited and may be selected properly from known electrodes, according to the application and purpose of the luminescent device.

Examples of the materials for cathode include metals, alloys, metal oxides, electroconductive compounds, the mixtures thereof, and the like, and those having a work function of 4.5 eV or less are preferable. Typical examples thereof include alkali metals (e.g., Li, Na, K, Cs, etc.), alkali-earth metals (e.g., Mg, Ca, etc.), gold, silver, lead, aluminum, sodium-potassium alloys, lithium-aluminum alloys, magnesium-silver alloys, rare earth metals such as indium and ytterbium, and the like. These materials may be used alone, but two or more materials are favorably used in combination from the viewpoints of both stability and electron-injecting efficiency. Among them, alkali metals and alkali-earth metals are preferable from the point of electron-injecting efficiency, while materials mainly containing aluminum are preferable from the point of storage stability. The materials mainly containing aluminum include pure aluminum and alloys or mixtures of aluminum with an alkali metal or alkali-earth metal in an amount of 0.01 to 10 wt % (e.g., lithium-aluminum alloy, magnesium-aluminum alloy, etc). The materials for cathode are described in detail in JP-A Nos. 2-15595 and 5-121172, the disclosures of which are incorporated by reference herein.

The method of forming the cathode is not particularly limited, and e may be formed according to any one of known methods. For example, the cathode can be formed on a substrate according to a method properly selected, for example, by a printing method, a wet method such as coating, a physical method such as vacuum deposition, sputtering, or ion plating, or a chemical method such as CVD or plasma CVD, taking into considering the compatibility with the material. When a metal or the like is selected as the material for cathode, the cathode is formed, for example, by sputtering one or more of them simultaneously or sequentially.

Patterning of the cathode may be performed by chemical etching such as photolithography, physical etching with laser or the like, vacuum deposition or sputtering over a mask, a lift-off method, or a printing method.

The location of the cathode formed on the laminate that is obtained by laminating an electrode and organic compound layers (luminescent laminate) is not particularly limited, and may be formed entirely or partially on the organic compound layer.

In addition, a dielectric layer having a thickness of 0.1 to 5 nm of a fluoride, oxide, or the like of an alkali-earth metal or an alkali metal may be formed between the cathode and the organic compound layer. The dielectric layer may be considered as a kind of electron-injecting layer, and the dielectric layer can be formed, for example, by vacuum deposition, sputtering, ion plating, or the like.

The thickness of the cathode can not be specified and may be selected porperly according to the material used, but is usually 10 nm to 5 μM and preferably 50 nm to 1 μm.

The cathode may be transparent or opaque. The transparent cathode can be formed by forming a thin layer of cathode material having a thickness of 1 to 10 nm and additionally laminating a transparent conductive material such as ITO or IZO.

### <Organic Compound Layer>

### —Formation of Organic Compound Layer—

The method of forming the organic compound layer according to the invention is not particularly limited, and examples thereof include resistance-heating vapor deposition, electrophotography, electron beam, sputtering, molecular lamination, coating (spray coating, dip coating, impregnation, roll coating, gravure coating, reverse coating, roll-brush coating, air knife coating, curtain coating, spin coating, flow coating, bar coating, microgravure coating, air doctor coating, blade coating, squeeze coating, transfer roll coating, kiss coating, cast coating, extrusion coating, wire bar coating, screen coating, etc.), inkjet ejection, printing, transferring, and the like; and resistance-heating deposition, coating, and transferring methods are preferable, from the points of the properties of the device, easiness of production, cost, and the like. When the luminescent device has a laminate structure of two or more layers, the methods above may be used in combination.

In a coating method, a solution or dispersion of a resin component may be used, and examples of the resin components include polyvinyl chloride, polycarbonate, polystyrene, polymethyl methacrylate, polyester, polysulfone, polyphenylene oxide, polybutadiene, poly(N-vinylcarbazole), hydrocarbon resins, ketone resins, phenoxy resins, polyamide, ethylcellulose, vinyl acetate, ABS resins, polyurethane, melamine resins, unsaturated polyester resins, alkyd resins, epoxy resins, silicone resins, and the like.

### —Hole-Transporting and Hole-Injecting Layers—

The material for the hole-transporting layer or hole-injecting layers is not particularly limited, if it has a function of injecting holes from the anode, transporting the holes, or blocking the electron injected from the cathode. The hole-transporting layer according to the invention generally include a layer called hole-injecting layer.

Typical examples of the materials for the hole-transporting layer or the hole-injecting layer include carbazole, imidazole, dibenzazepine, tribenzazepine, triazole, oxazole, oxadiazole, polyarylalkane, pyrylazoline, pyrylazolone, phenylenediamine, arylamine, amino-substituted chalcones, styrylanthracene, fluorenone, hydrylazone, stilbene, silazane, aromatic tertiary amine compounds, styrylamine, aromatic dimethylydene compounds, porphyrin compounds, polysilane compounds, poly(N-vinylcarbazole), aniline-based copolymers, thiophene oligomers, conductive oligomers such as of polythiophene, organic metal complexes, transition metal complexes or the derivatives thereof, and the like.

In the invention, from the viewponts of reducing the driving voltage and improving the durability, at least one of the hole-transporting layers preferably contains a compound selected from the group consisting of an azepine compound, an amine compound, a carbazole compound, a pyrrole compound, and an indole compound. Among the hole-transporting layers, the layer adjacent to the luminescent layer preferably contains a compound selected from the group consisting of an azepine compound, an amine compound, a carbazole compound, a pyrrole compound, and an indole compound.

In the invention, the material for the hole-transporting layer adjacent to the luminescent layer is preferably carbazole, phenylenediamine, an arylamine, an aromatic tertiary amine compound, dibenzoazepine, or tribenzoazepine and more preferably carbazole, an aromatic tertiary amine compound, or tribenzoazepine among those described above.

The material for the other hole-transporting layers is preferably carbazole, phenylenediamine, an arylamine, an aromatic tertiary amine compound, dibenzoazepine, or tribenzoazepine, and more preferably carbazole, an aromatic tertiary amine compound, or tribenzoazepine, among them.

As described above, in the first, third and fifth aspects of the invention, when the ionization potential of the luminescent layer is designated as IP₀, the ionization potential of the hole-transporting layer adjacent to the luminescent layer is designated as Ip₁, and the ionization potential of of the n-th hole-transporting layer from the luminescent layer is designated as Ipₙ, these values should satisfy the relationship represented by the following formula (1).

Ip₀>Ip₁>Ip₂> . . . >IPₙ₋₁<Ipₙ

In formula (1), n is an integer of 2 or more.

In selecting the material for the two or more hole-transporting layers, the relationship with the material contained in the luminescent layer is considered.

The thickness of the hole-injecting layer or the hole-transporting layer is not particularly limited, but normally, preferably in the range of 1 nm to 5 μm, more preferably 5 nm to 1 μm, and still more preferably 10 to 500 nm. The hole-transporting layer may have a single layer structure of one or more materials described above or a multilayer structure consisting of multiple layers in the same composition or different compositions.

The hole-injecting layer or the hole-transporting layer may contain an electron-accepting dopant. Any material such as an inorganic compound or an organic compound may be used as the electron-accepting dopant contained in the hole-injecting layer or the hole-transporting layer as long as it has electron-accepting properties and is capable of oxidizing organic compounds.

Preferable examples of the organic electron-accepting dopants include Lewis acid compounds such as ferric chloride, aluminum chloride, gallium chloride, indium chloride and antimony pentachloride.

Preferable examples of the organic electron-accepting dopants include compounds having a nitro group, a halogen, a cyano group, a trifluoromethyl group or the like as a substituent thereof, quinone compounds, acid anhydride compounds, and fullerenes.

These electron-accepting dopants may be used singly or in combination of two or more thereof. The amount of the electron-accepting dopant may vary depending on a material thereof. It is preferably 0.01 to 50 wt %, more preferably 0.05 to 20 wt %, and still more preferably 0.1 to 10 wt %, with respect to the materials contained in the hole-transporting layer or the hole injecting layer.

### —Electron-Transporting and Electron-Injecting Layers—

The material for the electron-transporting layer or electron-injecting layer is not particularly limited, if it has a function of injecting electrons from the cathode, transporting the electrons, or blocking the holes injected from the anode. The electron-transporting layer according to the invention includes a layer generally called electron-injecting layer.

Typical examples of the materials for the electron-transporting layer or electron-injecting layer include pyridine, pyrimidine, triazole, triazine, oxazole, phenanthroline, oxadiazole, imidazole, fluorenone, anthraquinodimethane, anthrone, diphenylquinone, thiopyranedioxide, carbodiimide, fluorenylidenemethane, distyrylpyrazine, sirole, imidazopyridine, anhydrides of aromatic ring tetracarboxylic acid (examples of aromatic ring include naphthalene and perylene), phthalocyanine, metal complexes of 8-quinolinol derivatives, metal phthalocyanines, various metal complexes represented by metal complexes having a ligand such as benzoxazole or benzothiazole or the derivatives thereof, and the like.

In the invention, the material for the electron-transporting layer adjacent to the luminescent layer is preferably pyridine, pyrimidine, triazine, phenanthroline, oxadiazole, imidazole, sirole, or imidazopyridine, and more preferably triazine, oxadiazole, imidazole, or imidazopyridine among them.

Among the materials above, the material for other electron-transporting layers is preferably pyridine, pyrimidine, triazine, phenanthroline, oxadiazole, imidazole, silole, or imidazopyridine and more preferably triazine, phenanthroline, oxadiazole, imidazole, silole, or imidazopyridine.

As described above, in the second, third and fifth aspects of the invention, when the electron affinity of the luminescent layer is designated as Ea₀, the electron affinity of the electron-transporting layer adjacent to the the luminescent layer is designated as Ea₁, and the electron affinity of the m-th electron-transporting layer from the luminescent layer is designated as Eaₘ, these values should satisfy the relationship represented by the following formula (2):

Ea₀<Ea₁<Ea₂< . . . <Eaₘ₋₁<Eaₘ Formula (2)

In formula (2), m is an integer of 2 or more.

In selecting the material for the two or more electron-transporting layers, the relationship with the material contained in the luminescent layer material is considered.

The thickness of the electron-injecting or the electron-transporting layer is not particularly limited, but normally, preferably in the range of 1 nm to 5 μm, more preferably 5 nm to 1 μm, and still more preferably 10 to 500 nm. The electron-injecting layer or the electron-transporting layer may have a single layer structure of one or more materials described above, or a multilayer structure consisting of multiple layers in the same composition or different compositions.

The electron-injecting layer or the electron-transporting layer may contain an electron-donating dopant. Any materials may be used as the electron-donating dopant contained in the electron injecting layer or the electron-transporting layer as long as it has electron-donating properties and is capable of reducing organic compounds. Preferable examples of the electron-donating dopants include alkali metals such as Li, alkaline earth metals such as Mg, transition metals including rare earth metals, and reductive organic compounds. Metals having a work function of 4.2 eV or less may be preferably used. Specific examples thereof include Li, Na, K, Be, Mg, Ca, Sr, Ba, Y, Cs, La, Sm, Gd and Yb. Specific examples of the reductive organic compounds include nitrogen-containing compounds, sulfur-containing compounds and phosphorus-containing compounds.

These electron-donating dopants may be used singly or in combination of two or more thereof. The amount of the electron-donating dopant may vary depending on a material thereof. It is preferably 0:1 to 99 wt %, more preferably 1.0 to 80 wt %, and still more preferably 2.0 to 70 wt %, with respect to the materials contained in the electron-transporting layer or the electron-injecting layer.

### —Luminescent Layer—

The luminescent layer according to the invention is a layer containing a luminescent material and a host material.

The host material is a material having functions of receiving the holes from the hole-transporting or hole-injecting layer and the electrons from the electron-injecting or electron-transporting layer when voltage is applied, transporting the injected charges, providing a place for recombination of the holes and the electrons and generating excitons, and transporting the excitation energy.

Examples of the host materials for use in the invention include benzoxazole, benzimidazole, benzothiazole, polyphenyl, coumarin, oxadiazole, pyrralizine, pyrrolopyridine, thiadiazolopyridine, aromatic dimethylydene compounds, carbazole, imidazole, triazole, oxazole, oxadiazole, polyarylalkanes, pyrylazoline, pyrylazolone, phenylenediamine, arylamines, amino-substituted chalcones, fluorenone, hydrylazone, silazane, aromatic tertiary amine compounds, aromatic dimethylydene compounds, porphyrin compounds, polysilane compounds, poly(N-vinylcarbazole), various metal complexes represented by metal complexes having benzoxazole or benzothiazole as the ligand or the derivatives thereof, and the like. The host materials may be used alone or in combination of two or more.

The total content of the host materials in the luminescent layer is preferably 50 to 99.9 wt %, more preferably 60 to 99.7 wt %, and still more preferably 80 to 99.5 wt %, with respect to the weight of the luminescent layer.

In the fourth and fifth aspects of the invention, each of the first and second luminescent layers has a particular host material different from each other.

Preferable materials for the luminescent material contained in the luminescent layer are the same as those described above.

The thickness of the luminescent layer is not particularly limited, but normally, preferably 1 to 500 nm, more preferably 5 to 200 nm, and still more preferably 10 to 100 nm.

When a plurality of luminescent layers are formed as in the fourth or fifth aspect, the thickness of each luminescent layer is not particularly limited, but preferably 1 to 250 nm, more preferably 2 to 100 nm, and still more preferably 5 to 50 nm.

When there are a plurality of luminescent layers, the luminescent material contained in each layer may be the same or different. The number of luminescent layers layered is not specifically limited, and is preferably two or three.

By using two or more luminescent materials which are different from each other, a luminescent device which can emit light with desired colors can be obtained. For example, white light may be emitted based on the combination of luminescent materials which emit light with complementary emission colors, such as blue light emission/yellow light emission, light blue light emission/orange light emission, or green light emission/purple light emission. Alternatively, white light may be emitted based on the combination of three luminescent materials of different emission colors from each other such as blue light emission/green light emission/red light emission.

The host material may function as a luminescent material. White light may be emitted, for example, based on the light emission of the host material and a luminescent material.

Two or more luminescent materials different from each other may be contained in the same luminescent layer. Alternatively, each layer of the plurality of luminescent layers may contain a different luminescent material, such as blue luminescent layer/green luminescent layer/red luminescent layer, or blue luminescent layer/yellow luminescent layer.

When the organic EL device includes a plurality of luminescent layers, the device may have a configuration in which one or more charge generating layers are formed.

The charge generating layer has functions of generating charges (holes and electrons) and injecting the generated charges into the adjacent layer.

Any material may be used for forming a charge generating layer as long as it has functions as described above. A charge generating layer may be formed from a single compound or a plurality of compounds. Specific examples of the materials for forming a charge generating layer include electrical conductive materials, semiconductive materials (for example, a doped organic layer), electrelectrical insulating materials, and materials disclosed in JP-A Nos. 11-329748, 2003-272860, or 2004-39617, the disclosures of which are incorporated by reference herein.

When the organic EL device of the invention has a configuration having one or more charge generating layers as described above, each unit between a charge generating layer and the electrode, or between the charge generating layers preferably has the configuration of the invention.

### <Protective Layer>

In the invention, the luminescent device may be protected with a protective layer entirely. The material for the protective layer is preferably a material that blocks penetration into the device of the molecules that accelerate degradation of the device such as water and oxygen. Typical examples thereof include metals such as In, Sn, Pb, Au, Cu, Ag, Al, Ti, and Ni; metal oxides such as MgO, SiO, SiO₂, Al₂O₃, GeO, NiO, CaO, BaO, Fe₂O₃, Y₂O₃, and TiO₂; metal nitrides such as SiNx and SiNxOy; metal fluorides such as MgF₂, LiF, AlF₃, and CaF₂; polyethylene, polypropylene, polymethyl methacrylate, polyimide, polyurea, polytetrafluoroethylene, polychlorotrifluoroethylene, polydichlorodifluoroethylene, copolymers of chlorotrifluoroethylene and dichlorodifluoroethylene, copolymers obtained by copolymerizing a monomer mixture containing tetrafluoroethylene and at least one comonomer, fluorine-containing copolymers having a cyclic structure in the copolymer main chain, water-absorbing substances having a water absorption of 1% or more, moisture-proof substances having a water absorption of 0.1% or less, and the like.

The method of forming the protective layer is also not particularly limited, and for example, it can be prepared by vacuum deposition, sputtering, reactivity sputtering, MBE (molecular beam epitaxy), cluster ion beaming, ion plating, plasma polymerization (high-frequency excitation ion plating), plasma CVD, laser CVD, thermal CVD, gas source CVD, coating, printing, or transferring.

### <Sealing>

In the invention, the device according to the invention may be sealed entirely in a sealing container. In addition, a water absorbent or an inactive liquid may be enclosed in the space between the sealing container and the luminescent device. The water absorbent is not particularly limited, and examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieve, zeolite, magnesium oxide, and the like. The inactive liquid is not particularly limited, and examples thereof include paraffins, liquid paraffins, perfluoroalkanes, perfluoroamines, fluorine solvents such as perfluoroethers, chlorine-based solvents, and silicone oils.

### <Driving of Device>

The luminescent device according to the invention emits light when a DC (may contain as needed an AC component) voltage (normally at 2 to 40 volt) or a DC current is applied between the transparent anode and the cathode. The methods described in JPA Nos. 2-148687, 6-301355, 5-29080, 7-134558, 8-234685, and 8-241047, U.S. Pat. Nos. 5,828,429 and 6,023,308, Japanese Patent 2784615, the disclosures of which are incorporated by reference herein, and others may be used for driving the luminescent device according to the invention.

### Examples

Hereinafter, the organic electroluminescent device according to the invention will be described with reference to Examples, but it should be understood that the invention is not restricted by these Examples.

### 1. Preparation of Organic Electroluminescent Device

### (1) Preparation of an Organic Electroluminescent Device of Comparative Example (Device 1)

A glass plate having an ITO film of 0.5 mm in thickness and 2.5 cm square (manufactured by Geomatec Co., Ltd., surface resistance: 10 Ω/sq) was placed in a washing container, washed with 2-propanol under ultrasonic irradiation, and treated with UV and ozone for 30 minutes. The following organic compound layers were vapor-deposited one by one on the transparent anode (ITO film) by vacuum deposition.

The vapor deposition rate in the Examples of the invention is 0.2 nm/sec, unless specified otherwise. The vapor deposition rate was determined by using a quartz resonator. The film thickness described below was also determined by using a quartz resonator.

The ionization potential and the electron affinity of the respective organic compound layers in device 1 are indicated in the configuration shown below.

### (Hole-Transporting Layer)

NPD: thickness: 40 nm, ionization potential: 5.4 eV, electron affinity: 2.4 eV

### (Luminescent Layer)

Mixed layer of mCP (95% by weight) and BPM-1 (5% by weight): thickness: 35 nm, ionization potential: 6.0 eV, electron affinity: 2.4 eV

### (Electron-Transporting Layer)

BAlq: thickness: 45 nm, ionization potential: 5.9 eV, electron affinity: 2.9 eV

The structures of NPD, mCP, BPM-1, and BAlq above are shown below.

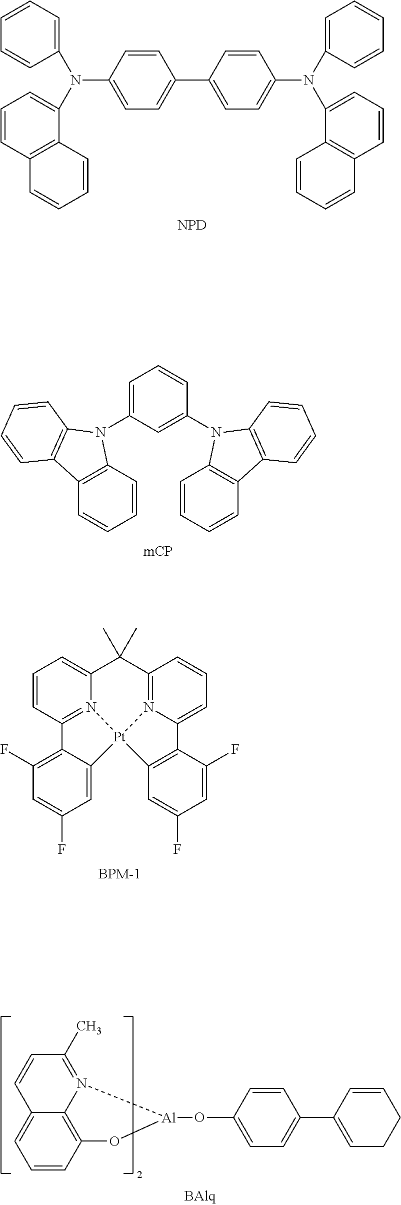

Finally, metal aluminum was vapor-deposited thereon to a thickness of 100 nm, to give a cathode.

The composite was placed in a glove box previously substituted with an argon gas without exposure to air, sealed in a stainless steel sealing container with an ultraviolet ray-hardening adhesive (XNR5516HV, manufactured by Nagase ChemteX Corp.), to give an organic electroluminescent device of Comparative Example (device 1).

(2) Preparation of organic electroluminescent device of Example (device 2)

An organic electroluminescent device of Example (device 2) was prepared in the same manner as the organic electroluminescent device of Comparative Example (device 1), except that the configuration of the organic compound layers was changed to that below. The ionization potential and the electron affinity of the respective organic compound layers in device 2 are indicated in the configuration.

### (First Hole-Transporting Layer)

CuPc: thickness: 10 nm, ionization potential: 5.1 eV, electron affinity: 3.4 eV

### (Second Hole-Transporting Layer)

NPD: thickness: 30 nm, ionization potential: 5.4 eV, electron affinity: 2.4 eV

### (Luminescent Layer)

Mixed layer of mCP (95% by weight) and BPM-1 (5% by weight): thickness: 35 nm, ionization potential: 6.0 eV, electron affinity: 2.4 eV

### (First Electron-Transporting Layer)

BAlq: thickness: 5 nm, ionization potential: 5.9 eV, electron affinity: 2.9 eV

### (Second Electron-Transporting Layer)

Alq: thickness: 40 nm, ionization potential: 5.8 eV, electron affinity: 3.0 eV

The structures of NPD, mCP, BPM-1, and BAlq are shown above.

Below shown are the structures of CuPc and Alq.

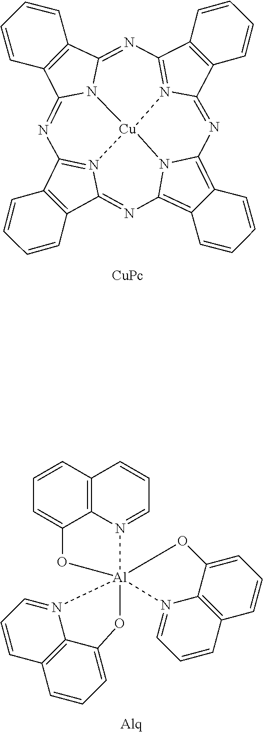

### (3) Preparation of Organic Electroluminescent Device of Example (Device 3)

An organic electroluminescent device of Example (device 3) was prepared in the same manner as the organic electroluminescent device of Comparative Example (device 1), except that the configuration of the organic compound layers was changed to that below. The ionization potential and the electron affinity of the respective organic compound layers in device 3 are indicated in the configuration.

### (First Hole-Transporting Layer)

m-MTDATA: thickness: 10 nm, ionization potential: 5.1 eV, electron affinity: 1.9 eV

### (Second Hole-Transporting Layer)

NPD: thickness: 30 nm, ionization potential: 5.4 eV, electron affinity: 2.4 eV

### (Luminescent Layer)

Mixed layer of mCP (95% by weight) and BPM-1 (5% by weight): thickness: 35 nm, ionization potential: 6.0 eV, electron affinity: 2.4 eV

### (First Electron-Transporting Layer)

BAlq: thickness: 5 nm, ionization potential: 5.9 eV, electron affinity: 2.9 eV

### (Second Electron-Transporting Layer)

Alq: thickness: 40 nm, ionization potential: 5.8 eV, electron affinity: 3.0 eV

The structures of NPD, mCP, BPM-1, BAlq and Alq are shown above. Below shown is the structure of m-MTDATA.

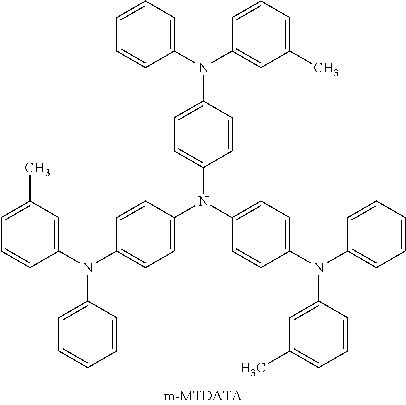 [SMILES: Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

### (4) Preparation of Organic Electroluminescent Device of Example (Device 4)

An organic electroluminescent device of Example (device 4) was prepared in the same manner as the organic electroluminescent device of Comparative Example (device 1), except that the configuration of the organic compound layers was changed to that below. The ionization potential and the electron affinity of the respective organic compound layers in device 3 are indicated in the configuration.

### (First Hole-Transporting Layer)

Copper phthalocyanine: thickness: 10 nm, ionization potential: 5.1 eV, electron affinity: 3.4 eV

### (Second Hole-Transporting Layer)

NPD: thickness: 25 nm, ionization potential: 5.4 eV, electron affinity: 2.4 eV

### (Third Hole-Transporting Layer)

HTM-1: thickness: 5 nm, ionization potential: 5.8 eV, electron affinity: 2.2 eV

### (Luminescent Layer)

Mixed layer of mCP (95% by weight) and BPM-1 (5% by weight): thickness: 35 nm, ionization potential: 6.0 eV, electron affinity: 2.4 eV

### (First Electron-Transporting Layer)

BAlq: thickness: 5 nm, ionization potential: 5.9 eV, electron affinity: 2.9 eV

### (Second Electron-Transporting Layer)

Alq: thickness: 40 nm, ionization potential: 5.8 eV, electron affinity: 3.0 eV

The structures of copper phthalocyanine, NPD, mCP, BPM-1, BAlq, and Alq above are shown above. Below shown is the structure of HTM-1.

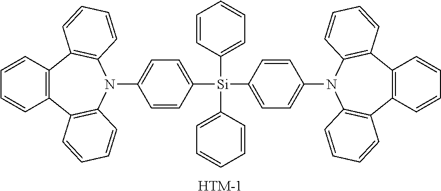

### (5) Preparation of Organic Electroluminescent Device of Example (Device 5)

An organic electroluminescent device of Example (device 5) was prepared in the same manner as the organic electroluminescent device of Comparative Example (device 1), except that the configuration of the organic compound layers was changed to that below. The ionization potential and the electron affinity of the respective organic compound layers in device 5 are indicated in the configuration.

### (First Hole-Transporting Layer)

Copper phthalocyanine: thickness 10 nm, ionization potential: 5.1 eV, electron affinity: 3.4 eV

### (Second Hole-Transporting Layer)

NPD: thickness: 25 nm, ionization potential: 5.4 eV, electron affinity: 2.4 eV

### (Third Hole-Transporting Layer)

HTM-1: thickness: 5 nm, ionization potential: 5.8 eV, electron affinity: 2.2 eV

### (Luminescent Layer)

Mixed layer of mCP (95% by weight) and BPM-1 (5% by weight): thickness: 35 nm, ionization potential: 6.0 eV, electron affinity: 2.4 eV

### (First Electron-Transporting Layer)

ETM-1: thickness: 5 nm, ionization potential: 6.1 eV, electron affinity: 2.5 eV

### (Second Electron-Transporting Layer)

BAlq: thickness: 5 nm, ionization potential: 5.9 eV, electron affinity: 2.9 eV

### (Third Electron-Transporting Layer)

Alq: thickness: 35 nm, ionization potential: 5.8 eV, electron affinity: 3.0 eV

The structures of copper phthalocyanine, NPD, HTM-1, mCP, BPM-1, BAlq, and Alq are shown above. The structure of ETM-1 is shown below.

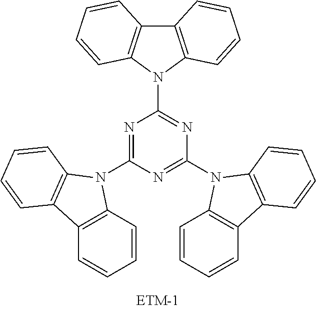 [SMILES: c1ccc2c(c1)c1ccccc1n2-c1nc(-n2c3ccccc3c3ccccc32)nc(-n2c3ccccc3c3ccccc32)n1]

### (6) Preparation of Organic Electroluminescent Device of Example (Device 6)

An organic electroluminescent device of Example (device 6) was prepared in the same manner as the organic electroluminescent device of Comparative Example (device 1), except that the configuration of the organic compound layers was changed to that below. The ionization potential and the electron affinity of the respective organic compound layers in device 6 are indicated in the configuration.

### (First Hole-Transporting Layer)

Copper phthalocyanine: thickness 10 nm, ionization potential: 5.1 eV, electron affinity: 3.4 eV

### (Second Hole-Transporting Layer)

NPD: thickness: 25 nm, ionization potential: 5.4 eV, electron affinity: 2.4 eV

### (Third Hole-Transporting Layer)

HTM-2: thickness: 5 nm, ionization potential: 5.7 eV, electron affinity: 2.3 eV

### (Luminescent Layer)

Mixed layer of mCP (95% by weight) and BPM-1 (5% by weight): thickness: 35 nm, ionization potential: 6.0 eV, electron affinity: 2.4 eV

### (First Electron-Transporting Layer)

BAlq: thickness: 5 nm, ionization potential: 5.9 eV, electron affinity: 2.9 eV

### (Second Electron-Transporting Layer)

Alq: thickness: 40 nm, ionization potential: 5.8 eV, electron affinity: 3.0 eV

The structures of copper phthalocyanine, NPD, mCP, BPM-1, BAlq, and Alq are shown above. The structure of HTM-2 is shown below.

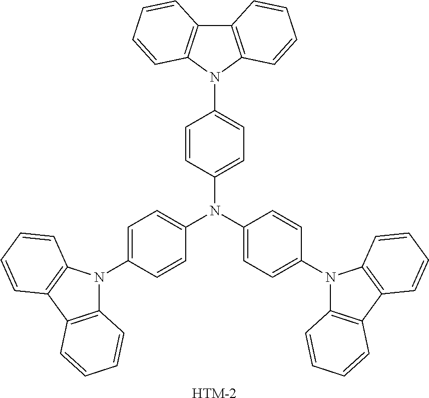

### (7) Preparation of Organic Electroluminescent Device of Example (Device 7)

An organic electroluminescent device of Example (device 7) was prepared in the same manner as the organic electroluminescent device of Comparative Example (device 1), except that the configuration of the organic compound layers was, changed to that below. The ionization potential and the electron affinity of the respective organic compound layers in device 7 are indicated in the configuration.

### (First Hole-Transporting Layer)

Copper phthalocyanine: thickness 10 nm, ionization potential: 5.1 eV, electron affinity: 3.4 eV

### (Second Hole-Transporting Layer)

NPD: thickness: 25 nm, ionization potential: 5.4 eV, electron affinity: 2.4 eV

### (Third Hole-Transporting Layer)

HTM-2: thickness: 5 nm, ionization potential: 5.7 eV, electron affinity: 2.3 eV

### (Luminescent Layer)

Mixed layer of mCP (95% by weight) and BPM-1 (5% by weight): thickness: 35 nm, ionization potential: 6.0 eV, electron affinity: 2.4 eV

### (First Electron-Transporting Layer)

ETM-1: thickness: 5 nm, ionization potential: 6.1 eV, electron affinity: 2.5 eV

### (Second Electron-Transporting Layer)

BAlq: thickness: 5 nm, ionization potential: 5.9 eV, electron affinity: 2.9 eV

### (Third Electron-Transporting Layer)

Alq: thickness: 35 nm, ionization potential: 5.8 eV, electron affinity: 3.0 eV The structures of copper phthalocyanine, NPD, HTM-2, mCP, BPM-1, ETM-1, BAlq, and Alq are shown above.

### (8) Preparation of Organic Electroluminescent Devices of Example (Devices 8 and 9)

An organic electroluminescent device of Example (device 8) was prepared in the same manner as the organic electroluminescent device of Example (device 6) except that HTM-2 in device 6 was changed to HTM-3 shown below.

An organic electroluminescent device of Example (device 9) was prepared in the same manner as the organic electroluminescent device of Example (device 7) except that HTM-2 in device 7 was changed to HTM-3 shown below.

The ionization potential and the electron affinity of the HTM-3 are 5.8 eV and 2.5 eV respectively.

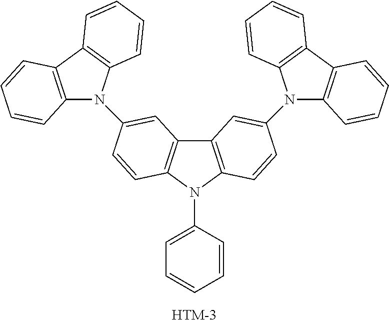

### (9) Preparation of Organic Electroluminescent Devices of Example (Devices 10-15)

Organic electroluminescent devices of Example (devices 10-15) were prepared in the same manner as the organic electroluminescent devices of Example (devices 4 to 9) respectively, except that BPM-1 in devices 4 to 9 was change to BPM-2 shown below.

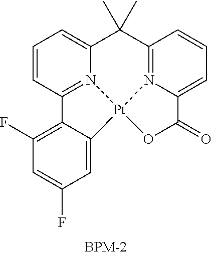

(10) Preparation of an Organic Electroluminescent Device of Comparative Example (device 16)

An organic electroluminescent device of Comparative Example (device 16) was prepared in the same manner as devices 1, except that the configuration of the organic compound layers was changed to that below. The ionization potential and the electron affinity of the respective organic compound layers in device 16 are indicated in the configuration shown below.

### (First Hole-Transporting Layer)

Copper phthalocyanine: thickness 10 nm, ionization potential: 5.1 eV, electron affinity: 3.4 eV

### (Second Hole-Transporting Layer)

NPD: thickness: 25 nm, ionization potential: 5.4 eV, electron affinity: 2.4 eV

### (Third Hole-Transporting Layer)

HTM-1: thickness: 5 nm, ionization potential: 5.8 eV, electron affinity: 2.2 eV

### (Luminescent Layers)

Mixed layer of mCP (95% by weight) and Ir(ppy)₃ (5% by weight): thickness: 30 nm, ionization potential: 6.0 eV, electron affinity: 2.4 eV

Mixed layer of CBP (95% by weight) and Ir(ppy)₃ (5% by weight): thickness: 30 nm, ionization potential: 6.1 eV, electron affinity: 2.7 eV

### (First Electron-Transporting Layer)

BAlq: thickness: 5 nm, ionization potential: 5.9 eV, electron affinity: 2.9 eV

### (Second Electron-Transporting Layer)

Alq: thickness: 40 nm, ionization potential: 5.8 eV, electron affinity: 3.0 eV The structure of Ir(ppy)₃ and CBP are shown below.

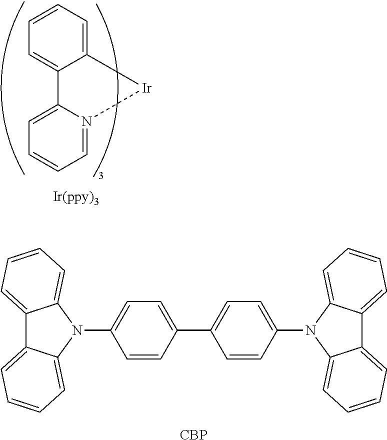

### (11) Preparation of an Organic Electroluminescent Device of Example (Device 17)

An organic electroluminescent device of Example (device 17) was prepared in the same manner as devices 16, except that the configuration of the luminescent layers was changed to that below.

### (Luminescent Layers)

Mixed layer of mCP (95% by weight) and GPM-1 (5% by weight): thickness: 30 nm, ionization potential: 6.0 eV, electron affinity: 2.4 eV

Mixed layer of CBP (95% by weight) and GPM-1 (5% by weight): thickness: 30 nm, ionization potential: 6.1 eV, electron affinity: 2.7 eV

The structure of GPM-1 is shown below.

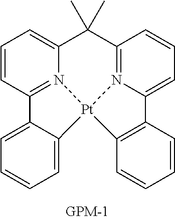

A luminescent device which emits white light can be prepared in the same manner as devices 17, except that the configuration of the organic compound layers was changed to that below.

### (Luminescent Layers)

Mixed layer of CBP (90% by weight) and BPM-1 (10% by weight): thickness: 20 nm

Mixed layer of CBP (95% by weight) and RPM-1 (5% by weight): thickness: 20 nm

The structure of RPM-1 is shown below.

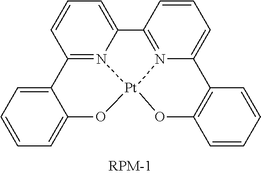

### 2. Evaluation of the Physical Properties of Materials

### (1) Ionization Potential

Each component used for preparation of the organic compound layer was vapor-deposited on a glass plate to a thickness of 50 nm. The ionization potential of the film was determined at room temperature under atmospheric pressure, by using an ultraviolet photoelectron analyzer AC-1 manufactured Riken Keiki Co., Ltd. Results are shown in Table 1.

### (2) Electron Affinity

The ultraviolet/visible absorption spectrum of the film used for measurement of ionization potential was determined in UV3100 Spectrophotometer manufactured by Shimadzu Corporation, and the excitation energy was determined from the energy at the longest wavelength terminal of the absorption spectrum. The electron affinity was calculated from the excitation energy and the ionization potential. Results are shown in Table 1.

TABLE 1

| Compound name | Ionization potential (eV) | Electron affinity (eV) |
|---|---|---|
| CuPc | 5.1 | 3.4 |
| m-MTDATA | 5.1 | 1.9 |
| NPD | 5.4 | 2.4 |
| HTM-1 | 5.8 | 2.2 |
| HTM-2 | 5.7 | 2.3 |
| HMT-3 | 5.8 | 2.5 |
| mCP | 6.0 | 2.4 |
| ETM-1 | 6.1 | 2.5 |
| BAlq | 5.9 | 2.9 |
| Alq | 5.8 | 3.0 |
| BPM-1 | 5.9 | 3.1 |

### 3. Evaluation of Organic Electroluminescent Device

The driving durability of each of the organic electroluminescent devices thus obtained (devices 1 to 17) was evaluated according to the following method:

Constant electric current was applied to the EL devices (device 1 to 17) such that the initial luminance was 300 cd/m². The time the luminance takes to decreased to 150 cd/m² (t_{0.5}) was determined as an indicator of durability.

Regarding devices 1 to 15, when t_{0.5} of device 1 was regarded as 1, the device having a relative value of 3.5 or more was ranked A; that of 1.5 or more and less than 3.5, B; and that of 1.5 or less, C. Results are shown in Table 2.

Regarding devices 16 and 17, when t_{0.5} of device 16 was regarded as 1, the device having a relative value of 3.5 or more was ranked A; that of 1.5 or more and less than 3.5, B; and that of 1.5 or less, C. Results are shown in Table 3.

TABLE 2

| Device number | Driving durability | Remarks |
|---|---|---|
| Device 1 | Standard | Comparative Example |
| Device 2 | B | Example |
| Device 3 | B | Example |
| Device 4 | A | Example |
| Device 5 | A | Example |
| Device 6 | A | Example |
| Device 7 | A | Example |
| Device 8 | A | Example |
| Device 9 | A | Example |
| Device 10 | A | Example |
| Device 11 | A | Example |
| Device 12 | A | Example |
| Device 13 | A | Example |
| Device 14 | A | Example |
| Device 15 | A | Example |

TABLE 3

| Device number | Driving durability | Remarks |
|---|---|---|
| Device 16 | Standard | Comparative Example |
| Device 17 | B | Example |

As shown in Table 2, the organic electroluminescent devices of Examples (devices 2 to 15) have a higher driving durability than the organic electroluminescent device of Comparative Example (device 1).

As shown in Table 3, the organic electroluminescent device of Example (device 17) has a higher driving durability than the organic electroluminescent device of Comparative Example (device 16).

When organic electroluminescent devices were prepared in the same manner as the above-described devices of Example except that BPM-1, BPM-2 or GMP-1 were changed to a compound represented by formula (II) or (III), and were evaluated in the same manner as above, the obtained devices were excellent in driving durability.

The invention provides an organic electroluminescent device having a lower driving voltage and/or a higher driving durability.

The invention also provides an organic electroluminescent device capable of driving at low-voltage, having high driving durability, and superior in luminous efficiency that allows improvement in color purity and emission of lights in various colors (red, green, and/or blue, etc.) by properly selecting the kind of the metal complex having a tri- or higher-dentate ligand.

1. An organic electroluminescent device comprising a plurality of organic compound layers between a pair of electrodes, wherein
the plurality of organic compound layers include a luminescent layer, two or more hole-transporting layers, and two or more electron-transporting layers,
the hole-transporting layers include a layer adjacent to the luminescent layer,
the electron-transporting layers include a layer adjacent to the luminescent layer,
the luminescent layer contains a host material and a luminescent material,
the luminescent material is a metal complex containing a tri- or higher-dentate ligand, and
when the ionization potential of the luminescent layer is designated as Ip₀, the ionization potential of the hole-transporting layer adjacent to the luminescent layer among the hole-transporting layers is designated as Ip₁, and the ionization potential of an n-th hole-transporting layer from the luminescent layer among the hole-transporting layers is designated as Ipₙ, these values satisfy the relationship represented by the following formula (1):
Ip₀> . . . >Ipₙ₋₁>Ipₙ Formula (1)
wherein n is an integer of 2 or more; and
when the electron affinity of the luminescent layer is designated as Ea₀, the electron affinity of the electron-transporting layer adjacent to the luminescent layer among the electron-transporting layers is designated as Ea₁, and the electron affinity of an m-th electron-transporting layer from the luminescent layer among the electron-transporting layers is designated as Eaₘ, these values satisfy the relationship represented by the following formula (2):
Ea₀<Ea₁<Ea₂< . . . <Eaₘ₋₁<Eaₘ Formula (2)
wherein m is an integer of 2 or more.

2. The organic electroluminescent device of claim 1, wherein the ionization potentials of the luminescent layer and the hole-transporting layers satisfy the relationship represented by the following formulae:
Ip₀−IP₁≦0.4 eV, Ip₁−Ip₂≦0.4 eV, . . . , and Ipₙ₋₁−Ipₙ≦0.4 eV.

3. The organic electroluminescent device of claim 1, wherein the tri- or higher-dentate ligand contained in the metal complex is a chained ligand.

4. The organic electroluminescent device of claim 3, wherein the metal complex is a compound represented by formula (I): 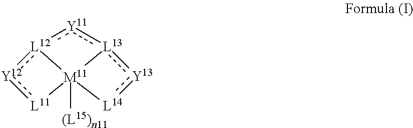
wherein in formula (I), M¹¹ represents a metal ion; L¹¹ to L¹⁵ each independently represent a moiety coordinating to M¹¹; in no case does an additional atomic group connect L¹¹ and L¹⁴ to form a cyclic ligand; in no case is L¹⁵ bound to both L¹¹ and L¹⁴ to form a cyclic ligand; Y¹¹ to Y¹³ each independently represent a connecting group, a single bond, or a double bond; when Y¹¹ is a connecting group, the bond between L¹² and Y¹¹ and the bond between Y¹¹ and L¹³ are each independently a single or double bond; when Y¹² is a connecting group, the bond between L¹¹ and Y¹² and the bond between Y¹² and L¹² are each independently a single or double bond; when Y¹³ is a connecting group, the bond between L¹³ and Y¹³ and the bond between Y¹³ and L¹⁴ are each independently a single or double bond; and n¹¹ represents an integer of 0 to 4.

5. The organic electroluminescent device of claim 3, wherein the metal complex is a compound represented by formula (II): 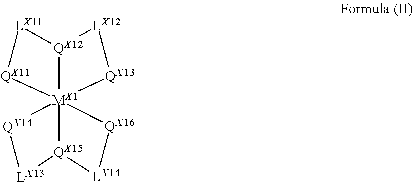
wherein in formula (II), M^{x1} represents a metal ion; Q^{x11} to Q^{x16} each independently represent an atom coordinating to M^{x1} or an atomic group containing an atom coordinating to M^{x1}; and L^{x11} to L^{x14} each independently represent a single bond, a double bond, or a connecting group.

6. The organic electroluminescent device of claim 1, wherein the tri- or higher-dentate ligand contained in the metal complex is a cyclic ligand.

7. The organic electroluminescent device of claim 6, wherein the metal complex is a compound represented by formula 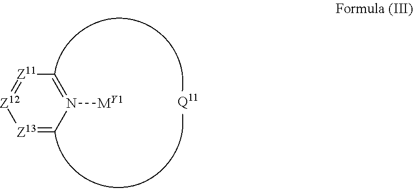
wherein in formula (III), Q¹¹ represents an atomic group forming a nitrogen-containing heterocycle; Z¹¹, Z¹², and Z¹³ each independently represent a substituted or non-substituted carbon or nitrogen atom; and M^{Y1} represents a metal ion which may further have one or more ligand(s).

8. The organic electroluminescent device of claim 1, wherein a metal ion contained in the metal complex is selected from the group consisting of a platinum ion, an iridium ion, a rhenium ion, a palladium ion, a rhodium ion, a ruthenium ion, and a copper ion.

9. The organic electroluminescent device of claim 1, wherein the hole-transporting layers comprise three or more layers.

10. The organic electroluminescent device of claim 1, wherein at least one of the hole-transporting layers comprises an azepine compound, an amine compound, a carbazole compound, a pyrrole compound, or an indole compound.

11. The organic electroluminescent device of claim 1, wherein among the hole-transporting layers the layer adjacent to the luminescent layer comprises an azepine compound, an amine compound, a carbazole compound, a pyrrole compound, or an indole compound.

12. (canceled)

13. The organic electroluminescent device of claim 1, wherein the electron affinities of the luminescent layer and the electron-transporting layers satisfy the relationship represented by the following formulae:
Ea₁−Ea₀≦0.4 eV, Ea₂−Ea₁≦0.4 eV, . . . , and Eaₘ−Eaₘ₋₁≦0.4 eV.

14-19. (canceled)

20. The organic electroluminescent device of claim 1, wherein the electron-transporting layers comprise three or more layers.

21-23. (canceled)

24. An organic electroluminescent device comprising a plurality of organic compound layers between a pair of electrodes, wherein
the plurality of organic compound layers include a first luminescent layer, a second luminescent layer, two or more hole-transporting layers, and two or more electron-transporting layers,
the hole-transporting layers include a layer adjacent to the first luminescent layer,
the electron-transporting layers include a layer adjacent to the second luminescent layer,
each of the first and second luminescent layers contains a host material and a luminescent material,
the host materials contained in the first and second luminescent layers differ from each other, and
each of the luminescent materials contained in the first and second luminescent layers is a metal complex containing a tri- or higher-dentate ligand, and wherein
when the ionization potential of the first luminescent layer is designated as Ip₀, the ionization potential of the hole-transporting layer adjacent to the first luminescent layer among the hole-transporting layers is designated as Ip₁, the ionization potential of an n-th hole-transporting layer from the first luminescent layer among the hole-transporting layers is designated as Ipₙ, the electron affinity of the second luminescent layer is designated as Ea₀, the electron affinity of the electron-transporting layer adjacent to the second luminescent layer among the electron-transporting layers is Ea₁, and the electron affinity of an m-th electron-transporting layer from the second luminescent layer among the electron-transporting sans designated as Eaₘ,
these values satisfy the relationship represented by the following formulae (1) and (2):
Ip₀>Ip₁>Ip₂> . . . >Ipₙ₋₁>Ipₙ formula (1)
wherein n is an integer of 2 or more
Ea₀<Ea₁<Ea₂< . . . <Eaₘ₋₁<Eaₘ formula (2)
wherein m is an integer of 2 or more.

25. (canceled)

26. The organic electroluminescent device of claim 24, wherein the ionization potentials of the luminescent layer and the hole-transporting layers satisfy the relationship represented by the following formulae:
Ip₀−Ip₁≦0.4 eV, Ip₁−Ip₂≦0.4 eV, . . . , and Ipₙ₋₁−Ipₙ≦0.4 eV.

27. The organic electroluminescent device of claim 24, wherein the electron affinities of the luminescent layer and the electron-transporting layers satisfy the relationship represented by the following formulae:
Ea₁−Ea₀<0.4 eV, Ea₂−Ea₁<0.4 eV, . . . , and Eaₘ−Eaₘ₋₁<0.4 eV

28. The organic electroluminescent device of claim 24, wherein the tri- or higher-dentate ligand contained in the metal complex is a chained ligand.

29. The organic electroluminescent device of claim 28, wherein the metal complex is a compound represented by formula (I): 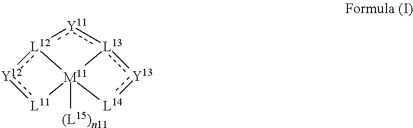
wherein in formula (I), M¹¹ represents a metal ion; L¹¹ to L¹⁵ each independently represent a moiety coordinating to M¹¹; in no case does an additional atomic group connect L¹¹ and L¹⁴ to form a cyclic ligand; in no case is L¹⁵ bound to both L¹¹ and L¹⁴ to form a cyclic ligand; Y¹¹ to Y¹³ each independently represent a connecting group, a single bond, or a double bond; when Y¹¹ is a connecting group, the bond between L¹² and Y¹¹ and the bond between Y¹¹ and L¹³ are each independently a single or double bond; when Y¹² is a connecting group, the bond between L¹¹ and Y¹² and the bond between Y¹² and L¹² are each independently a single or double bond; when Y¹³ is a connecting group, the bond between L¹³ and Y¹³ and the bond between Y¹³ and L¹⁴ are each independently a single or double bond; and n¹¹ represents an integer of 0 to 4.

30. The organic electroluminescent device of claim 28, wherein the metal complex is a compound represented by formula (II): 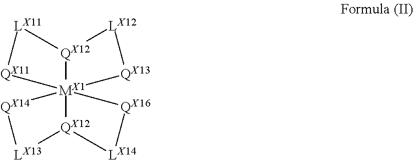
wherein in formula (II), M^{x} represents a metal ion; Q^{x11} to Q^{x16} each independently represent an atom coordinating to M^{x1} or an atomic group containing an atom coordinating to M^{x1}; and L^{x11} to L^{x14} each independently represent a single bond, a double bond, or a connecting group.

31. The organic electroluminescent device of claim 24, wherein the tri- or higher-dentate ligand contained in the metal complex is a cyclic ligand.

32. The organic electroluminescent device of claim 31, wherein the metal complex is a compound represented by formula (III): 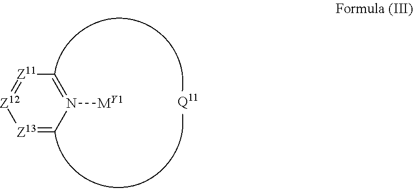
wherein in formula (III), Q¹¹ represents an atomic group forming a nitrogen-containing heterocycle; Z¹¹, Z¹², and Z¹³ each independently represent a substituted or non-substituted carbon or nitrogen atom; and M^{Y1} represents a metal ion which may further have one or more ligand(s).

33. The organic electroluminescent device of claim 24, wherein a metal ion contained in the metal complex is selected from the group consisting of a platinum ion, an iridium ion, a rhenium ion, a palladium ion, a rhodium ion, a ruthenium ion, and a copper ion.

34. The organic electroluminescent device of claim 24, wherein the hole-transporting layers comprise three or more layers.

35. The organic electroluminescent device of claim 24, wherein the electron-transporting layers comprise three or more layers.

36. The organic electroluminescent device of claim 24, wherein at least one of the hole-transporting layers comprises an azepine compound, an amine compound, a carbazole compound, a pyrrole compound, or an indole compound.

37. The organic electroluminescent device of claim 24, wherein among the hole-transporting layers the layer adjacent to the first luminescent layer comprises an azepine compound, an amine compound, a carbazole compound, a pyrrole compound, or an indole compound.

38. The organic electroluminescent device of claim 1, wherein the luminescent layer further comprises a second luminescent material.

39. The organic electroluminescent device of claim 38, wherein the second luminescent material is one of a fluorescent luminescent material and a phosphorescent luminescent material.

40. The organic electroluminescent device of claim 38, wherein the second luminescent material is a metal complex having a tridentate or higher-dentate ligand.
